(19) United States
(12) Patent Application Publication
(10) Pub. No.: US 2018/0094086 A1
(43) Pub. Date: Apr. 5, 2018

(54) NEAR INFRARED ABSORBING COMPOSITION, NEAR INFRARED CUT FILTER, METHOD OF MANUFACTURING NEAR INFRARED CUT FILTER, DEVICE, METHOD OF MANUFACTURING COPPER-CONTAINING POLYMER, AND COPPER-CONTAINING POLYMER

(71) Applicant: FUJIFILM Corporation, Tokyo (JP)

(72) Inventors: Kouitsu SASAKI, Haibara-gun (JP); Takashi KAWASHIMA, Haibara-gun (JP); Seiichi HITOMI, Haibara-gun (JP)

(73) Assignee: FUJIFILM Corporation, Tokyo (JP)

(21) Appl. No.: 15/821,363

(22) Filed: Nov. 22, 2017

Related U.S. Application Data
(63) Continuation of application No. PCT/JP2016/062246, filed on Apr. 18, 2016.

(30) Foreign Application Priority Data
Jun. 24, 2015 (JP) 2015-126879
Mar. 23, 2016 (JP) 2016-058470

(51) Int. Cl. C08F 8/42; H01L 27/148; H01L 27/146; G02B 5/20

(52) U.S. Cl. CPC C08F 8/42; H01L 27/14806; C08F 2810/50; G02B 5/208; C08F 2800/20; H01L 27/14621

(57) ABSTRACT

The near infrared absorbing composition includes: a copper-containing polymer having a copper complex site at a polymer side chain; and a solvent, in which the copper complex site includes a site multidentate-coordinated to a copper atom and at least one selected from the group consisting of a site monodentate-coordinated to a copper atom and a counter ion to a copper complex skeleton, and a polymer main chain and a copper atom at the copper complex site are bonded to each other through the site monodentate-coordinated to a copper atom or the counter ion.

### CROSS-REFERENCE TO RELATED APPLICATIONS

This application is a Continuation of PCT International Application No. PCT/JP2016/062246 filed on Apr. 18, 2016, which claims priority under 35 U.S.C § 119 (a) to Japanese Patent Application No. 2015-126879 filed on Jun. 24, 2015, and Japanese Patent Application No. 2016-058470 filed on Mar. 23, 2016. Each of the above application(s) is hereby expressly incorporated by reference, in its entirety, into the present application.

### BACKGROUND OF THE INVENTION

### 1. Field of the Invention

The present invention relates to a near infrared absorbing composition, a near infrared cut filter, a method of manufacturing a near infrared cut filter, a device, a method of manufacturing a copper-containing polymer, and a copper-containing polymer.

### 2. Description of the Related Art

In a video camera, a digital still camera, a mobile phone with a camera function, or the like, a charge coupled device (CCD) or a complementary metal-oxide semiconductor (CMOS), which is a solid image pickup element, is used. In a light receiving section of this solid image pickup element, a silicon photodiode having sensitivity to near infrared light is used. Therefore, it is necessary to correct visibility, and a near infrared cut filter is used in many cases.

As a material of the near infrared cut filter, for example, a copper compound is used.

JP2015-4943A describes a near infrared absorbing composition that includes a copper-containing polymer obtained from a reaction of a copper component and a polymer having an aromatic hydrocarbon group and/or an aromatic heterocyclic group at a main chain and having an acid group or a salt thereof.

JP2010-134457A describes a near infrared cut filter that includes a copper-containing polymer obtained from a reaction of a polymer having a phosphate group and a copper component.

JP1999-52127A (H11-52127A) describes a near infrared cut filter obtained by polymerization of a copper phosphate complex having a vinyl group.

### SUMMARY OF THE INVENTION

The present inventors performed an investigation on the near infrared cut filters described in JP2015-4943A, JP2010-134457A, and JP1999-52127A (H11-52127A), and found that heat resistance of the near infrared cut filters described in JP2010-134457A and JP1999-52127A (H11-52127A) is poor.

In addition, the present inventors performed an investigation on a copper-containing polymer in various ways and found that, depending on the kind of a ligand, it may be difficult to synthesize a copper-containing polymer using a method of the related art.

Accordingly, an object of the present invention is to provide a near infrared absorbing composition with which a film having excellent heat resistance and near infrared shielding properties can be formed, a near infrared cut filter, a method of manufacturing a near infrared cut filter, a device, a method of manufacturing a copper-containing polymer, and a copper-containing polymer.

The present inventors performed an investigation on a copper-containing polymer and found that a copper-containing polymer having excellent heat resistance can be easily manufactured by causing a polymer having a reactive site at a polymer side chain to react with a copper complex having a functional group which is reactive with the reactive site of the polymer.

Further, the present inventors performed an investigation on the copper-containing polymer manufactured using the above-described method and found that a film having excellent heat resistance and high near infrared shielding properties can be formed by using a copper-containing polymer satisfying any one of the following requirements (1) and (2), thereby completing the present invention.

(1) A copper-containing polymer having a copper complex site at a polymer side chain, in which the copper complex site includes a site multidentate-coordinated to a copper atom and at least one selected from the group consisting of a site monodentate-coordinated to a copper atom and a counter ion to a copper complex skeleton and in which a polymer main chain and a copper atom at the copper complex site are bonded to each other through the site monodentate-coordinated to a copper atom or the counter ion.

(2) A copper-containing polymer having a copper complex site at a polymer side chain, the copper-containing polymer including a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond between a polymer main chain and the copper complex site. In this case, in a case where the linking group has a —C(═O)O— bond, the linking group has at least one —C(═O)O— bond which is not directly bonded to the polymer main chain, and in a case where the linking group has a —NH—CO— bond, the linking group has at least one —NH—CO— bond which is not directly bonded to the polymer main chain.

The present invention provides the following.

<1> A near infrared absorbing composition comprising:

a copper-containing polymer having a copper complex site at a polymer side chain; and

a solvent,

in which the copper complex site includes a site multidentate-coordinated to a copper atom and at least one selected from the group consisting of a site monodentate-coordinated to a copper atom and a counter ion to a copper complex skeleton, and

a polymer main chain and a copper atom at the copper complex site are bonded to each other through the site monodentate-coordinated to a copper atom or the counter ion.

<2> A near infrared absorbing composition comprising:

a copper-containing polymer having a copper complex site at a polymer side chain; and

a solvent,

in which the copper-containing polymer includes a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond between a polymer main chain and the copper complex site,

in a case where the linking group has a —C(═O)O— bond, the linking group has at least one —C(═O)O— bond which is not directly bonded to the polymer main chain, and

in a case where the linking group has a —NH—CO— bond, the linking group has at least one —NH—CO— bond which is not directly bonded to the polymer main chain.

<3> The near infrared absorbing composition according to <1> or <2>,

in which the copper-containing polymer includes a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, and a —NH—C(═S)NH— bond between the polymer main chain and the copper complex site.

<4> A near infrared absorbing composition comprising:

a copper-containing polymer that is obtained by causing a polymer having a reactive site at a polymer side chain to react with a copper complex having a functional group which is reactive with the reactive site of the polymer; and

a solvent.

<5> The near infrared absorbing composition according to any one of <1> to <4>,

in which 10 mass % or higher of the copper-containing polymer is dissolved in cyclohexanone at 25° C.

<6> The near infrared absorbing composition according to any one of <1> to <5>,

in which the number of atoms constituting a chain that links the copper atom and the polymer main chain in the copper-containing polymer is 8 or more.

<7> The near infrared absorbing composition according to any one of <1> to <6>,

comprising:

a copper-containing polymer having a group represented by the following Formula (1) at a polymer side chain,

*-L¹-Y¹ (1),

in which in Formula (1), L¹ represents a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond,

Y¹ represents a copper complex site,

* represents a direct bond to the polymer,

in a case where L¹ has a —C(═O)O— bond, L¹ has at least one —C(═O)O— bond which is not directly bonded to the polymer main chain, and

in a case where L¹ has a —NH—CO— bond, L¹ has at least one —NH—CO— bond which is not directly bonded to the polymer main chain.

<8> The near infrared absorbing composition according to any one of <1> to <7>,

in which the copper-containing polymer includes a constitutional unit represented by the following Formula (A1-1),

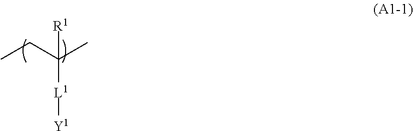

in Formula (A1-1), R¹ represents a hydrogen atom or a hydrocarbon group,

L¹ represents a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond,

Y¹ represents a copper complex site,

in a case where L¹ has a —C(═O)O— bond, L¹ has at least one —C(═O)O— bond which is not directly bonded to the polymer main chain, and

in a case where L¹ has a —NH—CO— bond, L¹ has at least one —NH—CO— bond which is not directly bonded to the polymer main chain.

<9> The near infrared absorbing composition according to any one of <1> to <8>,

in which the copper-containing polymer includes constitutional units represented by the following Formulae (A1-1-1), (A1-1-2), or (A1-1-3),

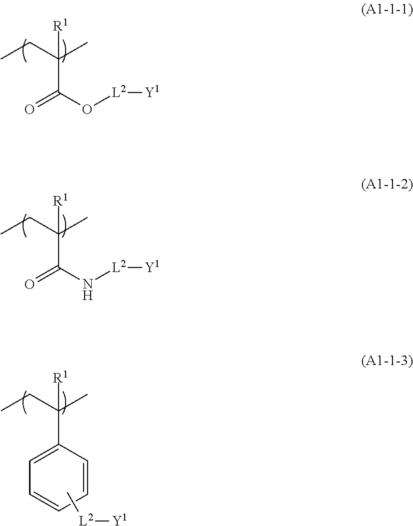

in Formulae (A1-1-1) to (A1-1-3), R¹ represents a hydrogen atom or a hydrocarbon group,

L² represents a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond, and

Y¹ represents a copper complex site.

<10> The near infrared absorbing composition according to any one of <1> to <9>,

in which the copper-containing polymer includes a site tetradentate- or pentadentate-coordinated to a copper atom.

<11> The near infrared absorbing composition according to any one of <1> to <10>, which is a composition for forming a near infrared cut filter.

<12> A near infrared cut filter which is formed using the near infrared absorbing composition according to any one of <1> to <11>.

<13> A method of manufacturing a near infrared cut filter,

in which the near infrared absorbing composition according to any one of <1> to <11> is used.

<14> A device comprising:

the near infrared cut filter according to <12>,

in which the device is at least one selected from the group consisting of a solid image pickup element, a camera module, and an image display device.

<15> A method of manufacturing a copper-containing polymer comprising: causing a polymer having a reactive site at a polymer side chain to react with a copper complex having a functional group which is reactive with the reactive site of the polymer.

<16> A copper-containing polymer having a copper complex site at a polymer side chain,

in which the copper complex site includes a site multidentate-coordinated to a copper atom and at least one selected from the group consisting of a site monodentate-coordinated to a copper atom and a counter ion to a copper complex skeleton, and

a polymer main chain and a copper atom at the copper complex site are bonded to each other through the site monodentate-coordinated to a copper atom or the counter ion.

<17> A copper-containing polymer having a copper complex site at a polymer side chain,

in which the copper-containing polymer includes a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond between a polymer main chain and the copper complex site,

in a case where the linking group has a —C(═O)O— bond, the linking group has at least one —C(═O)O— bond which is not directly bonded to the polymer main chain, and

in a case where the linking group has a —NH—CO— bond, the linking group has at least one —NH—CO— bond which is not directly bonded to the polymer main chain.

<18> A copper-containing polymer that is obtained by causing a polymer having a reactive site at a polymer side chain to react with a copper complex having a functional group which is reactive with the reactive site of the polymer.

According to the present invention, a near infrared absorbing composition with which a film having excellent heat resistance and near infrared shielding properties can be formed, a near infrared cut filter, a method of manufacturing a near infrared cut filter, a device, a method of manufacturing a copper-containing polymer, and a copper-containing polymer can be provided.

### BRIEF DESCRIPTION OF THE DRAWINGS

FIG. 1 is a schematic cross-sectional view showing a configuration of a camera module including a near infrared cut filter according to an embodiment of the present invention.

FIG. 2 is a schematic cross-sectional view showing an example of the vicinity of the near infrared cut filter in the camera module.

FIG. 3 is a schematic cross-sectional view showing an example of the vicinity of the near infrared cut filter in the camera module.

FIG. 4 is a schematic cross-sectional view showing an example of the vicinity of the near infrared cut filter in the camera module.

### DESCRIPTION OF THE PREFERRED EMBODIMENTS

Hereinafter, the details of the present invention will be described. In this specification of the present application, numerical ranges represented by “to” include numerical values before and after “to” as lower limit values and upper limit values.

In this specification, “(meth)acrylate” denotes acrylate and methacrylate, “(meth)acryl” denotes acryl and methacryl, and “(meth)acryloyl” denotes acryloyl and methacryloyl.

In this specification, “monomer” is distinguished from “oligomer” and “polymer” and denotes a compound having a molecular weight of 2000 or lower.

In this specification, “polymerizable compound” denotes a compound having a polymerizable group. “Polymerizable group” denotes a group relating to a polymerization reaction.

In this specification, unless specified as a substituted group or as an unsubstituted group, a group (atomic group) denotes not only a group (atomic group) having no substituent but also a group (atomic group) having a substituent.

In this specification, in a chemical formula, Me represents a methyl group, Et represents an ethyl group, Pr represents a propyl group, Bu represents a butyl group, and Ph represents a phenyl group.

In this specification, “near infrared light” denotes light (electromagnetic wave) in a wavelength range of 700 to 2500 nm.

In this specification, “total solid content” denotes the total mass of all the components of a composition excluding a solvent.

In this specification, “solid content” denotes a solid content at 25° C.

In this specification, “weight-average molecular weight” and “number-average molecular weight” are defined as values in terms of polystyrene obtained by gel permeation chromatography (GPC).

<Near Infrared Absorbing Composition>

A near infrared absorbing composition according to the present invention includes a copper-containing polymer described below and a solvent.

By using the near infrared absorbing composition according to the present invention, a film having high near infrared shielding properties and excellent heat resistance can be formed. The reason why this effect is obtained is not clear but is presumed to be that, since the copper-containing polymer used in the present invention has a copper complex site at a polymer side chain, a crosslinked structure is formed between side chains of the polymer with a copper atom as a source, and a film having excellent heat resistance can be obtained.

<<Copper-Containing Polymer>>

The near infrared absorbing composition according to the present invention includes a copper-containing polymer.

In the near infrared absorbing composition according to the present invention, the content of the copper-containing polymer is preferably 30 mass % or higher, more preferably 50 mass % or higher, still more preferably 70 to 100 mass %, and even still more preferably 80 to 100 mass % with respect to the total solid content of the near infrared absorbing composition. For example, the upper limit may be 99 mass % or lower, 98 mass % or lower, or 95 mass % or lower. By increasing the content of the copper-containing polymer, near infrared shielding properties can be improved. As the copper-containing polymer, one kind or two or more kinds may be used. In a case where two or more copper-containing polymers are used, it is preferable that the total content of the copper-containing polymers is in the above-described range.

It is preferable that the copper-containing polymer according to the present invention satisfies any one of the following requirements (1) and (2).

(1) A copper-containing polymer having a copper complex site at a polymer side chain, in which the copper complex site includes a site multidentate-coordinated to a copper atom and at least one selected from the group consisting of a site monodentate-coordinated to a copper atom and a counter ion to a copper complex skeleton and in which a polymer main chain and a copper atom at the copper complex site are bonded to each other through the site monodentate-coordinated to a copper atom or the counter ion.

(2) A copper-containing polymer having a copper complex site at a polymer side chain, the copper-containing polymer including a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond between a polymer main chain and the copper complex site. In this case, in a case where the linking group has a —C(═O)O— bond, the linking group has at least one —C(═O)O— bond which is not directly bonded to the polymer main chain, and in a case where the linking group has a —NH—CO— bond, the linking group has at least one —NH—CO— bond which is not directly bonded to the polymer main chain.

The copper-containing polymer satisfying any one of the requirements can be manufactured using a method of causing a polymer having a reactive site at a polymer side chain to react with a copper complex having a functional group which is reactive with the reactive site of the polymer (hereinafter, this method also referred to as “the manufacturing method according to the present invention”).

That is, it is preferable that the copper-containing polymer according to the present invention is a copper-containing polymer that is obtained by causing a polymer having a reactive site at a polymer side chain to react with a copper complex having a functional group which is reactive with the reactive site of the polymer.

Examples of a preferable combination of the reactive site of the polymer and the functional group of the copper complex and a bond formed from the reaction include the following (1) to (12). Among these, (1) to (6) are preferable. In the following formulae, the left side represents the reactive site of the polymer and the functional group of the copper complex, and the right side represents a bond that is obtained by causing them to react with each other. R represents a hydrogen atom or an alkyl group and may be bonded to the polymer main chain. X represents a halogen atom.

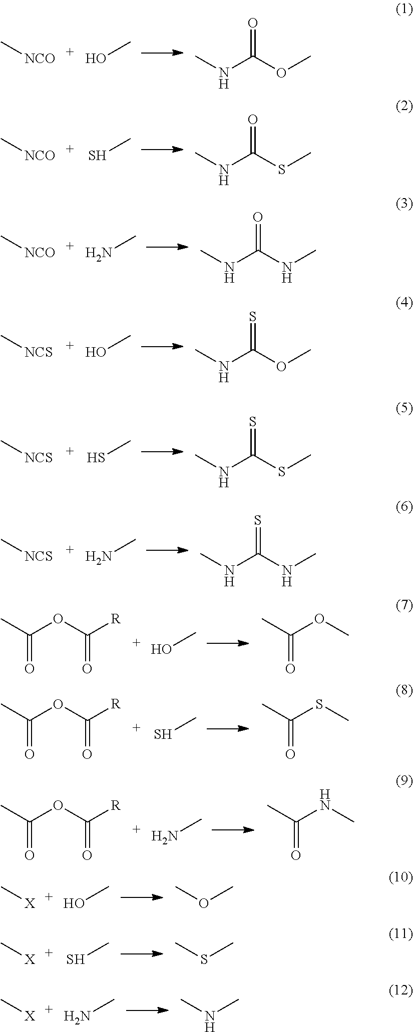

For example, in a case where R is bonded to the polymer main chain, (7) to (9) have the following structure.

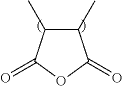

In addition, the copper-containing polymer satisfying any one of the requirements can also be manufactured using a method other than the manufacturing method according to the present invention.

For example, the copper-containing polymer satisfying the requirement (1) can be manufactured by causing a polymer having a site monodentate-coordinated to a copper atom at a polymer side chain, a copper compound, and a compound having a site bi- or higher coordinated to a copper atom to react with each other.

In addition, the copper-containing polymer satisfying the requirement (1) can also be manufactured by reacting a polymer having a counter ion to a copper complex skeleton, a copper compound, and a compound having a site bi- or higher coordinated to a copper atom to react with each other.

The copper-containing polymer satisfying the requirement (2) can be manufactured by causing a site monodentate-coordinated to a copper atom or a site bi- or higher coordinated to a copper atom to react with a copper compound through a linking group having the above-described bond at a polymer side chain.

In addition, the copper-containing polymer satisfying the requirement (2) can be manufactured by causing a polymer having a counter ion to a copper complex skeleton to react with a copper compound through a linking group having the above-described bond at a polymer side chain.

It is preferable that 10 mass % or higher of the copper-containing polymer according to the present invention is dissolved in cyclohexanone at 25° C. In a case where the solubility in cyclohexanone is high, the concentration of the copper-containing polymer in the near infrared absorbing composition can be increased. Therefore, a thick film can be applied, and a film having excellent near infrared shielding properties can be formed. In particular, by using the manufacturing method according to the present invention, deformation of the copper complex during the synthesis of the copper-containing polymer is not likely to occur. Therefore, the solubility in cyclohexanone can be increased. In the present invention, the solubility of the copper-containing polymer in cyclohexanone is a value measured using a method in Examples described below.

In the copper-containing polymer according to the present invention, the number of atoms constituting a chain that links the copper atom and the polymer main chain in the copper-containing polymer is preferably 8 or more, more preferably 10 or more, and still more preferably 12 or more. For example, the upper limit is preferably 20 or less. For example, in the following formula, the number of atoms constituting a chain that links the copper atom and the polymer main chain is 14.

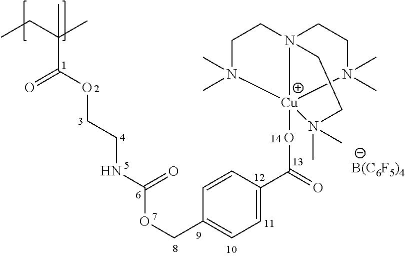

In the present invention, “polymer main chain” denotes a chain linking constitutional units of the polymer. For example, in the following polymers, a chain linking atoms to which numerical values are added is a polymer main chain. In the following formulae, R^{x1} represents a substituent.

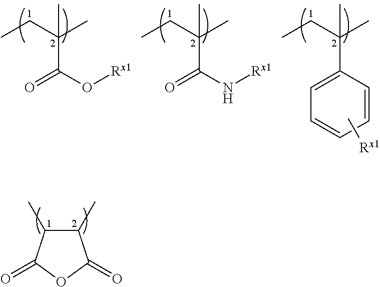

It is preferable that the copper-containing polymer according to the present invention has a group represented by the following Formula (1) at a polymer side chain.

*-L¹-Y (1)

In Formula (1), L¹ represents a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond, Y¹ represents a copper complex site, and * represents a direct bond to the polymer.

In this case, in a case where L¹ has a —C(═O)O— bond, L¹ has at least one —C(═O)O— bond which is not directly bonded to the polymer main chain, and in a case where L¹ has a —NH—CO— bond, L¹ has at least one —NH—CO— bond which is not directly bonded to the polymer main chain.

It is preferable that L¹ represents a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, and a —NH—C(═S)NH— bond.

Examples of the linking group represented by L¹ include a linking group having the above-described bond, and a linking group having a combination of the above-described bond and at least one selected from the group consisting of an alkylene group, an arylene group, a heteroarylene group, —O—, —S—, —CO—, —C(═O)O—, —SO₂—, and NR¹⁰ (R¹⁰ represents a hydrogen atom or an alkyl group and preferably a hydrogen atom). Among these, a linking group having a combination of the above-described bond and at least one selected from the group consisting of an alkylene group, an arylene group, —CO—, —C(═O)O—, and —NR¹⁰— is preferable, and a linking group having a combination of the above-described bond and at least one selected from the group consisting of an alkylene group, an arylene group, and —C(═O)O— is more preferable.

The number of carbon atoms in the alkylene group is preferably 1 to 30, more preferably 1 to 15, and still more preferably 1 to 10. The alkylene group may have a substituent but is preferably unsubstituted. The alkylene group may be linear, branched, or cyclic. In addition, the cyclic alkylene group may be monocyclic or polycyclic.

As the arylene group, an arylene group having 6 to 18 carbon atoms is preferable, an arylene group having 6 to 14 carbon atoms is more preferable, an arylene group having 6 to 10 carbon atoms is still more preferable, and a phenylene group is even still more preferable.

The heteroarylene group is not particularly limited, and a 5-membered or 6-membered ring is preferable. Examples of the kind of a heteroatom constituting the heteroarylene group include an oxygen atom, a nitrogen atom, and a sulfur atom. The number of heteroatoms constituting the heteroarylene group is preferably 1 to 3. The heteroarylene group may be a monocycle or a fused ring and is preferably a monocycle or a fused ring composed of 2 to 8 rings, and more preferably a monocycle or a fused ring composed of 2 to 4 rings.

Y¹ represents a copper complex site.

The copper complex site includes a copper atom and a site (coordination site) coordinated to a carbon atom. Examples of the site coordinated to a copper atom include a site coordinated by an anion or an unshared electron pair. In addition, it is preferable that the copper complex site includes a site tetradentate- or pentadentate-coordinated to a copper atom. According to this aspect, infrared absorption capability can be further improved. Hereinafter, the copper complex site will be described.

(Copper Complex Site)

In the present invention, it is preferable that the copper complex site includes a ligand (also referred to as “multidentate ligand”) having at least two coordination sites. The number of coordination sites in the multidentate ligand is more preferably at least 3, still more preferably 3 to 5, and even still more preferably 4 or 5. The multidentate ligand acts as a chelating ligand to a copper component. That is, at least two coordination sites of the multidentate ligand is chelate-coordinated to a copper atom. As a result, it is presumed that a structure of the copper complex is modified, high transmittance in a visible range can be obtained, infrared absorption capability can be improved, and color value can also be improved. Thus, even in a case where a near infrared cut filter is used for a long period of time, characteristics thereof do not deteriorate, and a camera module can be stably manufactured.

The multidentate ligand may have only two or more coordination sites coordinated by an anion, may have only two or more coordination sites coordinated by an unshared electron pair, or may have one coordination site coordinated by an anion and one coordination site coordinated by an unshared electron pair.

Examples of an aspect in which the multidentate ligand has three coordination sites include an aspect in which the multidentate ligand has three coordination sites coordinated by an anion, an aspect in which the multidentate ligand has two coordination sites coordinated by an anion and one coordination site coordinated by an unshared electron pair, an aspect in which the multidentate ligand has one coordination site coordinated by an anion and two coordination sites coordinated by an unshared electron pair, and an aspect in which the multidentate ligand has three coordination sites coordinated by an unshared electron pair.

Examples of an aspect in which the multidentate ligand has four coordination sites include an aspect in which the multidentate ligand has four coordination sites coordinated by an anion, an aspect in which the multidentate ligand has three coordination sites coordinated by an anion and one coordination site coordinated by an unshared electron pair, an aspect in which the multidentate ligand has two coordination sites coordinated by an anion and two coordination sites coordinated by an unshared electron pair, and an aspect in which the multidentate ligand has one coordination site coordinated by an anion and three coordination sites coordinated by an unshared electron pair, and an aspect in which the multidentate ligand has four coordination sites coordinated by an unshared electron pair.

Examples of an aspect in which the multidentate ligand has five coordination sites include an aspect in which the multidentate ligand has five coordination sites coordinated by an anion, an aspect in which the multidentate ligand has four coordination sites coordinated by an anion and one coordination site coordinated by an unshared electron pair, an aspect in which the multidentate ligand has three coordination sites coordinated by an anion and two coordination sites coordinated by an unshared electron pair, an aspect in which the multidentate ligand has two coordination sites coordinated by an anion and three coordination sites coordinated by an unshared electron pair, an aspect in which the multidentate ligand has one coordination site coordinated by an anion and four coordination sites coordinated by an unshared electron pair, and an aspect in which the multidentate ligand has five coordination sites coordinated by an unshared electron pair.

In the multidentate ligand, the anion may be an anion capable of coordination to a copper atom and is preferably an oxygen anion, a nitrogen anion, or a sulfur anion.

It is preferable that the coordination site coordinated by an anion is at least one selected from the following Group (AN-1) of monovalent functional groups or Group (AN-2) of divalent functional groups. In the following structural formulae, a wave line represents a binding site to an atomic group constituting a multidentate ligand.

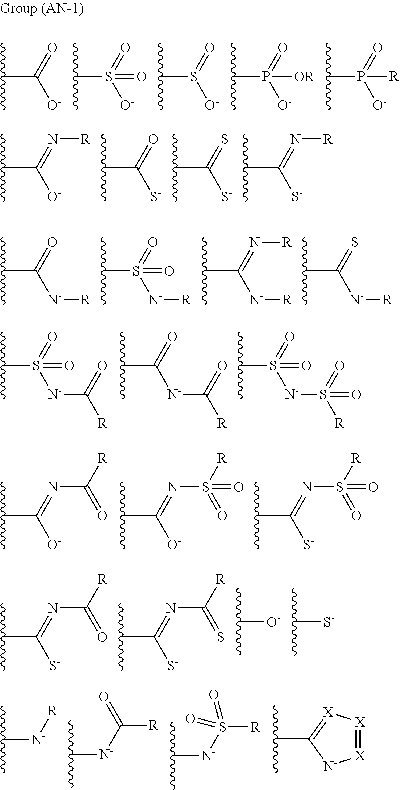

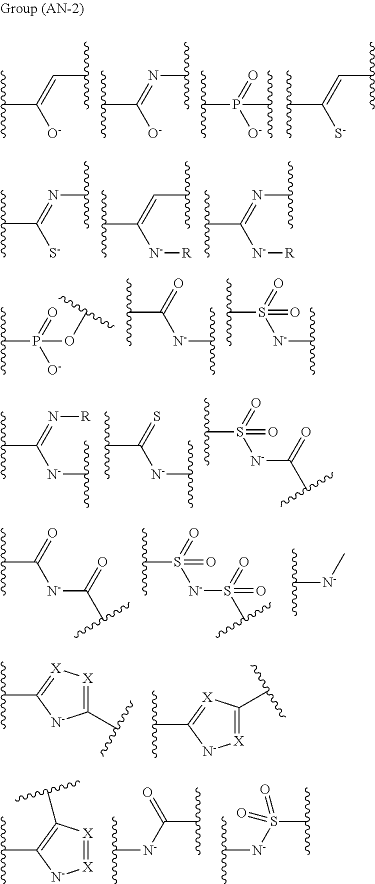

In the coordination site coordinated by an anion, it is preferable that X represents an N atom or CR and R represents a hydrogen atom, an alkyl group, an alkenyl group, an alkynyl group, an aryl group, or a heteroaryl group.

The alkyl group may be linear, branched, or cyclic and is preferably linear. The number of carbon atoms in the alkyl group is preferably 1 to 10, more preferably 1 to 6, and still more preferably 1 to 4. Examples of the alkyl group include a methyl group. The alkyl group may have a substituent. Examples of the substituent include a halogen atom, a carboxy group, and heterocyclic group. The heterocyclic group as the substituent may be monocyclic or polycyclic and may be aromatic or nonaromatic. The number of heteroatoms constituting the heterocycle is preferably 1 to 3 and more preferably 1 or 2. It is preferable that the heteroatom constituting the heterocycle is a nitrogen atom. In a case where the alkyl group has a substituent, the substituent may further have a substituent.

The alkenyl group may be linear, branched, or cyclic and is preferably linear. The number of carbon atoms in the alkenyl group is preferably 2 to 10 and more preferably 2 to 6. The alkenyl group may be unsubstituted or may have a substituent. Examples of the substituent include the above-described substituents.

The alkynyl group may be linear, branched, or cyclic and is preferably linear. The number of carbon atoms in the alkynyl group is preferably 2 to 10 and more preferably 2 to 6. The alkynyl group may be unsubstituted or may have a substituent. Examples of the substituent include the above-described substituents.

The aryl group may be monocyclic or polycyclic and is preferably monocyclic. The number of carbon atoms in the aryl group is preferably 6 to 18, more preferably 6 to 12, and still more preferably 6. The aryl group may be unsubstituted or may have a substituent. Examples of the substituent include the above-described substituents.

The heteroaryl group may be monocyclic or polycyclic. The number of heteroatoms constituting the heteroaryl group is preferably 1 to 3. It is preferable that the heteroatoms constituting the heteroaryl group are a nitrogen atom, a sulfur atom, or an oxygen atom. The number of carbon atoms in the heteroaryl group is preferably 1 to 18 and more preferably 1 to 12. The heteroaryl group may have a substituent or may be unsubstituted. Examples of the substituent include the above-described substituents.

As a coordinating atom coordinated by an unshared electron pair in the multidentate ligand, an oxygen atom, a nitrogen atom, a sulfur atom, or a phosphorus atom is preferable, an oxygen atom, a nitrogen atom, or a sulfur atom is more preferable, and an oxygen atom or a nitrogen atom is still more preferable.

In a case where the coordinating atom coordinated by an unshared electron pair in the multidentate ligand is a nitrogen atom, it is preferable that an atom adjacent to the nitrogen atom is a carbon atom or a nitrogen atom.

It is preferable that the coordinating atom coordinated by an unshared electron pair is included in a ring or at least one partial structure selected from the following Group (UE-1) of monovalent functional groups, Group (UE-2) of divalent functional groups, and Group (UE-3) of trivalent functional groups. In the following structural formulae, a wave line represents a binding site to an atomic group constituting a multidentate ligand.

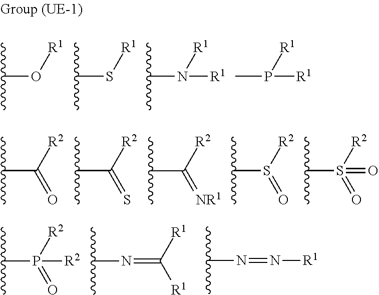

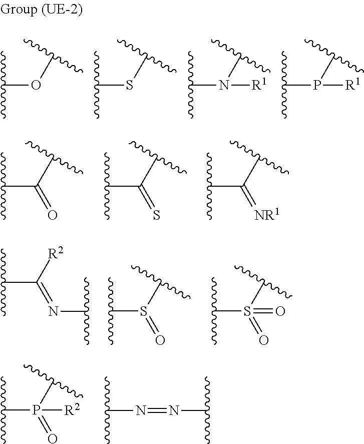

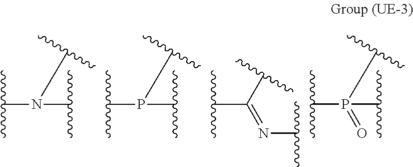

In Groups (UE-1) to (UE-3), R¹ represents a hydrogen atom, an alkyl group, an alkenyl group, an alkynyl group, an aryl group, or a heteroaryl group, and R² represents a hydrogen atom, an alkyl group, an alkenyl group, an alkynyl group, an aryl group, a heteroaryl group, an alkoxy group, an aryloxy group, a heteroaryloxy group, an alkylthio group, an arylthio group, a heteroarylthio group, an amino group, or an acyl group.

The coordinating atom coordinated by an unshared electron pair is included in a ring. In a case where the coordinating atom coordinated by an unshared electron pair is included in a ring, the ring including the coordinating atom coordinated by an unshared electron pair may be monocyclic or polycyclic and may be aromatic or nonaromatic. The ring including the coordinating atom coordinated by an unshared electron pair is preferably a 5- to 12-membered ring and more preferably a 5- to 7-membered ring.

The ring including the coordinating atom coordinated by an unshared electron pair may have a substituent. Examples of the substituent include a linear, branched, or cyclic alkyl group having 1 to 10 carbon atoms, an aryl group having 6 to 12 carbon atoms, a halogen atom, a silicon atom, an alkoxy group having 1 to 12 carbon atoms, an acyl group having 2 to 12 carbon atoms, an alkylthio group having 1 to 12 carbon atoms, and a carboxy group.

In a case where the ring including the coordinating atom coordinated by an unshared electron pair has a substituent, the substituent may further have a substituent. Examples of the substituent include a group which includes a ring including a coordinating atom coordinated by an unshared electron pair, a group which includes at least one partial structure selected from Groups (UE-1) to (UE-3), an alkyl group having 1 to 12 carbon atoms, an acyl group having 2 to 12 carbon atoms, and a hydroxyl group.

In a case where the coordinating atom coordinated by an unshared electron pair is included in a partial structure selected from Groups (UE-1) to (UE-3), R¹ represents a hydrogen atom, an alkyl group, an alkenyl group, an alkynyl group, an aryl group, or a heteroaryl group, and R² represents a hydrogen atom, an alkyl group, an alkenyl group, an alkynyl group, an aryl group, a heteroaryl group, an alkoxy group, an aryloxy group, a heteroaryloxy group, an alkylthio group, an arylthio group, a heteroarylthio group, an amino group, or an acyl group.

The alkyl group, the alkenyl group, the alkynyl group, the aryl group, and the heteroaryl group have the same definitions and the same preferable ranges as the alkyl group, the alkenyl group, the alkynyl group, the aryl group, and the heteroaryl group described above regarding the coordination site coordinated by an anion.

The number of carbon atoms in the alkoxy group is preferably 1 to 12 and more preferably 3 to 9.

The number of carbon atoms in the aryloxy group is preferably 6 to 18 and more preferably 6 to 12.

The heteroaryloxy group may be monocyclic or polycyclic. The heteroaryl group constituting the heteroaryloxy group has the same definition and the same preferable range as the heteroaryl group described above regarding the coordination site coordinated by an anion. The number of carbon atoms in the alkylthio group is preferably 1 to 12 and more preferably 1 to 9.

The number of carbon atoms in the arylthio group is preferably 6 to 18 and more preferably 6 to 12.

The heteroarylthio group may be monocyclic or polycyclic. The heteroaryl group constituting the heteroarylthio group has the same definition and the same preferable range as the heteroaryl group described above regarding the coordination site coordinated by an anion.

The number of carbon atoms in the acyl group is preferably 2 to 12 and more preferably 2 to 9.

R¹ represents preferably a hydrogen atom, an alkyl group, an alkenyl group, or an alkynyl group, more preferably a hydrogen atom or an alkyl group, and still more preferably an alkyl group. The number of carbon atoms in the alkyl group is preferably 1 to 3. By the substituent on the N atom, that is, R¹ representing an alkyl group, transmittance in a visible range is further improved. The reason is not clear but is presumed to be that, since the energy level of the ligand orbital changes, charge transfer transition between the ligand and a copper atom shifts to a shorter wavelength.

In a case where the multidentate ligand has two or more coordinating atoms coordinated by an unshared electron pair in one molecule, the number of coordinating atoms coordinated by an unshared electron pair may be 3 or more and is preferably 2 to 5 and more preferably 4.

The number of atoms linking the coordinating atoms coordinated by an unshared electron pair is preferably 1 to 6, more preferably 1 to 3, and still more preferably 2 or 3.

With the above-described configuration, the structure of the copper complex is more likely modified, and thus color value can be further improved.

As the atom linking the coordinating atoms coordinated by an unshared electron pair, one kind or two or more kinds may be used. As the atom linking the coordinating atoms coordinated by an unshared electron pair, a carbon atom is preferable.

It is preferable that the multidentate ligand is represented by any one of the following Formulae (IV-1) to (IV-14). For example, in a case where the multidentate ligand has four coordination sites, the following Formula (IV-3), (IV-6), (IV-7), or (IV-12) is preferable, and the following formula (IV-12) is more preferable because the multidentate ligand can be more strongly coordinated to the metal center to form a stable pentadentate-coordinated complex having high heat resistance. In addition, in a case where the multidentate ligand has five coordination sites, the following Formula (IV-4), (IV-8) to (IV-11), (IV-13), or (IV-14) is preferable, and the following formula (IV-9), (IV-10), (IV-13), or (IV-14) is more preferable because the multidentate ligand can be more strongly coordinated to the metal center to form a stable pentadentate-coordinated complex having high heat resistance.

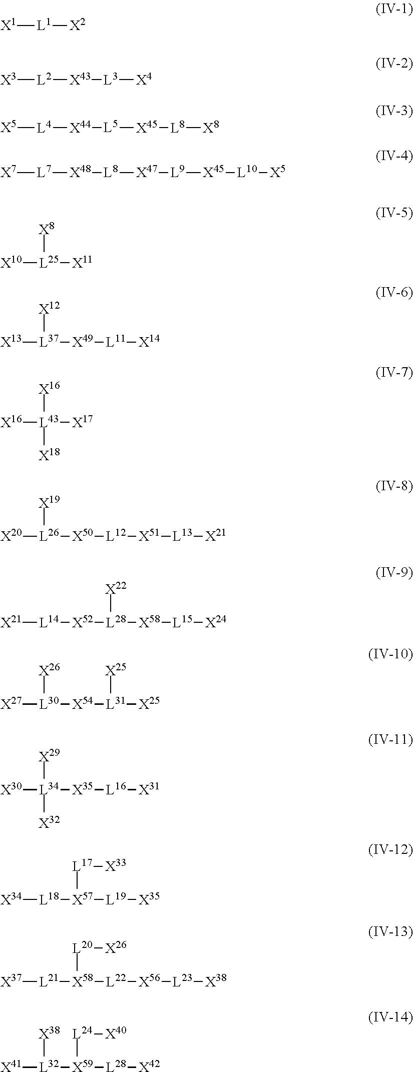

In Formulae (IV-1) to (IV-14), it is preferable that X¹ to X⁵⁹ each independently represent a coordination site, L¹ to L²⁵ each independently represent a single bond or a divalent linking group, L²⁶ to L³² each independently represent a trivalent linking group, and L³³ to L³⁴ each independently represent a tetravalent linking group.

It is preferable that X¹ to X⁴² each independently represent a group which includes a ring including a coordinating atom coordinated by an unshared electron pair or at least one selected from Group (AN-1) or Group (UE-1).

It is preferable that X⁴³ to X⁵⁶ each independently represent a group which includes a ring including a coordinating atom coordinated by an unshared electron pair or at least one selected from Group (AN-2) or Group (UE-2).

It is preferable that X⁵⁷ to X⁵⁹ each independently represent at least one selected from Group (UE-3).

L¹ to L²⁵ each independently represent a single bond or a divalent linking group. As the divalent linking group, an alkylene group having 1 to 12 carbon atoms, an arylene group having 6 to 12 carbon atoms, —SO—, —O—, —SO₂—, or a group including a combination of the above-described groups is preferable, and an alkylene group having 1 to 3 carbon atoms, a phenylene group, —SO₂—, or a group of a combination of the above-described groups is more preferable.

L²⁶ to L³² each independently represent a trivalent linking group. Examples of the trivalent linking group include a group obtained by removing one hydrogen atom from the divalent linking group.

L³³ to L³⁴ each independently represent a tetravalent linking group. Examples of the tetravalent linking group include a group obtained by removing two hydrogen atoms from the divalent linking group.

Here, regarding R in Groups (AN-1) and (AN-2) and R¹ in Groups (UE-1) to (UE-3), R's, R¹'s, or R and R¹ may be linked to each other to form a ring. For example, specific examples of Formula (IV-2) include the following Formula (IV-2A). X³, X⁴, and X⁴³ represent the following groups, L² and L³ represent a methylene group, and R¹ represents a methyl group. R¹'s may be linked to each other to form a ring and have a structure represented by the following Formula (IV-2B) or (IV-2C).

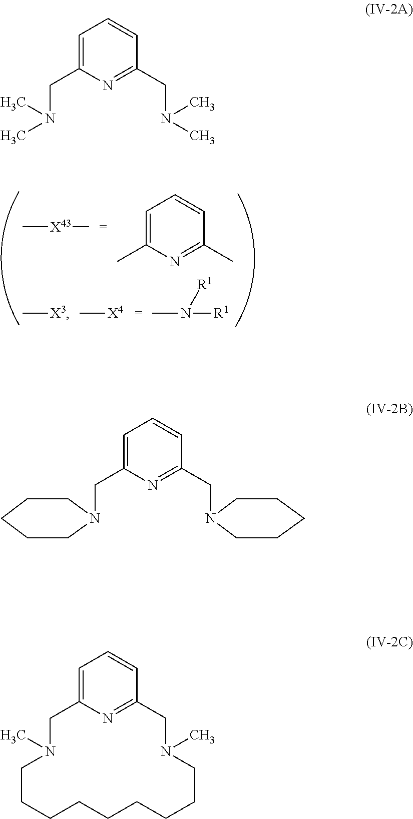

Specific examples of the multidentate ligand are as follows.

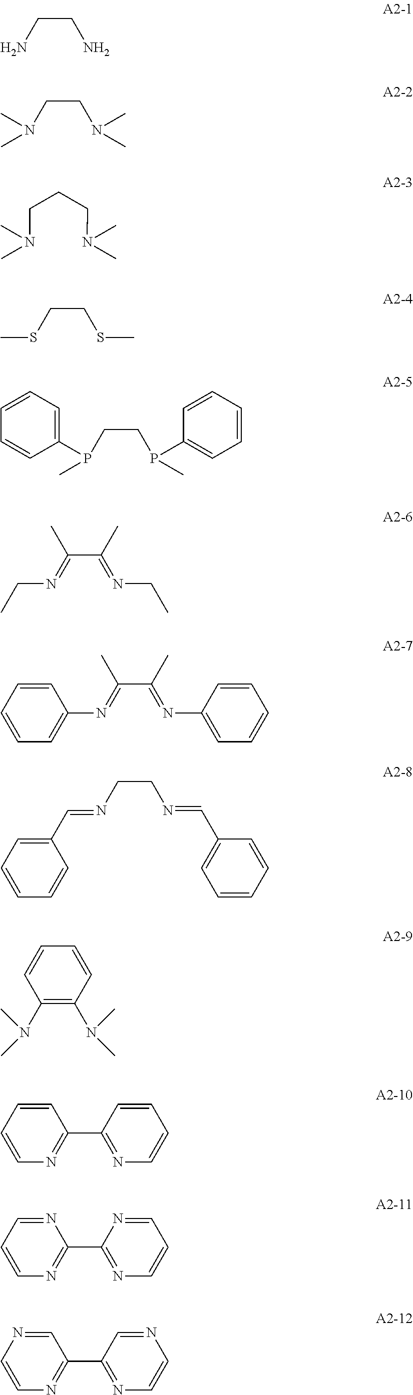

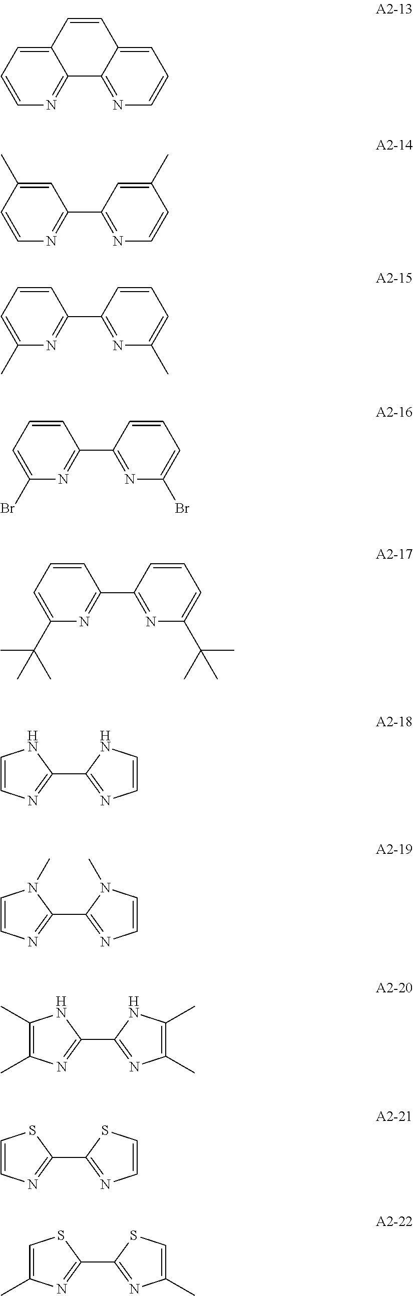

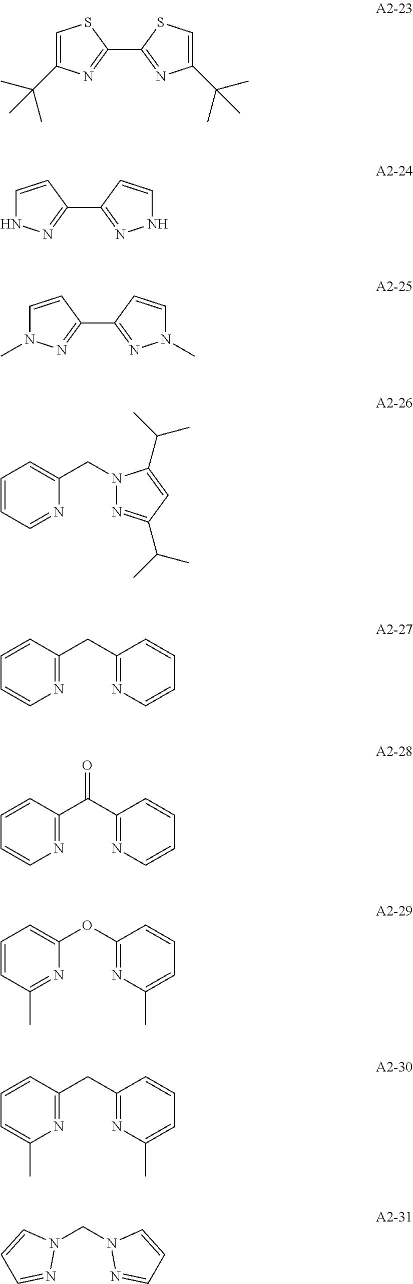

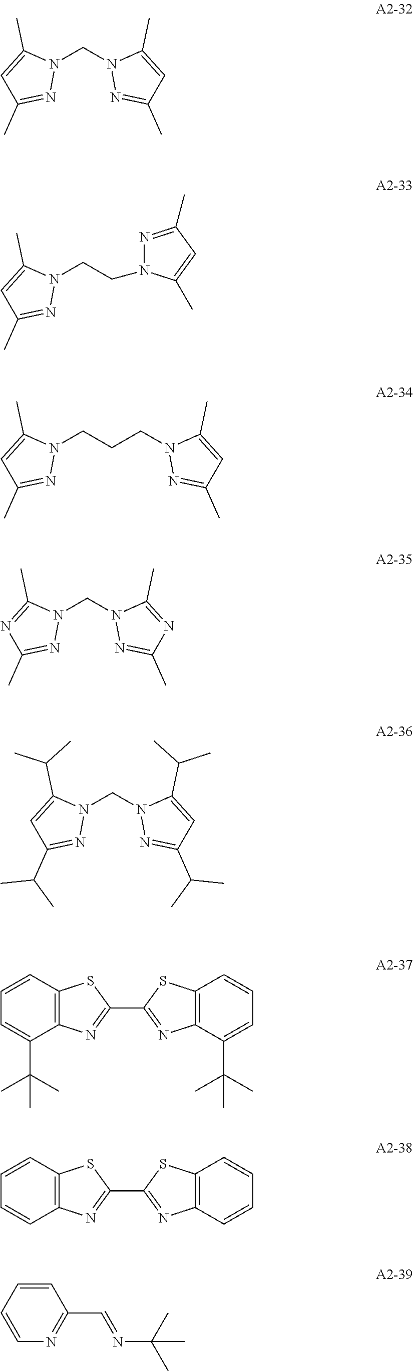

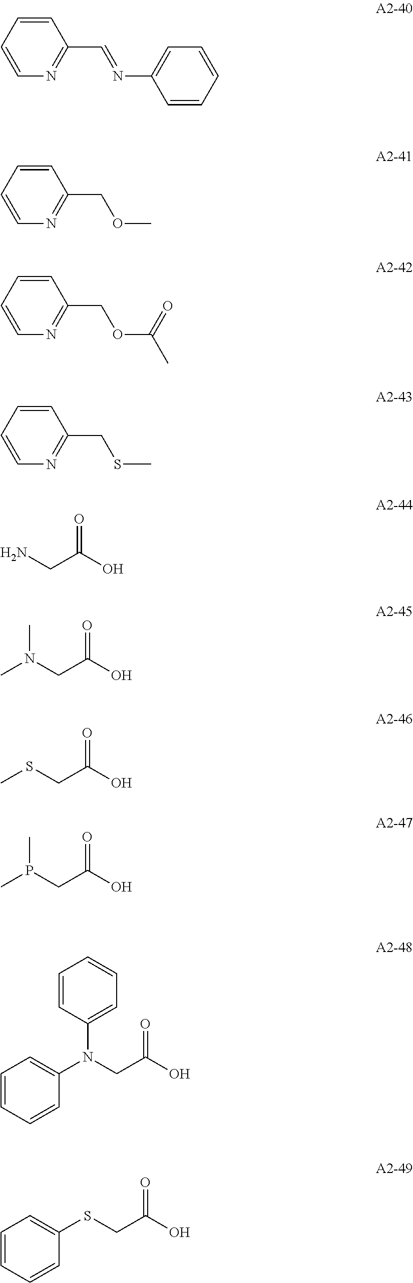

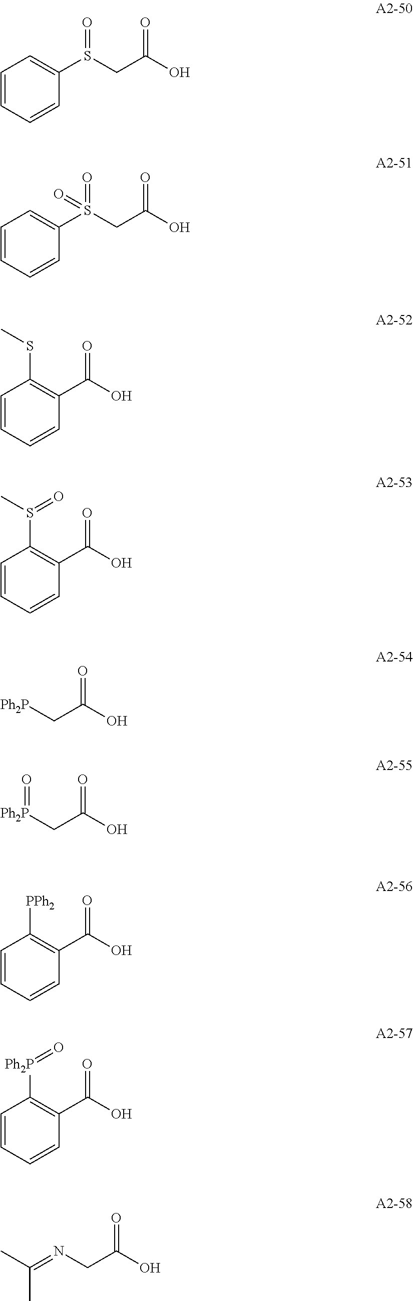

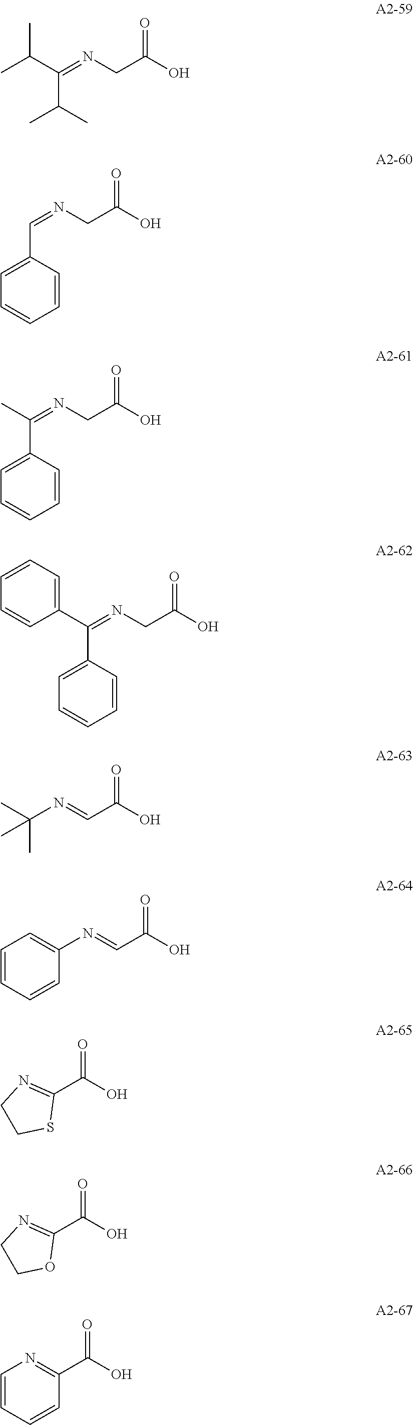

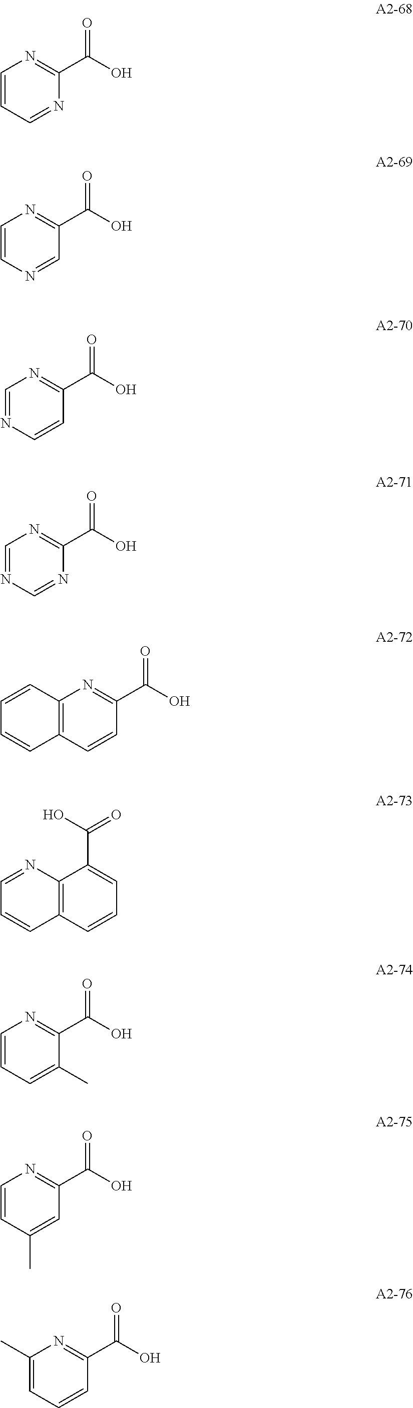

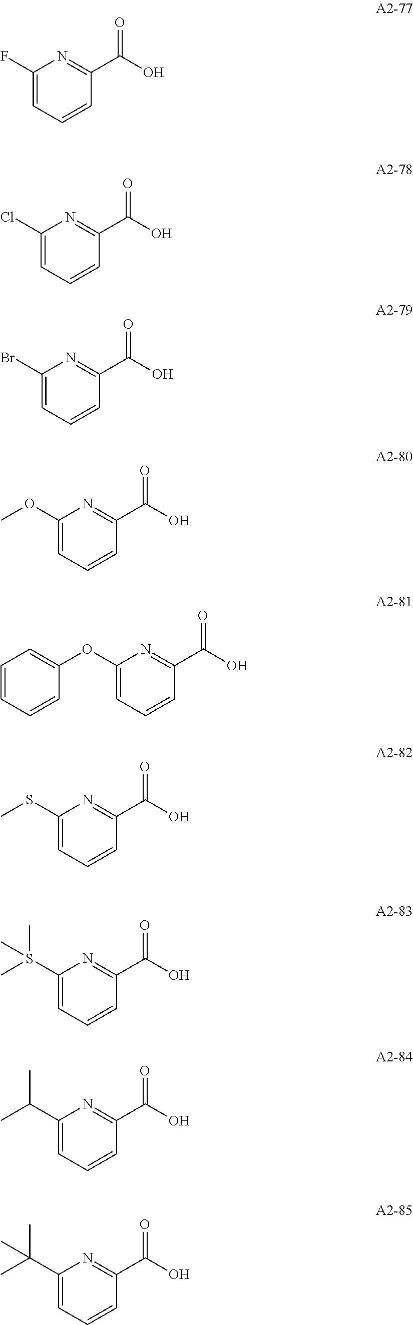

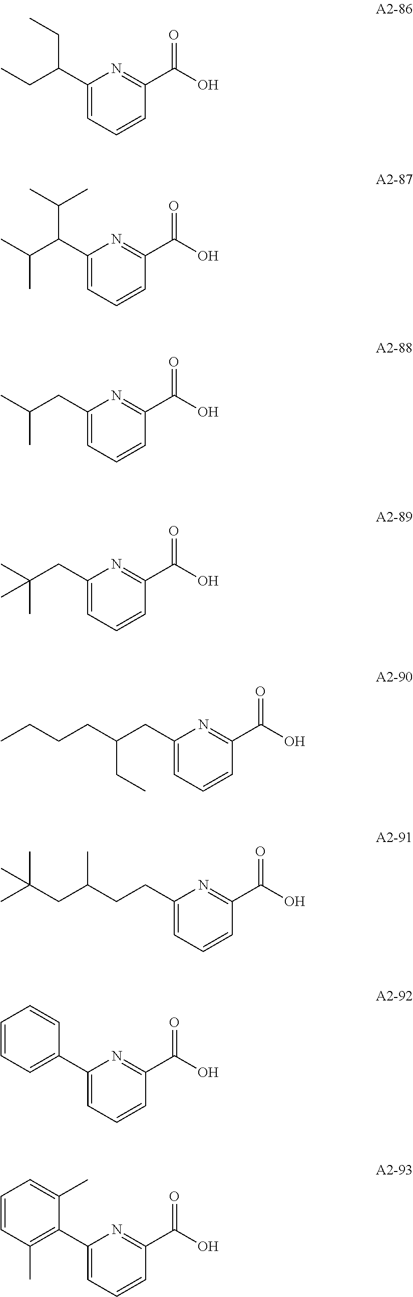

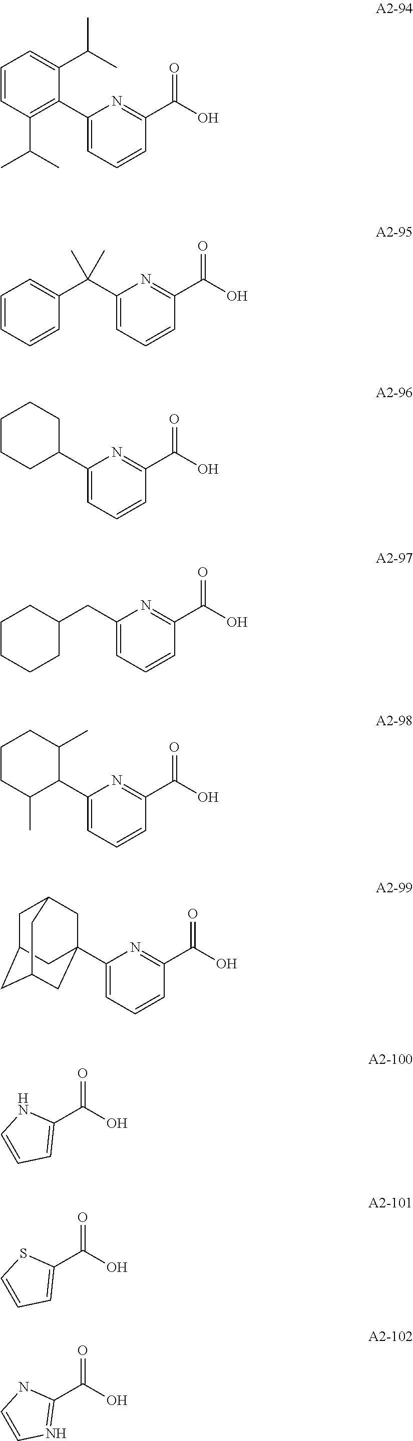

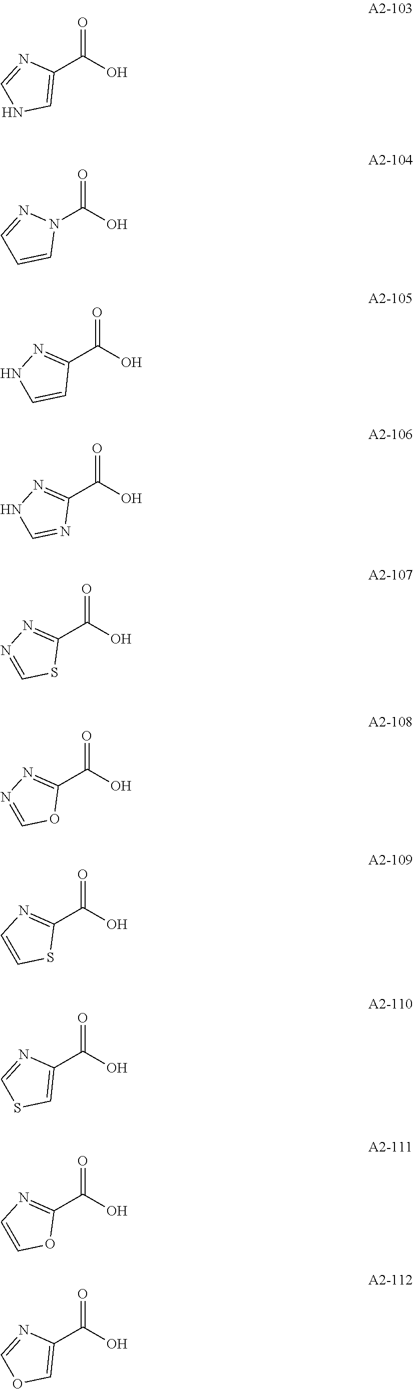

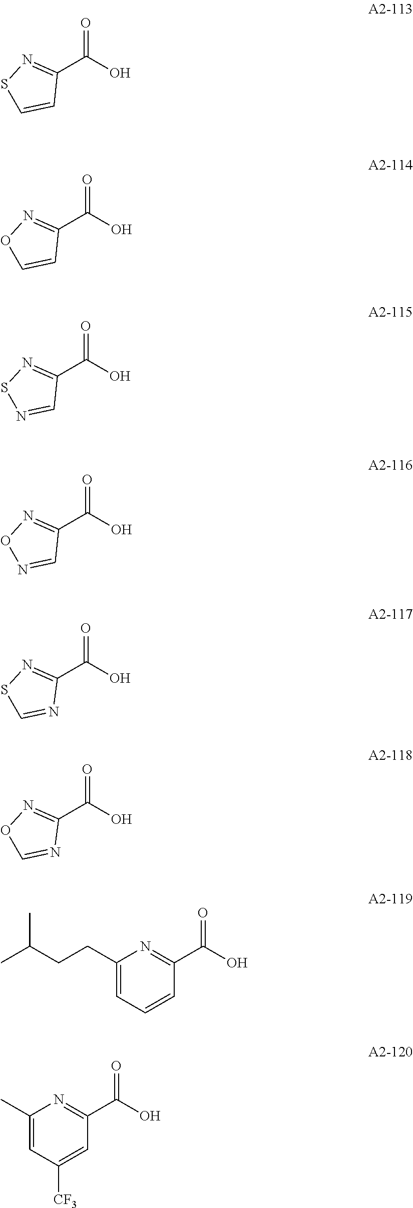

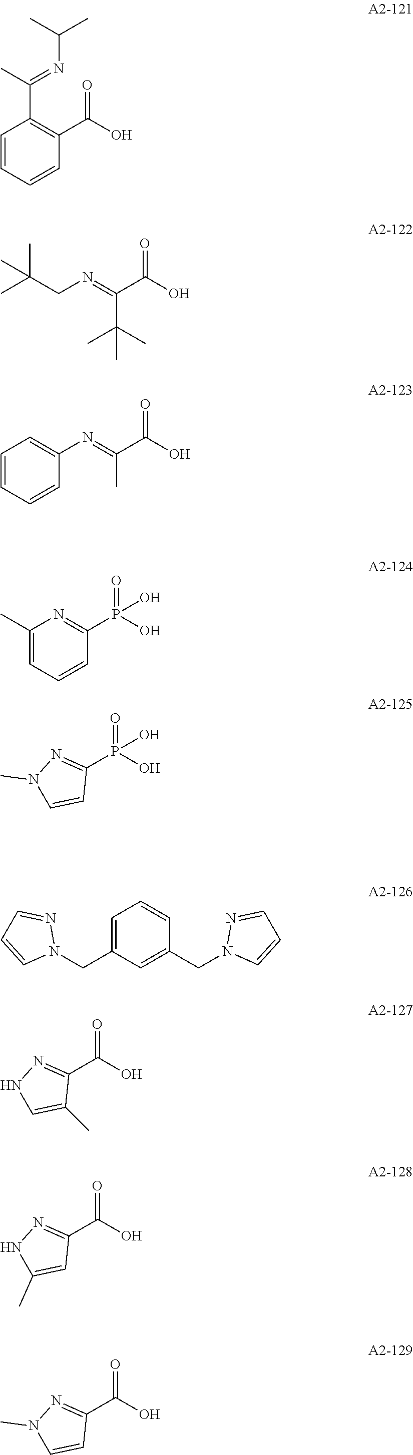

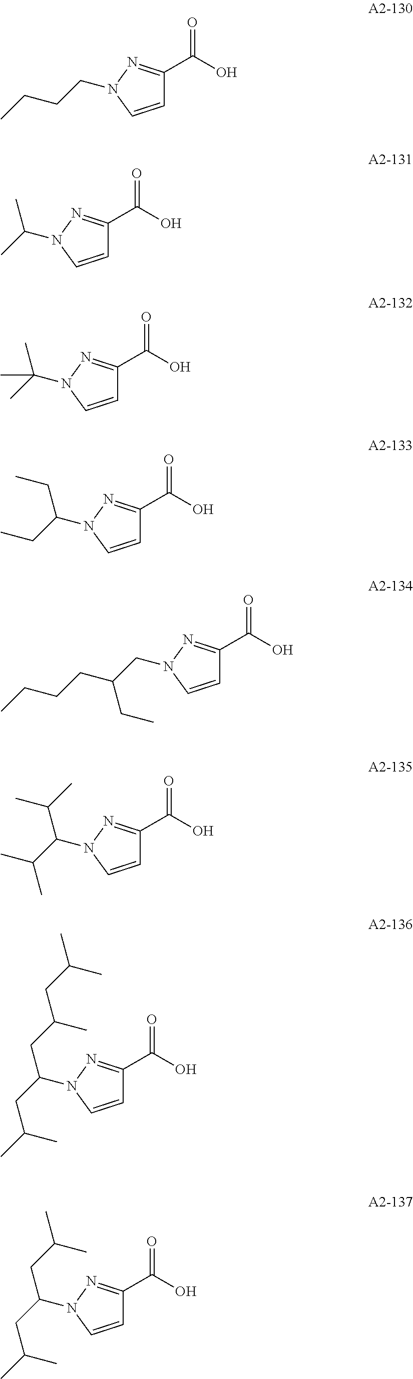

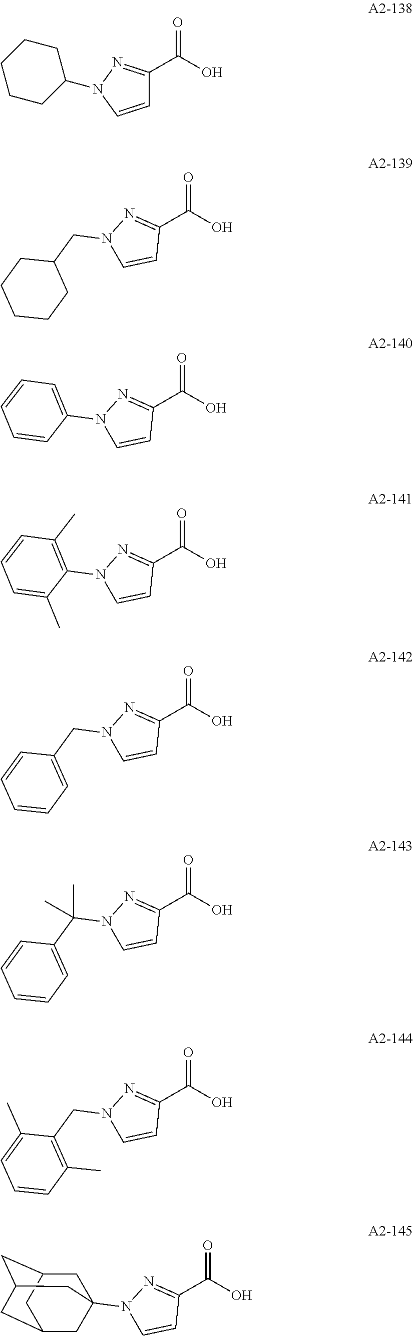

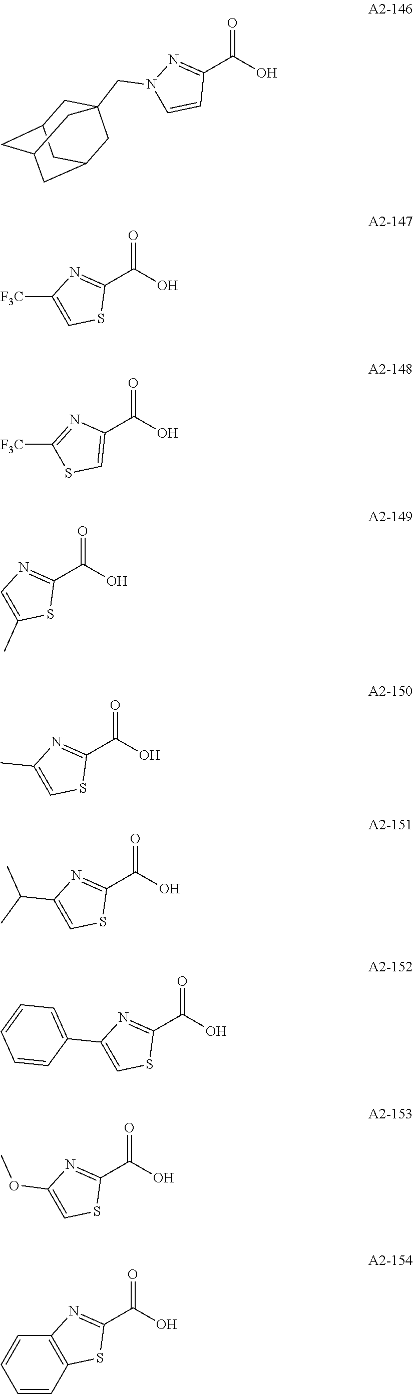

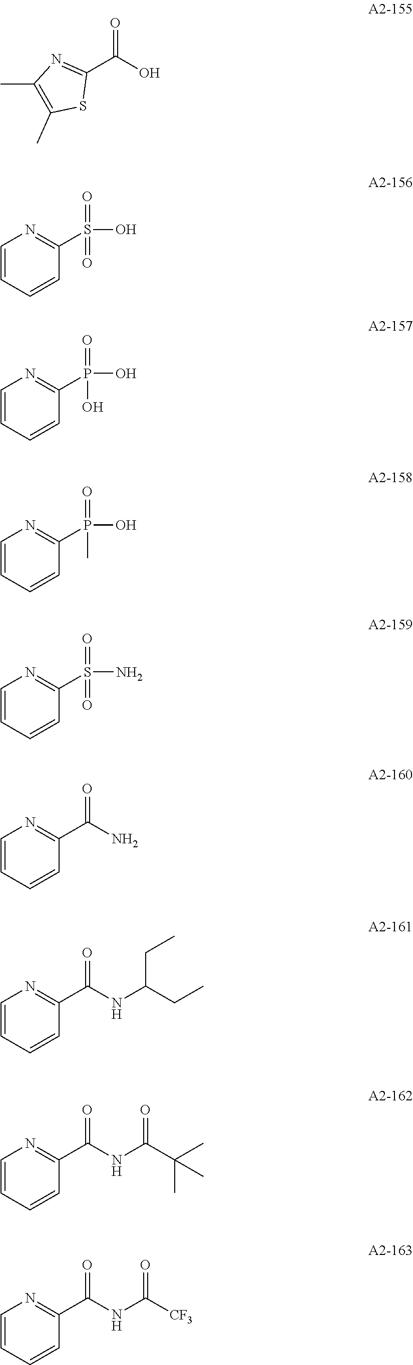

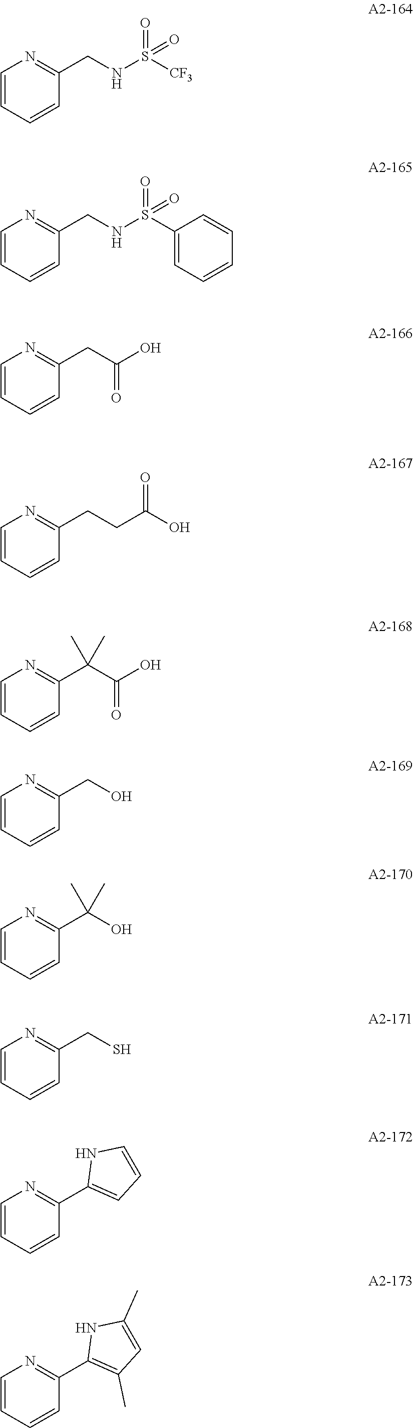

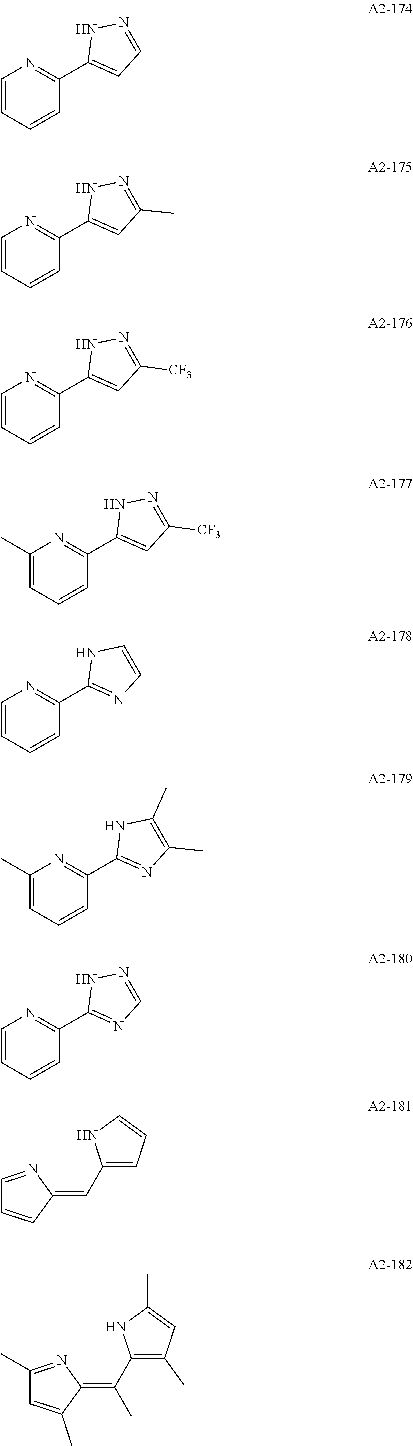

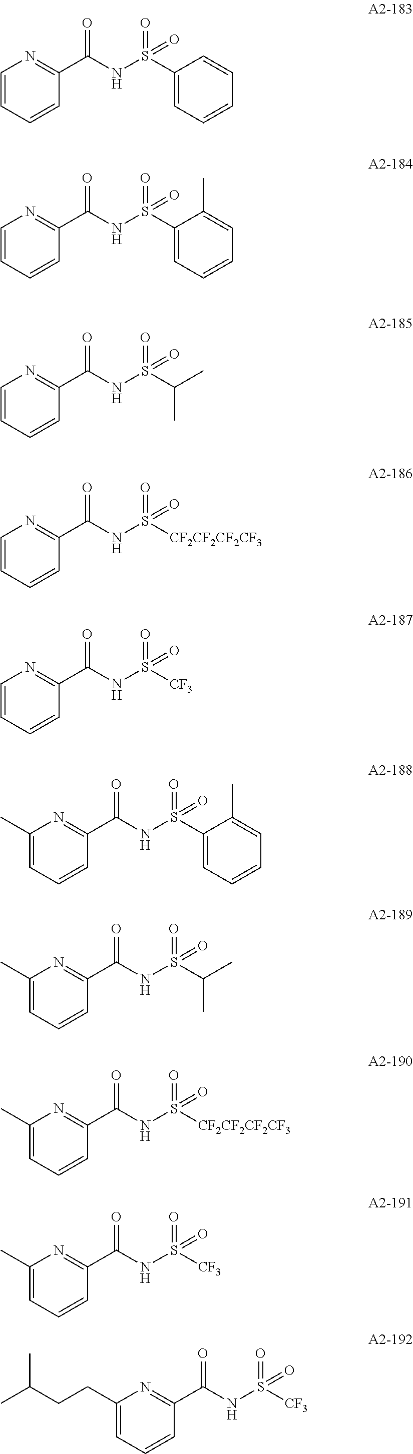

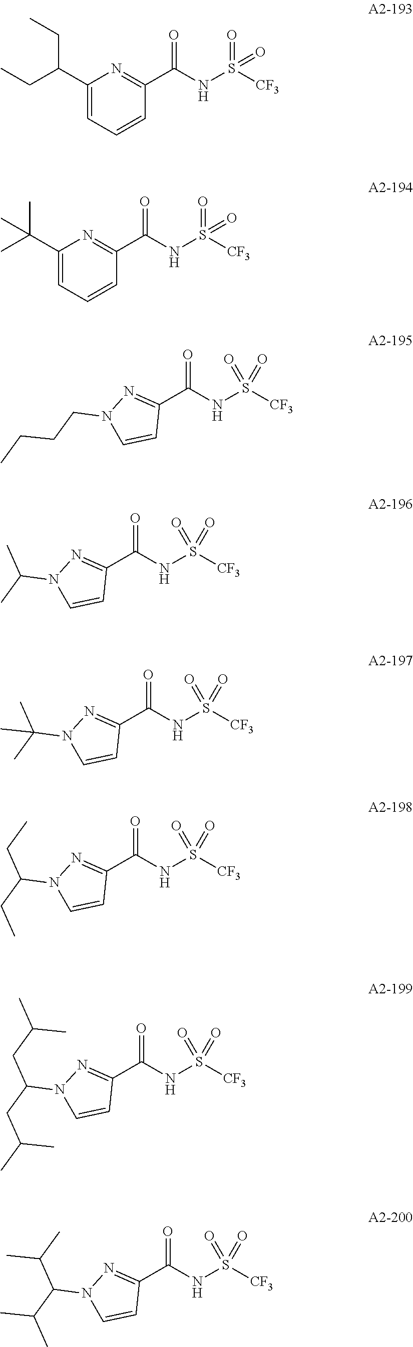

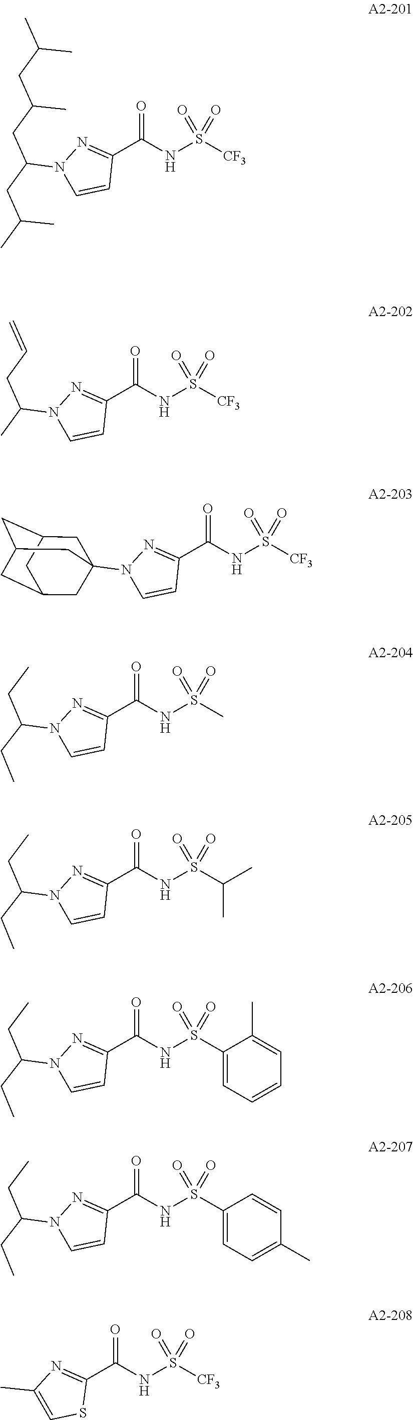

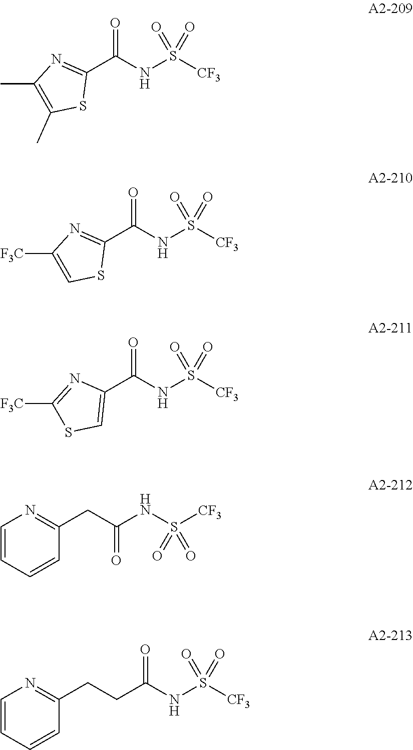 [SMILES: Cc1nc(C(=O)NS(=O)(=O)C(F)(F)F)sc1C ; O=C(NS(=O)(=O)C(F)(F)F)c1nc(C(F)(F)F)cs1 ; O=C(NS(=O)(=O)C(F)(F)F)c1csc(C(F)(F)F)n1 ; O=C(Cc1ccccn1)NS(=O)(=O)C(F)(F)F ; O=C(CCc1ccccn1)NS(=O)(=O)C(F)(F)F]

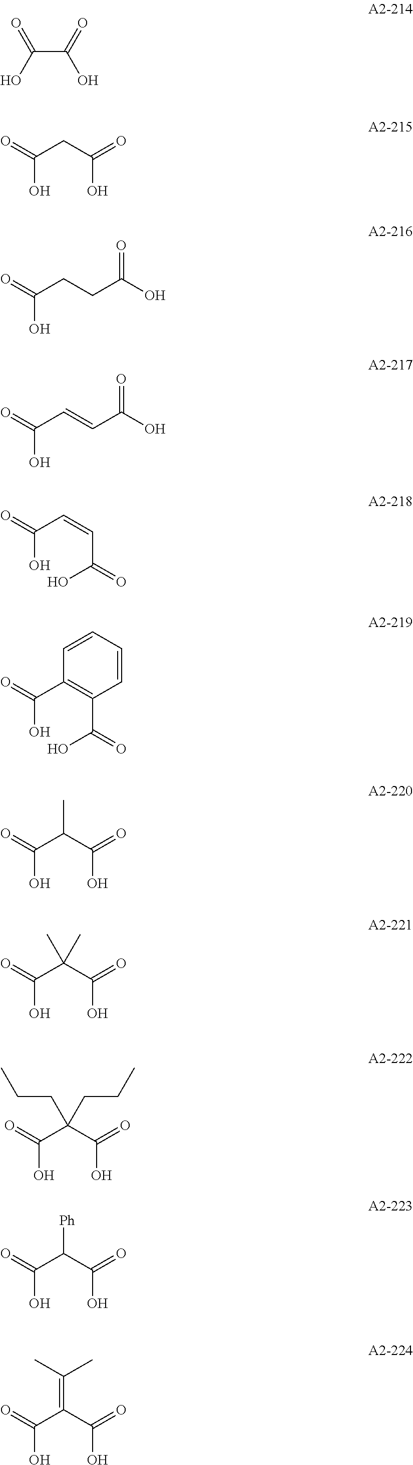

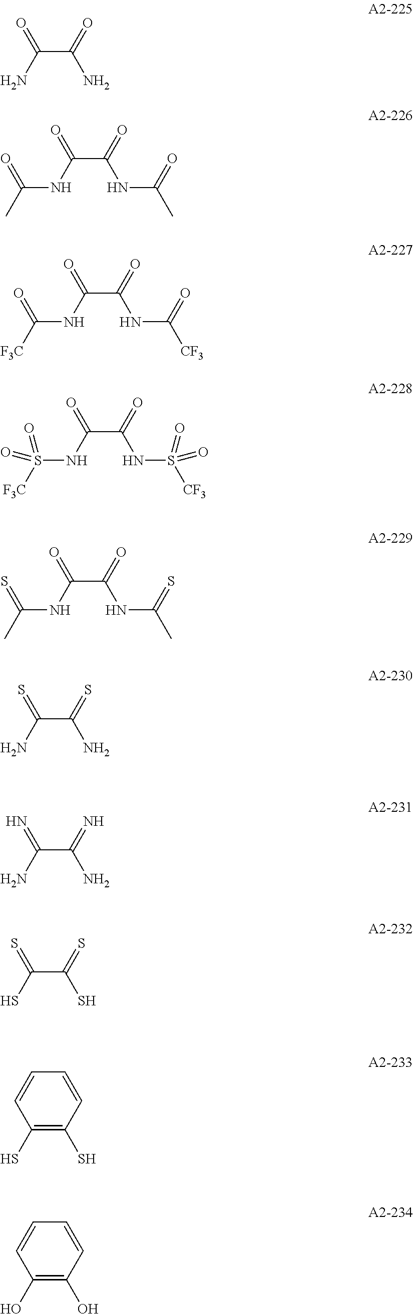

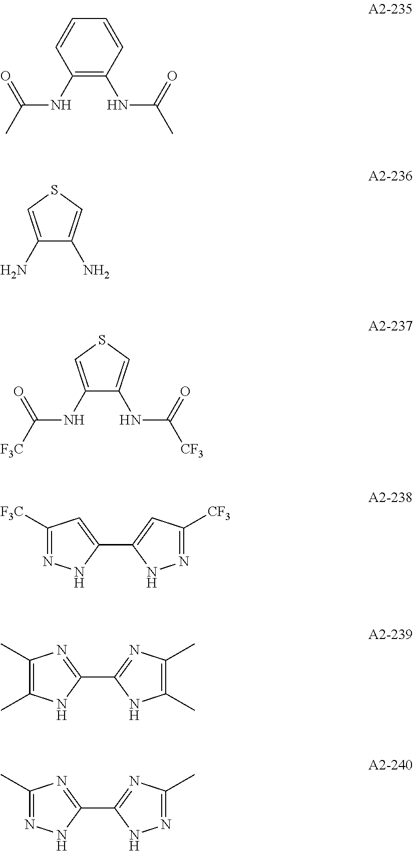

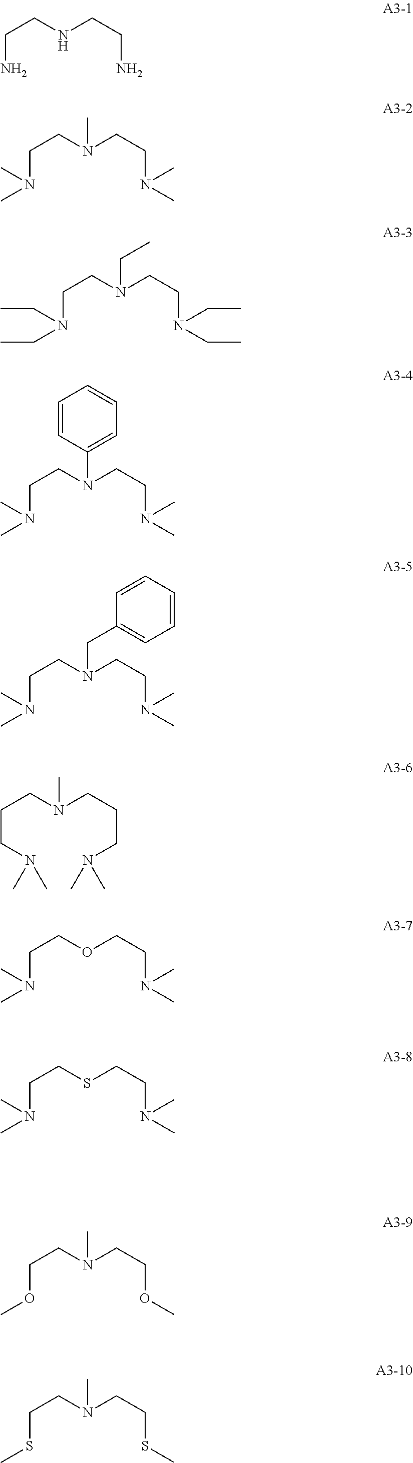

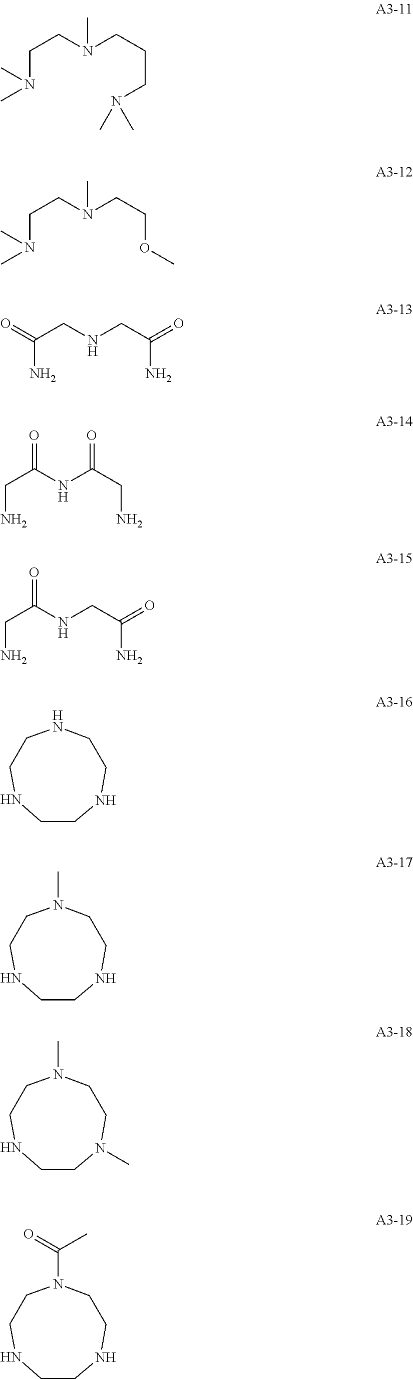

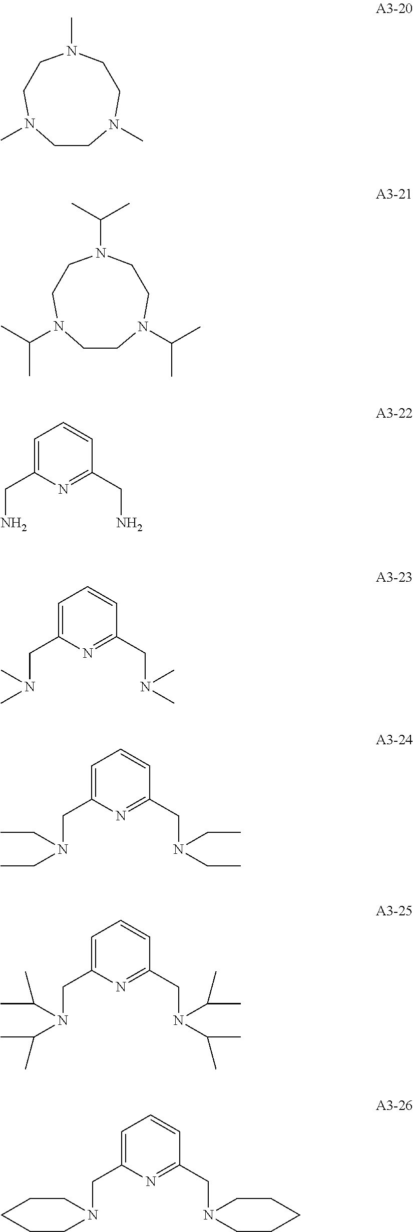

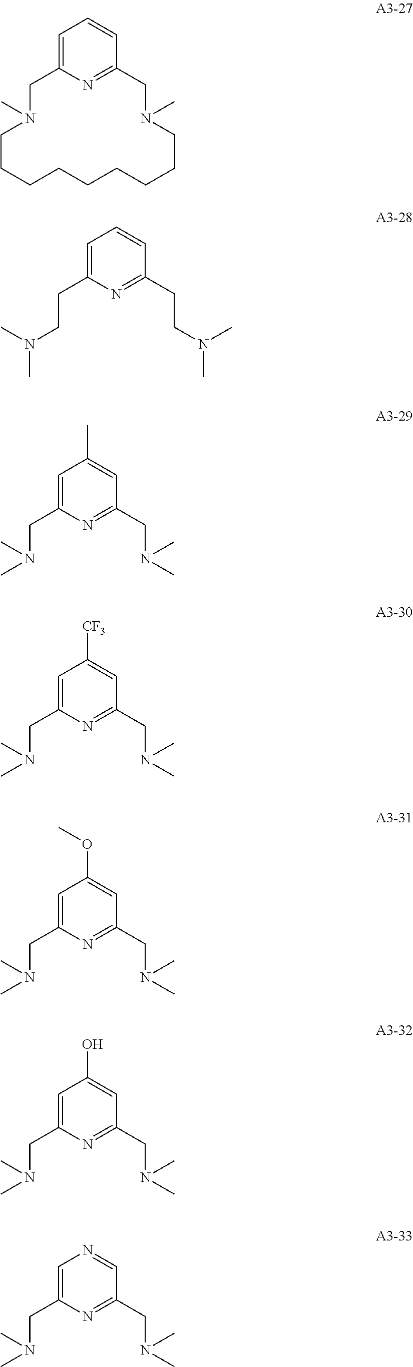

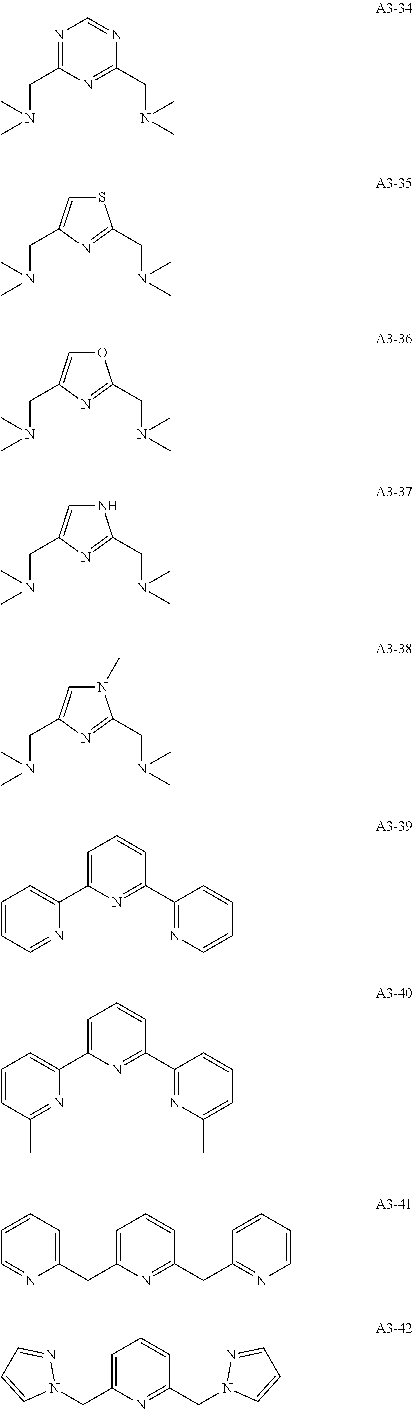

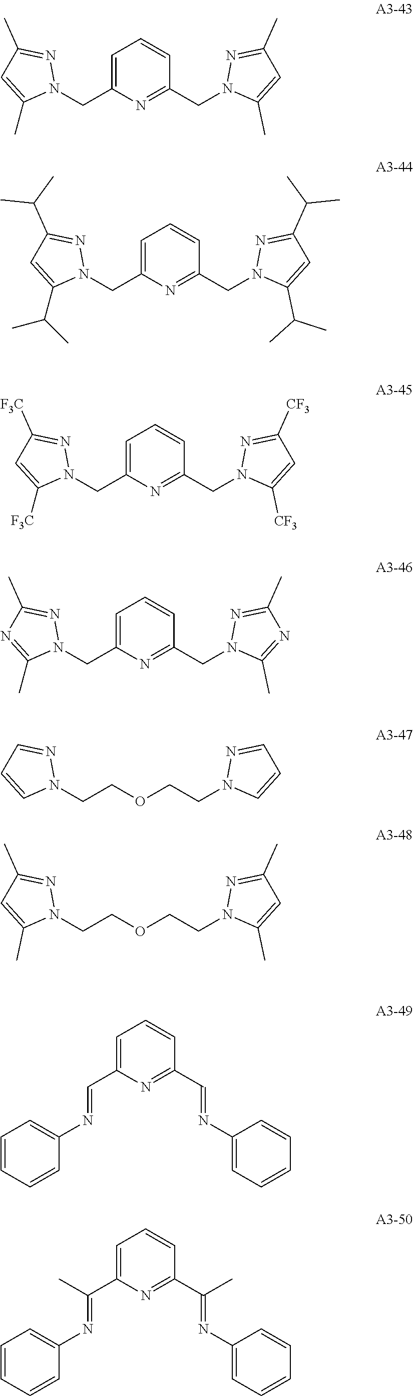

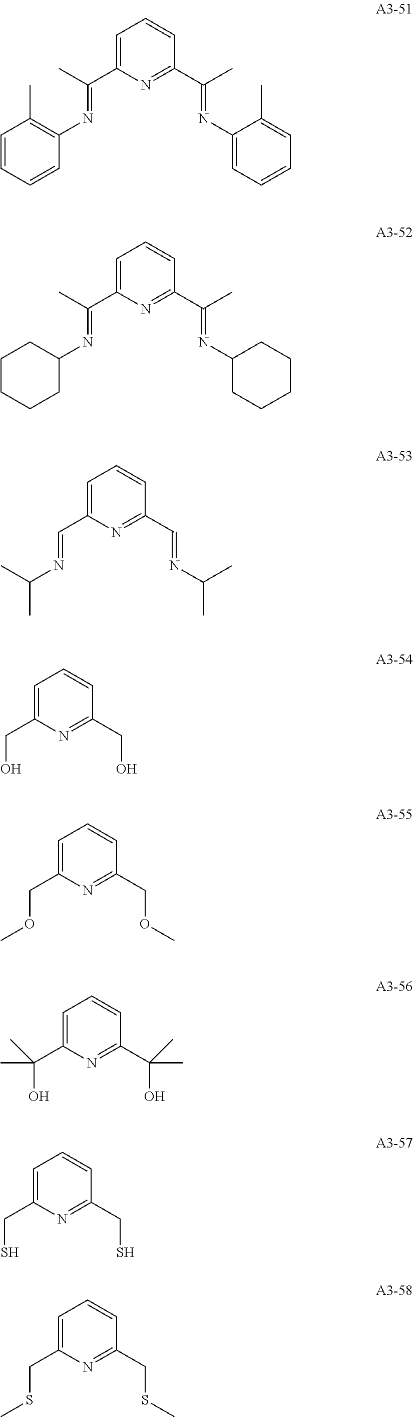

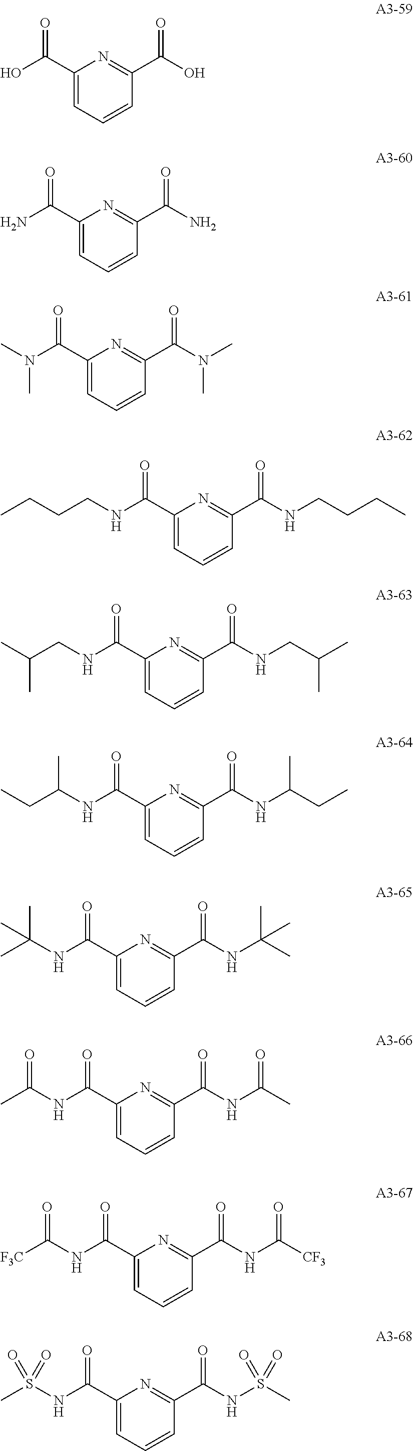

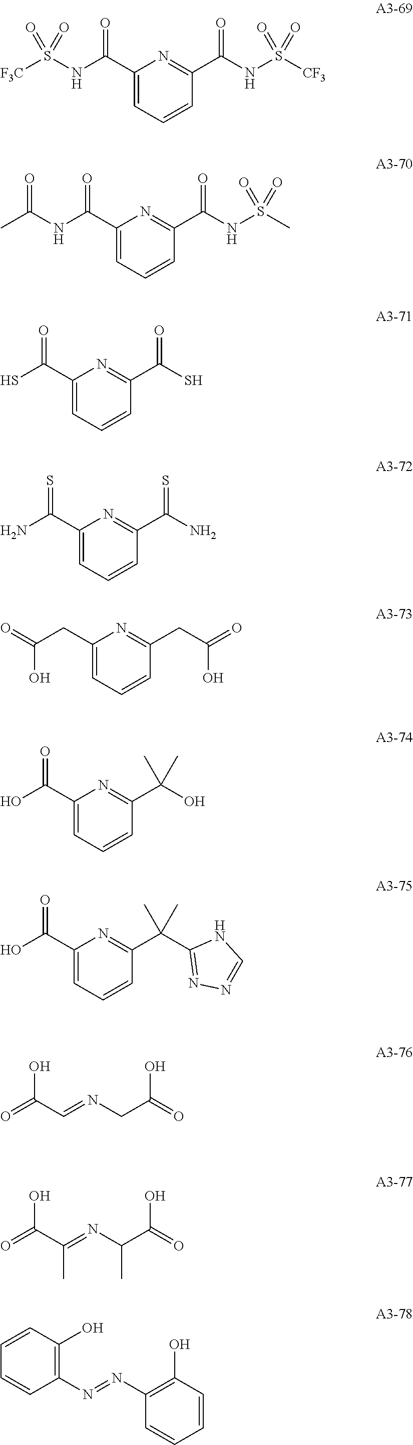

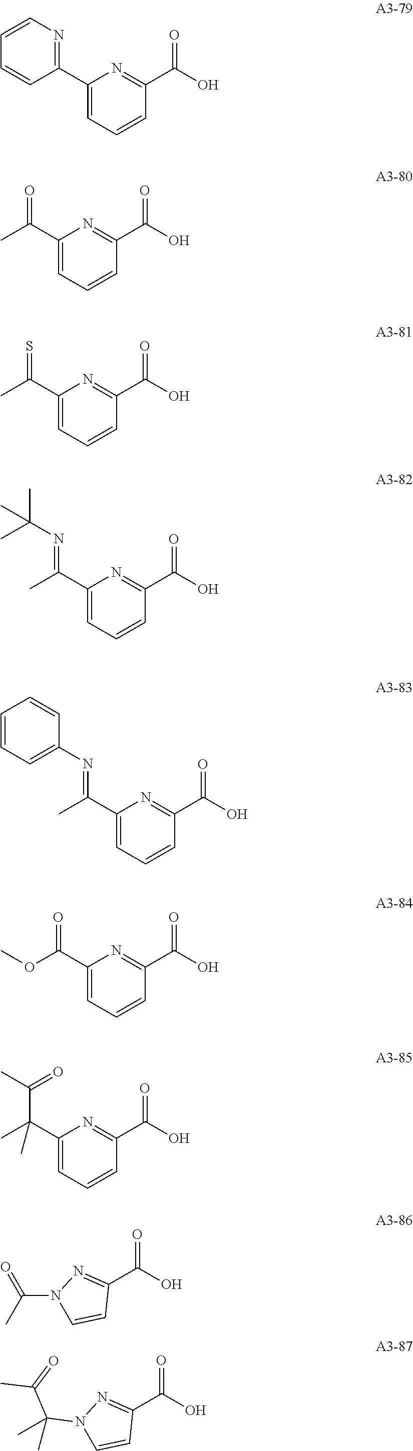

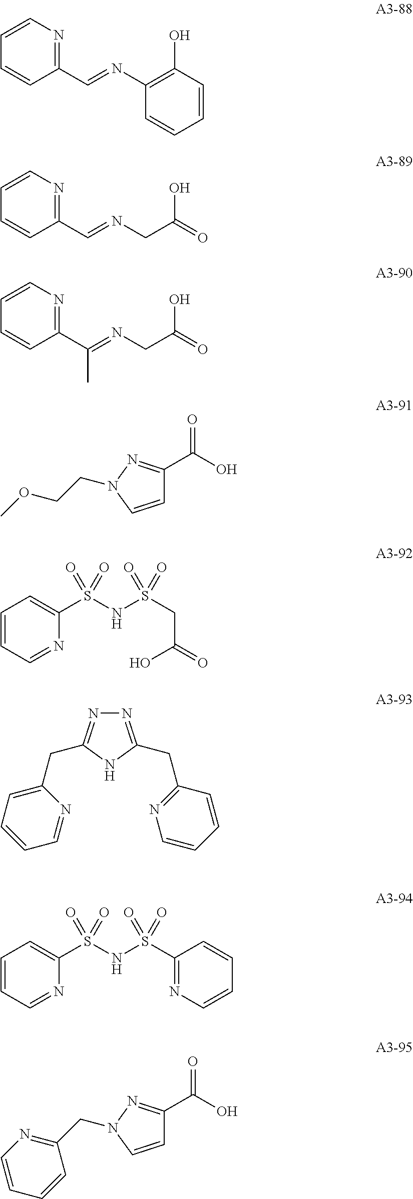

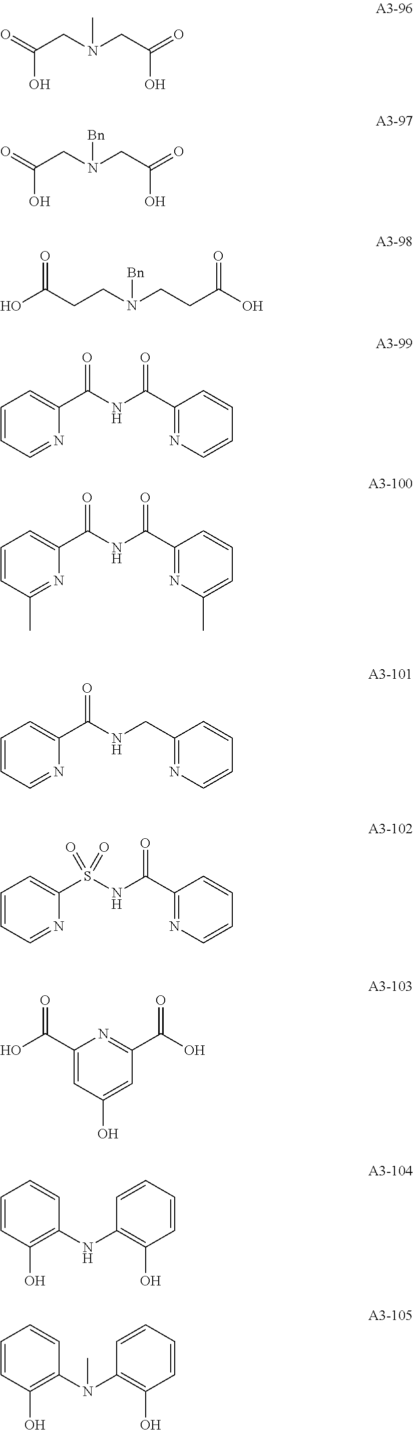

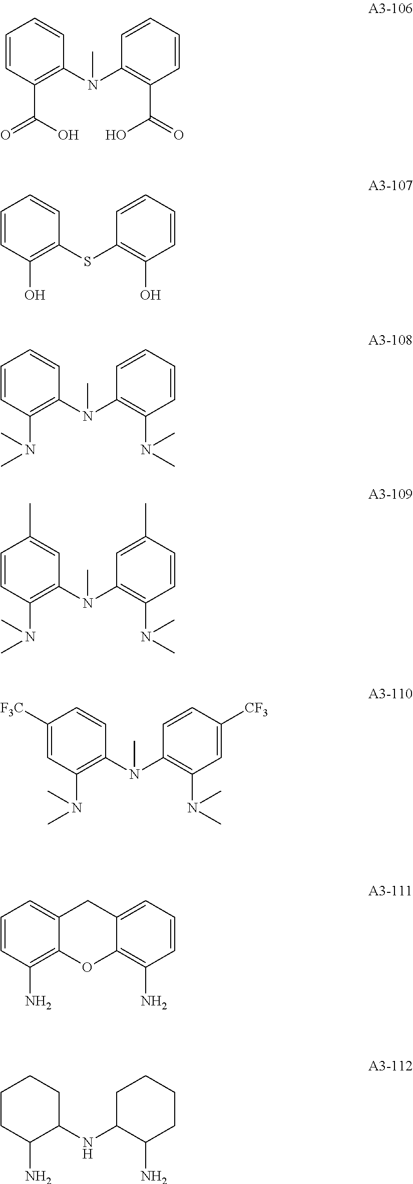

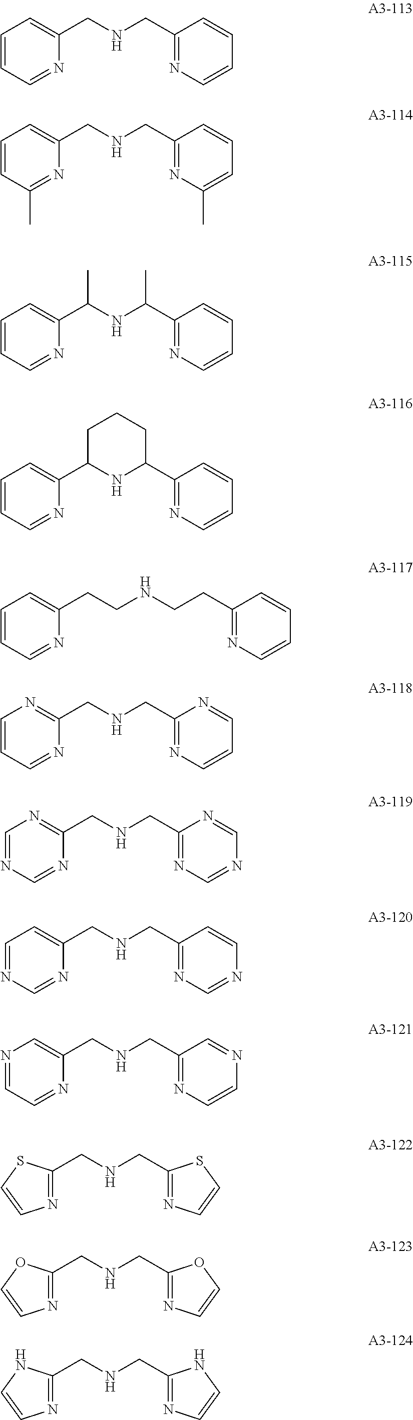

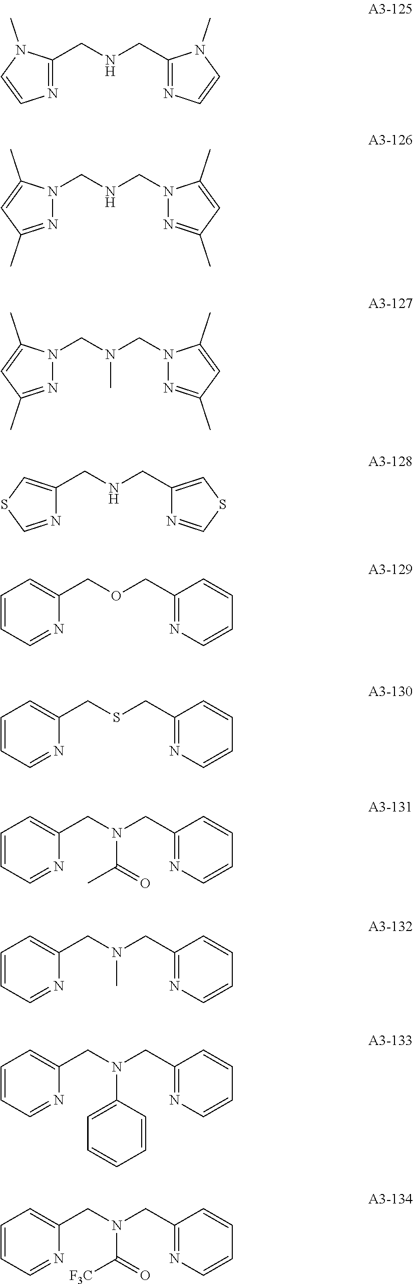

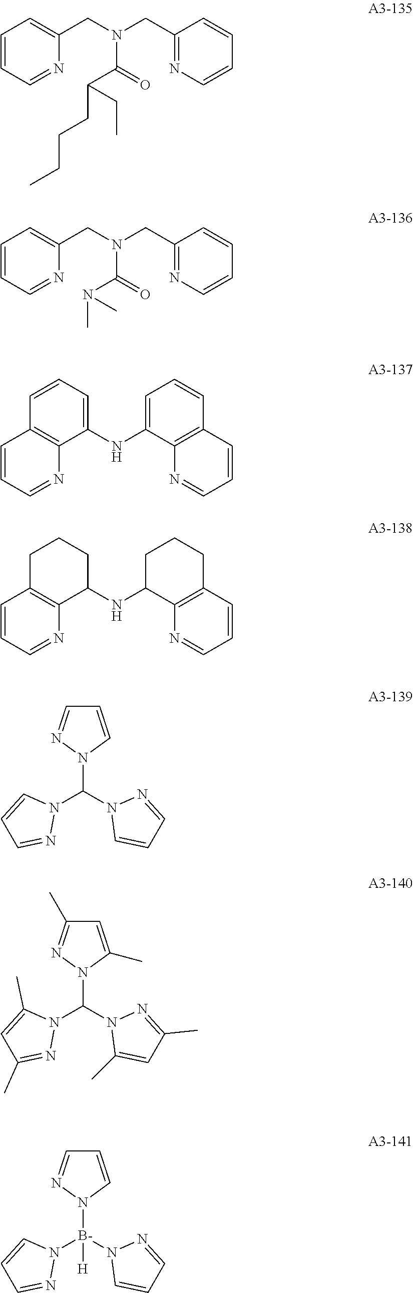

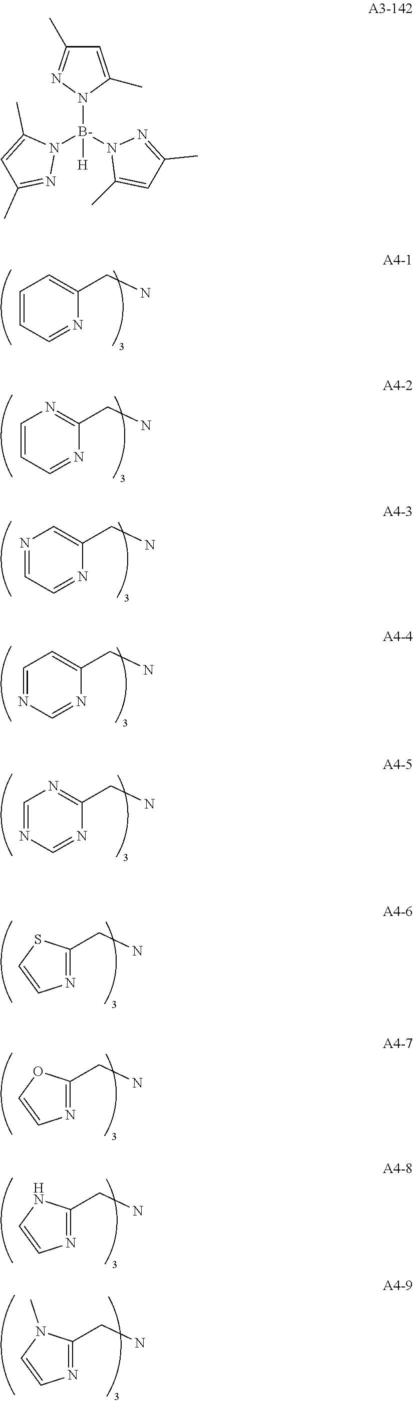

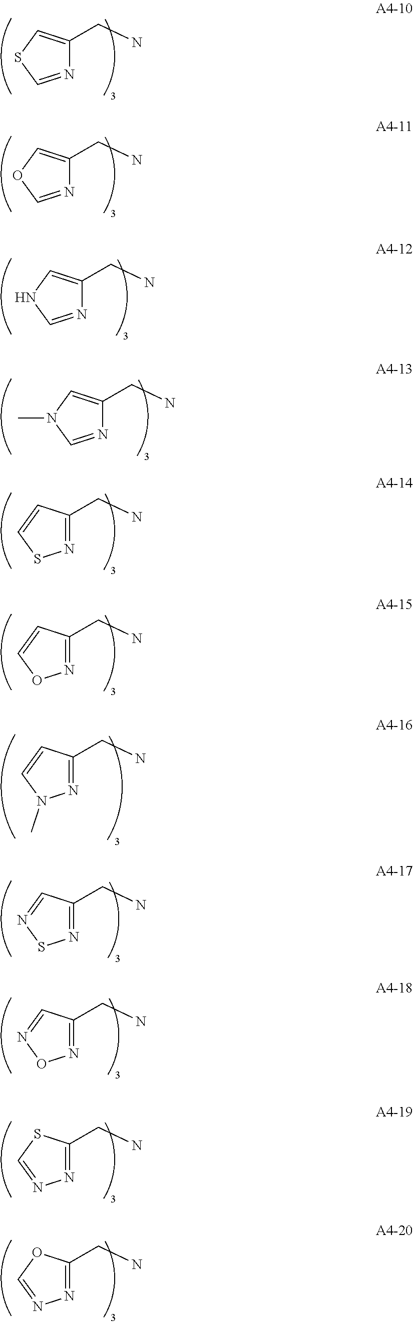

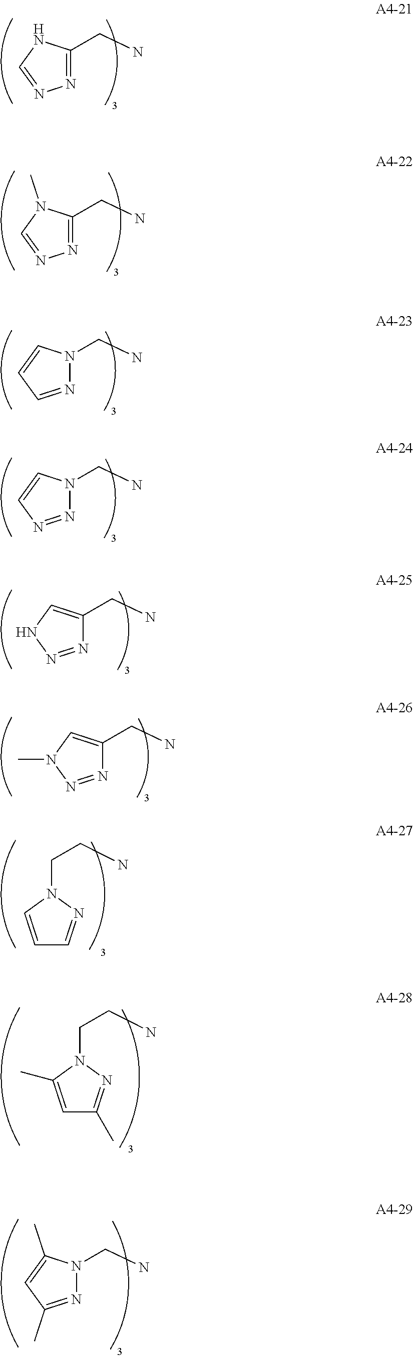

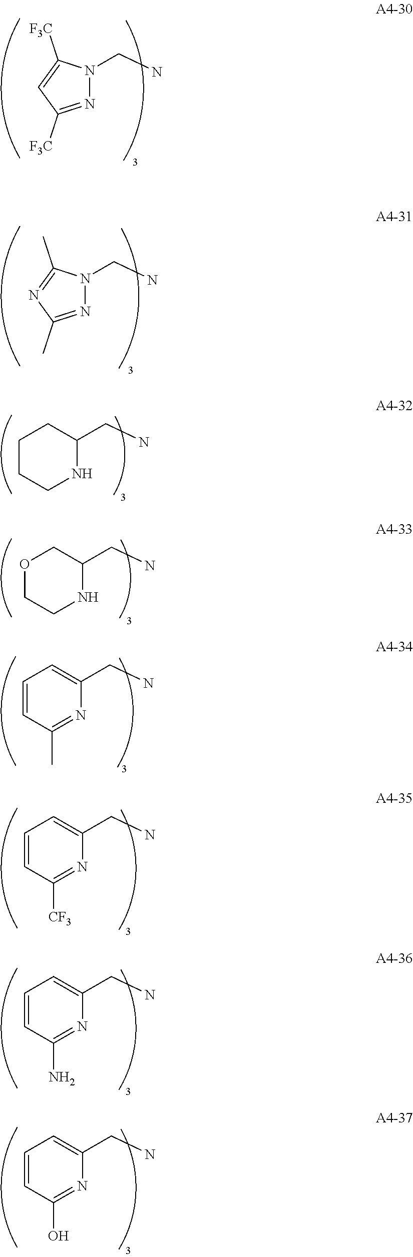

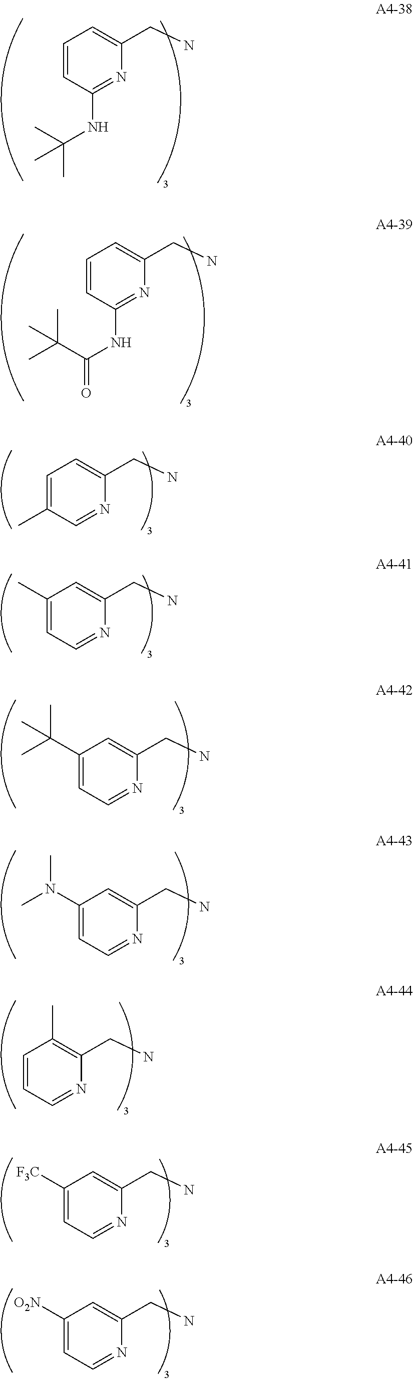

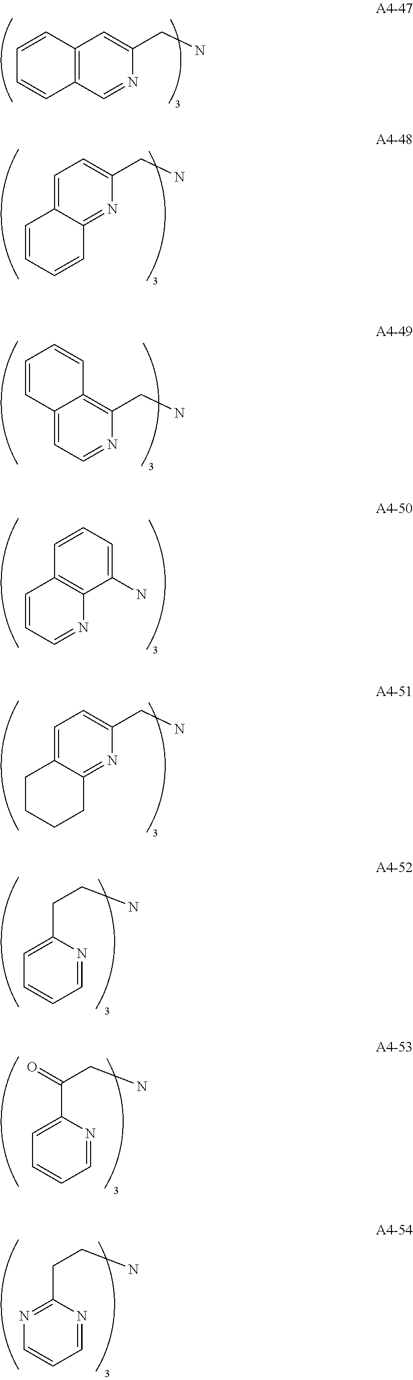

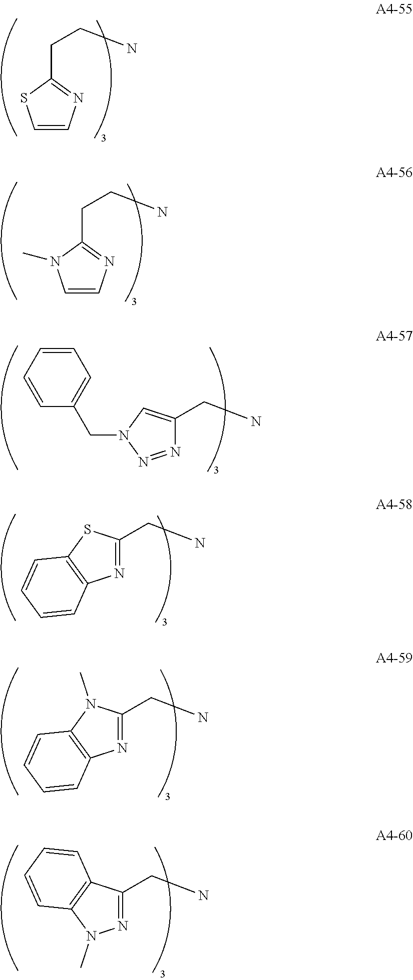

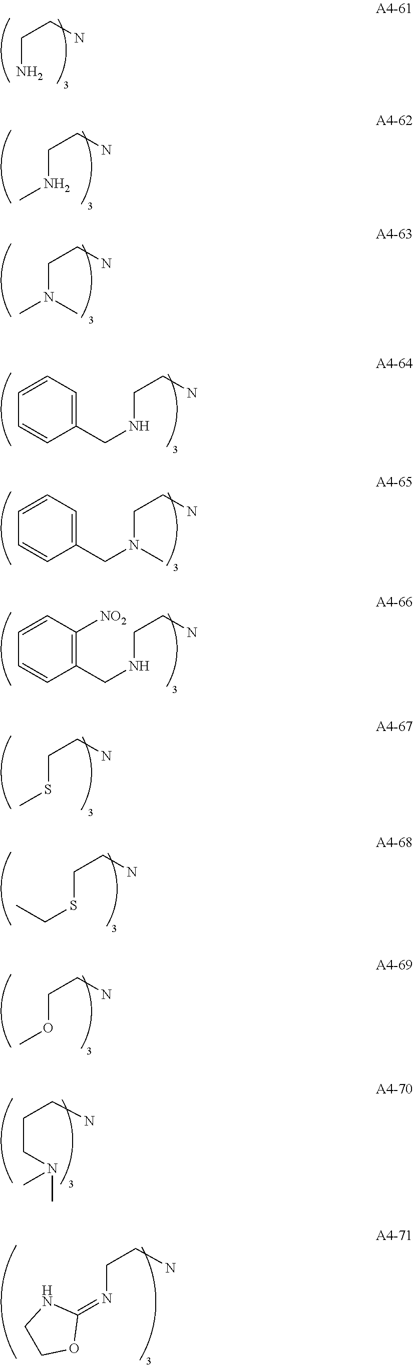

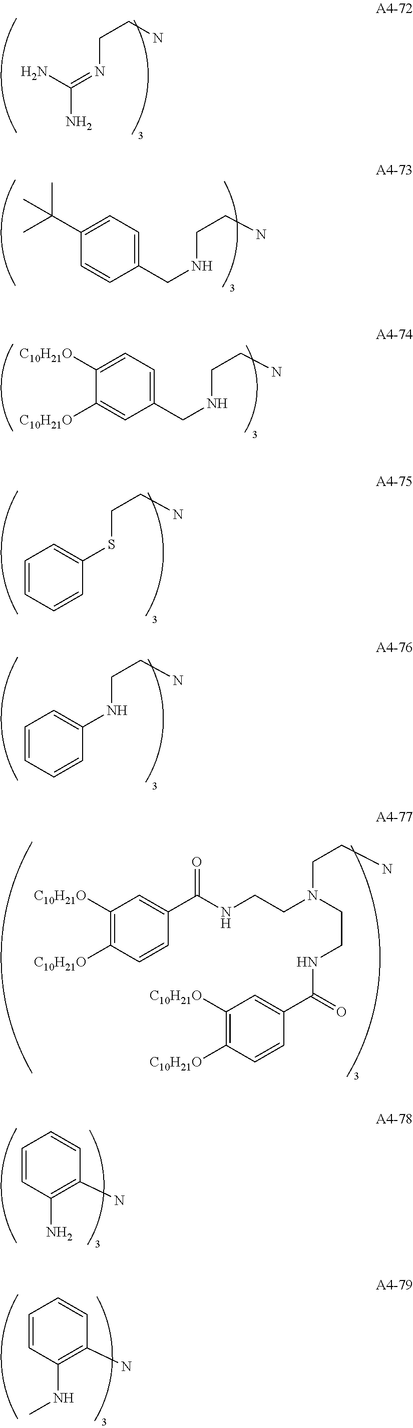

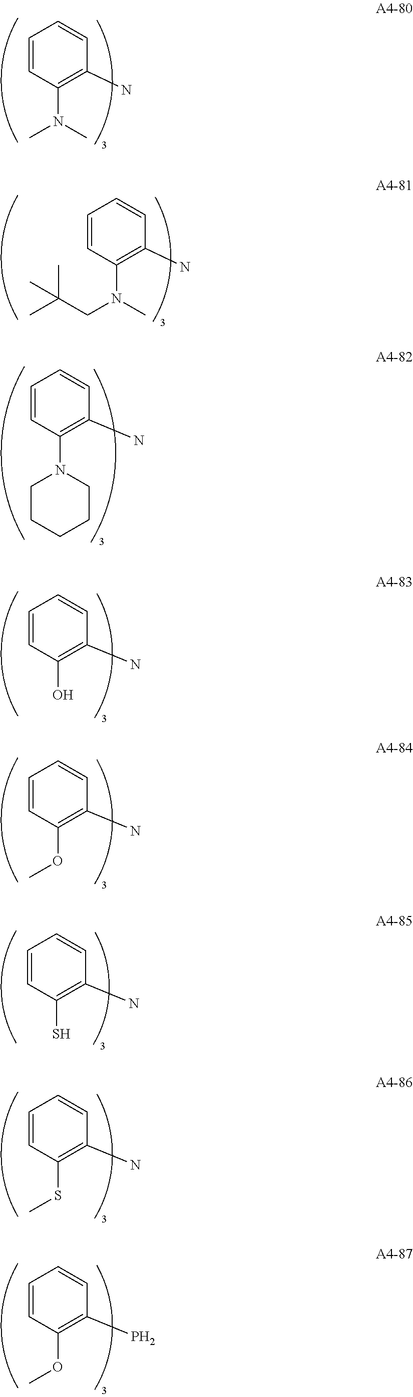

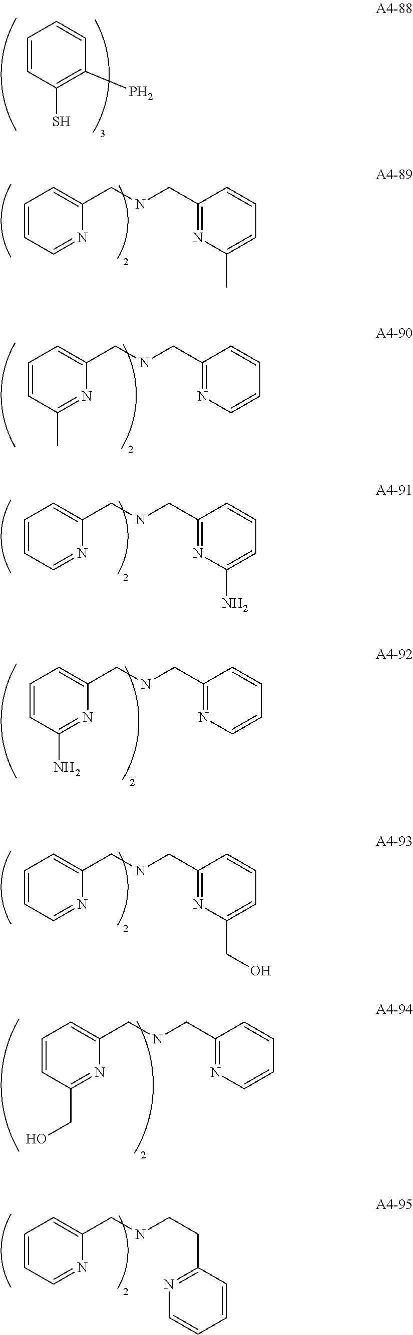

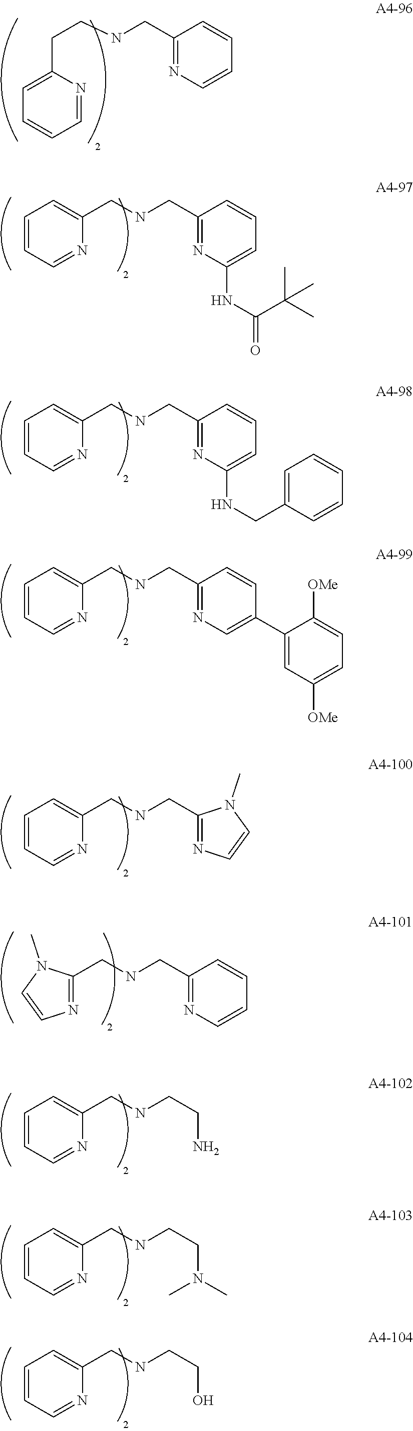

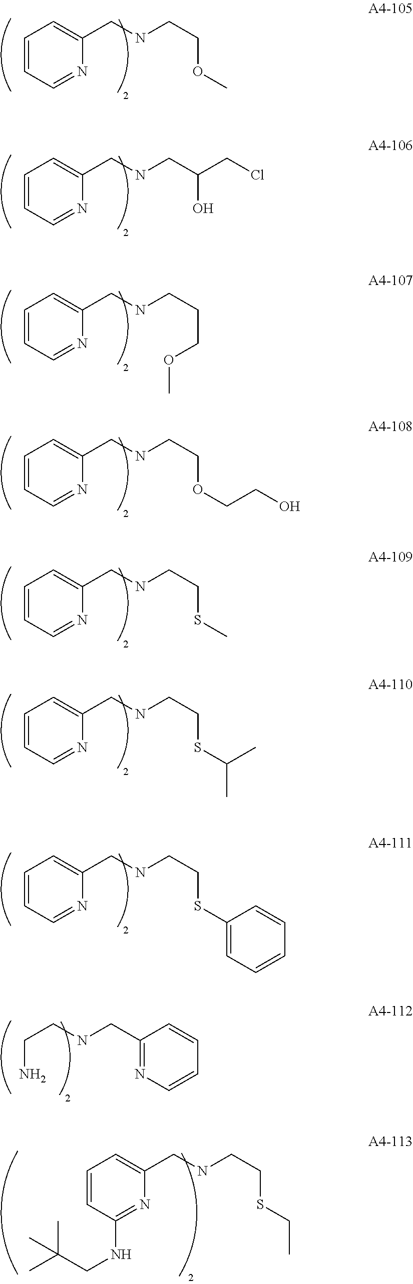

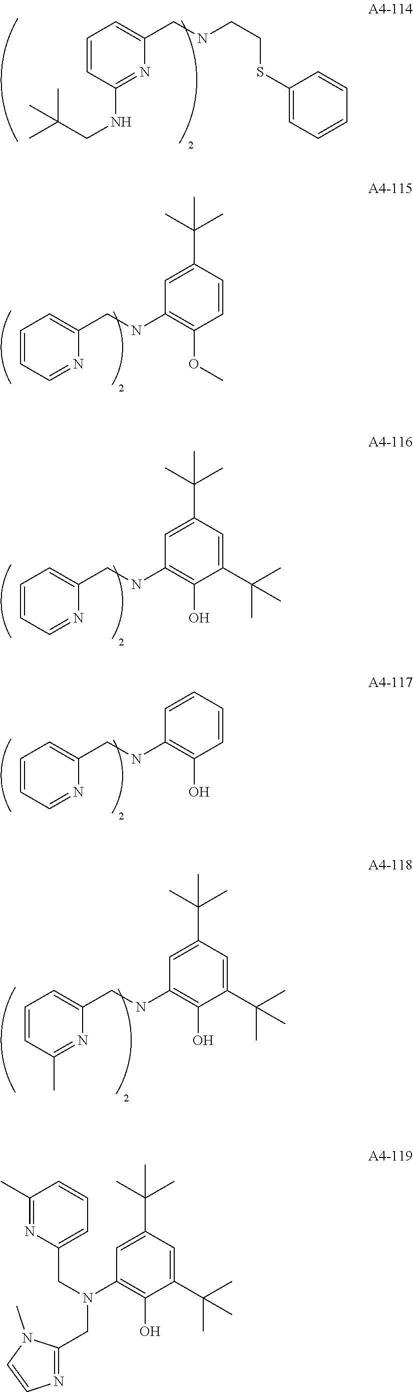

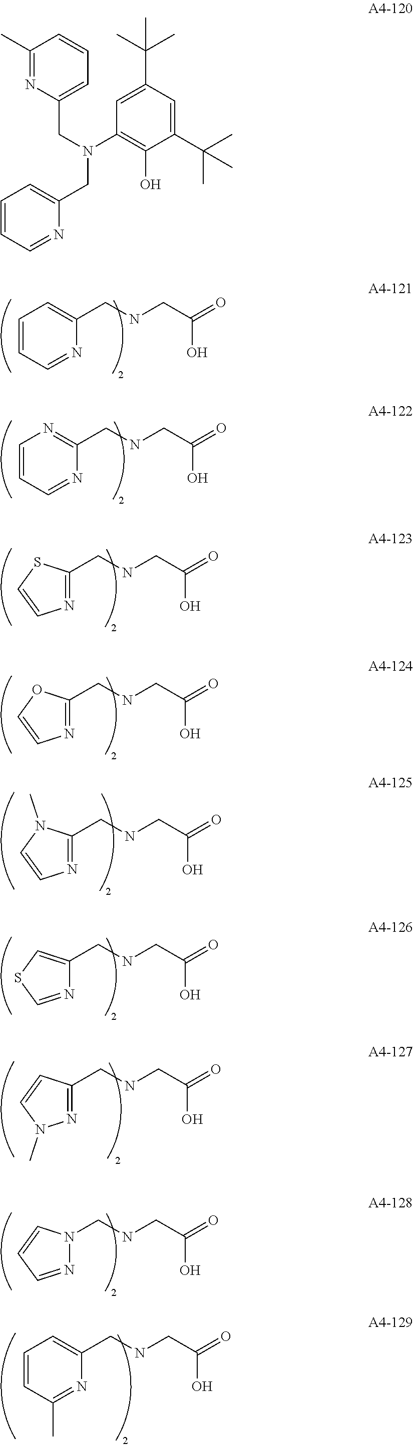

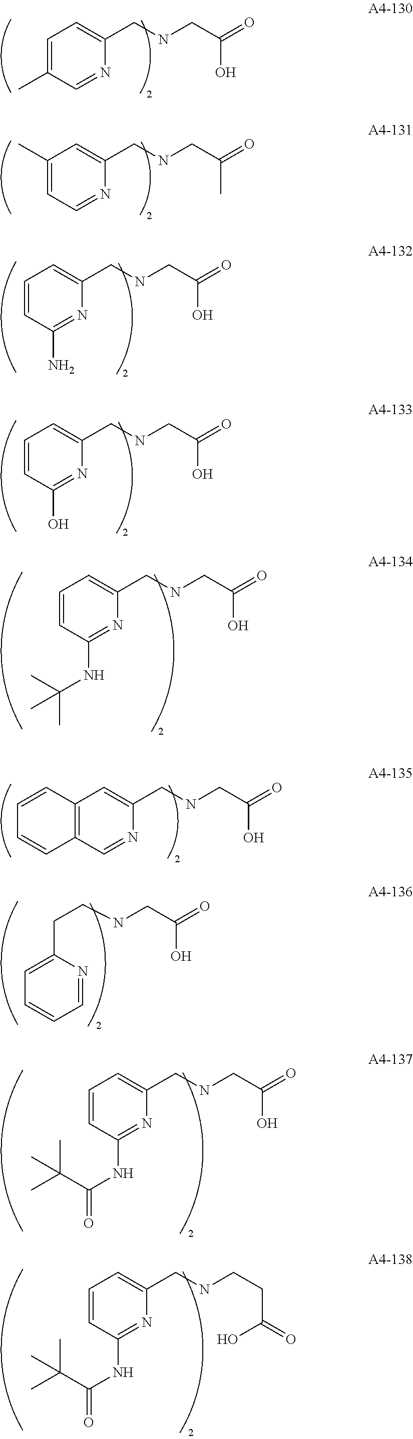

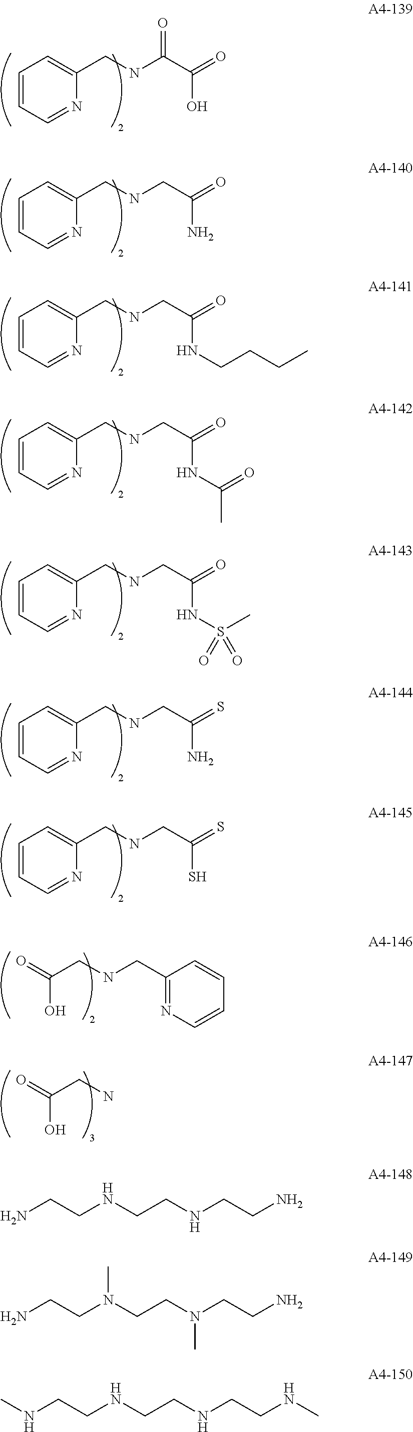

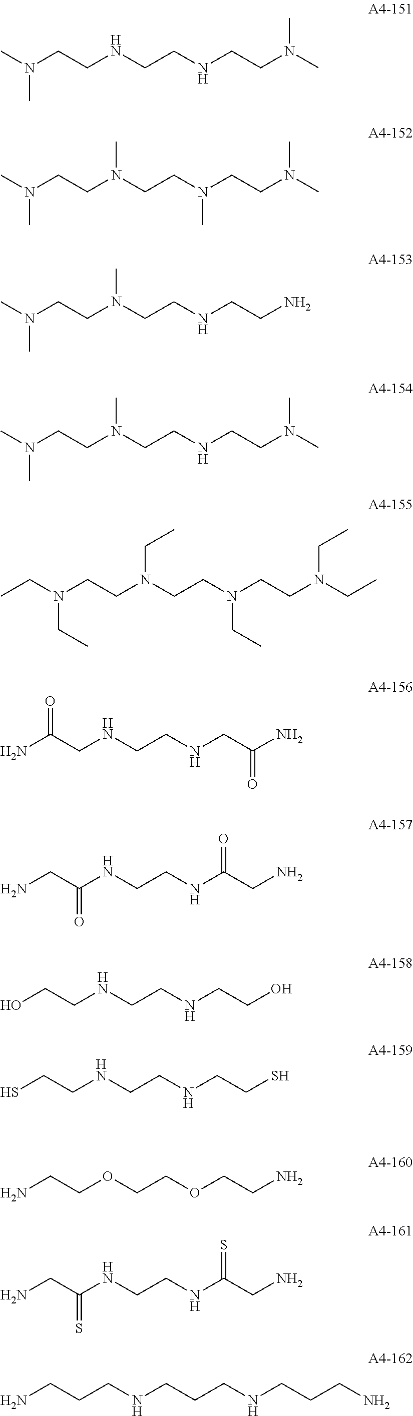

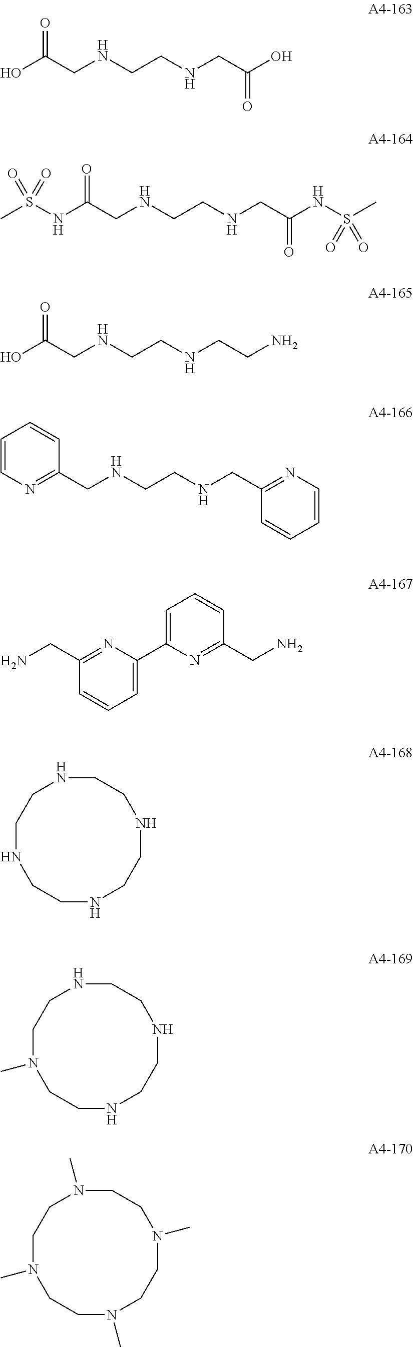

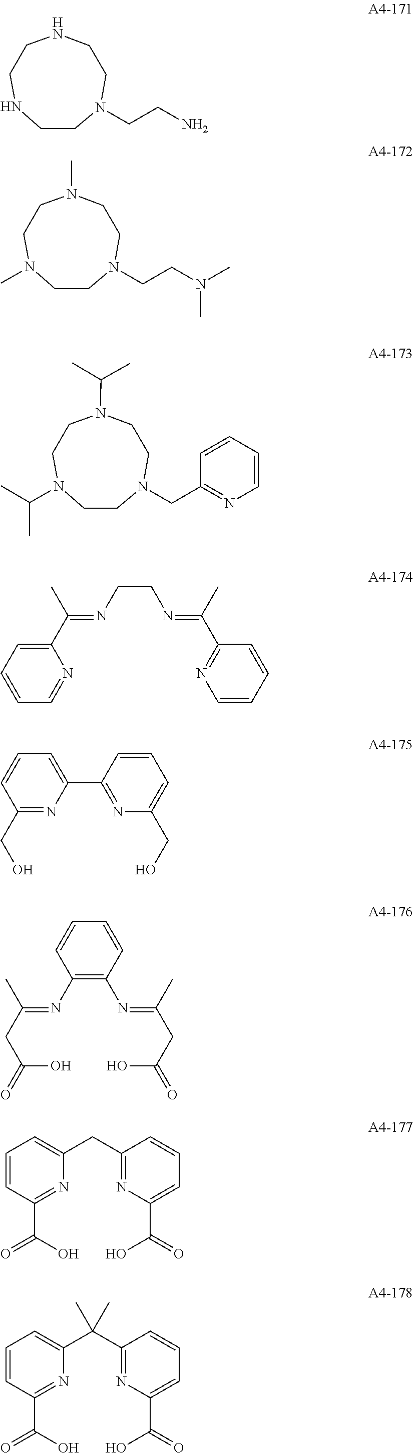

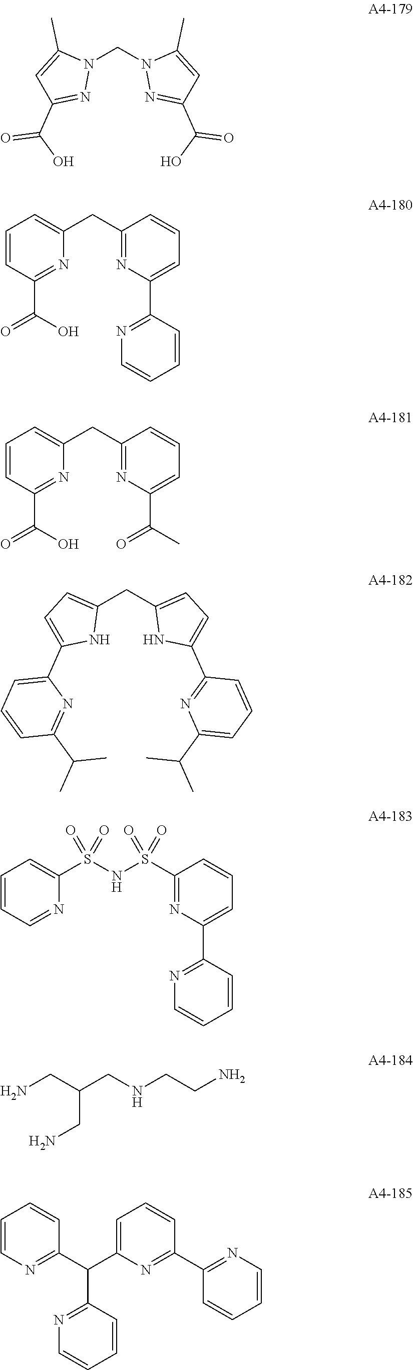

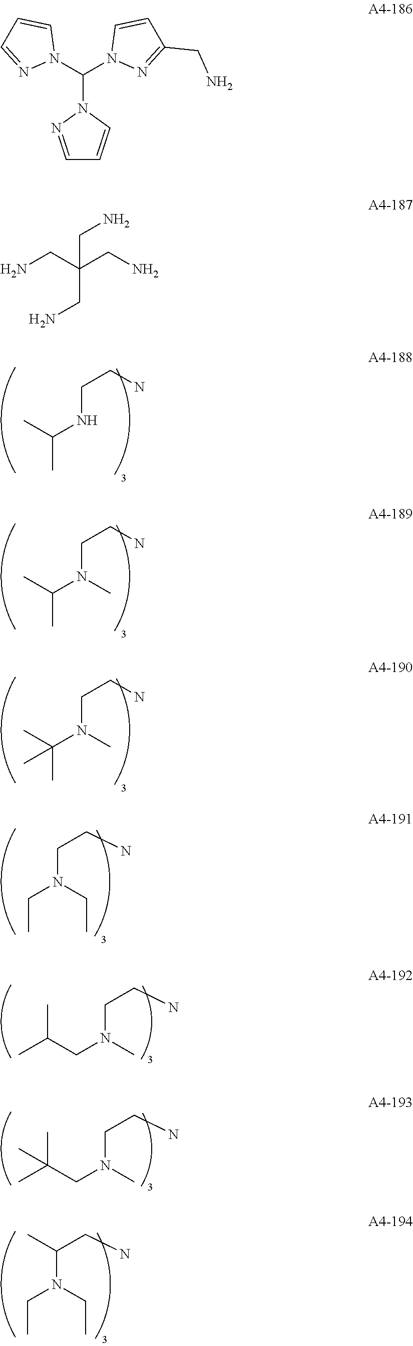

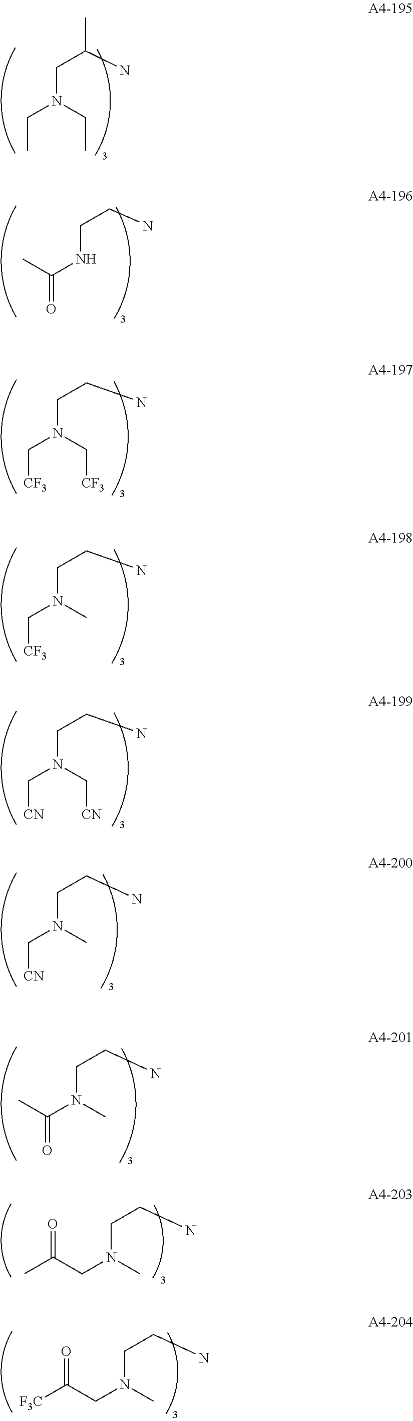

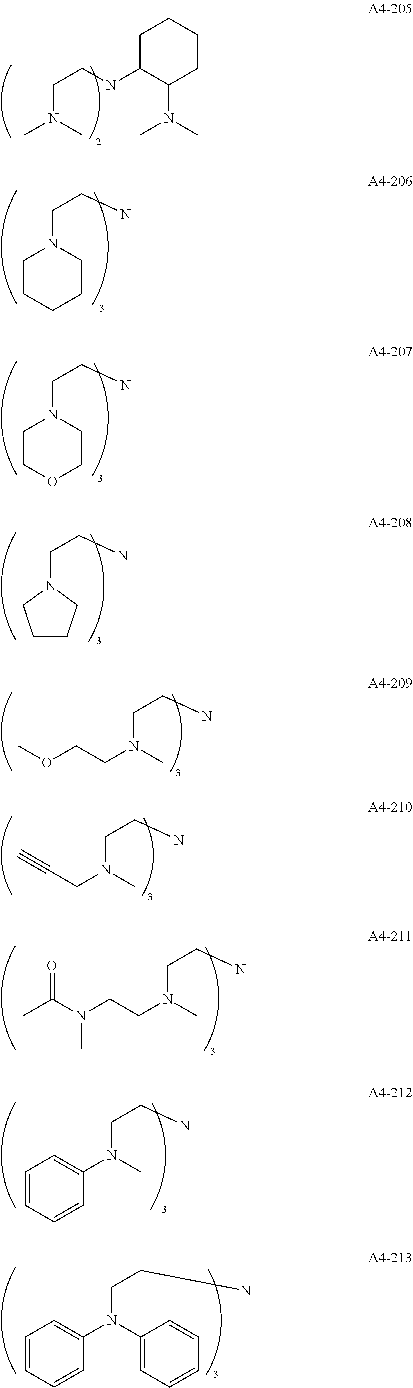

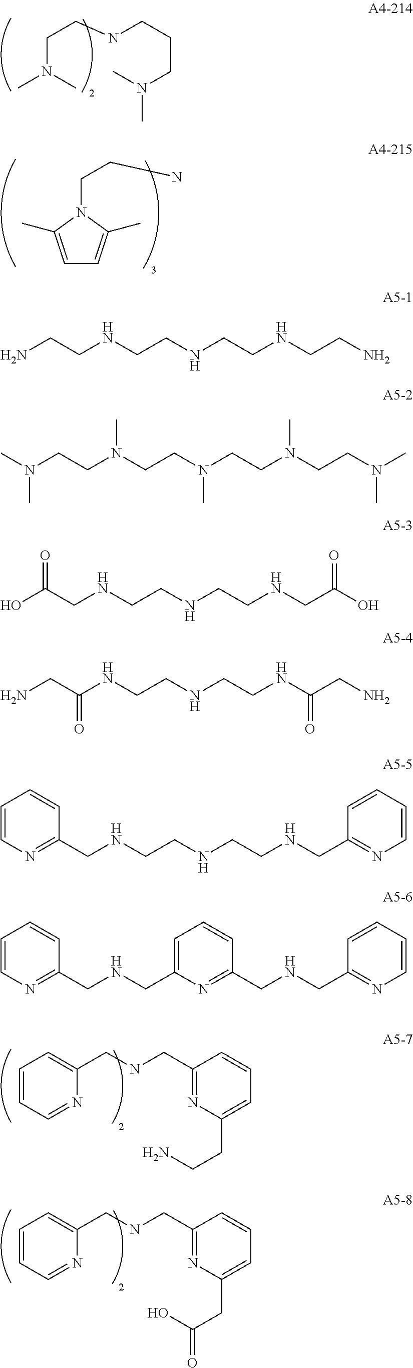

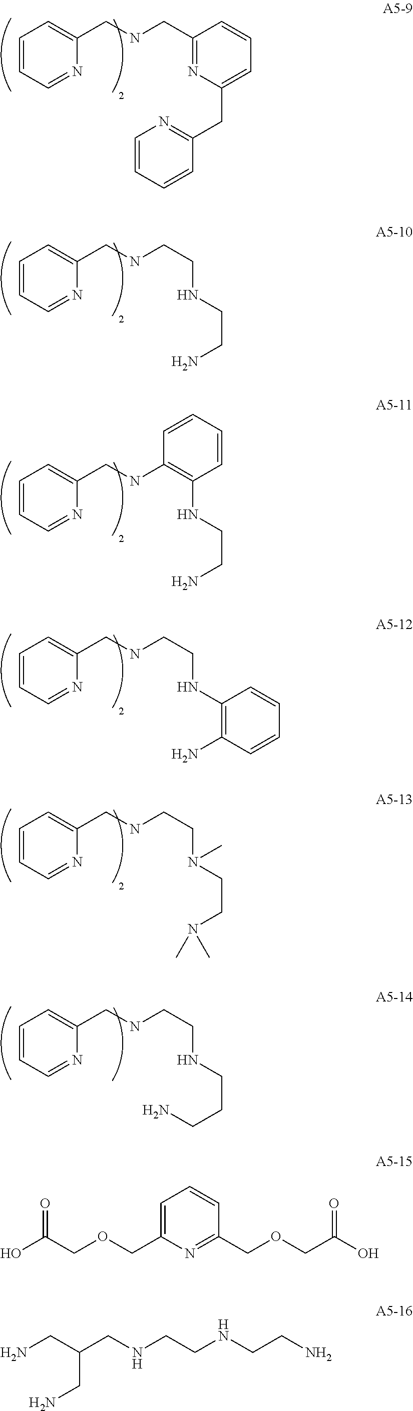

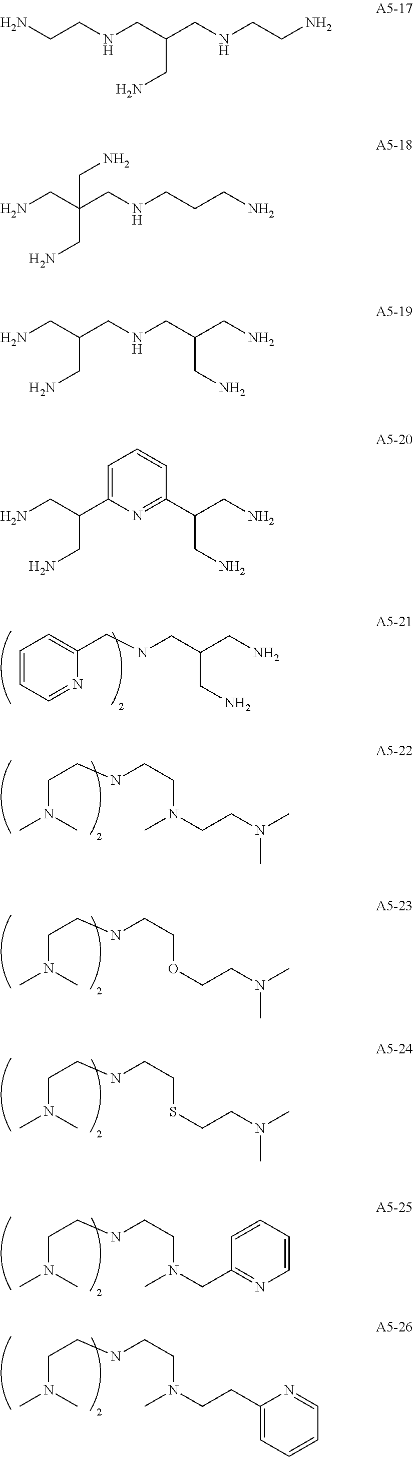

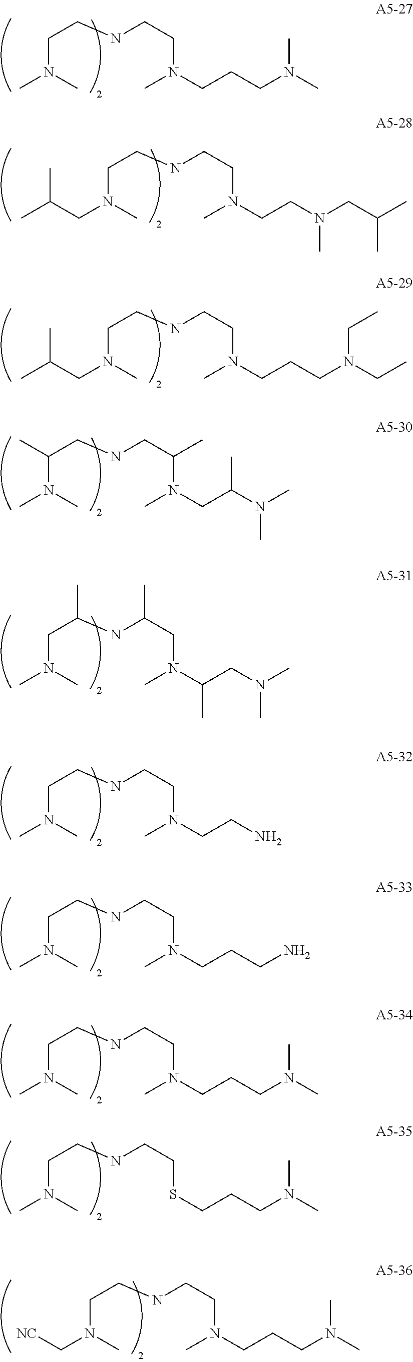

The copper complex site may include two or more multidentate ligands. In a case where the copper complex site includes two or more multidentate ligands, the multidentate ligands may be the same as or different from each other.

The copper complex site may be tetradentate-coordinated, pentadentate-coordinated, or hexadentate-coordinated, more preferably tetradentate-coordinated or pentadentate-coordinated, and still more preferably pentadentate-coordinated.

In addition, in the copper complex site, it is preferable that a copper atom and the ligand may form at least one selected from a 5-membered ring and a 6-membered ring. This copper complex is stable in shape and has excellent complex stability.

The copper complex site can be obtained by causing a compound having a coordination site to react with a copper component (copper or a compound including copper).

It is preferable that the copper component is a compound including divalent copper. As the copper component, one kind may be used alone, or two or more kinds may be used in combination.

As the copper component, for example, copper oxide or a copper salt can be used. As the copper salt, for example, copper carboxylate (for example, copper acetate, copper ethylacetoacetate, copper formate, copper benzoate, copper stearate, copper naphthenate, copper citrate, or copper 2-ethylhexanoate), copper sulfonate (for example, copper methasulfonate), copper phosphate, copper phosphoric acid ester, copper phosphonate, copper phosphonic acid ester, copper phosphinate, copper amide, copper sulfone amide, copper imide, copper acyl sulfone imide, copper bissulfone imide, copper methide, alkoxy copper, phenoxy copper, copper hydroxide, copper carbonate, copper sulfate, copper nitrate, copper perchlorate, copper fluoride, copper chloride, copper bromide is preferable, copper carboxylate, copper sulfonate, copper sulfone amide, copper imide, copper acyl sulfone imide, copper bissulfone imide, alkoxy copper, phenoxy copper, copper hydroxide, copper carbonate, copper fluoride, copper chloride, copper sulfate, copper nitrate, is more preferable, copper carboxylate, copper acyl sulfone imide, phenoxy copper, copper chloride, copper sulfate, copper nitrate is still more preferable, and copper carboxylate, copper acyl sulfone imide, copper chloride, copper sulfate is even still more preferable.

A molar ratio (compound having a coordination site:copper component) of the amount of the compound having a coordination site to the amount of the copper component which is caused to react with the compound is preferably 1:0.5 to 1:8 and more preferably 1:0.5 to 1:4.

In addition, when the copper component and the compound having a coordination site are caused to react with each other, for example, it is preferable that reaction conditions are 20° C. to 100° C. and 0.5 hours or longer.

The copper complex site may include a monodentate ligand. Examples of the monodentate ligand include a monodentate ligand coordinated by an anion or an unshared electron pair. Examples of the monodentate ligand coordinated by an anion include a halide anion, a hydroxide anion, an alkoxide anion, a phenoxide anion, an amide anion (including amide substituted with an acyl group or a sulfonyl group), an imide anion (including imide substituted with an acyl group or a sulfonyl group), an anilide anion (including anilide substituted with an acyl group or a sulfonyl group), a thiolate anion, a hydrogen carbonate anion, a carboxylate anion, a thiocarboxylate anion, a dithiocarboxylate anion, a hydrogen sulfate anion, a sulfonate anion, a dihydrogen phosphate anion, a phosphoric acid diester anion, a phosphonic acid monoester anion, a hydrogen phosphonate anion, a phosphinate anion, a nitrogen-containing heterocyclic anion, a nitrate anion, a hypochlorite anion, a cyanide anion, a cyanate anion, an isocyanate anion, a thiocyanate anion, an isothiocyanate anion, and an azide anion. Examples of the monodentate ligand coordinated by an unshared electron pair include water, alcohol, phenol, ether, amine, aniline, amide, imide, imine, nitrile, isonitrile, thiol, thioether, a carbonyl compound, a thiocarbonyl compound, sulfoxide, a heterocyclic ring, carbonic acid, carboxylic acid, sulfuric acid, sulfonic acid, phosphoric acid, phosphonic acid, phosphinic acid, nitric acid, and an ester thereof.

The kind and number of monodentate ligands can be appropriately selected according to a compound multidentate-coordinated to a copper atom.

Specific examples of the monodentate ligand include the following monodentate ligands, but the present invention is not limited thereto.

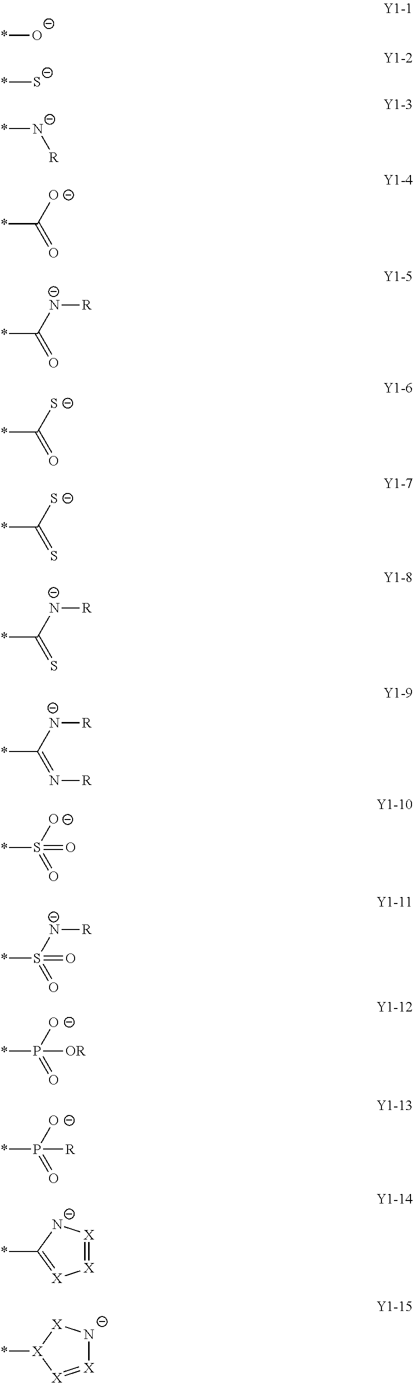

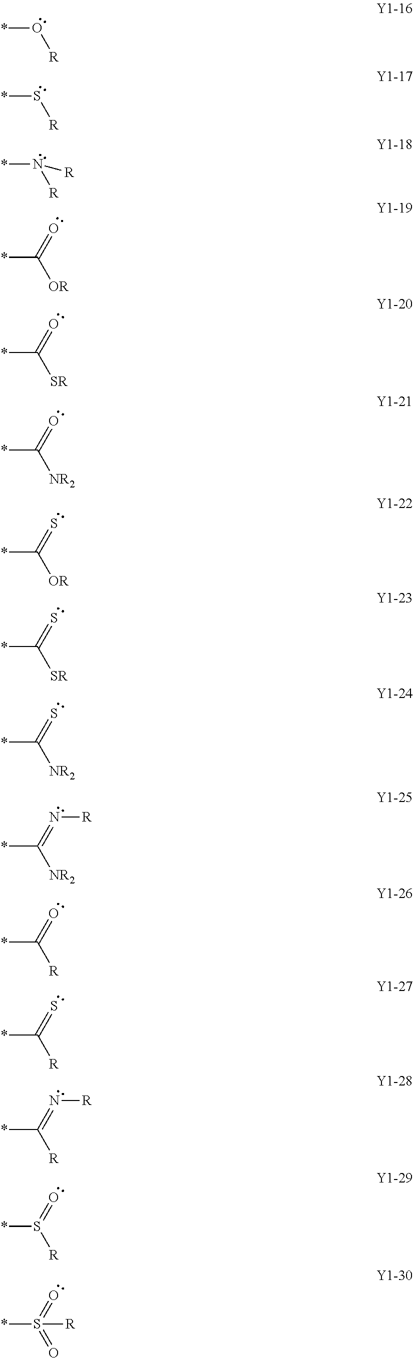

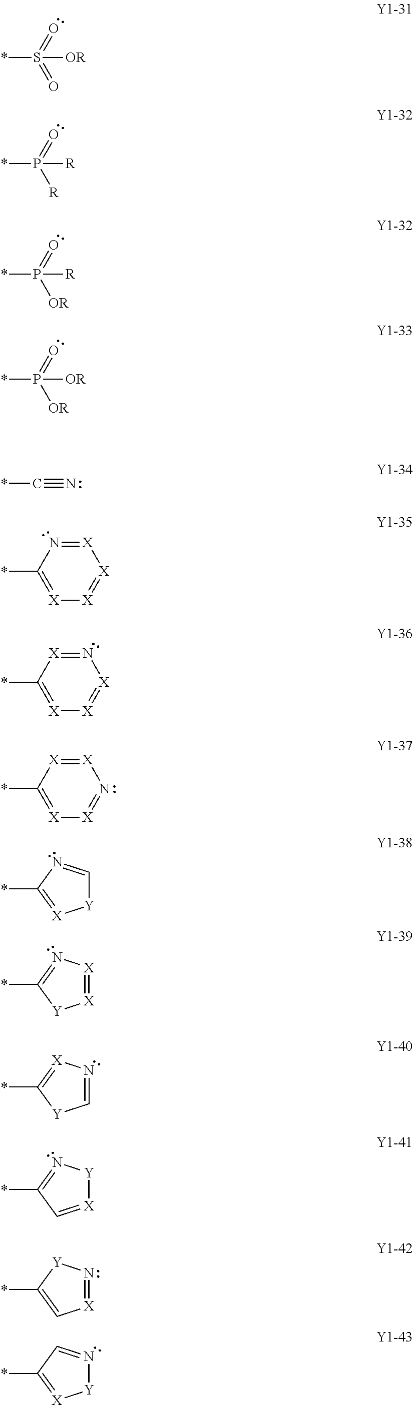

In the structural formulae, X represents CR¹ or an N atom. Y represents an O atom, an S atom, or NR².

R, R¹, and R² each independently represent a hydrogen atom, an alkyl group, an alkenyl group, an alkynyl group, an aryl group, a heteroaryl group, an acyl group, or a sulfonyl group.

Depending on the number of coordination sites coordinated by an anion, the copper complex site may be a neutral complex having no charge, a cationic complex, or an anionic complex. In this case, optionally, a counter ion is present to neutralize the charge of the copper complex.

In a case where the counter ion is a negative counter ion (also referred to as “counter anion”), for example, the counter anion may be an inorganic anion or an organic anion.

Specific examples include a hydroxide ion, a halogen anion (for example, a fluoride ion, a chloride ion, a bromide ion, or an iodide ion), a substituted or unsubstituted alkylcarboxylate ion (for example, an acetate ion or a trifluoroacetate ion), a substituted or unsubstituted arylcarboxylate ion (for example, a benzoate ion or a hexafluorobenzoate ion), a substituted or unsubstituted alkylmethanesulfonate ion (for example, a methanesulfonate ion, a trifluoromethanesulfonate ion), a substituted or unsubstituted arylsulfonate ion (for example, a p-toluenesulfonate ion, a p-chlorobenzenesulfonate ion, or a hexafluorobenzenesulfonate ion), an aryldisulfonate ion (for example, a 1,3-benzenedisulfonate ion, a 1,5-naphthalene disulfonate ion, or an 2,6-naphthalenedisulfonate ion), an alkylsulfate ion (for example, a methylsulfate ion), a sulfate ion, a thiocyanate ion, a nitrate ion, a perchlorate ion, a tetrafluoroborate ion, a trifluorofluoroalkylborate ion (for example, BF₃CF₃), a tetraarylborate ion, a pentafluorophenylborate ion (for example, B⁻(C₆F₅)₄ or B⁻(C₆F₅)₃Ph), a hexafluorophosphate ion, a picrate ion, an imide ion (including an imide ion substituted with an acyl group or a sulfonyl group; for example, a bissulfonylimide ion such as N⁻(SO₂CF₃)₂, N⁻(SO₂F)₂, N⁻(SO₂CF₂CF₃)₂, N⁻(SO₂CF₂CF₂CF₂CF₃)₂, or an imide ion having a structure shown below, or an acylsulfonylimide ion such as a N-(trifluoromethanesulfonyl)trifluoroacetamide ion)), a methide ion (including a methide ion substituted with an acyl group or a sulfonyl group; for example, a trisulfonylmethide ion such as C⁻(SO₂CF₃)₃). As the counter anion, a halogen anion, a substituted or unsubstituted alkylcarboxylate ion, a sulfate ion, a nitrate ion, a tetrafluoroborate ion, a trifluorofluoroalkylborate ion (for example, BF₃CF₃), a tetraarylborate ion, a pentafluorophenylborate ion (for example, B⁻(C₆F₅)₄ or B⁻(C₆F₅)₃Ph), a hexafluorophosphate ion, an imide ion (including imide substituted with an acyl group or a sulfonyl group), or a methide ion (including a methide ion substituted with an acyl group or a sulfonyl group) is preferable. Ph represents a phenyl group.

As the counter anion, a counter anion having a low highest occupied molecular orbital (HOMO) level in order to suppress a nucleophilic reaction or an electron transfer reaction. By using the counter anion having a low HOMO level, heat resistance can be improved. An alkylcarboxylate ion substituted with an electron-withdrawing group (for example, a trifluoroacetate ion), an arylcarboxylate ion substituted with an electron-withdrawing group (for example, a hexafluorobenzoate ion), a substituted or unsubstituted alkylsulfonate ion, a substituted or unsubstituted arylsulfonate ion (for example, a hexafluorobenzenesulfonate ion), an aryl disulfonate ion, a tetrafluoroborate ion, a trifluorofluoroalkylborate ion, a tetraarylborate ion, a pentafluorophenylborate ion (for example, B⁻(C₆F₅)₄ or B⁻(C₆F₅)₃Ph), a hexafluorophosphate ion, an imide ion (including imide substituted with an acyl group or a sulfonyl group), or a methide ion (including a methide ion substituted with an acyl group or a sulfonyl group) is more preferable. An alkylsulfonate ion substituted with an electron-withdrawing group (a trifluoromethanesulfonate ion), an arylsulfonate ion substituted with an electron-withdrawing group (a hexafluorobenzenesulfonate ion), a tetrafluoroborate ion, a trifluorofluoroalkylborate ion, a heptafluorophenylborate ion, a hexafluorophosphate ion, a bissulfonylimide ion (for example, N⁻(SO₂CF₃)₂ or an imide anion having the following structure), an acylsulfonylimide ion (for example, a N-(trifluoromethanesulfonyl)trifluoroacetamide ion), a trisulfonylmethide ion (for example, C⁻(SO₂CF₃)₃) is still more preferable. A heptafluorophenylborate ion, a bissulfonylimide ion, or a trisulfonylmethide ion is even still more preferable.

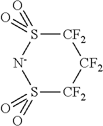 [SMILES: O=S1(=O)[N-]S(=O)(=O)C(F)(F)C(F)(F)C1(F)F]

In a case where the counter ion is a positive counter ion, examples of the positive counter ion include an inorganic or organic ammonium ion (for example, a tetraalkylammonium ion such as a tetrabutylammonium ion, a triethylbenzylammonium ion, or a pyridinium ion), a phosphonium ion (for example, a tetraalkylphosphonium ion such as a tetrabutylphosphonium ion, an alkyltriphenylphosphonium ion, or a triethylphenylphosphonium ion), an alkali metal ion, and a proton.

As the copper complex site, for example, the following aspects (1) to (5) are preferable, the aspects (2) to (5) are more preferable, the aspects (3) to (5) are still more preferable, and the aspect (4) is even still more preferable.

(1) An aspect where the copper complex site includes one or two or more bidentate ligands

(2) An aspect where the copper complex site includes a tridentate ligand

(3) An aspect where the copper complex site includes a bidentate ligand and a tridentate ligand

(4) An aspect where the copper complex site includes a tetradentate ligand

(5) An aspect where the copper complex site includes a pentadentate ligand

In the aspect (1), it is preferable that the bidentate ligand is a ligand having two coordination sites coordinated by an unshared electron pair or a ligand having a coordination site coordinated by an anion and a coordination site coordinated by an unshared electron pair. In a case where the copper complex site includes two or more bidentate ligands, the two or more bidentate ligands may be the same as or different from each other.

In addition, in the aspect (1), the copper complex site may further include the monodentate ligand. The number of monodentate ligands may be 0 or 1 to 3. Regarding the kind of the monodentate ligand, a monodentate ligand coordinated by an anion or a monodentate ligand coordinated by an unshared electron pair is preferable. In a case where the bidentate ligand has two coordination sites coordinated by an unshared electron pair, a monodentate ligand coordinated by an anion is more preferable because a coordination force is strong. In a case where the bidentate ligand has a coordination site coordinated by an anion and a coordination site coordinated by an unshared electron pair, a monodentate ligand coordinated by an unshared electron pair is more preferable because the entire complex has no charge.

In the aspect (2), as the tridentate ligand, a ligand having a coordination site coordinated by an unshared electron pair is preferable, and a ligand having three coordination sites coordinated by an unshared electron pair is more preferable.

In addition, in the aspect (2), the copper complex site may further include the monodentate ligand. The number of monodentate ligands may be 0. In addition, the number of monodentate ligands may be 1 or more and is preferably 1 to 3, more preferably 1 or 2, and still more preferably 2. Regarding the kind of the monodentate ligand, a monodentate ligand coordinated by an anion or a monodentate ligand coordinated by an unshared electron pair is preferable, and a monodentate ligand coordinated by an anion is more preferable due to the above-described reason.

In the aspect (3), as the tridentate ligand, a ligand having a coordination site coordinated by an anion and a coordination site coordinated by an unshared electron pair is preferable, and a ligand having two coordination sites coordinated by an anion and one coordination site coordinated by an unshared electron pair is more preferable. Further, it is still more preferable that the two coordination sites coordinated by an anion are different from each other. In addition, as the bidentate ligand, a ligand having a coordination site coordinated by an unshared electron pair is preferable, and a ligand having two coordination sites coordinated by an unshared electron pair is more preferable. In particular, it is preferable that the tridentate ligand is a ligand having two coordination sites coordinated by an anion and one coordination site coordinated by an unshared electron pair and the bidentate ligand is a ligand having two coordination sites coordinated by an unshared electron pair.

In addition, in the aspect (3), the copper complex site may further include the monodentate ligand. The number of monodentate ligands may be 0 or 1 or more. The number of monodentate ligand is preferably 0.

In the aspect (4), as the tetradentate ligand, a ligand having a coordination site coordinated by an unshared electron pair is preferable, a ligand having two or more coordination sites coordinated by an unshared electron pair is more preferable, and a ligand having four coordination sites coordinated by an unshared electron pair is still more preferable.

In addition, in the aspect (4), the copper complex site may further include the monodentate ligand. The number of monodentate ligands may be 0, 1 or more, or 2 or more. The number of monodentate ligand is preferably 1. Regarding the kind of the monodentate ligand, a monodentate ligand coordinated by an anion or a monodentate ligand coordinated by an unshared electron pair is preferable.

In the aspect (5), as the pentadentate ligand, a ligand having a coordination site coordinated by an unshared electron pair is preferable, a ligand having two or more coordination sites coordinated by an unshared electron pair is more preferable, and a ligand having five coordination sites coordinated by an unshared electron pair is still more preferable.

In addition, in the aspect (5), the copper complex site may further include the monodentate ligand. The number of monodentate ligands may be 0 or 1 or more. The number of monodentate ligand is preferably 0.

Specific examples of the copper complex site are as follows. In the formulae, a wave line represents a binding site to L¹ in Formula (1). In the following formulae, Me represents a methyl group, Et represents an ethyl group, Bu represents a butyl group, and Ph represents a phenyl group. In addition, Cu32 denotes a structure in which Het has any one of the following structures. All the Het's may be the same as or different from each other.

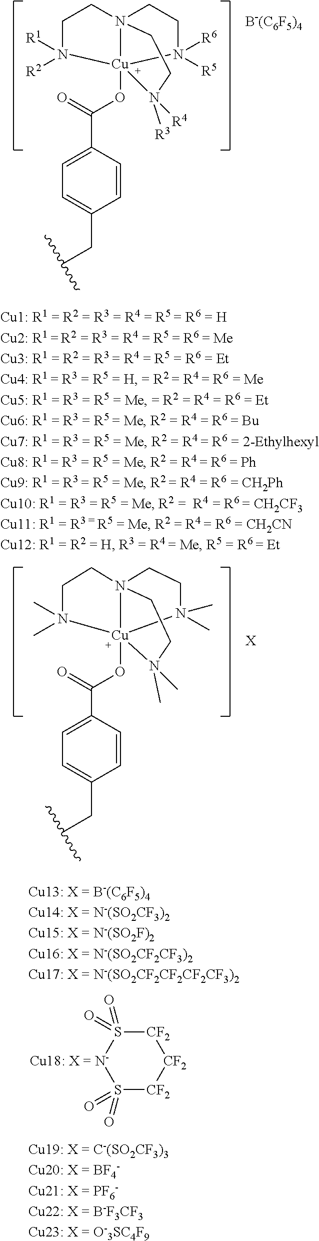

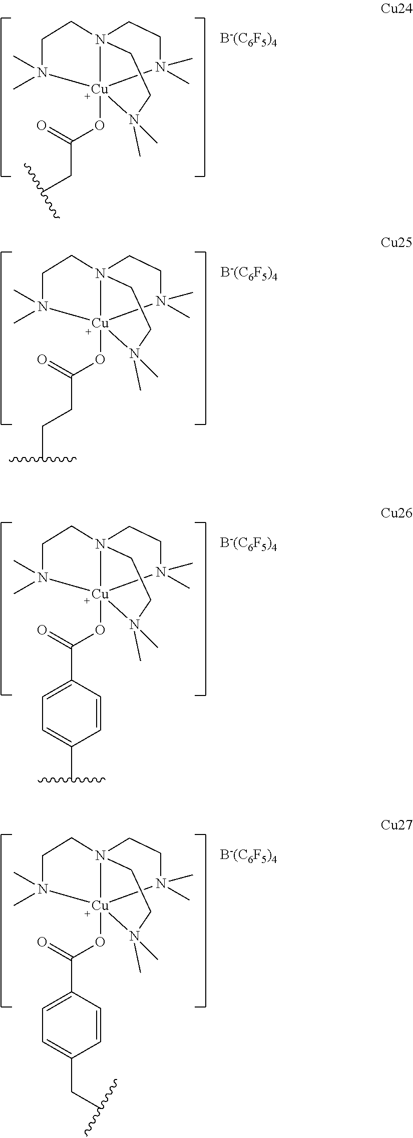

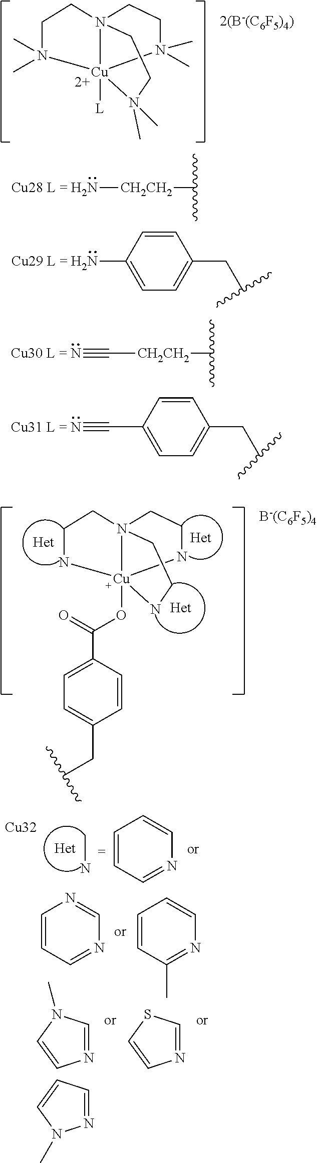

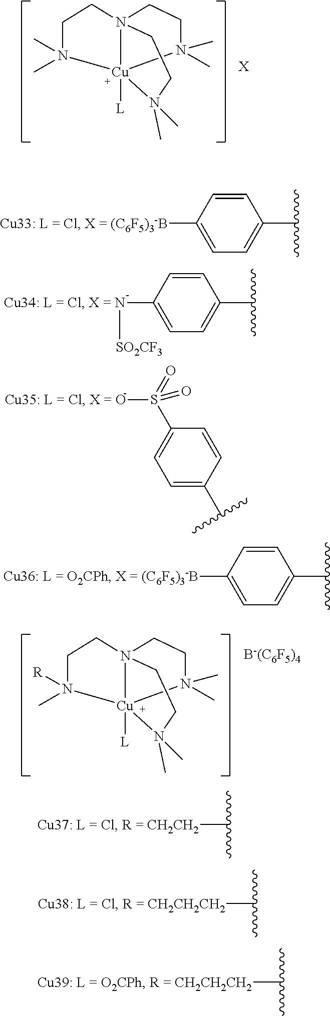

It is preferable that the copper-containing polymer according to the present invention includes a constitutional unit represented by the following Formula (A1-1).

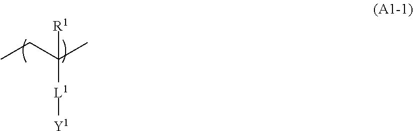

In Formula (A1-1), R¹ represents a hydrogen atom or a hydrocarbon group.

L¹ represents a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond.

Y¹ represents a copper complex site.

In this case, in a case where L¹ has a —C(═O)O— bond, L¹ has at least one —C(═O)O— bond which is not directly bonded to the polymer main chain, and in a case where L¹ has a —NH—CO— bond, L¹ has at least one —NH—CO— bond which is not directly bonded to the polymer main chain.

In Formula (A1-1), R¹ represents a hydrogen atom or a hydrocarbon group. Examples of the hydrocarbon group include a linear, branched, or cyclic aliphatic hydrocarbon group and an aromatic hydrocarbon group. The hydrocarbon group may have a substituent but is preferably unsubstituted. The number of carbon atoms in the hydrocarbon group is preferably 1 to 10, more preferably 1 to 5, and still more preferably 1 to 3. In addition, the hydrocarbon group is preferably a methyl group. It is preferable that R¹ represents a hydrogen atom or a methyl group.

L¹ and Y¹ in Formula (A1-1) have the same definitions and the same preferable ranges as L¹ and Y¹ in Formula (1).

Examples of the constitutional unit represented by Formula (A1-1) include constitutional units represented by the following Formulae (A1-1-1), (A1-1-2), or (A1-1-3).

The following formula (A1-1-1) is preferable.

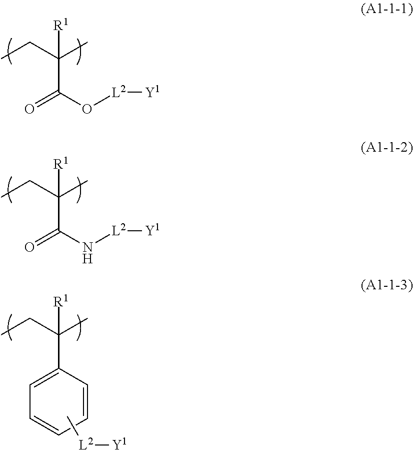

In the formula, R¹ represents a hydrogen atom or a hydrocarbon group.

L² represents a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond.

Y¹ represents a copper complex site.

R¹ and Y¹ in Formulae (A1-1-1) to (A1-1-3) have the same definitions and the same preferable ranges as R¹ and Y¹ in Formula (A1-1).

In Formulae (A1-1-1) to (A1-1-3), L² represents a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond. It is preferable that L² represents a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, and a —NH—C(═S)NH— bond.

Examples of the linking group represented by L² include a linking group having the above-described bond, and a linking group having a combination of the above-described bond and at least one selected from the group consisting of an alkylene group, an arylene group, a heteroarylene group, —O—, —S—, —CO—, —C(═O)O—, —SO₂—, and NR¹⁰ (R¹⁰ represents a hydrogen atom or an alkyl group and preferably a hydrogen atom). Among these, a linking group having a combination of the above-described bond and an alkylene group, an arylene group, —CO—, —C(═O)O—, or —NR¹⁰— is preferable, and a linking group having a combination of the above-described bond and at least one selected from the group consisting of an alkylene group, an arylene group, and —C(═O)O— is more preferable.

It is preferable that the linking group represented by L² is a linking group represented by the following formula.

*¹-L¹⁰¹-L¹⁰²-L¹⁰³-*²

In the formula, *¹ represents a direct bond to the polymer.

*² represents a direct bond to the copper complex site.

L¹⁰¹ represents an alkylene group.

L¹⁰² represents a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, or a —NH—CO— bond

L¹⁰³ represents a single bond, an alkylene group, an arylene group, a heteroarylene group, —O—, —S—, —CO—, —C(═O)O—, —SO₂—, —NR¹⁰— (R¹⁰ represents a hydrogen atom or an alkyl group and preferably a hydrogen atom), or a group including a combination of two or more kinds of the above-described groups.

The copper-containing polymer according to the present invention may include other constitutional units in addition to the constitutional unit represented by Formula (A1-1).

The details of components constituting the other constitutional units can be found in the description of copolymerization components in paragraphs “0068” to “0075” of JP2010-106268A (corresponding to paragraphs “0112” to “0118” of US2011/0124824A), the content of which is incorporated herein by reference.

In a case where the copper-containing polymer includes the other constitutional unit, a molar ratio of the amount of the constitutional unit represented by Formula (A1-1) to the amount of the other constitutional units is preferably 95:5 to 20:80 and more preferably 90:10 to 40:60.

Preferable examples of the other constitutional units include constitutional units represented by the following Formulae (A2-1) to (A2-6).

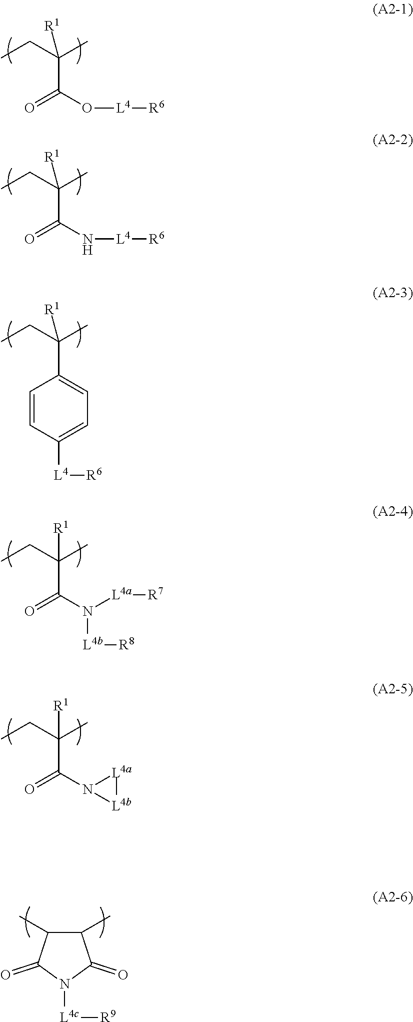

In the formulae, R¹ represents a hydrogen atom or a hydrocarbon group, L⁴, L^{4a}, L^{4b} and L⁴c each independently represent a single bond or a divalent linking group, and R⁶ to R⁹ each independently represent an alkyl group or an aryl group.

R¹ has the same definition and the same preferable range as R¹ in Formula (A1-1).

L⁴, L^{4a}, L^{4b}, and L⁴c each independently represent a single bond or a divalent linking group. As the linking group, an alkylene group, an arylene group, a heteroarylene group, —O—, —S—, —CO—, —C(═O)O—, —SO₂—, —NR¹⁰— (R¹⁰ represents a hydrogen atom or an alkyl group and preferably a hydrogen atom), or a group including a combination of two or more kinds of the above-described groups is preferable. As the group including a combination of two or more kinds of the above-described groups, an alkyleneoxy group (—(—O-Rx)ₙ-) is preferable. Rx represents an alkylene group, and n represents an integer of 1 or more (preferably an integer of 1 to 20).

The alkyl group represented by R⁶ to R⁹ may be linear, branched, or cyclic and is preferably linear or branched. The number of carbon atoms in the alkyl group is preferably 1 to 30, more preferably 1 to 20, and still more preferably 1 to 10. The alkyl group may have a substituent, and examples of the substituent include the above-described substituents.

The aryl group represented by R⁶ to R⁹ may be monocyclic or polycyclic and is preferably monocyclic. The number of carbon atoms in the aryl group is preferably 6 to 18, more preferably 6 to 12, and still more preferably 6.

Specific examples of the constitutional units are as follows.

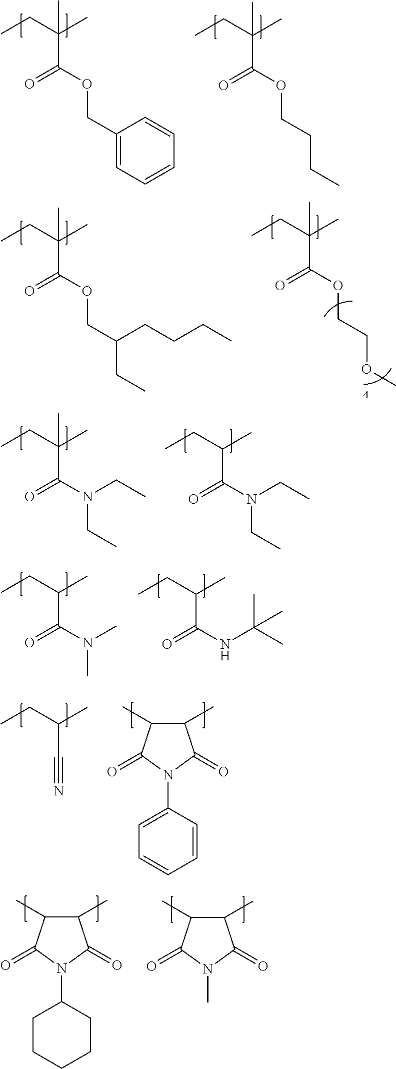

In a case where the copper-containing polymer includes the other constitutional units, the content of the other constitutional units is preferably 5 to 80 mol % with respect to all the constitutional units of the copper-containing polymer. The upper limit is preferably 10 mol % or higher and more preferably 20 mol %, or higher. The lower limit is preferably 75 mol % or lower and more preferably 70 mol % or lower.

In addition, it is also preferable that the copper-containing polymer according to the present invention includes a constitutional unit having a partial structure represented by M-X (also referred to as “constitutional unit (MX)” as the other constitutional units. According to this aspect, a film having excellent heat resistance is likely to be formed.

In the constitutional unit (MX), M represents an atom selected from the group consisting of Si, Ti, Zr, and Al, and represents preferably Si, Ti, or Zr, and more preferably Si.

In the constitutional unit (MX), X represents one selected from the group a hydroxyl group, an alkoxy group, an acyloxy group, a phosphoryloxy group, a sulfonyloxy group, an amino group, an oxime group, or O═C(R^{a})(R^{b}), and represents preferably an alkoxy group, an acyloxy group, or an oxime group and more preferably an alkoxy group. In a case where X represents O═C(R^{a})(R^{b}), X is bonded to M by an unshared electron pair of an oxygen atom in a carbonyl group (—CO). R^{a} and R^{b} each independently represent a monovalent organic group.

In the partial structure represented by M-X, it is preferable that M represents Si and X represents an alkoxy group. This combination has an appropriate reactivity, the storage stability of the near infrared absorbing composition can be improved. Further, a film having higher heat resistance is likely to be formed.

The number of carbon atoms in the alkoxy group is preferably 1 to 20, more preferably 1 to 10, still more preferably 1 to 5, and even still preferably 1 or 2. The alkoxy group may be linear, branched, or cyclic and is preferably linear or branched and more preferably linear.

The alkoxy group may be unsubstituted or may have a substituent, and is preferably unsubstituted. Examples of the substituent include a halogen atom (preferably, a fluorine atom), a polymerizable group (for example, a vinyl group, a (meth)acryloyl group, a styryl group, an epoxy group, or an oxetane group), an amino group, an isocyanate group, an isocyanurate group, an ureido group, a mercapto group, a sulfide group, a sulfo group, a carboxyl group, and a hydroxyl group.

As the acyloxy group, for example, a substituted or unsubstituted alkylcarbonyloxy group having 2 to 30 carbon atoms, or a substituted or unsubstituted arylcarbonyloxy group having 6 to 30 carbon atoms is preferable. Examples of the acyloxy group include a formyloxy group, an acetyloxy group, a pivaloyloxy group, stearoyloxy, a benzoyloxy group, and a p-methoxyphenylcarbonyloxy group. Examples of the substituent include the above-described substituents.

The number of carbon atoms in the oxime group is preferably 1 to 20, more preferably 1 to 10, and still more preferably 1 to 5. Examples of the oxime group include an ethyl methyl ketoxime group.

Examples of the amino group include an amino group, a substituted or unsubstituted alkylamino group having 1 to 30 carbon atoms, a substituted or unsubstituted arylamino group having 6 to 30 carbon atoms, and a heterocyclic amino group having 0 to 30 carbon atoms.

Examples of the amino group include amino, methylamino, dimethylamino, anilino, N-methyl-anilino, diphenylamino, and N-1,3,5-triazin-2-ylamino. Examples of the substituent include the above-described substituents.

Examples of the monovalent organic group represented by R^{a} and R^{b} include an alkyl group, an aryl group, and —R¹⁰¹—COR¹⁰².

The number of carbon atoms in the alkyl group is preferably 1 to 20 and more preferably 1 to 10. The alkyl group may be linear, branched, or cyclic. The alkyl group may be unsubstituted or may have the above-described substituent.

The number of carbon atoms in the aryl group is preferably 6 to 20 and more preferably 6 to 12. The aryl group may be unsubstituted or may have the above-described substituent.

In the group represented by —R¹⁰¹—COR¹⁰², R¹⁰¹ represents an arylene group, and R¹⁰² represents an alkyl group or an aryl group.

The number of carbon atoms in the arylene group represented by R¹⁰¹ is preferably 6 to 20 and more preferably 6 to 10. The arylene group may be linear, branched, or cyclic. The arylene group may be unsubstituted or may have the above-described substituent.

The alkyl group and the aryl group represented by R¹⁰² are the same as described above regarding R^{a} and R^{b}, and preferable ranges thereof are also the same.

Examples of the constitutional unit (MX) include the following formulae (MX2-1) to (MX2-4).

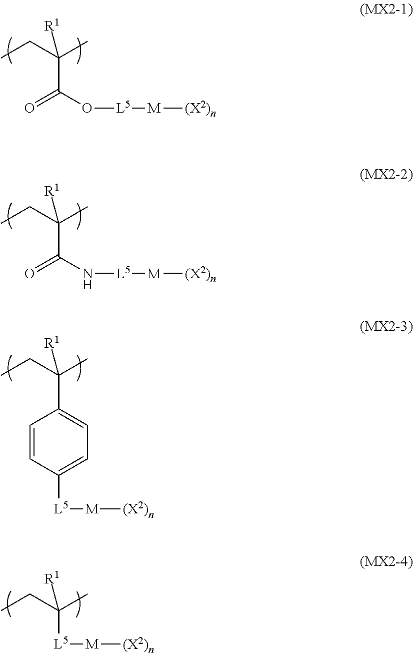

M represents an atom selected from the group consisting of Si, Ti, Zr, and Al, X² represents a substituent or a ligand, at least one of n X²'s represents one selected from the group a hydroxyl group, an alkoxy group, an acyloxy group, a phosphoryloxy group, a sulfonyloxy group, an amino group, an oxime group, and O═C(R^{a})(R^{b}), X²'s may be bonded to each other to form a ring, R¹ represents a hydrogen atom or an alkyl group, L⁵ represents a single bond or a divalent linking group, and n represents the number of direct bonds to X² of M.

M represents an atom selected from the group consisting of Si, Ti, Zr, and Al, and represents preferably Si, Ti, or Zr, and more preferably Si.

X² represents a substituent or a ligand, and at least one of n X²'s represents one selected from the group a hydroxyl group, an alkoxy group, an acyloxy group, a phosphoryloxy group, a sulfonyloxy group, an amino group, an oxime group, and O═C(R^{a})(R^{b}). It is preferable that at least one of n X² represents one selected from the group consisting of an alkoxy group, an acyloxy group, and an oxime group, it is more preferable that at least one of n X² represents an alkoxy group, and it is still more preferable that all the n X² represent an alkoxy group.

Among the substituents or the ligands, a hydroxyl group, an alkoxy group, an acyloxy group, a phosphoryloxy group, a sulfonyloxy group, an amino group, an oxime group, and O═C(R^{a})(R^{b}) have the same definitions and the same preferable ranges as described above.

As a substituent other than a hydroxyl group, an alkoxy group, an acyloxy group, a phosphoryloxy group, a sulfonyloxy group, an amino group, and an oxime group, a hydrocarbon group is preferable. Examples of the hydrocarbon group include an alkyl group, an alkenyl group, and an aryl group.

The alkyl group may be linear, branched, or cyclic. The number of carbon atoms in the linear alkyl group is preferably 1 to 20, more preferably 1 to 12, and still more preferably 1 to 8. The number of carbon atoms in the branched alkyl group is preferably 3 to 20, more preferably 3 to 12, and still more preferably 3 to 8. The cyclic alkylene group may be monocyclic or polycyclic. The number of carbon atoms in the cyclic alkyl group is preferably 3 to 20, more preferably 4 to 10, and still more preferably 6 to 10.

The number of carbon atoms in the alkenyl group is preferably 2 to 10, more preferably 2 to 8, and still more preferably 2 to 4.

The number of carbon atoms in the aryl group is preferably 6 to 18, more preferably 6 to 14, and still more preferably 6 to 10.

The hydrocarbon group may have a substituent. Examples of the substituent include an alkyl group, a halogen atom (preferably, a fluorine atom), a polymerizable group (for example, a vinyl group, a (meth)acryloyl group, a styryl group, an epoxy group, or an oxetane group), an amino group, an isocyanate group, an isocyanurate group, an ureido group, a mercapto group, a sulfide group, a sulfo group, a carboxyl group, a hydroxyl group, and an alkoxy group.

X²'s may be bonded to each other to form a ring.

R¹ represents a hydrogen atom or an alkyl group. The number of carbon atoms in the alkyl group is preferably 1 to 5, more preferably 1 to 3, and still more preferably 1. The alkyl group is preferably linear or branched and more preferably linear. At least a portion or all of the hydrogen atoms in the alkyl group may be substituted with halogen atoms (preferably fluorine atoms).

L⁵ represents a single bond or a divalent linking group. Examples of the divalent linking group include an alkylene group, an arylene group, —O—, —S—, —CO—, —COO—, —OCO—, —SO₂—, —NR¹⁰— (R¹⁰ represents a hydrogen atom or an alkyl group and preferably a hydrogen atom), and a group including a combination thereof. Among these, an alkylene group, an arylene group, or a group including at least an alkylene group is preferable, and an arylene group or an alkylene group is more preferable.

The number of carbon atoms in the alkylene group is preferably 1 to 30, more preferably 1 to 15, and still more preferably 1 to 10. The alkylene group may have a substituent but is preferably unsubstituted. The alkylene group may be linear, branched, or cyclic. In addition, the cyclic alkylene group may be monocyclic or polycyclic.

As the arylene group, an arylene group having 6 to 18 carbon atoms is preferable, an arylene group having 6 to 14 carbon atoms is more preferable, an arylene group having 6 to 10 carbon atoms is still more preferable, and a phenylene group is even still more preferable.

Specific examples of the constitutional unit (MX) are as follows.

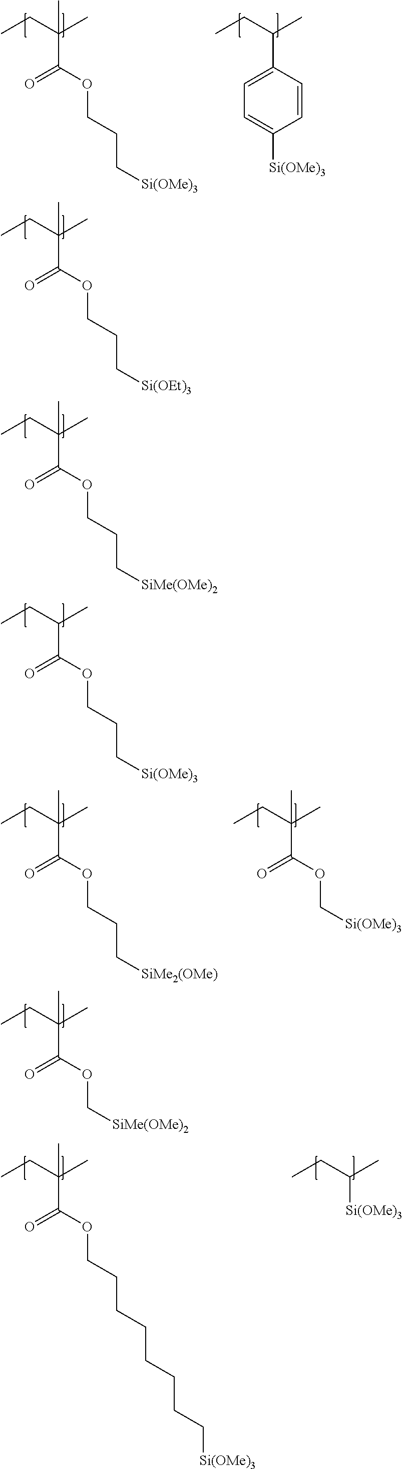

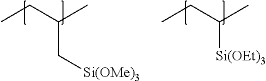

In a case where the copper-containing polymer includes the constitutional unit (MX), the content of the constitutional unit (MX) is preferably 5 to 80 mol % with respect to all the constitutional units of the copper-containing polymer. The upper limit is preferably 10 mol % or higher and more preferably 20 mol % or higher. The lower limit is preferably 70 mol % or lower and more preferably 60 mol % or lower.

The weight-average molecular weight of the copper-containing polymer is preferably 2000 or higher, more preferably 2000 to 2000000, and still more preferably 6000 to 200000.

By adjusting the weight-average molecular weight of the copper-containing polymer to be in the above-described range, the heat resistance of the obtained cured film tends to be further improved.

Specific examples of the copper-containing polymer are as follows.

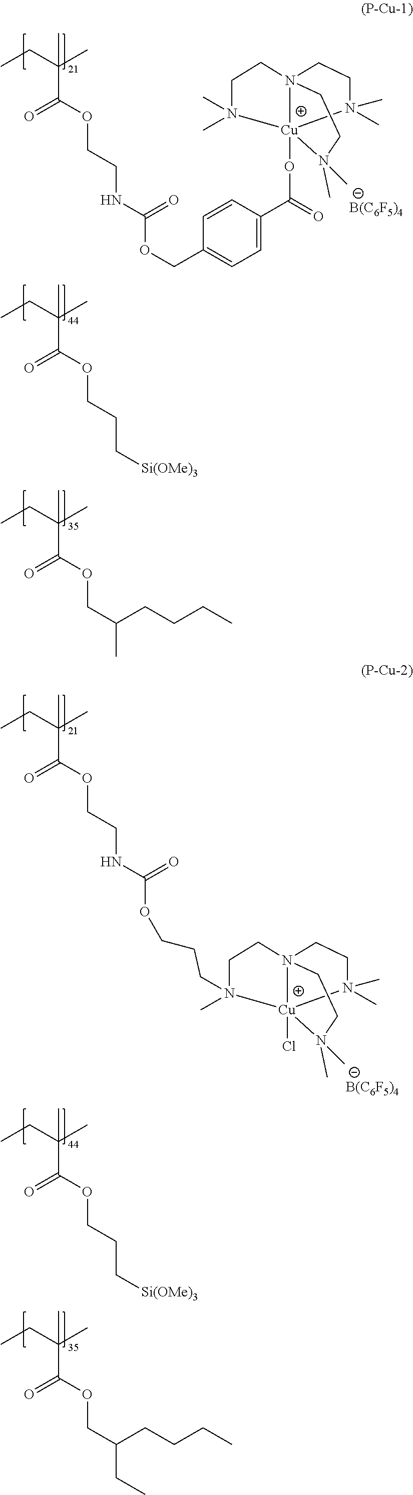

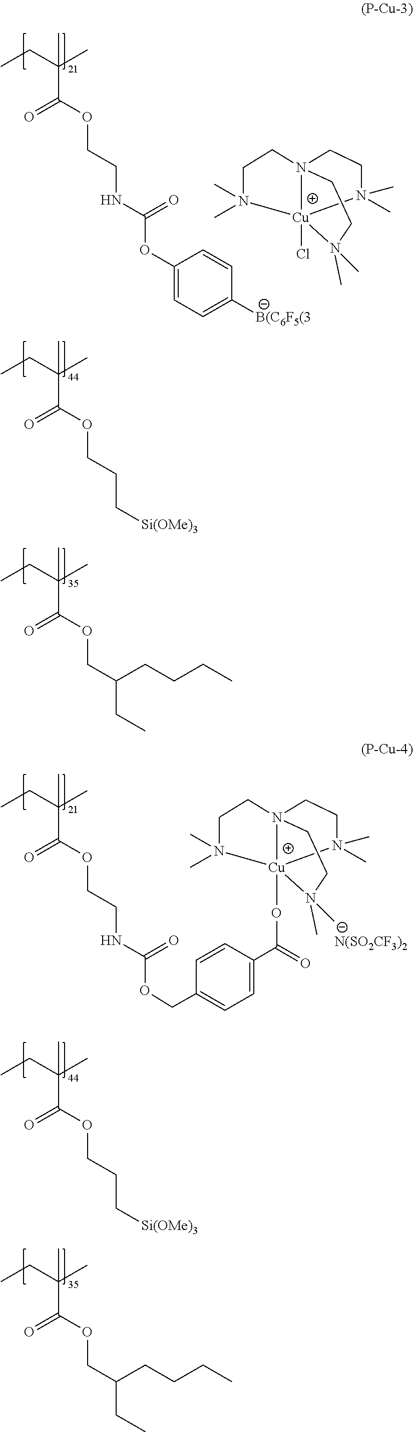

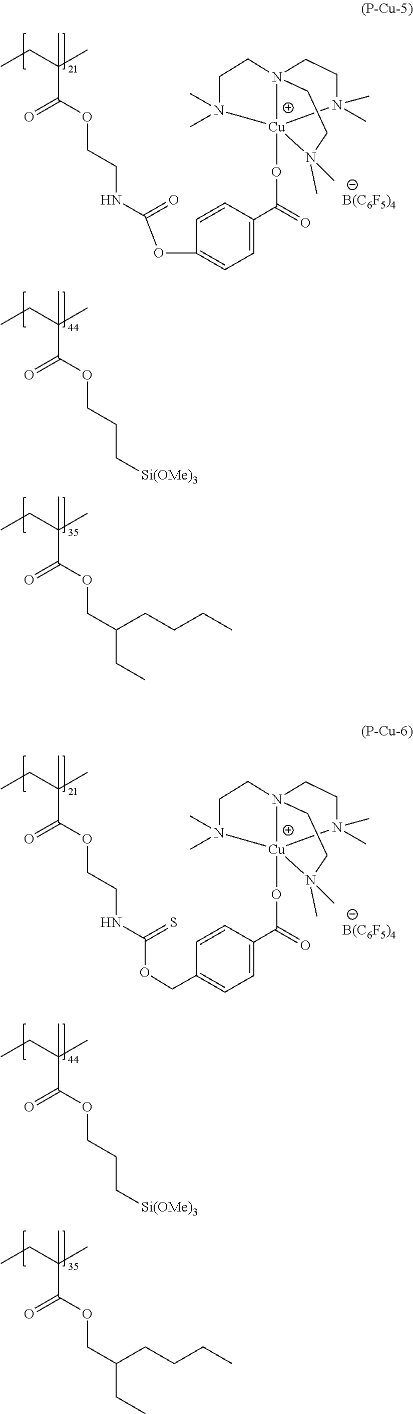

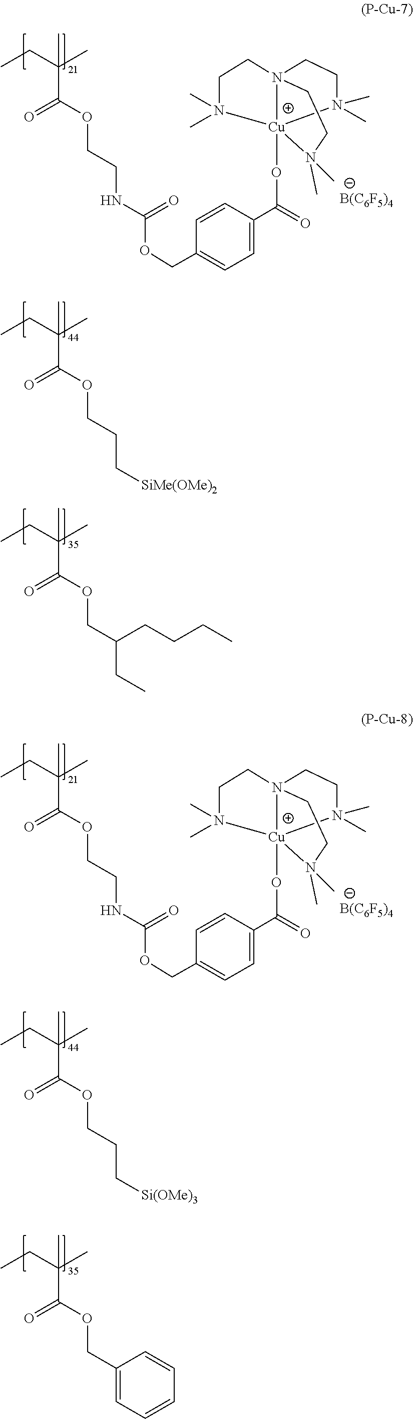

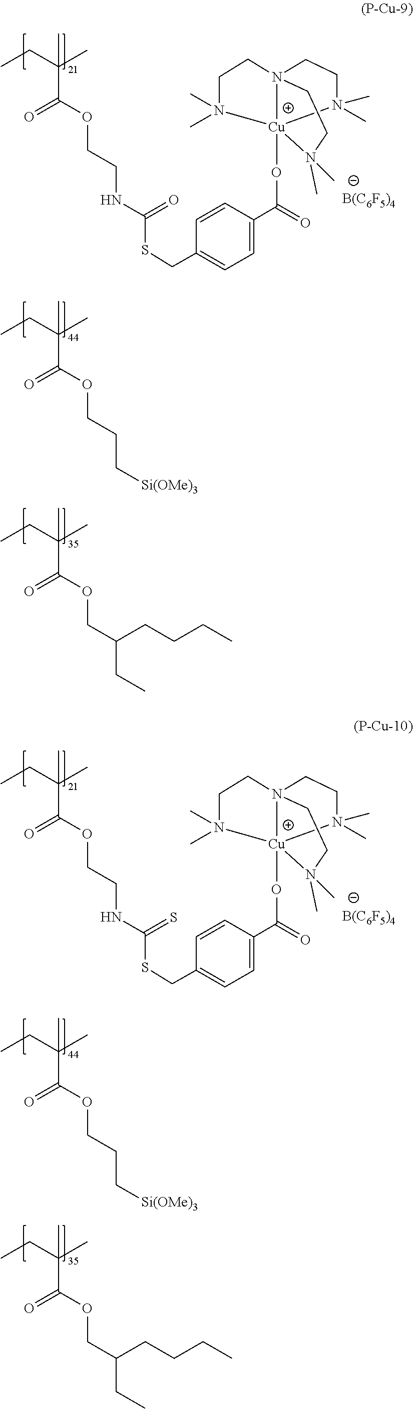

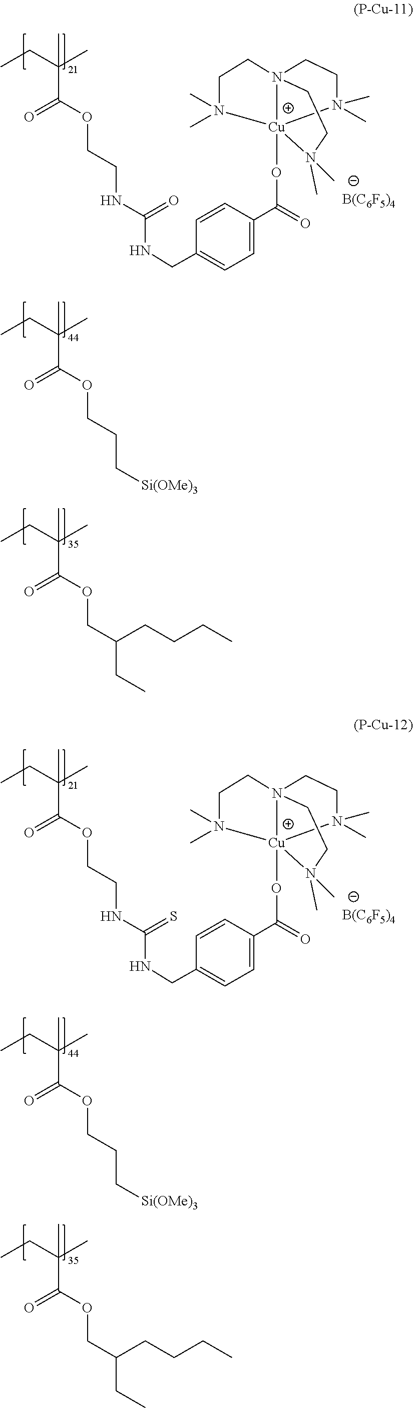

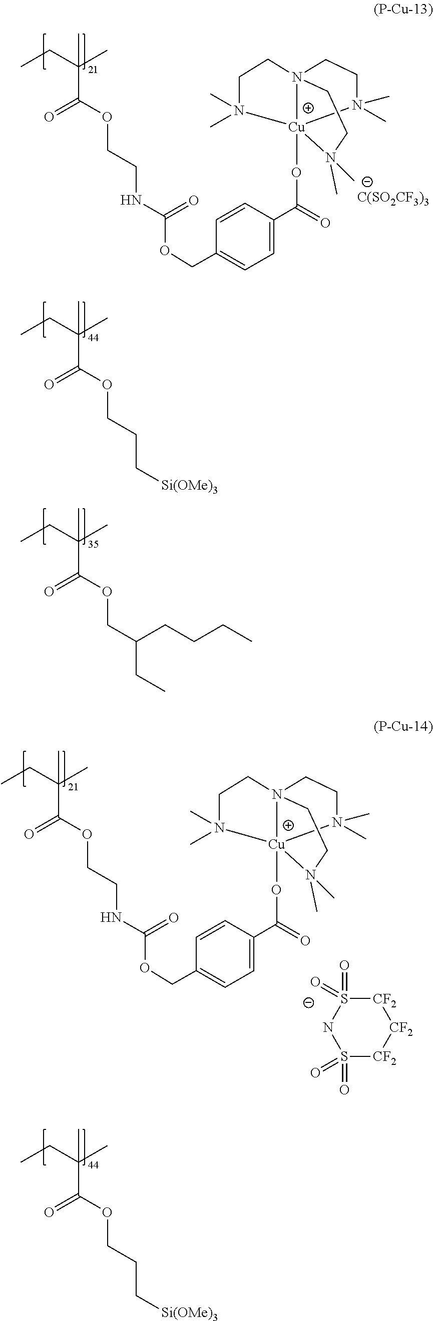

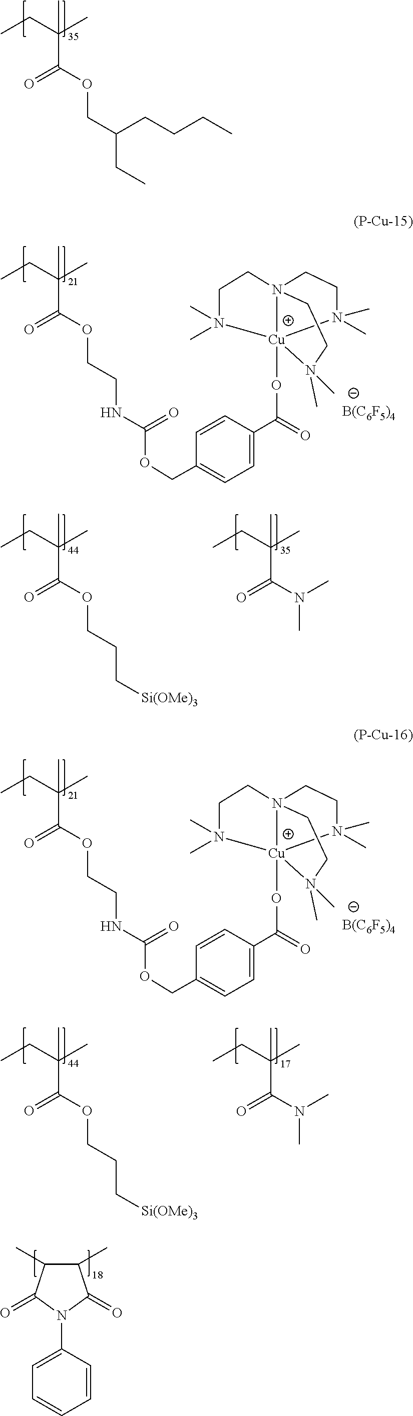

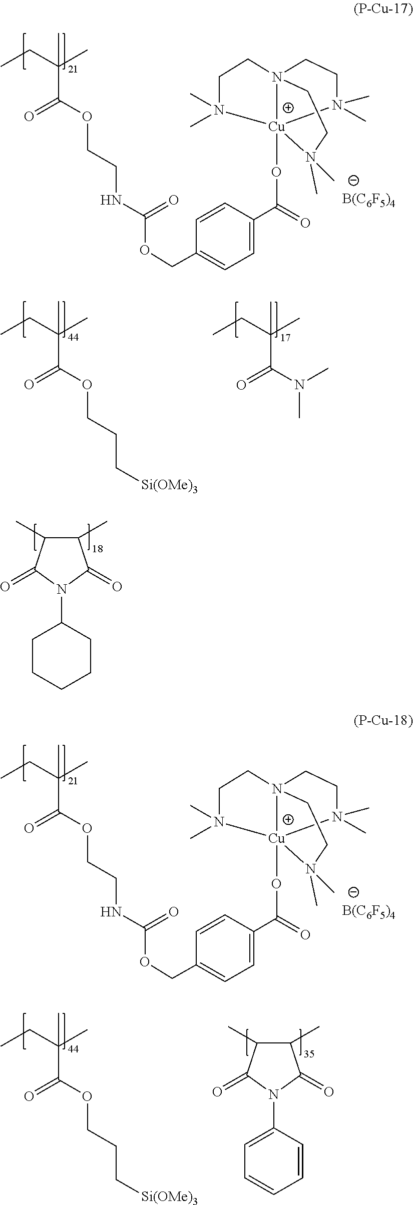

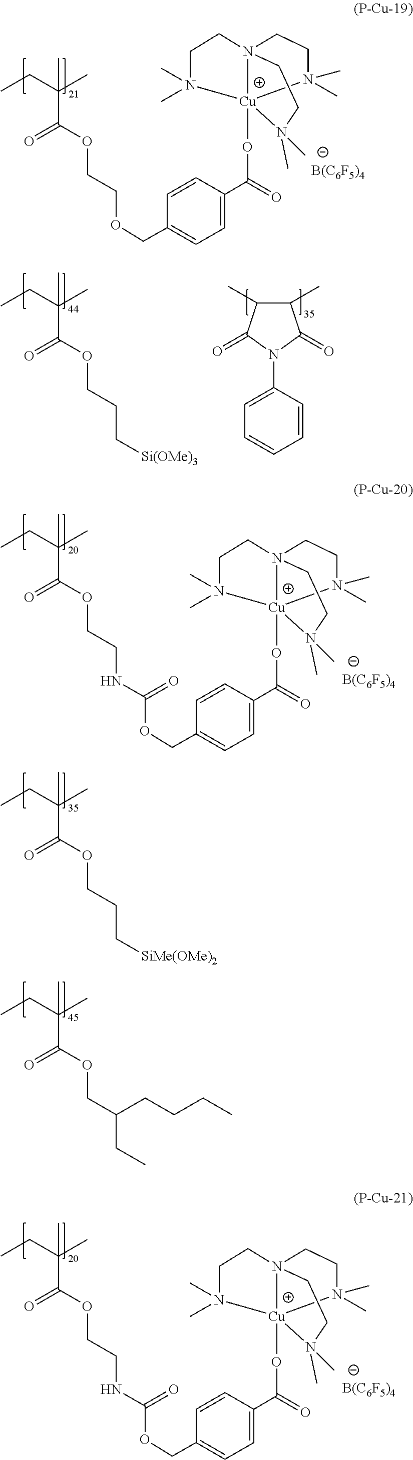

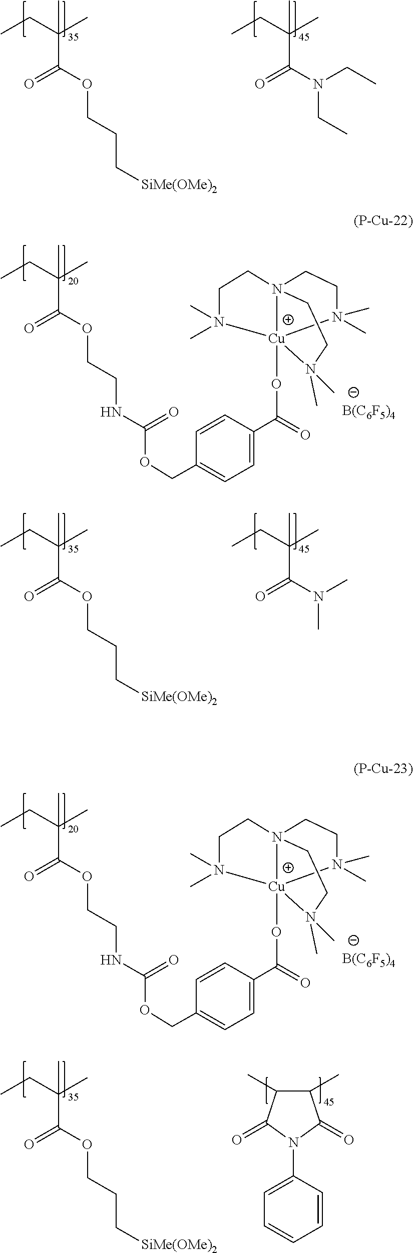

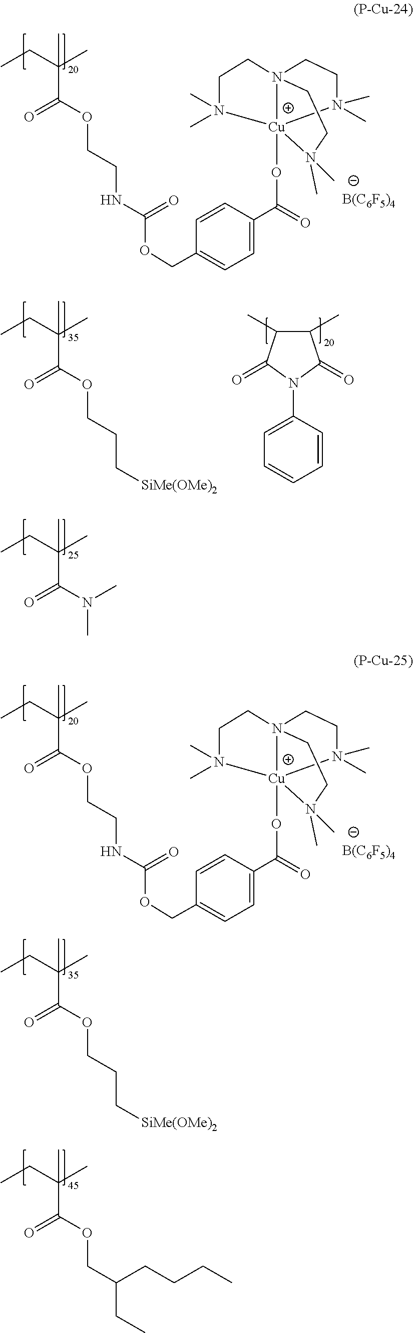

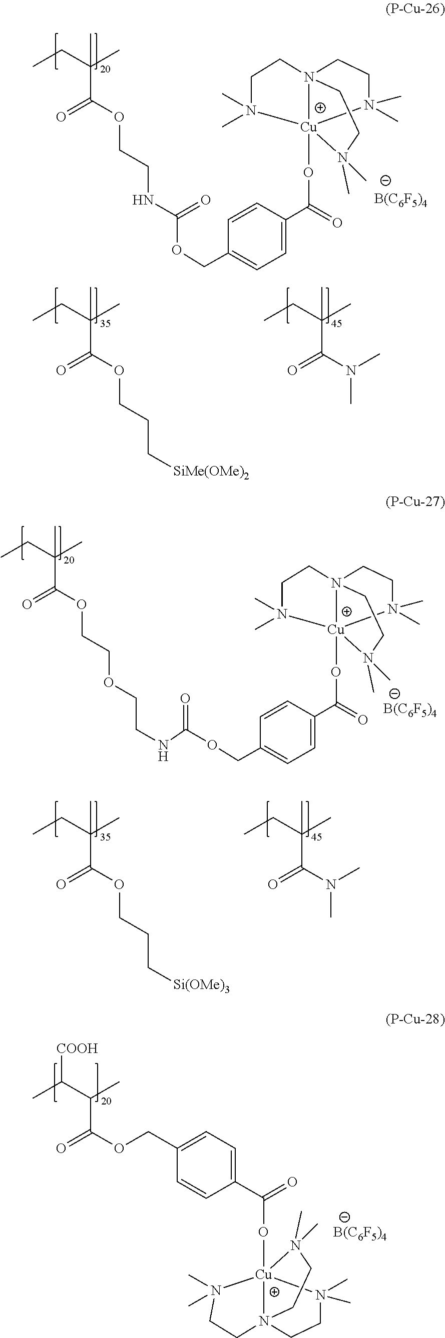

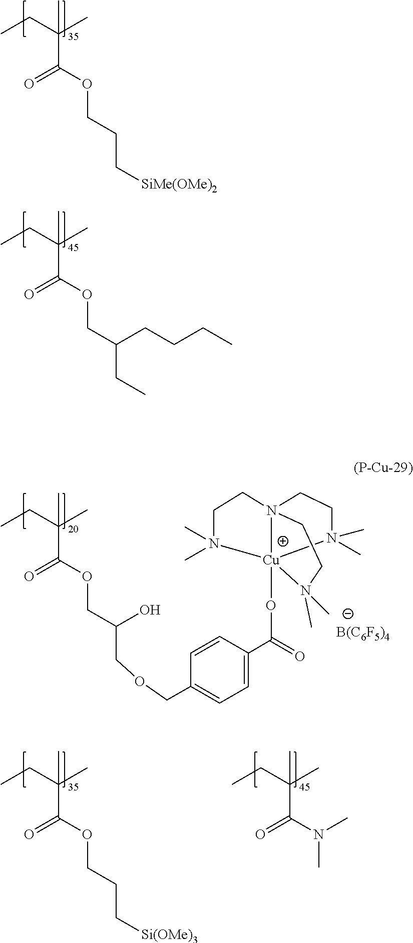

(Method of Manufacturing Copper-Containing Polymer)

Next, a method of manufacturing a copper-containing polymer according to the present invention will be described.

The copper-containing polymer according to the present invention can be manufactured by causing a polymer (A′) having a reactive site at a polymer side chain and a copper complex (B′) having a functional group which is reactive with the reactive site of the polymer (A′) to react with each other.

Examples of a preferable combination of the reactive site of the polymer and the functional group of the copper complex (B′) and a bond formed from the reaction include (1) to (12) shown above. Among these, (1) to (6) are preferable.

As the polymer (A′), any polymer having a reactive site which is reactive with the functional group of the copper complex (B′) can be preferably used. It is preferable that the reactive site is present at a side chain of the polymer.

It is preferable that the polymer (A′) includes a constitutional unit represented by the following Formula (A′1-1).

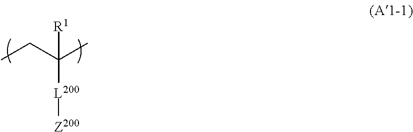

In Formula (A′1-1), R¹ represents a hydrogen atom or a hydrocarbon group, L²⁰⁰ represents a single bond or a linking group, and Z²⁰⁰ represents a reactive site.

R¹ in Formula (A′1-1) has the same definition and the same preferable range as R¹ in Formula (A1-1).

L²⁰⁰ represents a single bond or a linking group. Examples of the linking group represented by L² include a linking group having a combination including at least one selected from the group consisting of an alkylene group, an arylene group, a heteroarylene group, —O—, —S—, —CO—, —C(═O)O—, —SO₂—, and NR¹⁰ (R¹⁰ represents a hydrogen atom or an alkyl group and preferably a hydrogen atom).

Z²⁰⁰ represents a reactive site. The reactive site may be any site which is reactive with the functional group of the copper complex (B). Examples of the reactive site include —NCO, —NCS, —C(═O)OC(═O)—R, and a halogen atom. R represents a hydrogen atom or an alkyl group and may be bonded to the polymer main chain.

Examples of the constitutional unit represented by Formula (A′1-1) include constitutional units represented by the following Formulae (A′1-1-1) to (A′1-1-3). The following formula (A′1-1-1) is preferable.

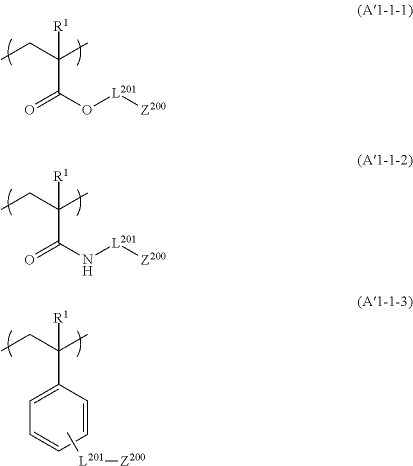

In the formula, R¹ represents a hydrogen atom or a hydrocarbon group, L²⁰¹ represents a single bond or a linking group, and Z²⁰⁰ represents a reactive site.

R¹ and Z²⁰⁰ in Formulae (A′1-1-1) to (A′1-1-3) have the same definitions and the same preferable ranges as R¹ and Z²⁰⁰ in Formula (A′1-1).

L²⁰¹ in Formulae (A′1-1-1) to (A′1-1-3) represents a single bond or a linking group.

Examples of the linking group represented by L² include a linking group having a combination including at least one selected from the group consisting of an alkylene group, an arylene group, a heteroarylene group, —O—, —S—, —CO—, —C(═O)O—, —SO₂—, and NR¹⁰ (R¹⁰ represents a hydrogen atom or an alkyl group and preferably a hydrogen atom). An alkylene group is preferable.

The polymer (A′) may include other constitutional units. Examples of the other constitutional units include the constitutional units represented by (A2-1) to (A2-6) described above regarding the copper-containing polymer and the constitutional unit (MX).

The weight-average molecular weight of the polymer (A′) is preferably 2000 or higher, more preferably 2000 to 2000000, and still more preferably 6000 to 200000. By adjusting the weight-average molecular weight of the polymer (A′) to be in the above-described range, the heat resistance of the obtained cured film tends to be further improved.

Specific examples of the polymer (A′) are as follows.

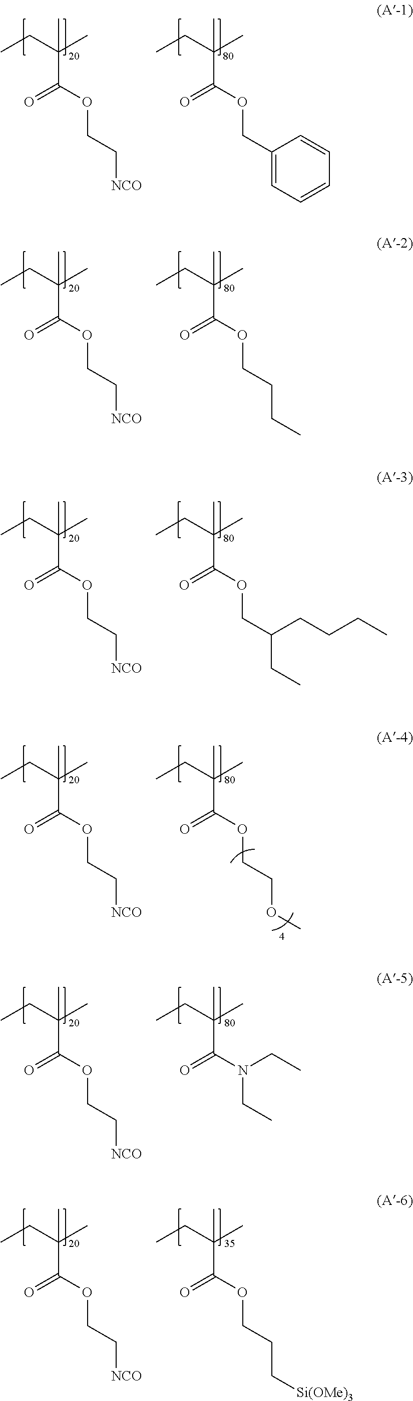

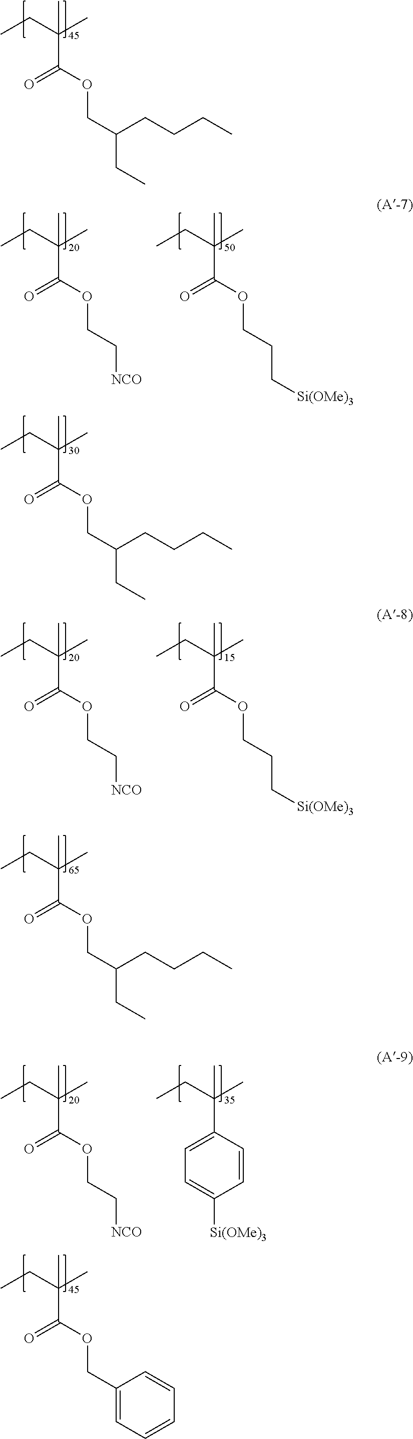

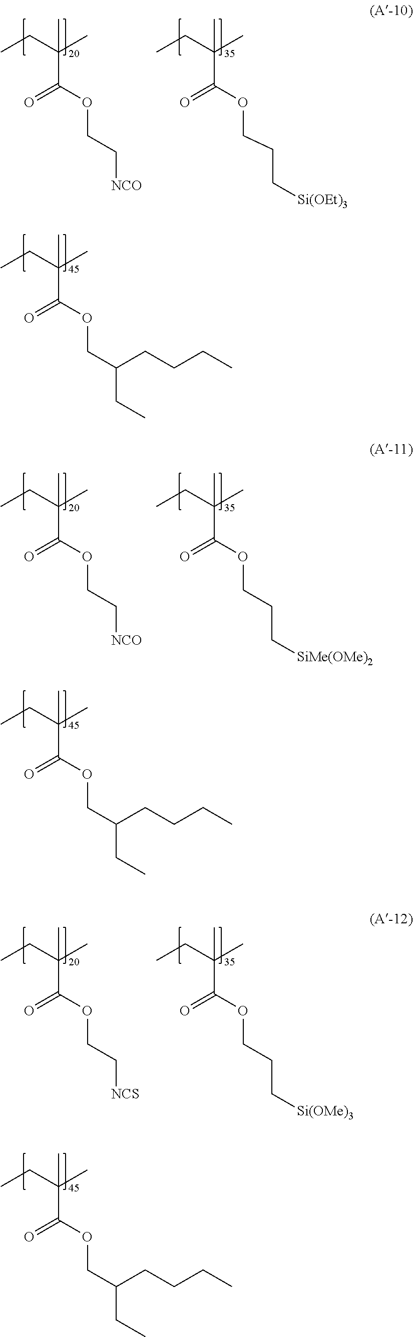

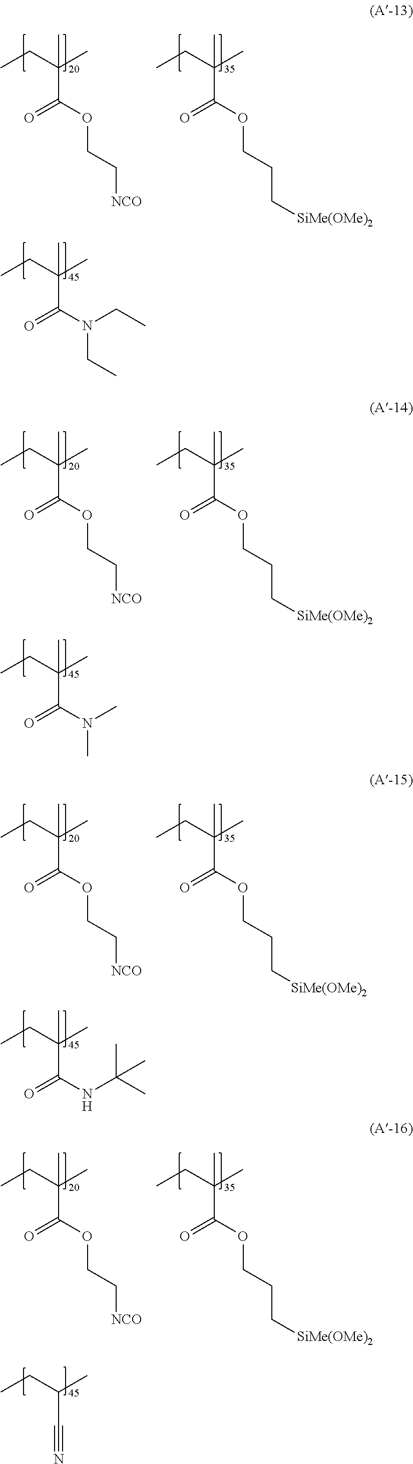

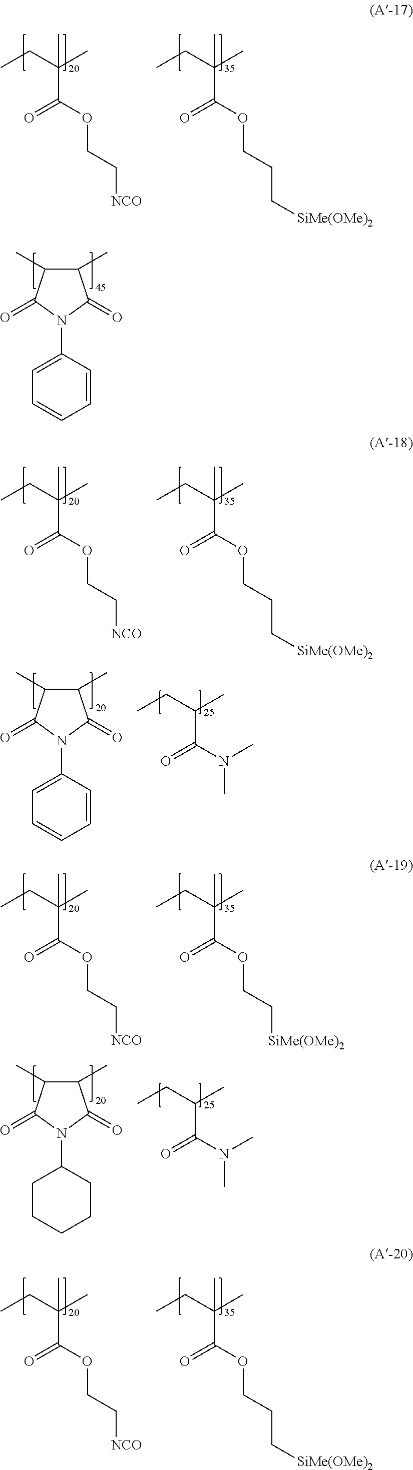

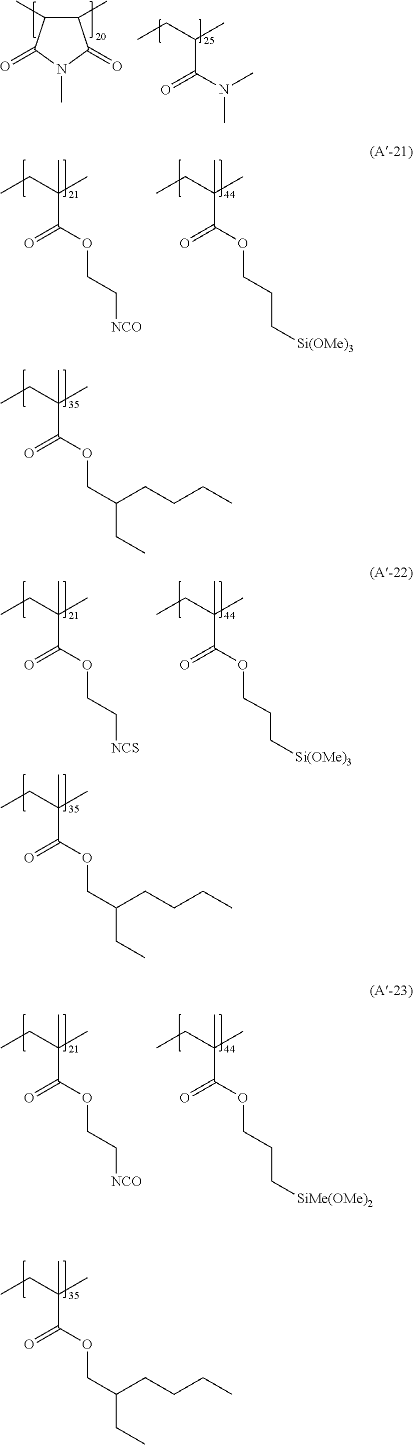

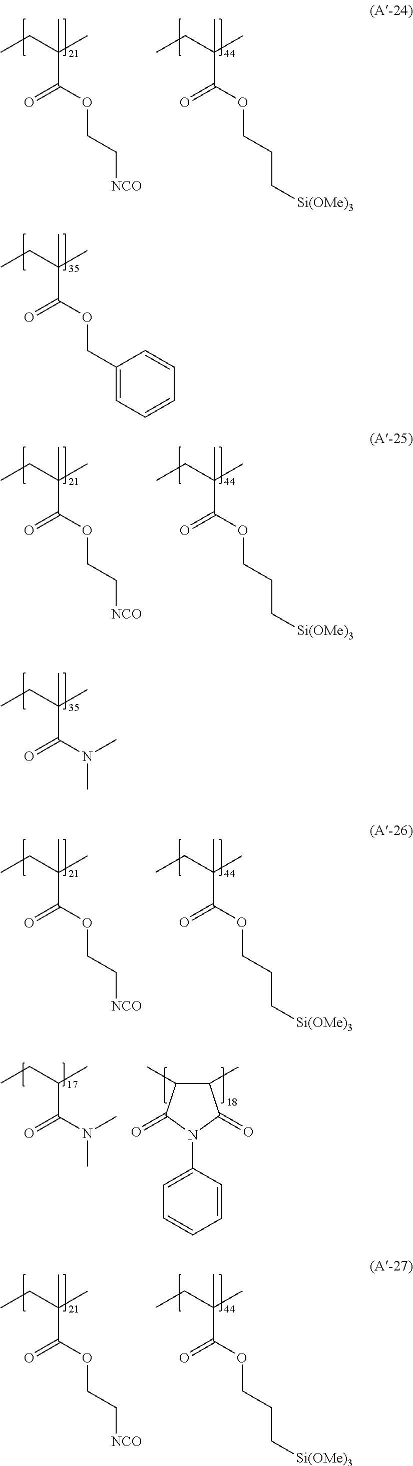

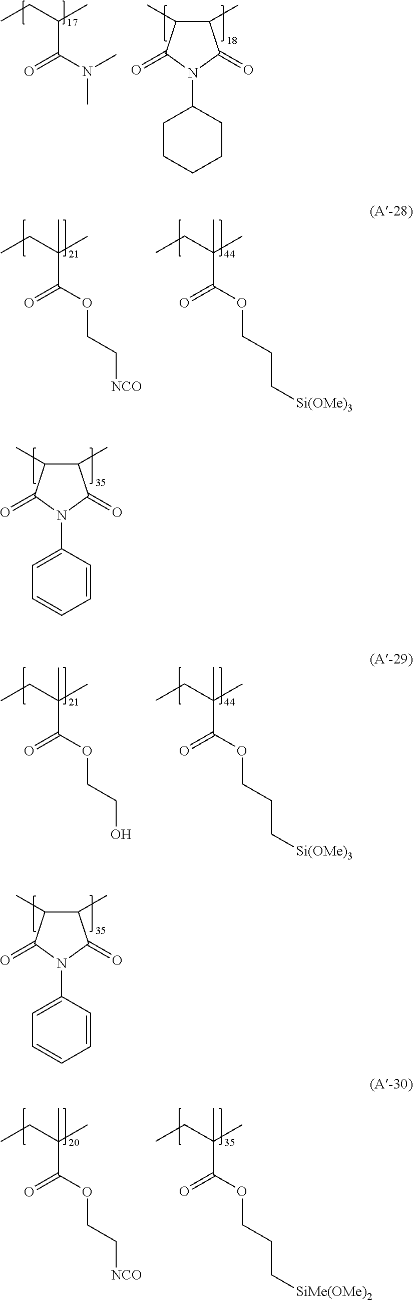

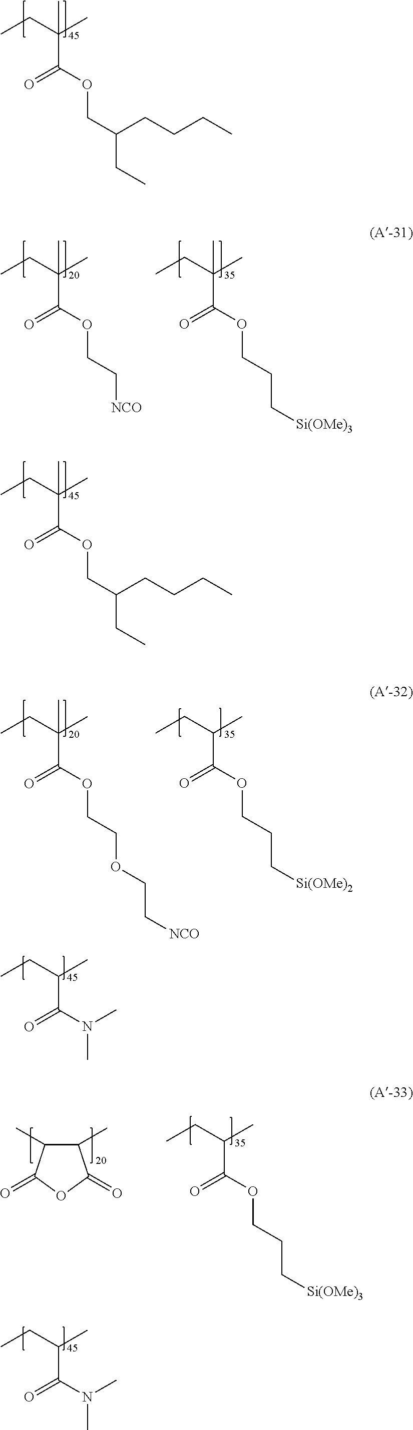

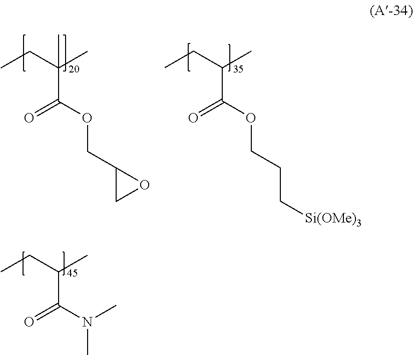

The polymer can be obtained by causing a polymerization reaction to occur using a monomer having the constitutional unit. The polymerization reaction can be performed using a well-known polymerization initiator. As the polymerization initiator, an azo polymerization initiator can be used, and specific examples thereof include a water-soluble azo polymerization initiator, an oil-soluble azo polymerization initiator, and a high-molecular-weight polymerization initiator. As the polymerization initiator, one kind may be used alone, or two or more kinds may be used in combination.

Examples of the monomer are as follows.

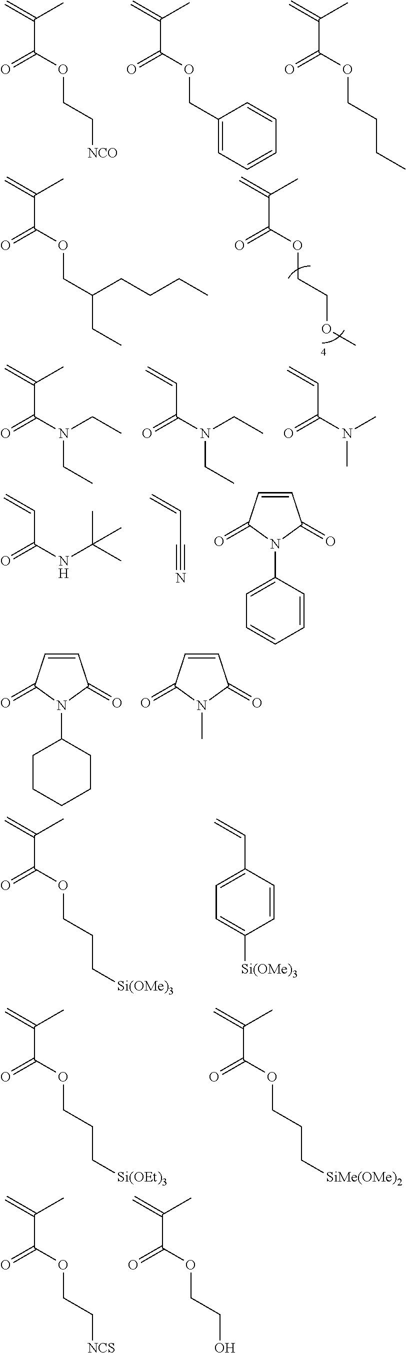

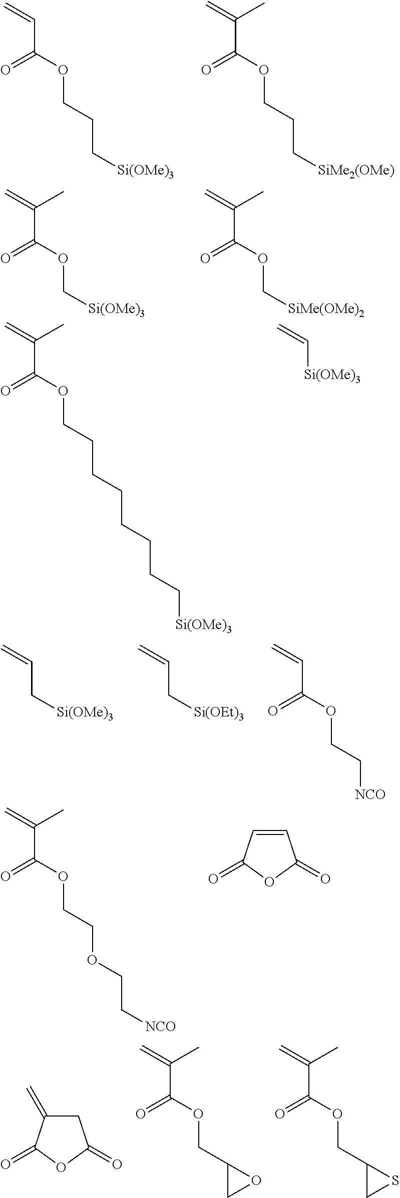

As the water-soluble polymerization initiator, for example, VA-044, VA-046B, V-50, VA-057, VA-061, VA-067, or VA-086 which is a commercially available product (trade names, all of which are manufactured by Wako Pure Chemical Industries, Ltd.) can be used. As the oil-soluble azo polymerization initiator, for example, V-60, V-70, V-65, V-601, V-59, V-40, VF-096, or VAm-110 which is a commercially available product (trade name, all of which are manufactured by Wako Pure Chemical Industries, Ltd.) can be used. As the high-molecular-weight polymerization initiator, for example, VPS-1001 or VPE-0201 which is a commercially available product (trade names, all of which are manufactured by Wako Pure Chemical Industries, Ltd.) can be used.

In the present invention, it is preferable that the copper complex (B′) includes a ligand (also referred to as “multidentate ligand”) having at least two coordination sites. The copper complex (B′) includes a copper atom and a ligand having a site (coordination site) coordinated to a carbon atom. Examples of the site coordinated to a copper atom include a site coordinated by an anion or an unshared electron pair. In addition, it is preferable that the ligand has a site tetradentate- or pentadentate-coordinated to a copper atom.

The copper complex (B′) may include a monodentate ligand and a counter ion to a copper complex skeleton. Examples of the multidentate ligand, the monodentate ligand, and the counter ion are the same as described above regarding the copper complex site.

In the present invention, it is preferable that the multidentate ligand, the monodentate ligand, or the counter ion has a functional group which is reactive with the reactive site of the polymer (A′), and it is more preferable that the monodentate ligand or the counter ion has the functional group.

Examples of the functional group include —OH, —SH, —NH₂, and a halogen atom. The functional group can be appropriately selected according to the reactivity with the reactive site of the polymer (A′). —OH, —SH, or —NH2 is preferable.

Specific examples of the copper complex (B′) are as follows. In the following formulae, Me represents a methyl group, Et represents an ethyl group, Bu represents a butyl group, and Ph represents a phenyl group. In addition, B′-34 denotes a structure in which Het has any one of the following structures. All the Het's may be the same as or different from each other.

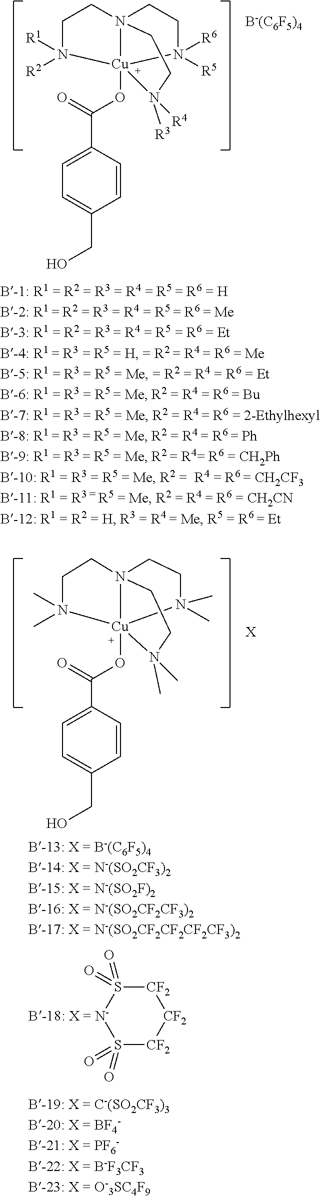

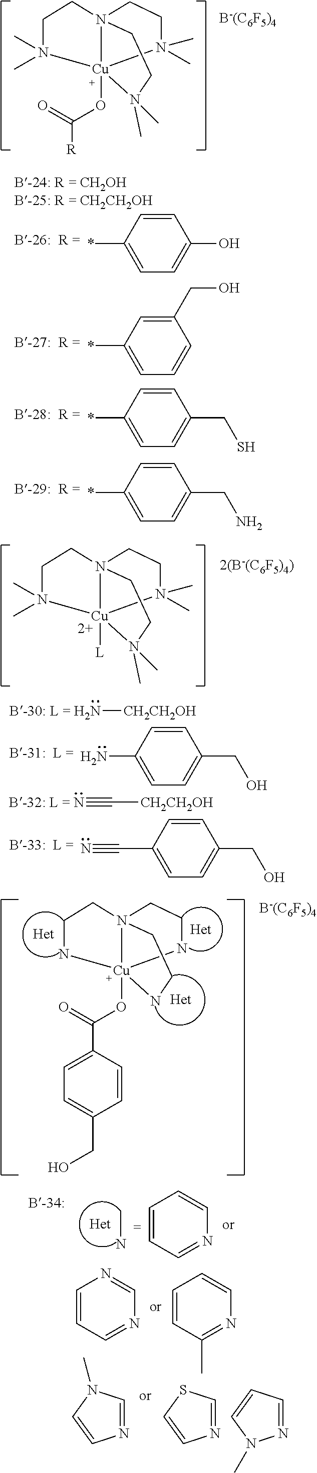

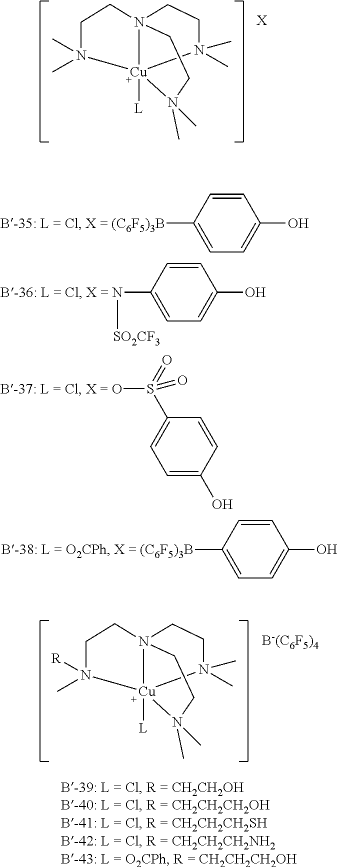

Reaction conditions of the polymer (A′) and the copper complex (B′) are preferably 20° C. to 150° C. and more preferably 40° C. to 100° C.

It is preferable that the polymer (A′) and the copper complex (B′) are caused to react with each other in a solvent. Examples of the solvent include examples described below regarding a solvent. It is preferable that the solvent is selected in consideration of the solubility of the polymer (A′) and the copper complex (B′). For example, cyclohexanone can be used.

(Another Method of Manufacturing Copper-Containing Polymer)

The copper-containing polymer according to the present invention can also be manufactured by causing a copper component to react with a polymer (P) having a constitutional unit represented by the following Formula (A″1-1). In addition, in a case where Z³⁰⁰ in Formula (A″1-1) represents a group having a site monodentate-coordinated to a copper atom or a counter ion to a copper complex skeleton, it is preferable that a compound having a site bi- or higher coordinated to a copper atom is further used for the reaction.

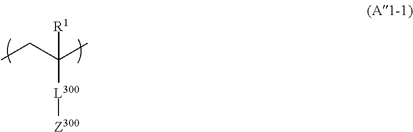

In Formula (A″1-1), R¹ represents a hydrogen atom or a hydrocarbon group.

L³⁰⁰ represents a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond.

Z³⁰⁰ represents a group having one or more sites coordinated to a copper atom or a counter ion to a copper complex skeleton.

In this case, in a case where L³⁰⁰ has a —C(═O)O— bond, L¹ has at least one —C(═O)O— bond which is not directly bonded to the polymer main chain, and in a case where L³⁰⁰ has a —NH—CO— bond, L¹ has at least one —NH—CO— bond which is not directly bonded to the polymer main chain.

Examples of the linking group represented by L³⁰⁰ include a linking group having the above-described bond, and a linking group having a combination of the above-described bond and at least one selected from the group consisting of an alkylene group, an arylene group, a heteroarylene group, —O—, —S—, —CO—, —C(═O)O—, —SO₂—, and NR¹⁰ (R¹⁰ represents a hydrogen atom or an alkyl group and preferably a hydrogen atom). Among these, a linking group having a combination of the above-described bond and an alkylene group, an arylene group, —CO—, —C(═O)O—, or —NR¹⁰— is preferable, and a linking group having a combination of the above-described bond and at least one selected from the group consisting of an alkylene group, an arylene group, and —C(═O)O— is more preferable.

The number of carbon atoms in the alkylene group is preferably 1 to 30, more preferably 1 to 15, and still more preferably 1 to 10. The alkylene group may have a substituent but is preferably unsubstituted. The alkylene group may be linear, branched, or cyclic. In addition, the cyclic alkylene group may be monocyclic or polycyclic.

As the arylene group, an arylene group having 6 to 18 carbon atoms is preferable, an arylene group having 6 to 14 carbon atoms is more preferable, an arylene group having 6 to 10 carbon atoms is still more preferable, and a phenylene group is even still more preferable.

The heteroarylene group is not particularly limited, and a 5-membered or 6-membered ring is preferable. Examples of the kind of a heteroatom constituting the heteroarylene group include an oxygen atom, a nitrogen atom, and a sulfur atom. The number of heteroatoms constituting the heteroarylene group is preferably 1 to 3. The heteroarylene group may be a monocycle or a fused ring and is preferably a monocycle or a fused ring composed of 2 to 8 rings, and more preferably a monocycle or a fused ring composed of 2 to 4 rings.

Z³⁰⁰ represents a group having one or more sites coordinated to a copper atom or a counter ion to a copper complex skeleton. Examples of the site coordinated to a copper atom include a site coordinated by an anion or an unshared electron pair.

It is preferable that Z³⁰⁰ represents a group having a site monodentate-coordinated to a copper atom or a counter ion to a copper complex skeleton. Examples of the group having one or more sites monodentate-coordinated to a copper atom and the counter ion to a copper complex skeleton include the monodentate ligands and the counter ions described above regarding the copper complex site. It is preferable that the group having one or more sites monodentate-coordinated to a copper atom or the counter ion to a copper complex skeleton is bonded to L³⁰⁰ at an arbitrary site.

The polymer (P) may include other constitutional units. Examples of the other constitutional units include the constitutional units represented by (A2-1) to (A2-6) described above regarding the copper-containing polymer and the constitutional unit (MX).

The weight-average molecular weight of the polymer (P) is preferably 2000 or higher, more preferably 2000 to 2000000, and still more preferably 6000 to 200000. By adjusting the weight-average molecular weight of the polymer (P) to be in the above-described range, the moisture resistance of the obtained cured film tends to be further improved.

Specific examples of the polymer (P) include the following compounds and salts thereof, but the present invention is not limited thereto. As an atom constituting the salt, a metal atom is preferable, and an alkali metal atom or an alkali earth metal atom is more preferable. Examples of the alkali metal atom include sodium and potassium. Examples of the alkali earth metal atom include calcium and magnesium.

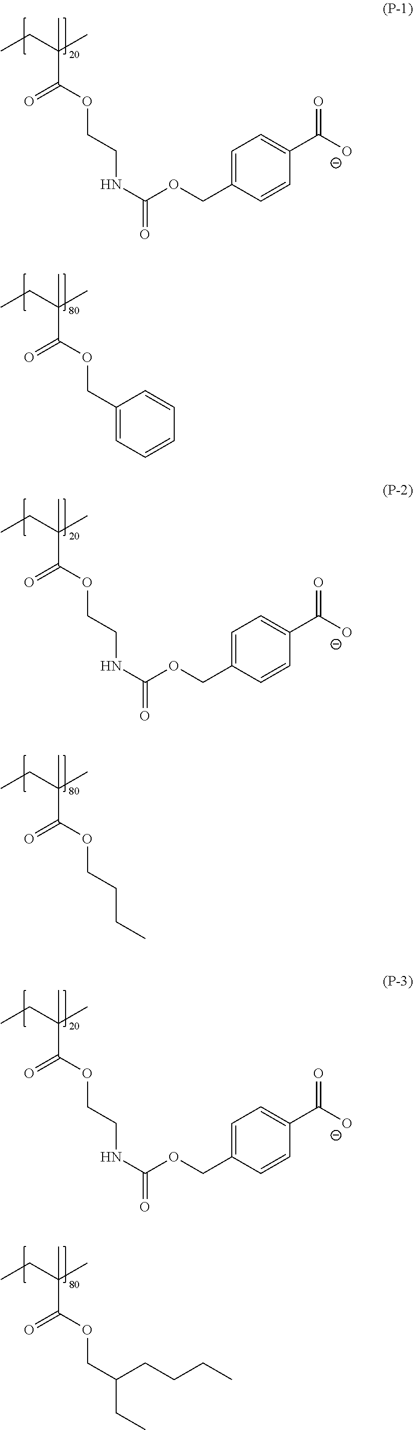

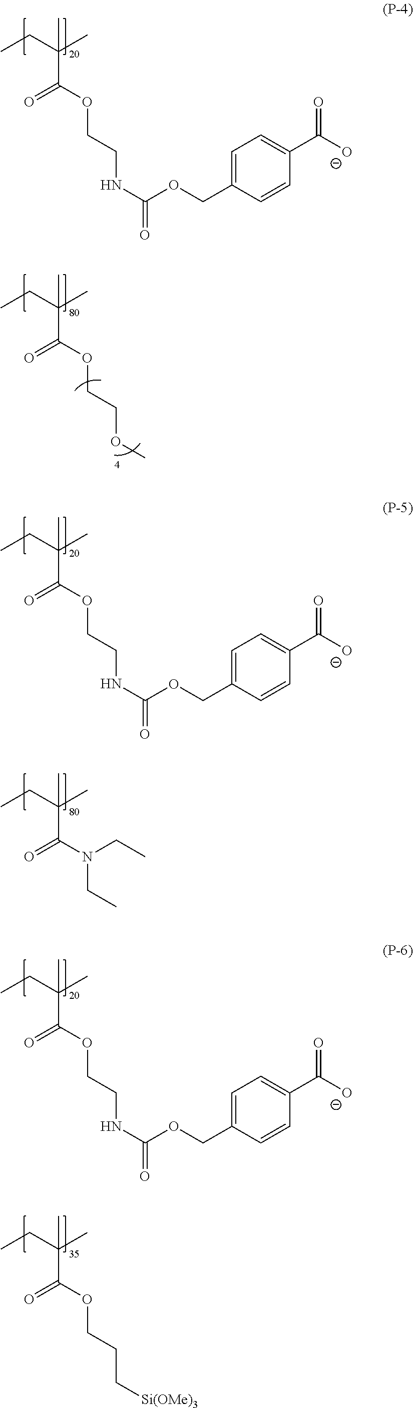

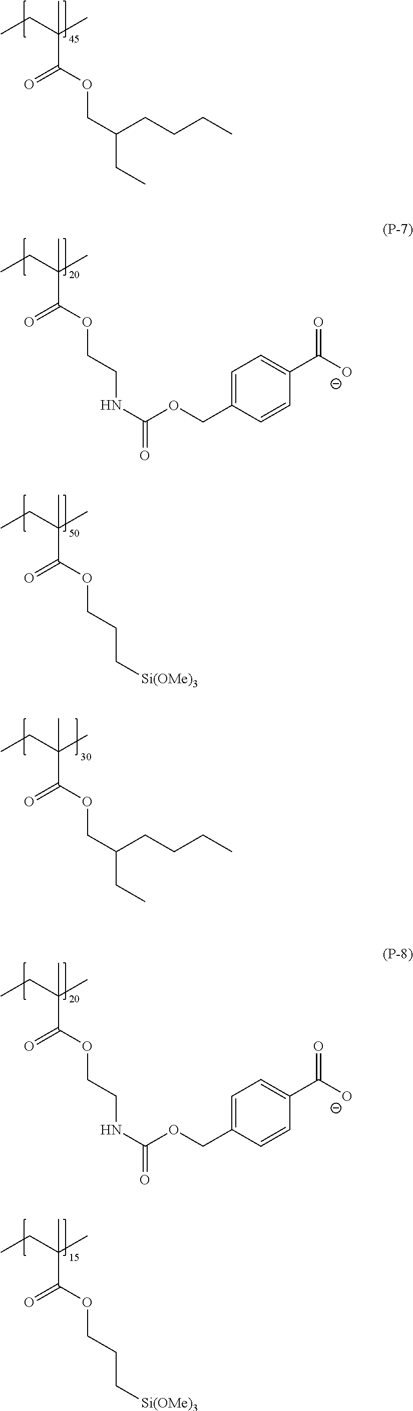

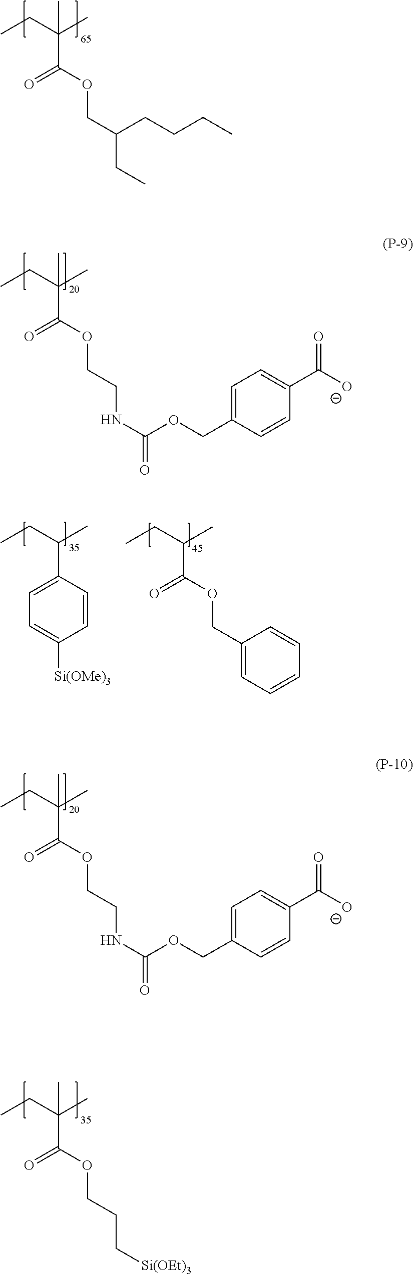

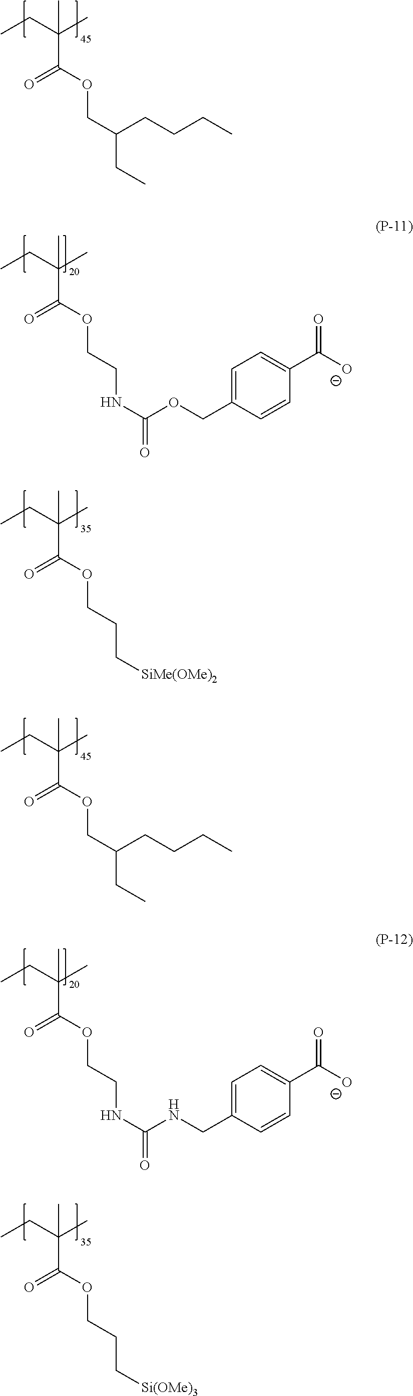

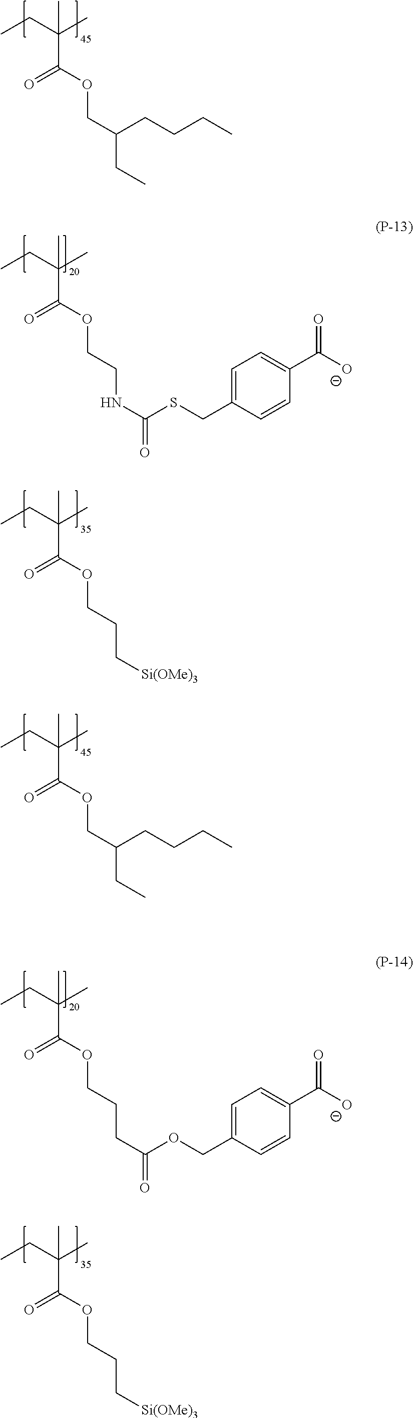

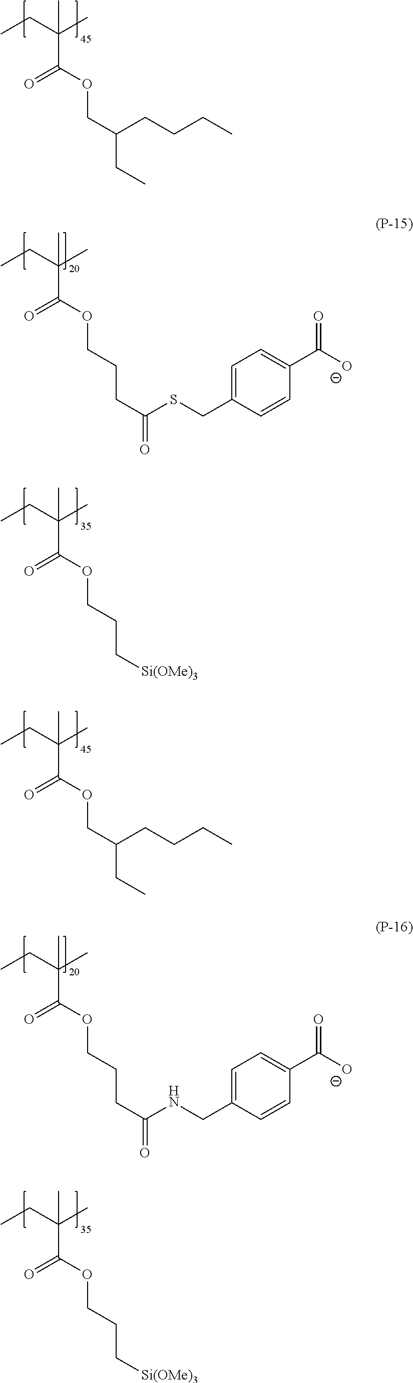

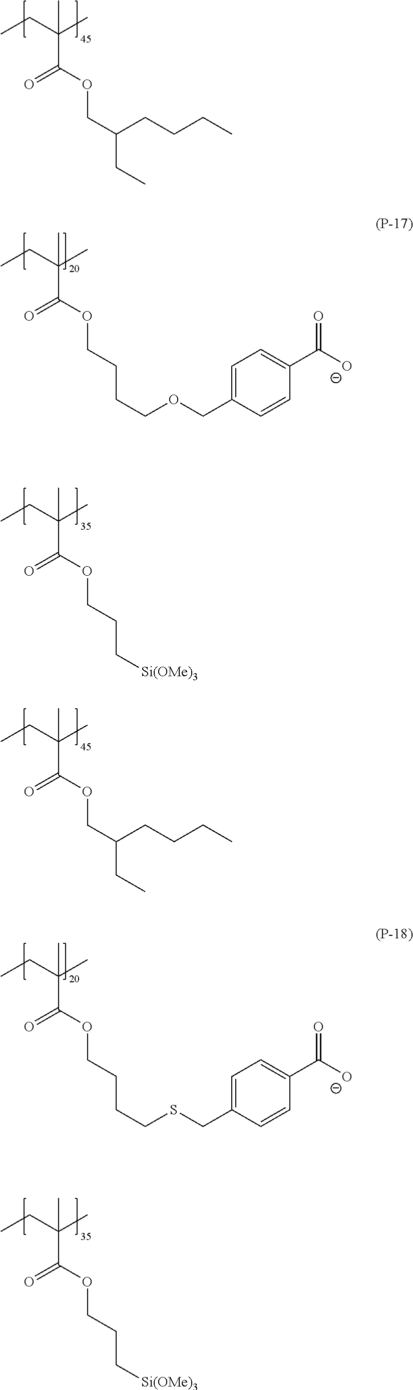

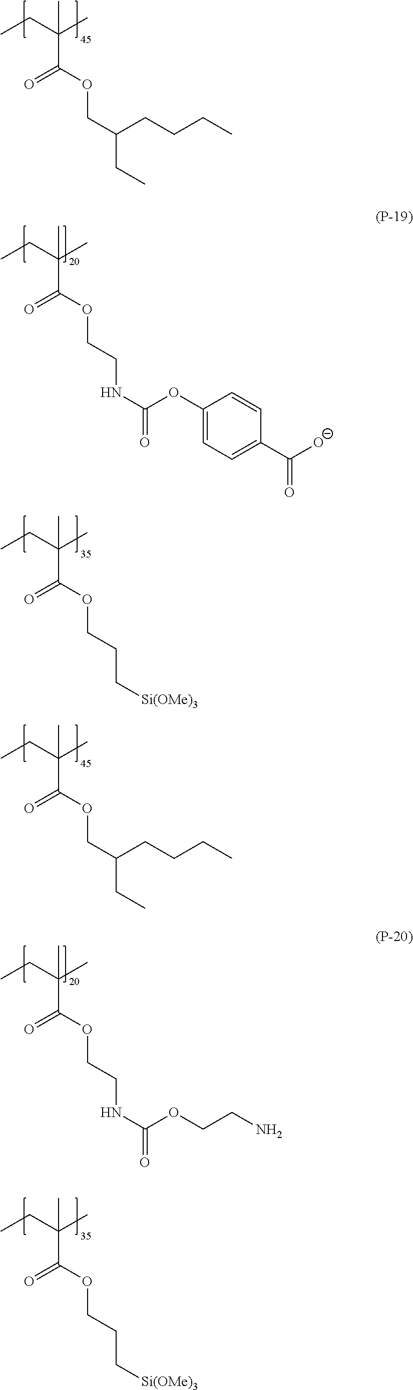

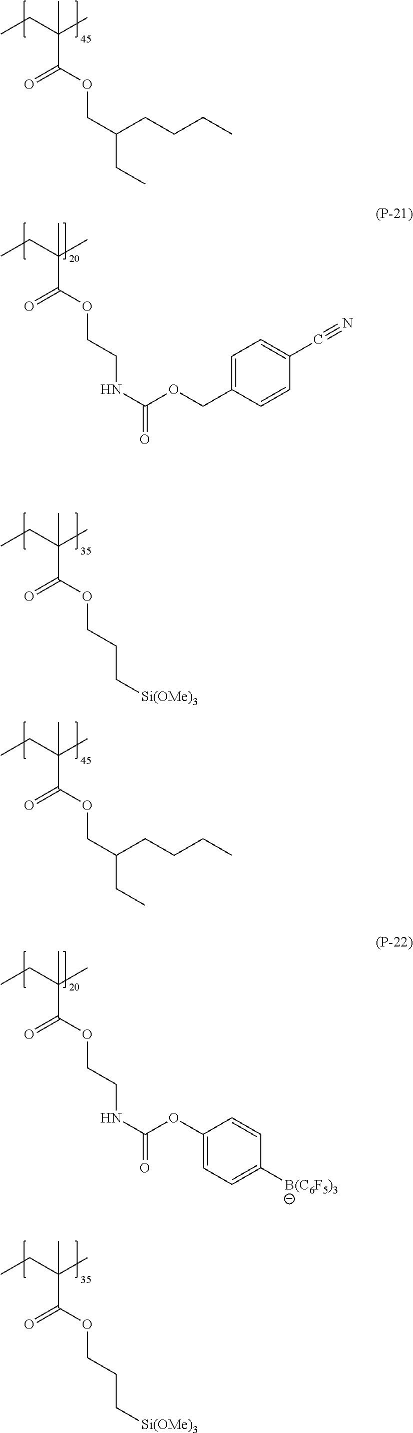

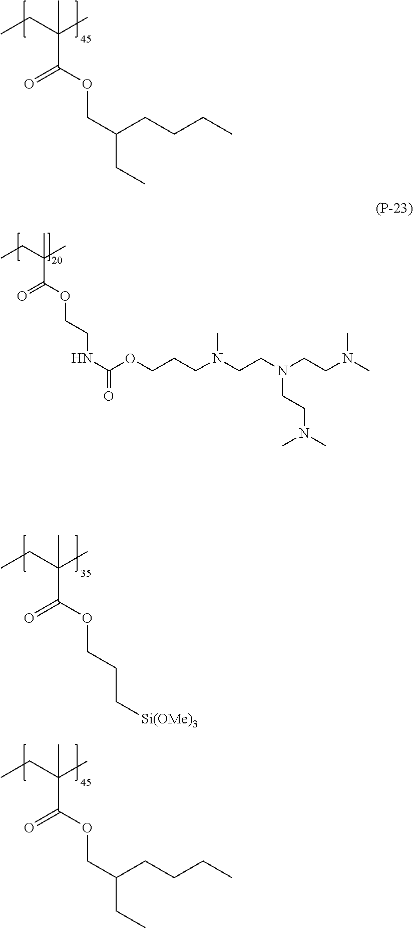

<<Low-Molecular-Weight Copper Complex>>

The near infrared absorbing composition according to the present invention may further include a low-molecular-weight copper complex. Examples of the low-molecular-weight copper complex include the copper complex (B′). By the near infrared absorbing composition including the low-molecular-weight copper complex, an effect of further improving near infrared shielding properties can be obtained.

The molecular weight of the low-molecular-weight copper complex is preferably 2000 or lower, more preferably 1500 or lower, and still more preferably 1200 or lower. For example, the lower limit is preferably 500 or lower.

In a case where the near infrared absorbing composition according to the present invention includes a low-molecular-weight copper complex, the content of the low-molecular-weight copper complex is preferably 0.5 to 45 mass % with respect to the total solid content of the near infrared absorbing composition. The lower limit is preferably 5 mass % or higher and more preferably 10 mass % or higher.

In addition, the near infrared absorbing composition according to the present invention may not substantially include the low-molecular-weight copper complex. By the near infrared absorbing composition substantially not including the low-molecular-weight copper complex, the solvent resistance of the film can be improved. Substantially not including the low-molecular-weight copper complex represents that the content of the low-molecular-weight copper complex is preferably 0.1 mass % or lower and more preferably 0.01 mass % or lower may be 0% with respect to the total solid content of the near infrared absorbing composition.

<<Other Near Infrared Absorbing Compounds>>

In order to further improve near infrared shielding properties, the near infrared absorbing composition according to the present invention may include near infrared absorbing compounds (hereinafter, referred to as “other near infrared absorbing compounds”) other than the copper-containing polymer.

The other near infrared absorbing compounds are not particularly limited as long as they have an absorption maximum in a wavelength range of 700 to 2500 nm preferably in a wavelength range of 700 to 1000 nm (near infrared range).

Examples of the other near infrared absorbing compounds include a pyrrolopyrrole compound, a cyanine compound, a phthalocyanine compound, a naphthalocyanine compound, an imonium compound, a thiol complex compound, a transition metal oxide compound, a squarylium compound, a quaterrylene compound, a dithiol metal complex compound, and a croconium compound.

As the pyrrolopyrrole compound, a pigment or a dye may be used, and a pigment is preferable because the coloring composition, with which a film having excellent heat resistance can be formed, is likely to be obtained. Examples of the pyrrolopyrrole compound include a pyrrolopyrrole compound described in paragraphs “0016” to “0058” of JP2009-263614A.

As the cyanine compound, the phthalocyanine compound, the imonium compound, the squarylium compound, or the croconium compound, for example, a compound described in paragraphs “0010” to “0081” of JP2010-111750A may be used, the content of which is incorporated herein by reference. In addition the cyanine compound can be found in, for example, “Functional Colorants by Makoto Okawara, Masaru Matsuoka, Teijiro Kitao, and Tsuneoka Hirashima, published by Kodansha Scientific Ltd.”, the content of which is incorporated herein by reference. In addition, the phthalocyanine compound can be found in the description of paragraphs “0013” to “0029” of JP2013-195480A, the content of which is incorporated herein by reference.

In a case where the near infrared absorbing composition according to the present invention includes the other near infrared absorbing compounds, the content of the other near infrared absorbing compounds is preferably 0.1 to 45 mass % with respect to the total solid content of the near infrared absorbing composition. The lower limit is preferably 0.5 mass % or higher and more preferably 1 mass % or higher.

<<Inorganic Particles>>

The near infrared absorbing composition according to the present invention may include inorganic particles. As the inorganic particles, one kind may be used alone, or two or more kinds may be used in combination.

The inorganic particles mainly function to shield (absorb) infrared light. As the inorganic particles, metal oxide particles or metal particles are preferable from the viewpoint of further improving near infrared shielding properties.

Examples of the metal oxide particles include indium tin oxide (ITO) particles, antimony tin oxide (ATO) particles, zinc oxide (ZnO) particles, Al-doped zinc oxide (Al-doped ZnO) particles, fluorine-doped tin dioxide (F-doped SnO₂) particles, and niobium-doped titanium dioxide (Nb-doped TiO₂) particles.

Examples of the metal particles include silver (Ag) particles, gold (Au) particles, copper (Cu) particles, and nickel (Ni) particles. In order to simultaneously realize near infrared shielding properties and photolithographic properties, it is preferable that the transmittance in an exposure wavelength range (365 to 405 nm) is high. From this point of view, indium tin oxide (ITO) particles or antimony tin oxide (ATO) particles are preferable.

The shape of the inorganic particles is not particularly limited and may have a sheet shape, a wire shape, or a tube shape irrespective of whether or not the shape is spherical or non-spherical.

In addition, as the inorganic particles, a tungsten oxide compound can be used.

Specifically, a tungsten oxide compound represented by the following Formula (compositional formula) (I) is more preferable.

MₓW_{y}O_{z} (I)

M represents metal, W represents tungsten, and O represents oxygen.

0.001≤x/y≤1.1

2.2≤z/y≤3.0

Examples of the metal represented by M include an alkali metal, an alkali earth metal, Mg, Zr, Cr, Mn, Fe, Ru, Co, Rh, Ir, Ni, Pd, Pt, Cu, Ag, Au, Zn, Cd, Al, Ga, In, Tl, Sn, Pb, Ti, Nb, V, Mo, Ta, Re, Be, Hf, Os, and Bi. Among these, an alkali metal is preferable, Rb or Cs is more preferable, and Cs is still more preferable. As the metal represented by M, one kind or two or more kinds may be used.

By adjusting x/y to be 0.001 or higher, infrared light can be sufficiently shielded. By adjusting x/y to be 1.1 or lower, production of an impurity phase in the tungsten oxide compound can be reliably avoided.

By adjusting z/y to be 2.2 or higher, chemical stability as a material can be further improved. By adjusting z/y to be 3.0 or lower, infrared light can be sufficiently shielded.

Specific examples of the tungsten oxide compound represented by Formula (I) include Cs_{0.33}WO₃, Rb_{0.33}WO₃, K_{0.33}WO₃, and Ba_{0.33}WO₃. Cs_{0.33}WO₃ or Rb_{0.33}WO₃ is preferable, and Cs_{0.33}WO₃ is more preferable.

The tungsten oxide compound is available in the form of, for example, a dispersion of tungsten particles such as YMF-02 (manufactured by Sumitomo Metal Mining Co., Ltd.).

The average particle size of the inorganic particles is preferably 800 nm or less, more preferably 400 nm or less, and still more preferably 200 nm or less. By adjusting the average particle size of the inorganic particles to be in the above-described range, transmittance in a visible range can be increased. In addition, from the viewpoint of avoiding light scattering, the less the average particle size, the better. However, due to the reason of handleability during manufacturing or the like, the average particle size of the inorganic particle is typically 1 nm or more.

The content of the inorganic particles is preferably 0.01 to 30 mass % with respect to the total solid content of the near infrared absorbing composition. The lower limit is preferably 0.1 mass % or higher and more preferably 1 mass % or higher. The upper limit is preferably 20 mass % or lower, and more preferably 10 mass % or lower.

<<Solvent>>

It is preferable that the near infrared absorbing composition according to the present invention includes a solvent. The solvent is not particularly limited as long as the respective components can be uniformly dissolved or dispersed therein, and can be appropriately selected according to the purpose. For example, water or an organic solvent can be used.

Examples of the organic solvent include an alcohol, a ketone, an ester, an aromatic hydrocarbon, a halogenated hydrocarbon, dimethyl formamide, dimethylacetamide, dimethyl sulfoxide, and sulfolane. Among these, one kind may be used alone, or two or more kinds may be used in combination.

Specific examples of the alcohol, the aromatic hydrocarbon, and the halogenated hydrocarbon can be found in, for example, paragraph “0136” of JP2012-194534A, the content of which is incorporated herein by reference.

Specific examples of the ester, the ketone, and the ether can be found in, for example, paragraph “0497” of JP2012-208494A (corresponding to paragraph “0609” of US2012/0235099A). Other examples include n-amyl acetate, ethyl propionate, dimethyl phthalate, ethyl benzoate, methyl sulfate, acetone, methyl isobutyl ketone, diethyl ether, and ethylene glycol monobutyl ether acetate.

As the solvent, at least one selected from the group consisting of 1-methoxy-2-propanol, cyclopentanone, cyclohexanone, propylene glycol monomethyl ether acetate, N-methyl-2-pyrrolidone, butyl acetate, ethyl lactate, and propylene glycol monomethyl ether is preferably used.

In the present invention, as the solvent, a solvent having a low metal content is preferably used. For example, the metal content in the solvent is preferably 10 parts mass per billion (ppb) or lower. Optionally, a solvent having a metal content at a mass parts per trillion (ppt) level may be used. For example, such a high-purity solvent is available from Toyo Gosei Co., Ltd. (The Chemical Daily, Nov. 13, 2015).

Examples of a method of removing impurities such as metal from the solvent include distillation (for example, molecular distillation or thin-film distillation) and filtering using a filter. During the filtering using a filter, the pore size of a filter is preferably 10 nm or less, more preferably 5 nm or less, and still more preferably 3 nm or less. As a material of the filter, polytetrafluoroethylene, polyethylene, or nylon is preferable.

The solvent may include an isomer (a compound having the same number of atoms and a different structure). In addition, the organic solvent may include only one isomer or a plurality of isomers.

The content of the solvent is preferably 5 to 60 mass % with respect to the total solid content of the near infrared absorbing composition according to the present invention. The lower limit is more preferably 10 mass % or higher. The upper limit is more preferably 40 mass % or lower. As the solvent, one kind may be used alone, or two or more kinds may be used. In a case where two or more solvents are used in combination, it is preferable that the total content of the two or more solvents is in the above-described range.

<<Curable Compound>>

The near infrared absorbing composition according to the present invention may include a curable compound.

As the curable compound, a well-known compound which is crosslinkable by a radical, an acid, or heat can be used. Examples of the curable compound include a compound having a group having an ethylenically unsaturated bond, a cyclic ether (epoxy, oxetane) group, a methylol group, or an alkoxysilyl group. Examples of the group having an ethylenically unsaturated bond include a vinyl group, a (meth)allyl group, and a (meth)acryloyl group.

The curable compound may be in a chemical form of a monomer, an oligomer, a prepolymer, a polymer, or the like. The details of the curable compound can be found in, for example, paragraphs “0070” to “0191” of JP2014-41318A (corresponding to paragraphs “0071” to “0192” of WO2014/017669A) or paragraphs “0045” to “0216” of JP2014-32380A, the content of which is incorporated herein by reference.

In the present invention, the curable compound is preferably a polymerizable compound and more preferably a radically polymerizable compound. Thee polymerizable compound may be a monofunctional compound having one polymerizable group or a polyfunctional compound having two or more polymerizable groups, and is preferably a polyfunctional compound. By the near infrared absorbing composition including the polyfunctional compound, heat resistance can be further improved.

Examples of the polymerizable compound include a monofunctional (meth)acrylate, a polyfunctional (meth)acrylate (preferably trifunctional to hexafunctional (meth)acrylate), a polybasic acid-modified acrylic oligomer, an epoxy resin, and a polyfunctional epoxy resin.

In addition, in the present invention, a compound having a partial structure represented by M-X can be used as the curable compound. M represents an atom selected from the group consisting of Si, Ti, Zr, and Al. X represents one selected from the group a hydroxyl group, an alkoxy group, an acyloxy group, a phosphoryloxy group, a sulfonyloxy group, an amino group, an oxime group, or O═C(R^{a})(R^{b}). R^{a} and R^{b} each independently represent a monovalent organic group.

A cured product obtained by curing the compound having a partial structure represented by M-X is crosslinked by a strong chemical bond. Therefore, heat resistance is excellent. In addition, since an interaction with the copper complex is not likely to occur, deterioration in the properties of the copper complex can be suppressed. Therefore, a cured film having excellent heat resistance can be formed while maintaining high near infrared shielding properties.

<<<Compound Having Ethylenically Unsaturated Bond>>>

In the present invention, as the curable compound, a compound having an ethylenically unsaturated bond can also be used. Examples of the compound having an ethylenically unsaturated bond can be found in paragraphs “0033” and “0034” of JP2013-253224A, the content of which is incorporated herein by reference.

As the compound having an ethylenically unsaturated bond, ethyleneoxy-modified pentaerythritol tetraacrylate (as a commercially available product, NK ESTER ATM-35E manufactured by Shin-Nakamura Chemical Co., Ltd.), dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., A-DPH-12, manufactured by Shin-Nakamura Chemical Co., Ltd.), or a structure in which the (meth)acryloyl group is bonded through an ethylene glycol or a propylene glycol residue is preferable. In addition, oligomers of the above-described examples can be used.

In addition, the compound having an ethylenically unsaturated bond can be found in the description of a polymerizable compound in paragraphs “0034” to “0038” of JP2013-253224A, the content of which is incorporated herein by reference.

Examples of the compound having an ethylenically unsaturated bond include a polymerizable monomer in paragraph “0477” of JP2012-208494A (corresponding to paragraph “0585” of US2012/0235099A), the content of which is incorporated herein by reference.

In addition, diglycerin ethylene oxide (EO)-modified (meth)acrylate (as a commercially available product, M-460 manufactured by Toagosei Co., Ltd.) is preferable. Pentaerythritol tetraacrylate (A-TMMT manufactured by Shin-Nakamura Chemical Co., Ltd.) or 1,6-hexanediol diacrylate (KAYARAD HDDA manufactured by Nippon Kayaku Co., Ltd.) is also preferable. Oligomers of the above-described examples can be used. For examples, RP-1040 (manufactured by Nippon Kayaku Co., Ltd.) is used.

The compound having an ethylenically unsaturated bond may have an acid group such as a carboxyl group, a sulfo group, or a phosphate group.

Examples of the monomer having an acid group and an ethylenically unsaturated bond include an ester of an aliphatic polyhydroxy compound and an unsaturated carboxylic acid. A compound having an acid group obtained by causing a nonaromatic carboxylic anhydride to react with an unreacted hydroxy group of an aliphatic polyhydroxy compound is preferable. In particular, it is more preferable that, in this ester, the aliphatic polyhydroxy compound is pentaerythritol and/or dipentaerythritol. Examples of a commercially available product of the monomer having an acid group include M-305, M-510, and M-520 of ARONIX series as polybasic acid-modified acrylic oligomer (manufactured by Toagosei Co., Ltd.).

The acid value of the compound having an acid group and an ethylenically unsaturated bond is preferably 0.1 to 40 mgKOH/g. The lower limit is preferably 5 mgKOH/g or higher. The upper limit is preferably 30 mgKOH/g or lower.

<<<Compound Having Epoxy Group or Oxetanyl Group>>>

In the present invention, as the curable compound, a compound having an epoxy group or an oxetanyl group can be used. Examples of the compound having an epoxy group or an oxetanyl group include a polymer having an epoxy group at a side chain and a monomer or an oligomer having two or more epoxy groups in a molecule. Examples of the compound include a bisphenol A epoxy resin, a bisphenol F epoxy resin, a phenol novolac epoxy resin, a cresol novolac epoxy resin, and an aliphatic epoxy resin. In addition, a monofunctional or polyfunctional glycidyl ether compound can also be used, and a polyfunctional aliphatic glycidyl compound is preferable.

The weight-average molecular weight is preferably 500 to 5000000 and more preferably 1000 to 500000.

As the compound, a commercially available product may be used, or a compound obtained by introducing an epoxy group into a side chain of the polymer may be used.

Examples of the commercially available product can be found in, for example, paragraph “0191” JP2012-155288A, the content of which is incorporated herein by reference.

In addition, a polyfunctional aliphatic glycidyl ether compound such as DENACOL EX-212L, EX-214L, EX-216L, EX-321L, or EX-850L (all of which are manufactured by Nagase ChemteX Corporation) can be used. These commercially available products are low-chlorine products. A commercially available product which is not a low-chlorine product such as EX-212, EX-214, EX-216, EX-321, or EX-850 can also be used.

Other examples include: ADKEA RESIN EP-4000S, ADKEA RESIN EP-4003S, ADKEA RESIN EP-4010S, and ADEKA RESIN EP-4011S (all of which are manufactured by Adeka Corporation); NC-2000, NC-3000, NC-7300, XD-1000, EPPN-501, and EPPN-502 (all of which are manufactured by Adeka Corporation); JER1031S, CELLOXIDE 2021P, CELLOXIDE 2081, CELLOXIDE 2083, CELLOXIDE 2085, EHPE 3150, EPOLEAD PB 3600, and EPOLEAD PB 4700 (all of which are manufactured by Daicel Corporation); and CYCLOMER P ACA 200M, CYCLOMER P ACA 230AA, CYCLOMER P ACA Z250, CYCLOMER P ACA Z251, CYCLOMER P ACA Z300, and CYCLOMER P ACA Z320 (all of which are manufactured by Daicel Corporation).

Further, examples of a commercially available product of the phenol novolac epoxy resin include JER-157S65, JER-152, JER-154, and JER-157S70 (all of which are manufactured by Mitsubishi Chemical Corporation).

In addition, specific examples of a polymer having an oxetanyl group at a side chain and a polymerizable monomer or an oligomer having two or more oxetanyl groups in a molecule ARONE OXETANE OXT-121, OXT-221, OX-SQ, and PNOX (all of which are manufactured by Toagosei Co., Ltd.).

As the compound having an epoxy group, an epoxy compound having a glycidyl group such as glycidyl (meth)acrylate or allyl glycidyl ether or a compound having an alicyclic epoxy group can also be used. Examples of the compound having an epoxy group can be found in, for example, paragraph “0045” of JP2009-265518A, the content of which is incorporated herein by reference.

The compound having an epoxy group or an oxetanyl group may include a polymer having an epoxy group or an oxetanyl group as a constitutional unit.

<<Compound having Alkoxysilyl Group>>

In the present invention, as the curable compound, a compound having an alkoxysilyl group can also be used. Examples of the alkoxysilyl group include a monoalkoxysilyl group, a dialkoxysilyl group, and a trialkoxysilyl group. Among these, a dialkoxysilyl group or a trialkoxysilyl group is preferable.

The number of alkoxy groups in the alkoxysilyl group is preferably 1 to 5, more preferably 1 to 3, and still more preferably 1 or 2. It is preferable that two or more alkoxysilyl groups are present in one molecule, and it is more preferable that two or three alkoxysilyl groups are present in one molecule.

Specific examples of the compound having an alkoxysilyl group include methyl trimethoxysilane, dimethyl dimethoxysilane, phenyl trimethoxysilane, methyltriethoxysilane, and dimethyl diethoxysilane, phenyltriethoxysilane, n-propyltrimethoxysilane, n-propyltriethoxysilane, hexyl trimethoxysilane, hexyl triethoxysilane, octyl triethoxysilane, decyl trimethoxysilane, 1,6-bis(trimethoxysilyl)hexane, trifluoropropyltrimethoxysilane, hexamethyldisilazane, vinyl trimethoxysilane, vinyltriethoxysilane, 2-(3,4-epoxycyclohexyl)ethyltrimethoxysilane, 3-glycidoxypropylmethyldimethoxysilane, 3-glycidoxypropyltrimethoxysilane, 3-glycidoxypropylmethyldiethoxysilane, 3-glycidoxypropyltriethoxysilane, p-styryltrimethoxysilane, 3-methacryloxypropylmethyldimethoxysilane, 3-methacryloxypropyltrimethoxysilane, 3-methacryloxypropylethyldimethoxysilane, 3-methacryloxypropyltriethoxysilane, 3-acryloxypropyltrimethoxysilane, N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane, N-(vinylbenzyl)-2-aminoethyl-3-aminopropyltrimethoxysilane, tris-(trimethoxysilylpropyl)isocyanurate, 3-ureidopropyltriethoxysilane, 3-mercaptopropylmethyldimethoxysilane, 3-mercaptopropyltrimethoxysilane, and bis(triethoxysilylpropyl)tetrasulfide, and 3-isocyanatepropyltriethoxysilane. In addition to the above-described examples, an alkoxy oligomer can be used. In addition, the following compounds can also be used.

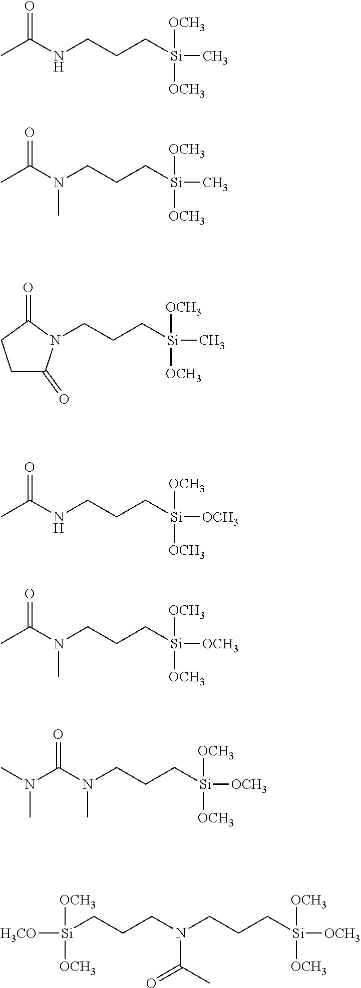

Examples of a commercially available product of the silane coupling agent include KBM-13, KBM-22, KBM-103, KBE-13, KBE-22, KBE-103, KBM-3033, KBE-3033, KBM-3063, KBM-3066, KBM-3086, KBE-3063, KBE-3083, KBM-3103, KBM-3066, KBM-7103, SZ-31, KPN-3504, KBM-1003, KBE-1003, KBM-303, KBM-402, KBM-403, KBE-402, KBE-403, KBM-1403, KBM-502, KBM-503, KBE-502, KBE-503, KBM-5103, KBM-602, KBM-603, KBM-903, KBE-903, KBE-9103, KBM-573, KBM-575, KBM-9659, KBE-585, KBM-802, KBM-803, KBE-846, KBE-9007, X-40-1053, X-41-1059A, X-41-1056, X-41-1805, X-41-1818, X-41-1810, X-40-2651, X-40-2655A, KR-513, KC-89S, KR-500, X-40-9225, X-40-9246, X-40-9250, KR-401N, X-40-9227, X-40-9247, KR-510, KR-9218, KR-213, X-40-2308, and X-40-9238 (all of which are manufactured by Shin-Etsu Chemical Co., Ltd.).

<<<Other Curable Compounds>>>

In the present invention, as the curable compound, a polymerizable compound having a caprolactone-modified structure can be used.

Examples of the polymerizable compound having a caprolactone-modified structure can be found in paragraphs “0042” to “0045” of JP2013-253224A, the content of which is incorporated herein by reference.

Examples of the polymerizable compound having a caprolactone-modified structure include: DPCA-20, DPCA-30, DPCA-60, and DPCA-120 which are commercially available as KAYARADDPCA series manufactured by Nippon Kayaku Co., Ltd.; SR-494 (manufactured by Sartomer) which is a tetrafunctional acrylate having four ethyleneoxy chains; and TPA-330 (manufactured by Nippon Kayaku Co., Ltd.) which is a trifunctional acrylate having three isobutyleneoxy chains.

In a case where the near infrared absorbing composition according to the present invention includes a curable compound, the content of the curable compound is preferably 1 to 90 mass % with respect to the total solid content of the near infrared absorbing composition. The lower limit is preferably 5 mass % or higher, more preferably 10 mass % or higher, and still more preferably 20 mass % or higher. The upper limit is preferably 80 mass % or lower, and more preferably 75 mass % or lower. As the curable compound, one kind may be used alone, or two or more kinds may be used. In a case where two or more curable compounds are used in combination, it is preferable that the total content of the two or more curable compounds is in the above-described range.

The near infrared absorbing composition according to the present invention may not substantially include the curable compound. “Substantially not including the curable compound” represents that the content of the curable compound is preferably 0.5 mass % or lower, more preferably 0.1 mass % or lower, and still more preferably 0% with respect to the total solid content of the near infrared absorbing composition.

<<Resin>>

For example, in order to improve properties of a film, the near infrared absorbing composition according to the present invention may include a resin. The resin in the present invention denotes a polymer which is different from the copper-containing polymer and does not contain copper.

As the resin, a resin having an acid group is preferably used. By the near infrared absorbing composition including the resin having an acid group, an effect of improving heat resistance and the like and an effect of finely adjusting coating suitability can be obtained.

The details of the resin having an acid group can be found in paragraphs “0558” to “0571” of JP2012-208494A (corresponding to paragraphs “0685” to “0700” of US2012/0235099A), the content of which is incorporated herein by reference.

As the resin, a resin including the constitutional unit represented by any one of Formula (A2-1) to (A2-6) described above regarding the copper-containing polymer or a resin including the constitutional unit (MX) can also be used. For example, the following resins can be preferably used.

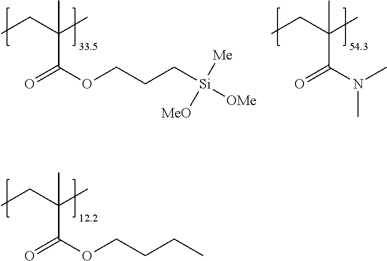

The content of the resin is preferably 1 to 80 mass % with respect to the total solid content of the near infrared absorbing composition. The lower limit is preferably 5 mass % or higher and more preferably 7 mass % or higher. The upper limit is preferably 50 mass % or lower, and more preferably 30 mass % or lower.

<<Polymerization Initiator>>

The near infrared absorbing composition according to the present invention may include a polymerization initiator. The polymerization initiator is not particularly limited as long as it has an ability to start polymerization of a polymerizable compound using either or both light and heat. In particular, a photopolymerizable compound (photopolymerization initiator) is preferable. For example, in a case where polymerization starts by light, a photopolymerization initiator having photosensitivity to light in a range from an ultraviolet range to a visible range is preferable. In addition, in a case where polymerization starts by heat, a polymerization initiator which is decomposed at 150° C. to 250° C. is preferable.

As the polymerization initiator, a compound having an aromatic group is preferable. Examples of the polymerization initiator include an acylphosphine compound, an acetophenone compound, an ca-aminoketone compound, a benzophenone compound, a benzoin ether compound, a ketal derivative compound, a thioxanthone compound, an oxime compound, a hexaarylbiimidazole compound, a trihalomethyl compound, an azo compound, an organic peroxide, an onium salt compound such as a diazonium compound, an iodonium compound, a sulfonium compound, an azinium compound, or a metallocene compound, an organic boron salt compound, a disulfone compound, and a thiol compound.

For example, the details of the polymerization initiator can be found in paragraphs “0217” to “0228” of JP2013-253224A, the content of which is incorporated herein by reference.

As the polymerization initiator, an oxime compound, an acetophenone compound or an acylphosphine compound is preferable.

As a commercially available product of the oxime compound, for example, IRGACURE-OXE01 (manufactured by BASF SE), IRGACURE-OXE02 (manufactured by BASF SE), TR-PBG-304 (manufactured by Changzhou Tronly New Electronic Materials Co., Ltd.), ADEKA ARKLS NCI-831 (manufactured by Adeka Corporation), or ADEKA ARKLS NCI-930 (manufactured by Adeka Corporation) can be used.

As a commercially available product of the acetophenone compound, for example, IRGACURE-907, IRGACURE-369, or IRGACURE-379 (trade name, all of which are manufactured by BASF SE) can be used.

As a commercially available product of the acylphosphine compound, IRGACURE-819 or DAROCUR-TPO (trade name, all of which are manufactured by BASF SE) can be used.

The content of the polymerization initiator is preferably 0.01 to 30 mass % with respect to the total solid content of the near infrared absorbing composition. The lower limit is more preferably 0.1 mass % or higher. The upper limit is preferably 20 mass % or lower, and more preferably 15 mass % or lower.

As the polymerization initiator, one kind may be used alone, or two or more kinds may be used. In a case where two or more polymerization initiators are used in combination, it is preferable that the total content of the two or more polymerization initiators is in the above-described range.

<<<Heat Stability Imparting Agent>>>

The near infrared absorbing composition according to the present invention may include an oxime compound as a heat stability imparting agent.

As a commercially available product of the oxime compound, for example, IRGACURE-OXE01, IRGACURE-OXE02, IRGACURE-OXE03, or IRGACURE-OXE04 (all of which are manufactured by BASF SE), TR-PBG-304 (manufactured by Changzhou Tronly New Electronic Materials Co., Ltd.), ADEKA ARKLS NCI-930 (manufactured by Adeka Corporation), or ADEKA OPTOMER N-1919 (manufactured by Adeka Corporation, a photopolymerization initiator 2 described in JP2012-14052A) can be used.

As the oxime compound, an oxime compound having a nitro group can be used. It is preferable that the oxime compound having a nitro group is a dimer. Specific examples of the oxime compound having a nitro group include compounds described in paragraphs “0031” to “0047” of JP2013-114249A, compounds described in paragraphs “0008” to “0012” and “0070” to “0079” of JP2014-137466A, compounds described in paragraphs “0007” to 0025” of JP4223071B, and ADEKA ARKLS NCI-831 (manufactured by Adeka Corporation).

In the present invention, as the oxime compound, an oxime compound having a benzofuran skeleton can also be used. Specific examples include OE-01 to OE-75 described in WO2015/036910A.

In addition, as the oxime compound, a compound described in JP2016-21012A can be used.

The content of the heat stability imparting agent is preferably 0.01 to 30 mass % with respect to the total solid content of the near infrared absorbing composition. The lower limit is more preferably 0.1 mass % or higher. The upper limit is preferably 20 mass % or lower, and more preferably 10 mass % or lower.

<<Metal Catalyst>>

It is preferable that the near infrared absorbing composition according to the present invention includes a metal catalyst. For example, in a case where the copper-containing polymer includes the constitutional unit (MX), or in a case where a compound having a partial structure represented by M-X is used as the curable compound, the near infrared absorbing composition includes the metal catalyst such that crosslinking of the copper-containing polymer or the like can be promoted and a stronger film can be manufactured.

In the present invention, it is preferable that the metal catalyst is at least one selected from the group consisting of an oxide, a sulfide, a halide, a carbonate, a carboxylate, a sulfonate, a phosphate, a nitrate, a sulfate, an alkoxide, a hydroxide, and an acetylacetonato complex which may have a substituent, the at least one including at least one selected from the group consisting of Na, K, Ca, Mg, Ti, Zr, Al, Zn, Sn, and Bi.

Among these, at least one selected from the group consisting of a halide of the metal, a carboxylate of the metal, a nitrate of the metal, a sulfate of the metal, a hydroxide of the metal, and an acetylacetonato complex of the metal which may have a substituent is preferable, and an acetylacetonato complex of the metal is more preferable. In particular, an acetylacetonato complex of Al is preferable.

Specific examples of the metal catalyst include sodium methoxide, sodium acetate, sodium 2-ethylhexanoate, sodium (2,4-pentanedionate), potassium butoxide, potassium acetate, potassium 2-ethylhexanoate, potassium (2,4-pentanedionate), calcium fluoride, calcium chloride, calcium bromide, calcium iodide, calcium oxide, calcium sulfide, calcium acetate, calcium 2-ethylhexanoate, calcium phosphate, calcium nitrate, calcium sulfate, calcium ethoxide, calcium bis(2,4-pentanedionate), magnesium fluoride, magnesium chloride, magnesium bromide, magnesium iodide, magnesium oxide, magnesium sulfate, magnesium acetate, magnesium 2-ethylhexanoate, magnesium phosphate, magnesium nitrate, magnesium sulfate, magnesium ethoxide, magnesium bis(2,4-pentanedionate), titanium ethoxide, titanium oxide bis(2,4-pentanedionate), zirconium ethoxide, zirconium tetrakis(2,4-pentanedionate), vanadium chloride, manganese oxide, manganese bis(2,4-pentanedionate), iron chloride, iron tris(2,4-pentanedionate), iron bromide, ruthenium chloride, cobalt chloride, rhodium chloride, iridium chloride, nickel chloride, nickel bis(2,4-pentanedionate), palladium chloride, palladium acetate, palladium bis(2,4-pentanedionate), platinum chloride, copper chloride, copper oxide, copper sulfate, copper bis(2,4-pentanedionate), silver chloride, aluminum isopropoxide, aluminum diacetate hydroxide, aluminum 2-ethylhexanoate, aluminum dihydroxy stearate, aluminum hydroxy distearate, aluminum tristearate, aluminum tris(2,4-pentanedionate), zinc chloride, zinc nitrate, zinc, acetate, zinc benzoate, zinc oxide, zinc sulfide, zinc bis(2,4-pentanedionate), zinc 2-ethylhexanoate, tin chloride, tin 2-ethylhexanoate, tin dichloride bis(2,4-pentanedionate), lead chloride, bismuth 2-ethylhexanoate, and bismuth nitrate.

In a case where the near infrared absorbing composition according to the present invention includes the metal catalyst, the content of the metal catalyst is preferably 0.001 to 20 mass % with respect to the total solid content of the near infrared absorbing composition. The upper limit is preferably 15 mass % or lower, more preferably 10 mass % or lower, and still more preferably 5 mass % or lower. The lower limit is preferably 0.05 mass % or higher, more preferably 0.01 mass % or higher, and still more preferably 0.1 mass % or higher.

<<Surfactant>>

The near infrared absorbing composition according to the present invention may include a surfactant. Among these surfactants, one kind may be used alone, or two or more kinds may be used in combination. The content of the surfactant is preferably 0.0001 to 5 mass % with respect to the total solid content of the near infrared absorbing composition. The lower limit is preferably 0.005 mass % or higher and more preferably 0.01 mass % or higher. The upper limit is preferably 2 mass % or lower, and more preferably 1 mass % or lower.

As the surfactants, various surfactants such as a fluorine surfactant, a nonionic surfactant, a cationic surfactant, an anionic surfactant, or a silicone surfactant can be used. It is preferable that the near infrared absorbing composition includes at least one of a fluorine surfactant or a silicone surfactant. The interfacial tension between a coated surface and a coating solution decreases, and the wettability on the coated surface is improved. Therefore, liquid properties (in particular, fluidity) of the composition are improved, and uniformity in coating thickness and liquid saving properties can be further improved. As a result, even in a case where a thin film having a thickness of several micrometers is formed using a small amount of the coating solution, a film having a uniform thickness with reduced unevenness in thickness can be formed.

The fluorine content in the fluorine surfactant is preferably 3 to 40 mass %. The lower limit is preferably 5 mass % or higher and more preferably 7 mass % or higher. The upper limit is more preferably 30 mass % or lower, and still more preferably 25 mass % or lower. In a case where the fluorine content is in the above-described range, there are advantageous effects in the uniformity in the thickness of the coating film and liquid saving properties, and the solubility is also excellent.

Specific examples of the fluorine surfactant include a surfactant described in paragraphs “0060” to “0064” of JP2014-41318A (paragraphs “0060” to “0064” of corresponding WO2014/17669A) and a surfactant described in paragraphs “0117” to “0132” of JP2011-132503A, the content of which is incorporated herein by reference. Examples of a commercially available product of the fluorine surfactant include: MEGAFACE F-171, MEGAFACE F-172, MEGAFACE F-173, MEGAFACE F-176, MEGAFACE F-177, MEGAFACE F-141, MEGAFACE F-142, MEGAFACE F-143, MEGAFACE F-144, MEGAFACE R30, MEGAFACE F-437, MEGAFACE F-475, MEGAFACE F-479, MEGAFACE F-482, MEGAFACE F-554, and MEGAFACE F-780, (all of which are manufactured by DIC Corporation); FLUORAD FC 430, FLUORAD FC 431, and FLUORAD FC 171 (all of which are manufactured by Sumitomo 3M Ltd.); SURFLON S-382, SURFLON SC-101, SURFLON SC-103, SURFLON SC-104, SURFLON SC-105, SURFLON SC1068, SURFLON SC-381, SURFLON SC-383, SURFLON S393, and SURFLON KH-40, (all of which are manufactured by Asahi Glass Co., Ltd.); and PolyFox PF636, PF656, PF6320, PF6520, and PF7002 (manufactured by OMNOVA Solutions Inc.).

In addition, as the fluorine surfactant, an acrylic compound in which, when heat is applied to a molecular structure which has a functional group having a fluorine atom, the functional group is cut and a fluorine atom is vaporized can also be preferably used. As the acrylic compound in which, when heat is applied to a molecular structure which has a functional group having a fluorine atom, the functional group is cut and a fluorine atom is vaporized, MEGAFACE DS series (manufactured by DIC Corporation, The Chemical Daily, Feb. 22, 2016, Nikkei Business Daily, Feb. 23, 2016), for example, MEGAFACE DS-21 may be used.

As the fluorine surfactant, a fluorine-containing polymer compound can be preferably used, the fluorine-containing polymer compound including: a constitutional unit derived from a (meth)acrylate compound having a fluorine atom; and a constitutional unit derived from a (meth)acrylate compound having 2 or more (preferably 5 or more) alkyleneoxy groups (preferably an ethyleneoxy group and a propyleneoxy group). For example, the following compound can also be used as the fluorine surfactant used in the present invention.

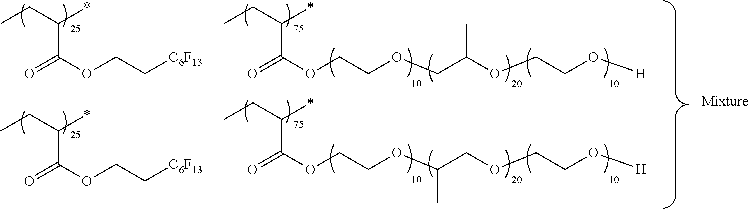

The weight-average molecular weight of the compound is preferably 3000 to 50000 and, for example, 14000.

In addition, a fluorine-containing polymer having an ethylenically unsaturated group at a side chain can also be preferably used as the fluorine surfactant. Specific examples include compounds described in paragraphs “0050” of “0090” and paragraphs “0289” to “0295” of JP2010-164965A, for example, MEGAFACE RS-101, RS-102, and RS-718K manufactured by DIC Corporation.

Specific examples of the nonionic surfactant include nonionic surfactants described in paragraph “0553” of JP2012-208494A (corresponding to paragraph “0679” of US2012/0235099A), the content of which is incorporated herein by reference.

Specific examples of the cationic surfactant include cationic surfactants described in paragraph “0554” of JP2012-208494A (corresponding to paragraph “0680” of US2012/0235099A), the content of which is incorporated herein by reference.

Specific examples of the anionic surfactant include W004, W005, and W017 (manufactured by Yusho Co., Ltd.).

Specific examples of the silicone surfactant include silicone surfactants described in paragraph “0556” of JP2012-208494A (corresponding to paragraph “0682” of US2012/0235099A), the content of which is incorporated herein by reference.

<<Ultraviolet Absorber>>

It is preferable that the near infrared absorbing composition according to the present invention includes an ultraviolet absorber. The ultraviolet absorber is preferably a conjugated diene compound and more preferably a compound represented by the following Formula (I).

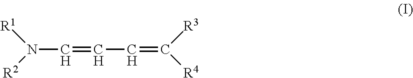

In Formula (I), R¹ and R² each independently represent a hydrogen atom, an alkyl group having 1 to 20 carbon atoms, or an aryl group having 6 to 20 carbon atoms, and may be the same as or different from each other but does not represent a hydrogen atom at the same time.

Specific examples of the ultraviolet absorber represented by Formula (I) include the following compounds. The description of a substituent of the ultraviolet absorber represented by Formula (I) can be found in paragraphs “0024” to “0033” of WO2009/123109A (corresponding to paragraphs “0040” to “0059” of US2011/0039195A), the content of which is incorporated herein by reference. Preferable specific examples of the compound represented by Formula (I) can be found in the description of Exemplary Compounds (1) to (14) in paragraphs “0034” to “0037” of WO2009/123109A (corresponding to paragraph “0060” of US2011/0039195A), the content of which is incorporated herein by reference.

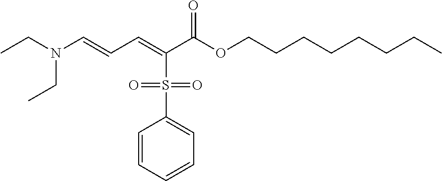 [SMILES: CCCCCCCCOC(=O)/C(=C/C=C/N(CC)CC)S(=O)(=O)c1ccccc1]

Examples of a commercially available product of the ultraviolet absorber include UV503 (manufactured by Daito Chemical Co., Ltd.). As the ultraviolet absorber, an ultraviolet absorber such as an amino diene compound, a salicylate compound, a benzophenone compound, a benzotriazole compound, an acrylonitrile compound, or a triazine compound can be preferably used. Specifically, a compound described in JP2013-68814A can be used. As the benzotriazole compound, MYUA series (manufactured by Miyoshi Oil&Fat Co., Ltd.; (The Chemical Daily, Feb. 1, 2016) may be used.

The content of the ultraviolet absorber is preferably 0.01 to 10 mass % and more preferably 0.01 to 5 mass % with respect to the total solid content of the near infrared absorbing composition.

<<Dehydrating Agent>>

It is preferable that the near infrared absorbing composition according to the present invention includes a dehydrating agent. By the near infrared absorbing composition including the dehydrating agent, the storage stability of the near infrared absorbing composition can be improved. Specific examples of the dehydrating agent include: a silane compound such as vinyl trimethoxysilane, dimethyl dimethoxysilane, tetraethoxysilane, methyl trimethoxysilane, methyltriethoxysilane, tetramethoxysilane, phenyl trimethoxysilane, or diphenyl dimethoxysilane; an orthoester compound such as methyl orthoformate, ethyl orthoformate, methyl orthoacetate, ethyl orthoacetate, trimethyl orthopropionate, triethyl orthopropionate, trimethyl orthoisopropionate, triethyl orthoisopropionate, trimethyl orthobutyrate, triethyl orthobutyrate, trimethyl orthoisobutyrate, or triethyl orthoisobutyrate; and a ketal compound such as acetone dimethyl ketal, diethyl ketone dimethyl ketal, acetophenone dimethyl ketal, cyclohexanone dimethyl ketal, cyclohexanone diethyl ketal, or benzophenone dimethyl ketal. Among these, one kind may be used alone, or two or more kinds may be used in combination.

As the dehydrating agent, a silane compound or an orthoester compound is preferable, and an orthoester compound is more preferable. Among the orthoester compounds, methyl orthoacetate, ethyl orthoacetate, trimethyl orthopropionate, triethyl orthopropionate, trimethyl orthoisopropionate, triethyl orthoisopropionate, trimethyl orthobutyrate, triethyl orthobutyrate, trimethyl orthoisobutyrate, triethyl orthoisobutyrate, is preferable, methyl orthoacetate, ethyl orthoacetate, trimethyl orthopropionate, triethyl orthopropionate, trimethyl orthoisopropionate, or triethyl orthoisopropionate is more preferable, and methyl orthoacetate or ethyl orthoacetate is still more preferable.

The content of the dehydrating agent is not particularly limited and is preferably 0.5 to 20 mass % and more preferably 2 to 10 mass % with respect to the total solid content of the near infrared absorbing composition.

<<Other Components>>

Examples of other components which can be used in combination with the near infrared absorbing composition according to the present invention include a dispersant, a sensitizer, a crosslinking agent, a curing accelerator, a filler, a thermal curing accelerator, a thermal polymerization inhibitor, and a plasticizer. Further, an accelerator for accelerating adhesion to a substrate surface and other auxiliary agents (for example, conductive particles, a filler, an antifoaming agent, a flame retardant, a leveling agent, a peeling accelerator, an antioxidant, an aromatic chemical, a surface tension adjuster, or a chain transfer agent) may be used in combination.

By the near infrared absorbing composition appropriately including the components, properties of a desired near infrared cut filter such as stability or film properties can be adjusted.

The details of the components can be found in, for example, paragraph “0183” of JP2012-003225A (corresponding to “0237” of US2013/0034812A) and paragraphs “0101” to “0104” and “0107” to “0109” of JP2008-250074A, the content of which is incorporated herein by reference.

<Preparation and Use of Near Infrared Absorbing Composition>

The near infrared absorbing composition according to the present invention can be prepared by mixing the above-described components with each other.

During the preparation of the composition, the respective components constituting the composition may be mixed with each other collectively, or may be mixed with each other sequentially after dissolved and/or dispersed in a solvent. In addition, during mixing, the order of addition or working conditions are not particularly limited.

It is preferable that the near infrared absorbing composition according to the present invention is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (having a high density and an ultrahigh molecular weight) such as polyethylene or polypropylene (PP). Among these materials, polypropylene (including high-density polypropylene) or nylon is preferable.

The pore size of the filter is suitably about 0.01 to 7.0 μm and is preferably about 0.01 to 3.0 μm and more preferably about 0.05 to 0.5 μm. In the above-described range, fine foreign matter can be reliably removed. In addition, a fibrous filter material is also preferably used, and examples of the filter material include polypropylene fiber, nylon fiber, and glass fiber. Specifically, a filter cartridge of SBP type series (manufactured by Roki Techno Co., Ltd.; for example, SBP008), TPR type series (for example, TPR002 or TPR005), SHPX type series (for example, SHPX003), or the like can be used.

In a filter is used, a combination of different filters may be used. At this time, the filtering using a first filter may be performed once, or twice or more.

In addition, a combination of first filters having different pore sizes in the above-described range may be used. Here, the pore size of the filter can refer to a nominal value of a manufacturer of the filter. A commercially available filter can be selected from various filters manufactured by Pall Corporation, Toyo Roshi Kaisha, Ltd., Entegris Japan Co., Ltd. (former Mykrolis Corporation), or Kits Microfilter Corporation.

A second filter may be formed of the same material as that of the first filter. The pore diameter of the second filter is preferably 0.2 to 10.0 μm, more preferably 0.2 to 7.0 μm, and still more preferably 0.3 to 6.0 μm. In the above-described range, foreign matter can be removed while allowing the component particles included in the composition to remain.

The near infrared absorbing composition according to the present invention can be made liquid. Therefore, a near infrared cut filter can be easily manufactured, for example, by applying the near infrared absorbing composition according to the present invention to a substrate or the like and drying the near infrared absorbing composition.

In a case where the near infrared cut filter is formed by applying the near infrared absorbing composition according to the present invention, the viscosity of the near infrared absorbing composition is preferably 1 to 3000 mPa·s. The lower limit is preferably 10 mPa·s or higher and more preferably 100 mPa·s or higher. The upper limit is preferably 2000 mPa·s or lower and more preferably 1500 mPa·s or lower.

The total solid content of the near infrared absorbing composition according to the present invention changes depending on a coating method and, for example, is preferably 1 to 50 mass %. The lower limit is more preferably 10 mass % or higher. The upper limit is more preferably 30 mass % or lower.

The use of the near infrared absorbing composition according to the present invention is not particularly limited. The near infrared absorbing composition can be preferably used for forming a near infrared cut filter or the like. For example, the near infrared absorbing composition can be preferably used, for example, for a near infrared cut filter (for example, a near infrared cut filter for a wafer level lens) on a light receiving side of a solid image pickup element or as a near infrared cut filter on a back surface side (opposite to the light receiving side) of a solid image pickup element In particular, the near infrared absorbing composition can be preferably used as a near infrared cut filter on a light receiving side of a solid image pickup element.

In addition, with the near infrared absorbing composition according to the present invention, a near infrared cut filter can be obtained in which heat resistance is high and high near infrared shielding properties can be realized while maintaining a high transmittance in a visible range. Further, the thickness of the near infrared cut filter can be reduced, which contributes to a reduction in the height of a camera module or an image display device.

<Near Infrared Cut Filter>

In addition, a near infrared cut filter according to the present invention will be described.

The near infrared cut filter according to the present invention is formed using the above-described near infrared absorbing composition according to the present invention.

It is preferable that the light transmittance of the near infrared cut filter according to the present invention satisfies at least one of the following (1) to (9), it is more preferable that the light transmittance of the near infrared cut filter according to the present invention satisfies all the following (1) to (8), and it is still more preferable that the light transmittance of the near infrared cut filter according to the present invention satisfies all the following (1) to (9).

(1) A light transmittance at a wavelength of 400 nm is preferably 80% or higher, more preferably 90% or higher, still more preferably 92% or higher, and even still more preferably 95% or higher

(2) A light transmittance at a wavelength of 450 nm is preferably 80% or higher, more preferably 90% or higher, still more preferably 92% or higher, and even still more preferably 95% or higher

(3) A light transmittance at a wavelength of 500 nm is preferably 80% or higher, more preferably 90% or higher, still more preferably 92% or higher, and even still more preferably 95% or higher

(4) A light transmittance at a wavelength of 550 nm is preferably 80% or higher, more preferably 90% or higher, still more preferably 92% or higher, and even still more preferably 95% or higher

(5) A light transmittance at a wavelength of 700 nm is preferably 20% or lower, more preferably 15% or lower, still more preferably 10% or lower, and even still more preferably 5% or lower

(6) A light transmittance at a wavelength of 750 nm is preferably 20% or lower, more preferably 15% or lower, still more preferably 10% or lower, and even still more preferably 5% or lower

(7) A light transmittance at a wavelength of 800 nm is preferably 20% or lower, more preferably 15% or lower, still more preferably 10% or lower, and even still more preferably 5% or lower

(8) A light transmittance at a wavelength of 850 nm is preferably 20% or lower, more preferably 15% or lower, still more preferably 10% or lower, and even still more preferably 5% or lower

(9) A light transmittance at a wavelength of 900 nm is preferably 20% or lower, more preferably 15% or lower, still more preferably 10% or lower, and even still more preferably 5% or lower

A light transmittance of the near infrared cut filter in a wavelength range of 400 to 550 nm is preferably 85% or higher, more preferably 90% or higher, and still more preferably 95% or higher. The higher the transmittance in a visible range, the better. It is preferable that the transmittance in a wavelength range of 400 to 550 nm is high. In addition, it is preferable that a light transmittance at one point in a wavelength range of 700 to 800 nm is 20% or lower, and it is more preferable that a light transmittance in the entire wavelength range of 700 to 800 nm is 20% or lower.

The thickness of the near infrared cut filter can be appropriately selected according to the purpose. For example, the thickness is preferably 500 μm or less, more preferably 300 μm or less, still more preferably 250 μm or less, and even still more preferably 200 μm or less.

For example, the lower limit of the thickness is preferably 0.1 μm or more, more preferably 0.2 μm or more, and still more preferably 0.5 μm or more.

The near infrared absorbing composition according to the present invention has high near infrared shielding properties. Therefore, the thickness of the near infrared cut filter can be reduced.

In the near infrared cut filter according to the present invention, a change rate of an absorbance at a wavelength of 400 nm measured before and after heating at 180° C. for 1 minute is preferably 6% or lower and more preferably 3% or lower, the change rate being expressed by the following expression. In addition, a change rate of an absorbance at a wavelength of 800 nm measured before and after heating at 180° C. for 1 minute is preferably 6% or lower and more preferably 3% or lower, the change rate being expressed by the following expression. In a case where the change rate of the absorbance is in the above-described range, heat resistance is excellent.

Change Rate (%) of Absorbance at Wavelength of 400 nm=|(Absorbance at Wavelength of 400 nm before Test-Absorbance at Wavelength of 400 nm after Test)/Absorbance at Wavelength of 400 nm before Test×100(%)

Change Rate (%) of Absorbance at Wavelength of 800 nm=|(Absorbance at Wavelength of 800 nm before Test-Absorbance at Wavelength of 800 nm after Test)/Absorbance at Wavelength of 800 nm before Test|×100(%)

In the near infrared cut filter according to the present invention, a change rate of an absorbance at a wavelength of 800 nm measured before and after dipping in methyl propylene glycol (MFG) at 25° C. for 2 minutes is preferably 6% or lower and more preferably 3% or lower, the change rate being expressed by the following expression.

Change Rate (%) of Absorbance at Wavelength of 800 nm=|(Absorbance at Wavelength of 800 nm before Test-Absorbance at Wavelength of 800 nm after Test)/Absorbance at Wavelength of 800 nm before Test|×100(%)

The near infrared cut filter according to the present invention can be used, for example, as a lens that has an ability to absorb and cut near infrared light (a camera lens for a digital camera, a mobile phone, or a vehicle-mounted camera, or an optical lens such as an a f-O lens or a pickup lens), an optical filter for a semiconductor light receiving element, a near infrared absorbing film or a near infrared absorbing plate that shields heat rays for power saving, an agricultural coating agent for selective use of sunlight, a recording medium using heat absorbed from near infrared light, a near infrared light for an electronic apparatus or a picture, an eye protector, sunglasses, a heat ray shielding filter, a filter for reading and recording an optical character, a filter for preventing classified documents from being copied, an electrophotographic photoreceptor, or a filter for laser welding. In addition, the near infrared cut filter according to the present invention is also useful as a noise cut filter for a CCD camera or a filter for a CMOS image sensor.

<Method of Manufacturing Near Infrared Cut Filter>

The near infrared cut filter according to the present invention can be manufactured using the above-described near infrared absorbing composition according to the present invention. Specifically, the near infrared cut filter according to the present invention can be manufactured through a step of applying the near infrared absorbing composition according to the present invention to a support or the like to form a film and a step of drying the film. The thickness and a laminate structure are not particularly limited and can be appropriately selected depending on the purpose. In addition, a step of forming a pattern may be further performed. In addition, a material in which the film formed of the near infrared absorbing composition according to the present invention is formed on the support may be used as the near infrared cut filter, or the film (single film) peeled off from the support may be used as the near infrared cut filter.

The step of forming a film can be performed, for example, by applying the near infrared absorbing composition according to the present invention to the support using a drop casting method, a spin coating method, a slit spin coating method, a slit coating method, a screen printing method, an application method using an applicator, or an application method using an injector. The application method using an injector is not particularly limited as long as the near infrared absorbing composition can be ejected using this method, and examples thereof include a method (in particular, pp. 115 to 133) described in “Extension of Use of Injector—Infinite Possibilities in Patent—” (February, 2005, S.B. Research Co., Ltd.) and methods described in JP2003-262716A, JP2003-185831A, JP2003-261827A, JP2012-126830A, and JP2006-169325A in which a composition to be ejected is replaced with the near infrared absorbing composition according to the present invention. In a case where the drop casting method is used, it is preferable that a drop range of the near infrared absorbing composition in which a photoresist is used as a partition wall is formed on the support such that a film having a predetermined uniform thickness can be obtained. A desired thickness can be obtained by adjusting the drop amount and solid content concentration of the near infrared absorbing composition and the area of the drop range.

The thickness of the dried film is not particularly limited and can be appropriately selected depending on the purpose.

The support may be a transparent substrate such as glass. In addition, the support may be a solid image pickup element. In addition, the support may be another substrate that is provided on a light receiving side of a solid image pickup element. In addition, the support may be a planarizing layer or the like that is provided on a light receiving side of a solid image pickup element.

In the step of drying the film, drying conditions vary depending on the kinds of the respective components and the solvent, ratios therebetween, and the like. For example, it is preferable that the film is dried at a temperature of 60° C. to 150° C. for 30 seconds to 15 minutes.

Examples of a method used in the step of forming a pattern include a method including: a step of applying the near infrared absorbing composition according to the present invention to a support or the like to form a composition layer having a film shape; a step of exposing the composition layer in a pattern shape; and a step of forming a pattern by removing a non-exposed portion by development. In the step of forming a pattern, a pattern may be formed using a photolithography method or using a dry etching method.

The method of manufacturing a near infrared cut filter may include other steps. The other steps are not particularly limited and can be appropriately selected depending on the purpose. Examples of the other steps include a substrate surface treatment step, a pre-heating step (pre-baking step), a curing step, and a post-heating step (post-baking step).

<<Pre-Heating Step and Post-Heating Step>>

A heating temperature in the pre-heating step and the post-heating step is preferably 80° C. to 200° C. The upper limit is preferably 150° C. or lower. The lower limit is preferably 90° C. or higher.

A heating time in the pre-heating step and the post-heating step is preferably 30 seconds to 240 seconds. The upper limit is preferably 180 seconds or shorter. The lower limit is preferably 60 seconds or longer.

<<Curing Step>>

In the curing step, the formed film is optionally cured. By curing the film, the mechanical strength of the near infrared cut filter is improved.

The curing step is not particularly limited and can be appropriately selected depending on the purpose. For example, an exposure treatment or a heating treatment is preferably used. Here, in the present invention, “exposure” denotes irradiation of not only light at various wavelengths but also radiation such as an electron beam or an X-ray.

It is preferable that exposure is performed by irradiation of radiation. As the radiation which can be used for exposure, ultraviolet light such as an electron beam, KrF, ArF, a g-ray, a h-ray, or an i-ray or visible light is preferably used.

Examples of an exposure type include exposure using a stepper and exposure using a high-pressure mercury lamp.

The exposure dose is preferably 5 to 3000 mJ/cm². The upper limit is preferably 2000 mJ/cm² or lower and more preferably 1000 mJ/cm² or lower. The lower limit is preferably 10 mJ/cm² or higher and more preferably 50 mJ/cm² or higher.

Examples of an exposure method include a method of exposing the entire area of the formed film. In a case where the near infrared absorbing composition includes a polymerizable compound, due to the exposure of the entire area, the curing of the polymerizable compound is accelerated, the curing of the film is further accelerated, and mechanical strength and durability are improved.

An exposure device is not particularly limited and can be appropriately selected depending on the purpose, and examples thereof include an ultraviolet exposure device such as an ultrahigh pressure mercury lamp.

In addition, examples of a method for the heat treatment include a method of heating the entire area of the formed film. Due to the heat treatment, the film hardness of the pattern is improved.

The heating temperature is preferably 100° C. to 260° C. The lower limit is preferably 120° C. or higher and more preferably 160° C. or higher. The upper limit is preferably 240° C. or lower and more preferably 220° C. or lower. In a case where the heating temperature is in the above-described range, a film having excellent strength is likely to be obtained.

The heating time is preferably 1 to 180 minutes. The lower limit is preferably 3 minutes or longer. The upper limit is preferably 120 minutes or shorter.

A heater can be appropriately selected from well-known devices without any particular limitation, and examples thereof include a dry oven, a hot plate, and an infrared heater.

<Solid Image Pickup Element and Camera Module>

A solid image pickup element according to the present invention includes the near infrared cut filter according to the present invention.

A camera module according to the present invention includes a solid image pickup element and the near infrared cut filter that is disposed on a light receiving side of the solid image pickup element.

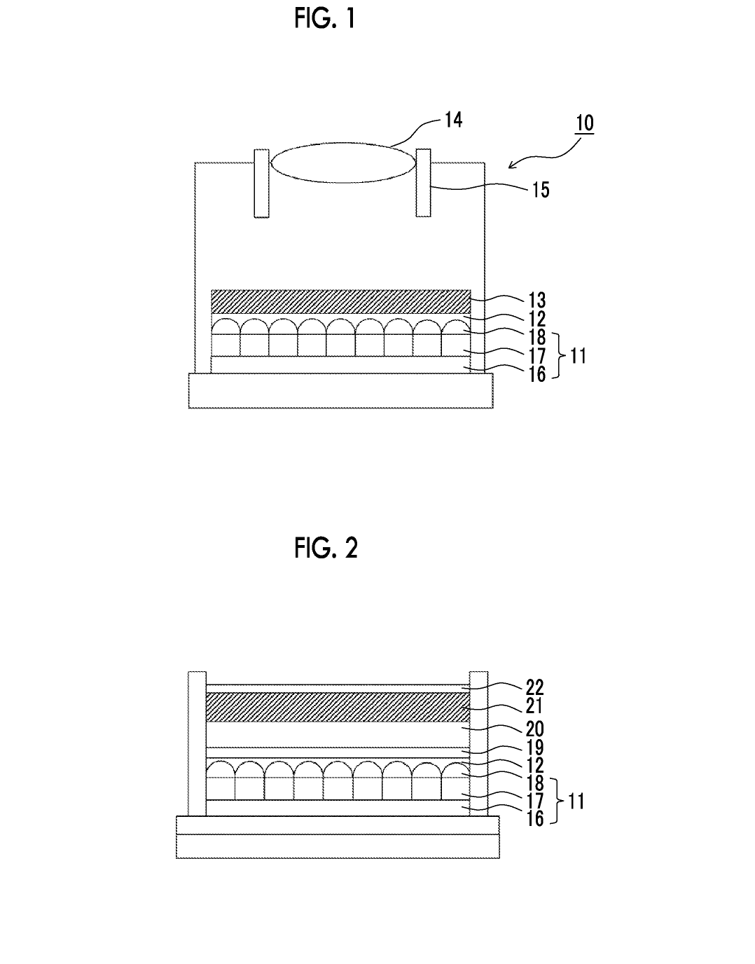

FIG. 1 is a schematic cross-sectional view showing a configuration of a camera module including a near infrared cut filter according to an embodiment of the present invention.

For example, a camera module 10 includes: a solid image pickup element 11; a planarizing layer 12 that is provided on a main surface side (light receiving side) of the solid image pickup element; a near infrared cut filter 13; and a lens holder 15 that is disposed above the near infrared cut filter and has an imaging lens 14 in an internal surface.

In the camera module 10, an incidence ray hv incident from the outside reaches an image pickup element portion of the solid image pickup element 11 after sequentially passing through the imaging lens 14, the near infrared cut filter 13, and the planarizing layer 12.

For example, the solid image pickup element 11 includes a photodiode (not shown), an interlayer insulator (not shown), a base layer (not shown), color filters 17, an overcoat (not shown), and microlenses 18 that are formed in this order on a main surface of a substrate 16. The color filters 17 (a red color filter, a green color filter, a blue color filter) and the microlenses 18 are disposed respectively corresponding to the solid image pickup element 11.

In addition, instead of providing the near infrared cut filter 13 on the surface of the planarizing layer 12, the near infrared cut filter 13 may be formed on a surface of the microlenses 18, between the base layer and the color filters 17, or between the color filters 17 and the overcoat. For example, the near infrared cut filter 13 may be provided at a position at a distance of less than 2 mm (more preferably 1 mm) from the surfaces of the microlenses. By providing the near infrared cut filter at this position, the step of forming the near infrared cut filter can be simplified, and unnecessary near infrared light for the microlens can be sufficiently cut. Therefore, near infrared shielding properties can be further improved.

The near infrared cut filter according to the present invention has excellent heat resistance and thus can be provided for a solder reflow step. By manufacturing a camera module through the solder reflow step, automatic packaging of an electronic component packaging substrate or the like where soldering is required to be performed can be realized, and thus productivity can be significantly improved compared to a case where the solder reflow step is not used. Further, since automatic packaging can be performed, the cost can be reduced. In a case where the near infrared cut filter according to the present invention is provided for the solder reflow step, the near infrared cut filter is exposed to a temperature of about 250° C. to 270° C. Therefore, it is preferable that the near infrared cut filter has enough heat resistance to withstand the solder reflow step (hereinafter, also referred to as “solder reflow resistance”).

In this specification, “having solder reflow resistance” represents that the properties as the near infrared cut filter can be maintained before and after heating at 180° C. for 1 minute. It is preferable that the properties as the near infrared cut filter can be maintained before and after heating at 230° C. for 10 minutes. It is more preferable that the properties as the near infrared cut filter can be maintained before and after heating at 250° C. for 3 minutes. In a case where the near infrared cut filter does not have solder reflow resistance, when the near infrared cut filter is held under the above-described conditions, near infrared shielding properties may deteriorate, or a function as a film may be insufficient.

In addition, the present invention also relates to a method of manufacturing a camera module including a reflow step. Since the near infrared cut filter according to the present invention has near infrared shielding properties, properties of a small, light, and high-performance camera module do not deteriorate even in the reflow step.

FIGS. 2 to 4 are schematic cross-sectional views showing an example of the vicinity of the near infrared cut filter in the camera module.

As shown in FIG. 2, the camera module includes the solid image pickup element 11, the planarizing layer 12, an ultraviolet-infrared reflection film 19, a transparent substrate 20, a near infrared light absorbing layer (near infrared cut filter) 21, and an antireflection layer 22 in this order.

The ultraviolet-infrared reflection film 19 has an effect of imparting or improving an effect of the near infrared cut filter. For example, the details of the ultraviolet-infrared reflection film 19 can be found in paragraphs “0033” to “0039” of JP2013-68688A, the content of which is incorporated herein by reference.

The transparent substrate 20 allows transmission of light in a visible wavelength range. For example, the details of the transparent substrate 20 can be found in paragraphs “0026” to “0032” of JP2013-68688A, the content of which is incorporated herein by reference.

The near infrared light absorbing layer 21 can be formed by applying the near infrared absorbing composition according to the present invention.

The antireflection layer 22 has a function of preventing reflection of light incident on the near infrared cut filter to improve the transmittance and to effectively utilize the incidence ray. For example, the details of the antireflection layer 22 can be found in paragraph “0040” of JP2013-68688A, the content of which is incorporated herein by reference.

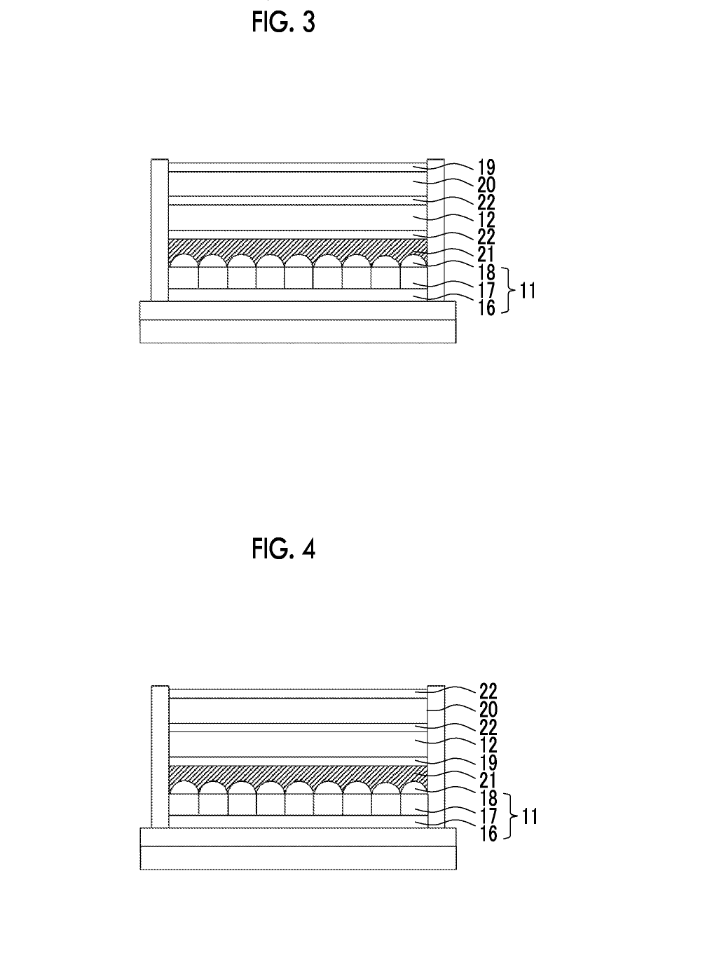

As shown in FIG. 3, the camera module may include the solid image pickup element 11, the near infrared light absorbing layer (near infrared cut filter) 21, the antireflection layer 22, the planarizing layer 12, the antireflection layer 22, the transparent substrate 20, and the ultraviolet-infrared reflection film 19 in this order.

As shown in FIG. 4, the camera module may include the solid image pickup element 11, the near infrared light absorbing layer (near infrared cut filter) 21, the ultraviolet-infrared reflection film 19, the planarizing layer 12, the antireflection layer 22, the transparent substrate 20, and an antireflection layer 22 in this order.

<Image Display Device>

An image display device according to the present invention includes the near infrared cut filter according to the present invention. The near infrared cut filter according to the present invention can also be used in an image display device such as a liquid crystal display device or an organic electroluminescence (organic EL) display device. For example, by using the near infrared cut filter in combination with the respective colored pixels (for example, red, green, blue), the near infrared cut filter can be used for the purpose of shielding infrared light included in light emitted from a backlight (for example, a white light emitting diode (white LED)) of a display device to prevent a malfunction of a peripheral device, or for the purpose of forming an infrared pixel in addition to the respective color display pixels.

The definition of a display device and the details of each display device can be found in, for example, “Electronic Display Device (by Akiya Sasaki, Kogyo Chosakai Publishing Co., Ltd., 1990)” or “Display Device (Sumiaki Ibuki, Sangyo Tosho Co., Ltd.). In addition, the details of a liquid crystal display device can be found in, for example, “Next-Generation Liquid Crystal Display Techniques (Edited by Tatsuo Uchida, Kogyo Chosakai Publishing Co., Ltd., 1994)”. The liquid crystal display device to which the present invention is applicable is not particularly limited. For example, the present invention is applicable to various liquid crystal display devices descried in “Next-Generation Liquid Crystal Display Techniques”.

The image display device may include a white organic EL element. It is preferable that the white organic EL element has a tandem structure. The tandem structure of the organic EL element is described in, for example, JP2003-45676A, or pp. 326-328 of “Forefront of Organic EL Technology Development—Know-How Collection of High Brightness, High Precision, and Long Life” (Technical Information Institute, 2008). It is preferable that a spectrum of white light emitted from the organic EL element has high maximum emission peaks in a blue range (430 nm to 485 nm), a green range (530 nm to 580 nm), and a yellow range (580 nm to 620 nm). It is more preferable that the spectrum has a maximum emission peak in a red range (650 nm to 700 nm) in addition to the above-described emission peaks.

### EXAMPLES

Hereinafter, the present invention will be described in detail using examples.

Materials, used amounts, ratios, treatment details, treatment procedures, and the like shown in the following examples can be appropriately changed within a range not departing from the scope of the present invention. Accordingly, the scope of the present invention is not limited to the following specific examples. Unless specified otherwise, “part(s)” and “%” represent “part(s) by mass” and “mass %”.

<Measurement of Weight-Average Molecular Weight (Mw)>

The weight-average molecular weight (Mw) was measured using the following method.

Kind of Column: TSKgel Super AWM-H (manufactured by Tosoh Corporation, 6.0 mm (Inner diameter)×15.0 cm)

Developing Solvent: a 10 mmol/L lithium bromide N-methylpyrrolidinone (NMP)

### Solution

Column temperature: 40° C.

Flow rate (sample injection volume): 10 μL

Device name: HLC-8220 GPC (manufactured by Tosoh Corporation)

Calibration curve base resin: polystyrene

<Measurement of Solubility of Copper-Containing Polymer>

100 g of a copper-containing polymer was added to 100 g of cyclohexanone at 25° C. under a pressure of 0.1 MPa. Next, the obtained solution was stirred at a temperature of 25° C. for 30 minutes. Next, the solid content was collected from the stirred solution, and the solubility of the copper-containing polymer was measured from the following expression.

Solubility (%)={(Mass of Copper-Containing Polymer before Dissolved in Cyclohexanone-Mass of Solid Content Collected from Solution after Dissolving Copper-Containing Polymer in Cyclohexanone)/Mass of Copper-Containing Polymer before Dissolved in Cyclohexanone}×100

<Synthesis of Copper-Containing Polymer>

### Synthesis Example 1

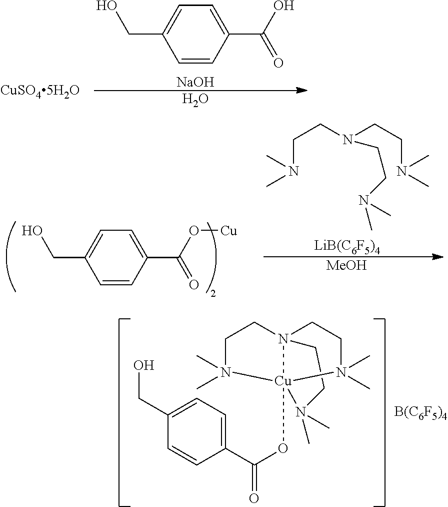

14.92 g of copper sulfate pentahydrate and 50 g of water were put into a flask and were stirred at room temperature to completely dissolve the components. 5.07 g of a 50.9% sodium hydroxide aqueous solution and 30 g of water were added to 10.00 g of 4-hydroxymethylbenzoic acid and adjusted to obtain a sodium 4-hydroxybenzoate aqueous solution, and the sodium 4-hydroxybenzoate aqueous solution was added dropwise to the copper sulfate aqueous solution. The obtained solution was stirred at room temperature for 30 minutes, and the precipitated crystals were collected by filtration, were washed with water, and were dried with air. As a result, 11.32 g of copper bis(4-hydroxymethylbenzoate) was obtained.

5.00 g of the copper bis(4-hydroxymethylbenzoate) and 60 mL of methanol were added to a flask and were stirred at 40° C. 3.31 g of tris[(2-dimethylamino)ethyl]amine was added to the solution, and the components were stirred at 40° C. for 30 minutes. Next, 11.21 g of lithium tetrakis(pentafluorophenyl)borate (solid content: 92%) was added to the obtained solution, and the components were stirred at 40° C. for 30 minutes. Water was slowly added dropwise to the reaction solution, and precipitated crystals were collected by filtration, were washed with water, and were dried with air. As a result, 16.02 g of a low-molecular-weight copper complex was obtained.

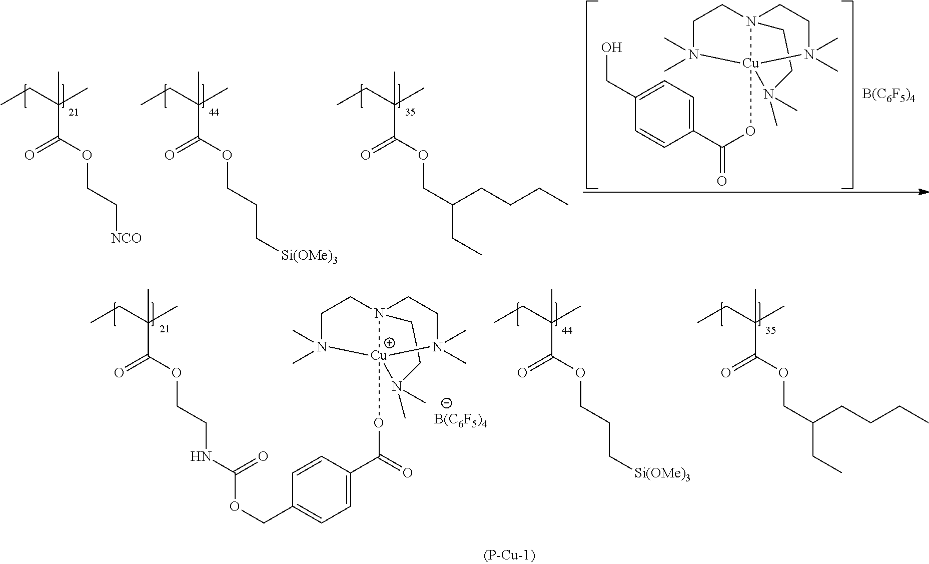

3.81 g of 3-)trimethylsilyl)propyl methacrylate, 3.81 g of 2-ethylhexyl methacrylate, 1.39 g of 2-isocyanatoethyl methacrylate, and 21.00 g of propylene glycol monomethyl ether acetate (PGMEA) were added to a flask and were stirred to dissolve the components. 0.501 g of dimethyl 2,2′-azobis(2-methylpropionate) (V-601, manufactured by Wako Pure Chemical Industries, Ltd.) was added to the solution, and the components were stirred at 80° C. for 4 hours, were then stirred at 90° C. for 3 hours, and were air-cooled. This way, a solution of a polymer as a material represented by the above formula was obtained (solid content: 30%, isocyanate: 0.992 meq/g). The weight-average molecular weight of the polymer was 23830.

0.892 g of the low-molecular-weight copper complex and 2.08 g of cyclohexanone were added to a flask and were stirred at room temperature. 3.333 g of the synthesized polymer solution and one droplet of NEOSTANN U-600 (manufactured by Nitto Kasei Co., Ltd.) were added to the solution, and the components were stirred at 70° C. for 4 hours and were air-cooled. This way, a solution of a copper-containing polymer (P—Cu-1) represented by the above formula was obtained. 10 mass % or higher of the copper-containing polymer (P—Cu-1) was dissolved in cyclohexanone at 25° C.

### Synthesis Example 2

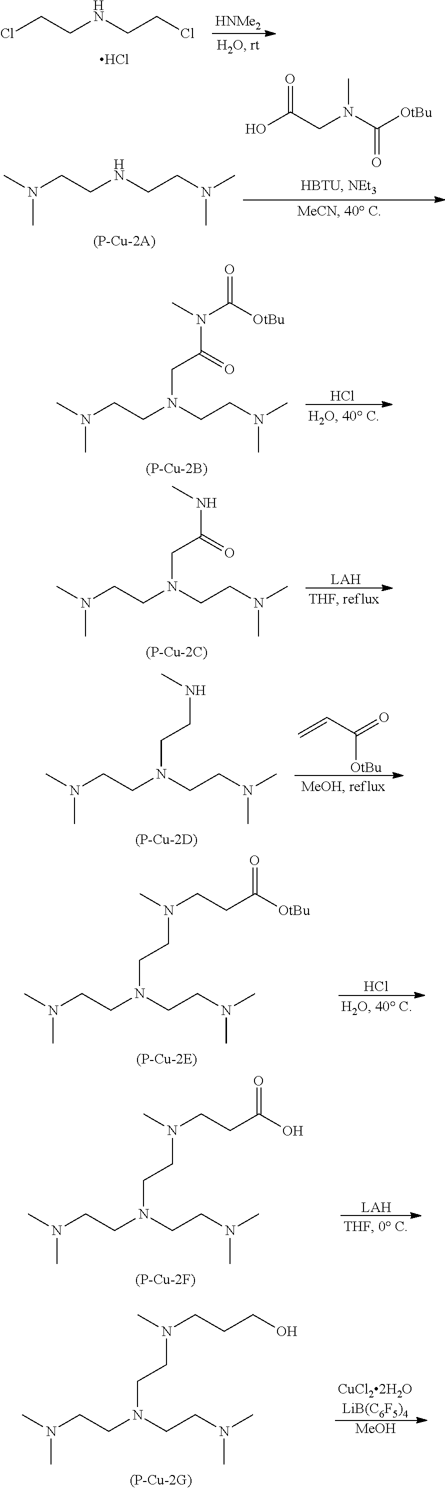

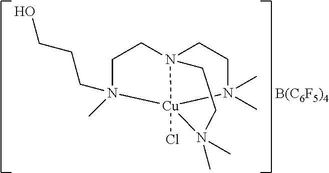

101 g of bis(2-chloroethyl)amine hydrochloride and 200 mL of water were added to a three-necked flask and were stirred at room temperature. 600 mL of a 50 mass % dimethylamine aqueous solution was added dropwise to the solution, and the components were stirred at room temperature for 7 days. 150 g of sodium hydroxide and 100 mL of t-butyl methyl ether were added to the obtained solution. The organic phase obtained by liquid separation was preliminarily dried by anhydrous sodium sulfate and then was concentrated under a reduced pressure. As a result, 24.4 g of a compound (P—Cu-2A) was obtained. 15.0 g of N-(tert-butoxycarbonyl)-N-methylglycine, 100 mL of acetonitrile, and 12 g of triethylamine were added to a three-necked flask and were stirred at room temperature. 38.1 g of O-(benzotriazol-1-yl)-N,N,N′,N′-tetramethyluronium Hexafluorophosphate (HBTU) was added to the solution, 12.0 g of the compound (P—Cu-2A) was further added thereto, and the components were stirred at 40° C. for 4 hours. 100 mL of a saturated sodium chloride aqueous solution was added to the obtained solution to obtain a neutral aqueous solution. Next, the obtained aqueous phase was washed with 150 mL of ethyl acetate three times, and 100 mL of a saturated potassium carbonate aqueous solution was added to obtain a basic aqueous solution. Liquid separation and extraction were performed on the aqueous solution three times using 150 mL of ethyl acetate to obtain an organic phase. The obtained organic phase was preliminarily dried by anhydrous sodium sulfate and then was concentrated under a reduced pressure. As a result, 5.7 g of a compound (P—Cu-2B) was obtained.

4.1 g of the compound (P—Cu-2B) and 10 mL of water were added to a flask, 3.7 mL of concentrated hydrochloric acid was added thereto while stirring the components at room temperature, and then the components were stirred at 40° C. for 2 hours. Sodium hydroxide was added to the reaction solution to obtain a basic aqueous solution. Next, liquid separation and extraction were performed using tert-butyl methyl ether to obtain an organic phase. As a result, the organic phase was preliminarily dried by anhydrous sodium sulfate and then was concentrated under a reduced pressure. As a result, 3.0 g of a compound (P—Cu-2C) was obtained.

In a nitrogen atmosphere, 3.78 g of lithium aluminum hydride (LAH) and 60 mL of dehydrated tetrahydrofuran were added to a three-necked flask and were cooled to 0° C. 40 mL of the dehydrated tetrahydrofuran solution of 3.0 g of the compound (P—Cu-2C) was added dropwise to the solution, and then the components were heated to reflux for 2 hours and were cooled to room temperature. Next, 4 mL of water, 4 mL of a 15 mass % sodium hydroxide aqueous solution, and 12 mL of water were slowly added dropwise to the obtained solution in this order while cooling the solution by ice. The produced white precipitate was separated by filtration, and the filtrate was concentrated under a reduced pressure to obtain an oil. The obtained oil was dissolved again in tert-butyl methyl ether, was preliminarily dried by anhydrous sodium sulfate and then was concentrated again under a reduced pressure. As a result, 1.1 g of a compound (P—Cu-2D) was obtained.

1.08 g of the compound (P—Cu-2D) and 10 mL of methanol were added to a flask, 0.80 g of t-butyl acrylate was added thereto while stirring the components, and the components were heated to reflux for 2 hours. The reaction solution was concentrated under a reduced pressure to obtain 1.4 g of a compound (P—Cu-2E).

1.3 g of the compound (P—Cu-2E) and 5 mL of water were added to a flask, 2.0 mL of concentrated hydrochloric acid was added thereto while stirring the components at room temperature, and then the components were stirred at 40° C. for 6 hours. Toluene was added to the reaction solution for azeotropic dehydration, and then the reaction solution was concentrated. As a result, a hydrochloride of the compound (P—Cu-2F) was obtained as a yellow solid. Methanol was added to the solution, and the components were stirred to obtain a suspension. When triethylamine was added to the suspension, a hydrochloride of the compound (P—Cu-2F) was completely dissolved. Further, when the triethylamine and ethyl acetate were added, triethylamine hydrochloride was precipitated, and the precipitated triethylamine hydrochloride was separated by filtration. This process was repeated until the triethylamine hydrochloride was not precipitated. Finally, the solution was concentrated to obtain 1.0 g of a compound (P—Cu-2F).

In a nitrogen atmosphere, 0.50 g of lithium aluminum hydride (LAH) and 10 mL of dehydrated tetrahydrofuran were added to a three-necked flask and were cooled to 0° C. 5 mL of the dehydrated tetrahydrofuran solution of 1.0 g of the compound (P—Cu-2F) was slowly added dropwise to the solution, and then the components were stirred at 0° C. for 2 hours.

Next, 0.5 mL of water, 0.5 mL of a 15 mass % sodium hydroxide aqueous solution, and 1.5 mL of water were slowly added dropwise to the obtained solution in this order. The produced white precipitate was separated by filtration, and the filtrate was concentrated under a reduced pressure to obtain an oil. The obtained oil was dissolved again in t-butyl methyl ether, was preliminarily dried by anhydrous sodium sulfate and then was concentrated again under a reduced pressure. As a result, 0.5 g of a compound (P—Cu-2G) was obtained.

0.25 of copper (II) chloride dihydrate and 8 mL of methanol were added to a flask and were stirred at 40° C. 0.42 g of the compound (P—Cu-2G) was added to the solution, and the components were stirred for 30 minutes. 1.5 mL of a methanol solution of 1.39 g of lithium tetrakis(pentafluorophenyl)borate was added dropwise to the solution, and the components were stirred at for 30 minutes. 5 mL of water was added dropwise to the obtained solution, and the precipitated solid was collected by filtration. As a result, a low-molecular-weight copper complex was obtained.

Using the low-molecular-weight copper complex synthesized as described above, a copper-containing polymer (P—Cu-2) was synthesized according to the following same synthesis scheme as that of (P—Cu-1). The weight-average molecular weight of the material polymer was 23830. 10 mass % or higher of the copper-containing polymer (P—Cu-2) was dissolved in cyclohexanone at 25° C.

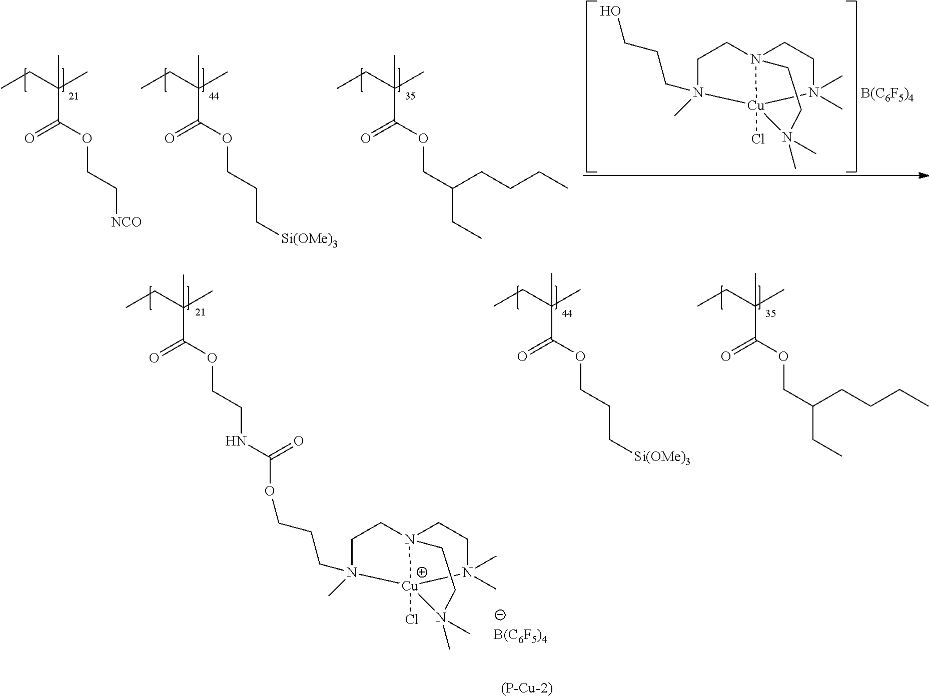

### Synthesis Example 3

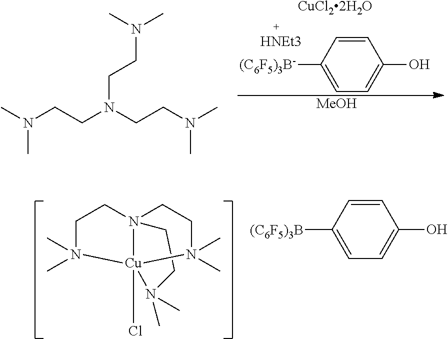

0.25 of copper (II) chloride dihydrate and 8 mL of methanol were added to a flask and were stirred at 40° C. 0.36 g of tris[(2-dimethylamino)ethyl]amine was added to the solution, and the components were stirred at for 30 minutes. 1.5 mL of a methanol solution of 1.30 g of triethylammonium tris(pentafluorophenyl)(4-hydroxylphenyl)borate (the synthesis method is described in JP1999-503113A (JP-H11-503113A)) was added dropwise to the solution, and the components were stirred for 30 minutes. 5 mL of water was added dropwise to the obtained solution, and the precipitated solid was collected by filtration. As a result, a low-molecular-weight copper complex was obtained.

Using the low-molecular-weight copper complex synthesized as described above, a copper-containing polymer (P—Cu-3) was synthesized according to the following same synthesis scheme as that of (P—Cu-1). The weight-average molecular weight of the material polymer was 23830. 10 mass % or higher of the copper-containing polymer (P—Cu-3) was dissolved in cyclohexanone at 25° C.

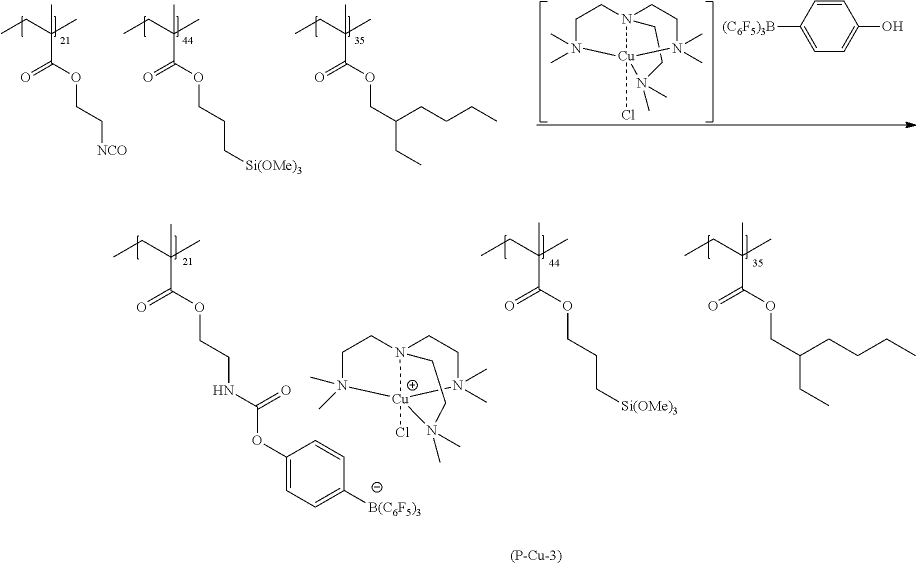

### Synthesis Example 4

A low-molecular-weight copper complex was synthesized using the same method as in Synthesis Example 1, except that lithium bis(trifluoromethanesulfonyl)imide was used instead of lithium tetrakis(pentafluorophenyl)borate. Using the low-molecular-weight copper complex synthesized as described above, a copper-containing polymer (P—Cu-4) was synthesized according to the following same synthesis scheme as that of (P—Cu-1). The weight-average molecular weight of the material polymer was 23830. 10 mass % or higher of the copper-containing polymer (P—Cu-4) was dissolved in cyclohexanone at 25° C.

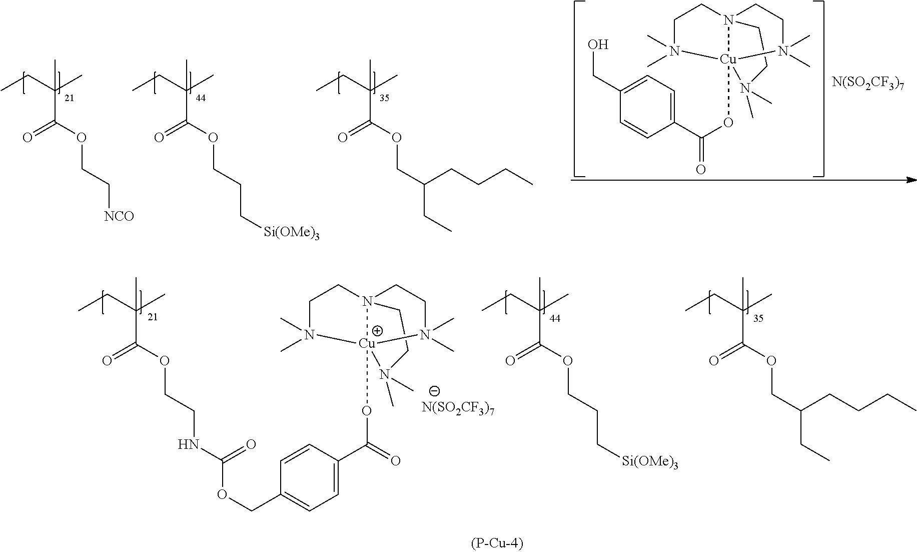

### Synthesis Example 5

A low-molecular-weight copper complex was synthesized using the same method as in Synthesis Example 1, except that 4-hydroxybenzoic acid was used instead of 4-hydroxymethylbenzoic acid. Using the low-molecular-weight copper complex synthesized as described above, a copper-containing polymer (P—Cu-5) was synthesized according to the following same synthesis scheme as that of (P—Cu-1). The weight-average molecular weight of the material polymer was 23830. 10 mass % or higher of the copper-containing polymer (P—Cu-5) was dissolved in cyclohexanone at 25° C.

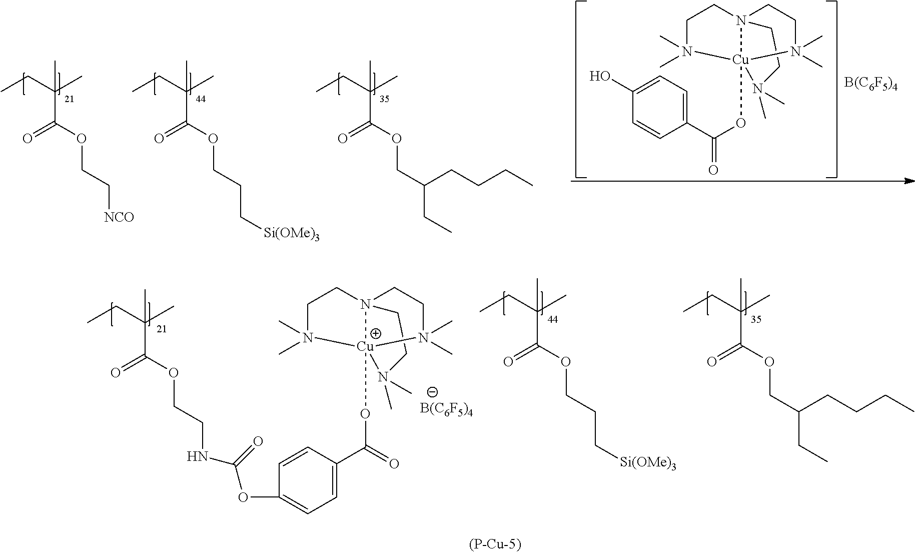

### Synthesis Example 6

A low-molecular-weight copper complex was synthesized using the same method as in Synthesis Example 1, except that 2-isothiocyanatoethyl methacrylate was used instead of 2-isocyanatoethyl methacrylate. Using the low-molecular-weight copper complex synthesized as described above, a copper-containing polymer (P—Cu-6) was synthesized according to the following same synthesis scheme as that of (P—Cu-1). The weight-average molecular weight of the material polymer was 22960. 10 mass % or higher of the copper-containing polymer (P—Cu-6) was dissolved in cyclohexanone at 25° C.

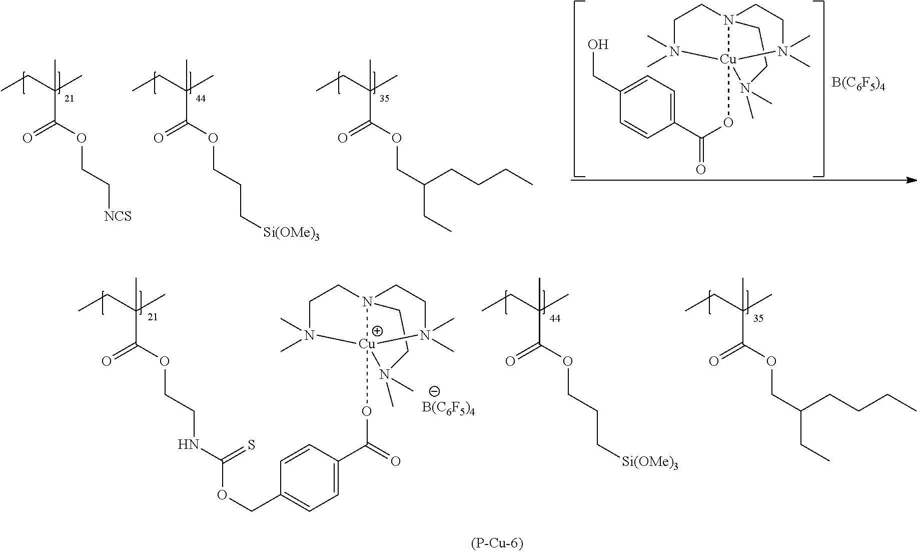

### Synthesis Example 7

A low-molecular-weight copper complex was synthesized using the same method as in Synthesis Example 1, except that 3-[dimethoxy(methyl)silyl]propyl methacrylate was used instead of 3-(trimethoxysilyl)propyl methacrylate. Using the low-molecular-weight copper complex synthesized as described above, a copper-containing polymer (P—Cu-7) was synthesized according to the following same synthesis scheme as that of (P—Cu-1). The weight-average molecular weight of the material polymer was 20560. 10 mass % or higher of the copper-containing polymer (P—Cu-7) was dissolved in cyclohexanone at 25° C.

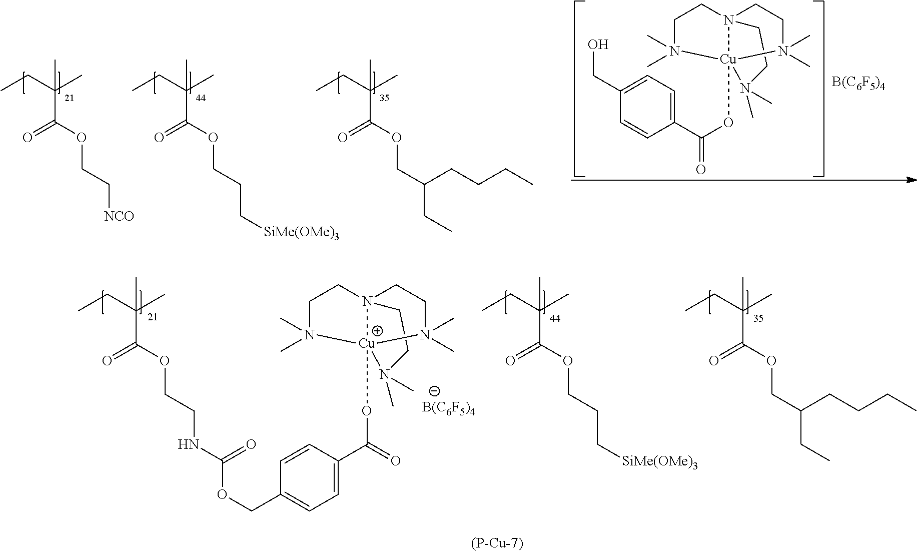

### Synthesis Example 8

A low-molecular-weight copper complex was synthesized using the same method as in Synthesis Example 1, except that benzyl methacrylate was used instead of 2-ethylhexyl methacrylate. Using the low-molecular-weight copper complex synthesized as described above, a copper-containing polymer (P—Cu-8) was synthesized according to the following same synthesis scheme as that of (P—Cu-1). The weight-average molecular weight of the material polymer was 18330. 10 mass % or higher of the copper-containing polymer (P—Cu-8) was dissolved in cyclohexanone at 25° C.

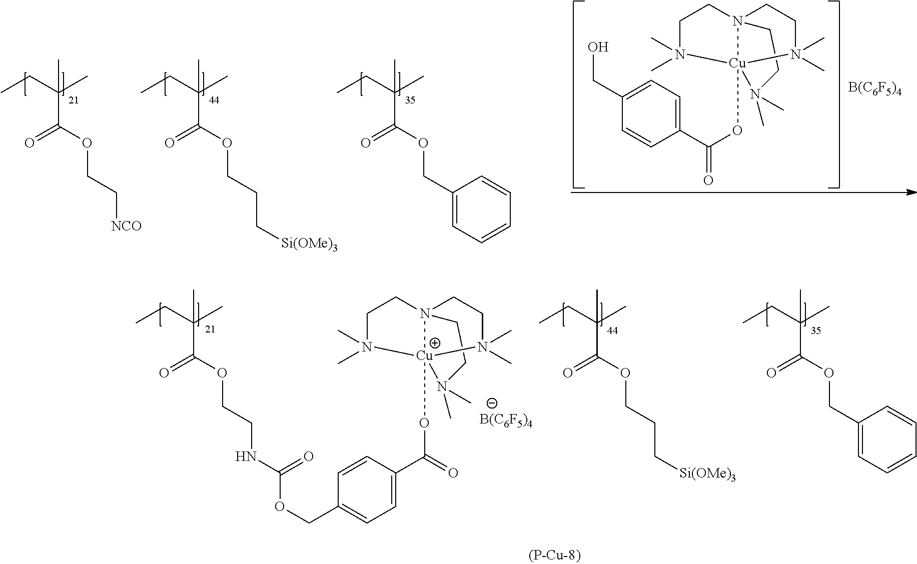

### Synthesis Example 9

A low-molecular-weight copper complex was synthesized using the same method as in Synthesis Example 1, except that 4-mercaptomethylbenzoic acid was used instead of 4-hydroxymethylbenzoic acid. Using the low-molecular-weight copper complex synthesized as described above, a copper-containing polymer (P—Cu-9) was synthesized according to the following same synthesis scheme as that of (P—Cu-1). The weight-average molecular weight of the material polymer was 23830. 10 mass % or higher of the copper-containing polymer (P—Cu-9) was dissolved in cyclohexanone at 25° C.

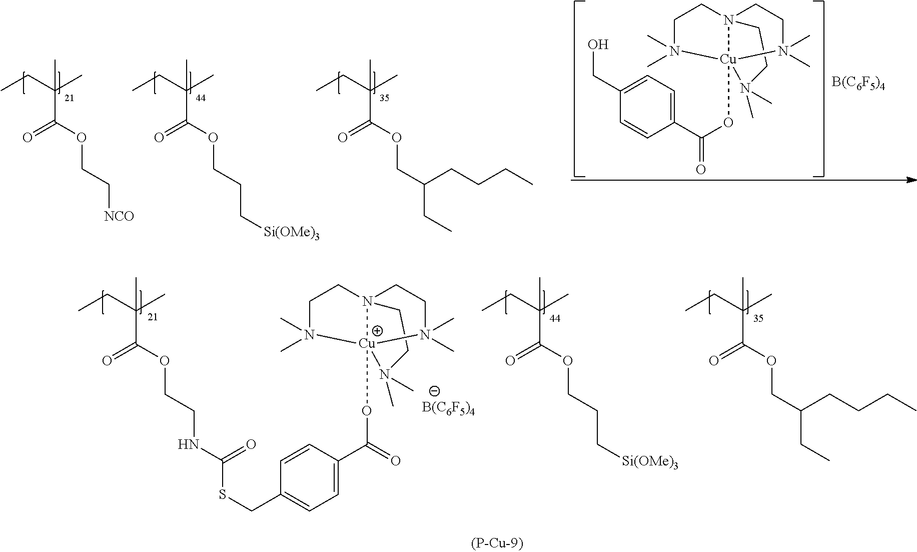

### Synthesis Example 10

Using the low-molecular-weight copper complex synthesized in Synthesis Example 9, a copper-containing polymer (P—Cu-10) was synthesized according to the following same synthesis scheme as that of (P—Cu-6). The weight-average molecular weight of the material polymer was 22960. 10 mass % or higher of the copper-containing polymer (P—Cu-10) was dissolved in cyclohexanone at 25° C.

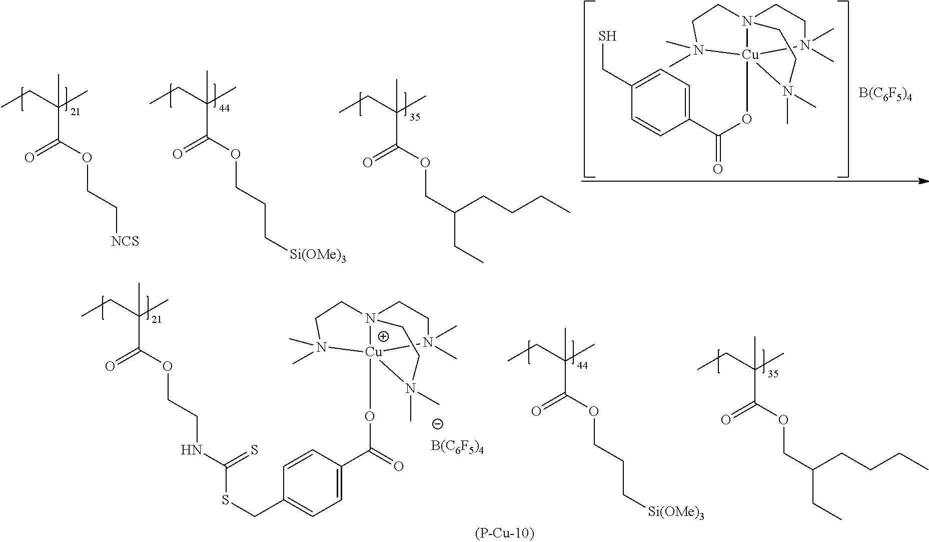

### Synthesis Example 11

A low-molecular-weight copper complex was synthesized using the same method as in Synthesis Example 1, except that 4-aminomethylbenzoic acid was used instead of 4-hydroxymethylbenzoic acid. Using the low-molecular-weight copper complex synthesized as described above, a copper-containing polymer (P—Cu-11) was synthesized according to the following same synthesis scheme as that of (P—Cu-1). The weight-average molecular weight of the material polymer was 23830. 10 mass % or higher of the copper-containing polymer (P—Cu-11) was dissolved in cyclohexanone at 25° C.

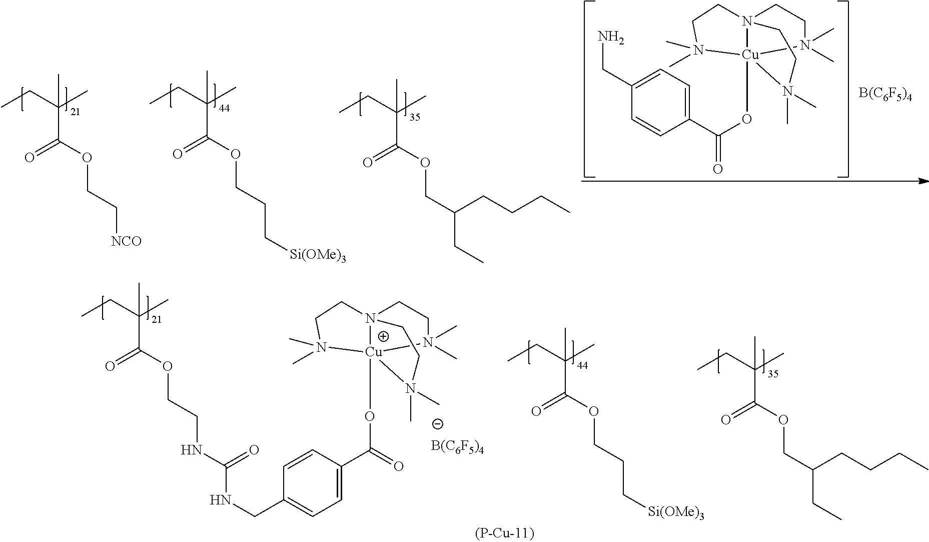

### Synthesis Example 12

Using the low-molecular-weight copper complex synthesized in Synthesis Example 11, a copper-containing polymer (P—Cu-12) was synthesized according to the following same synthesis scheme as that of (P—Cu-6). The weight-average molecular weight of the material polymer was 22960. 10 mass % or higher of the copper-containing polymer (P—Cu-12) was dissolved in cyclohexanone at 25° C.

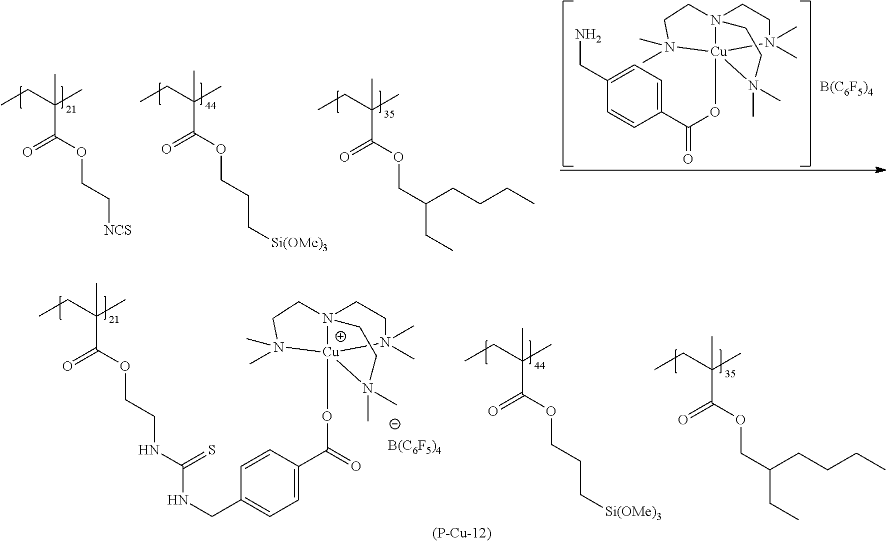

### Synthesis Example 13

A low-molecular-weight copper complex was synthesized using the same method as in Synthesis Example 1, except that potassium tris(trifluoromethanesulfonyl)methide was used instead of lithium tetrakis(pentafluorophenyl)borate. Using the low-molecular-weight copper complex synthesized as described above, a copper-containing polymer (P—Cu-13) was synthesized according to the following same synthesis scheme as that of (P—Cu-1). The weight-average molecular weight of the material polymer was 23830. 10 mass % or higher of the copper-containing polymer (P—Cu-13) was dissolved in cyclohexanone at 25° C.

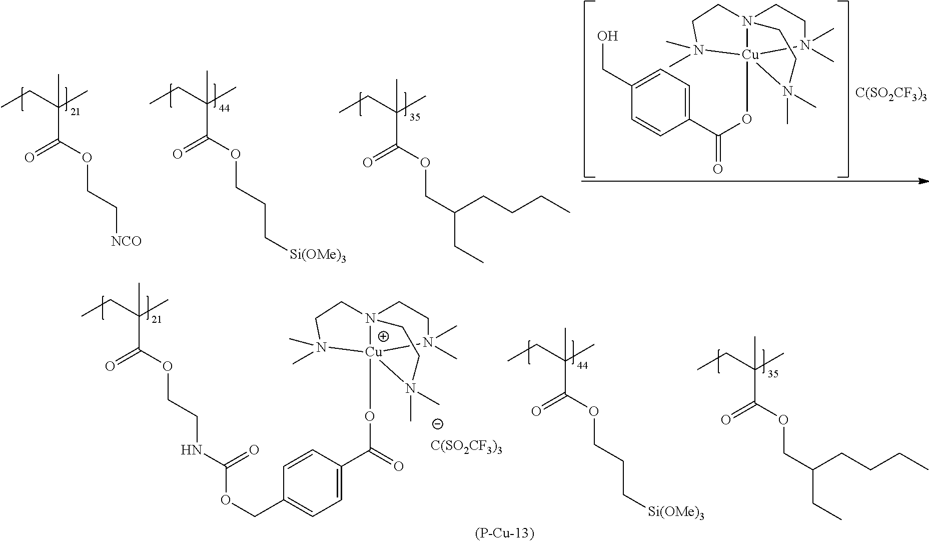

### Synthesis Example 14

A low-molecular-weight copper complex was synthesized using the same method as in Synthesis Example 1, except that lithium N,N-Hexafluoropropane-1,3-bis(sulfonyl)imide was used instead of lithium tetrakis(pentafluorophenyl)borate. Using the low-molecular-weight copper complex synthesized as described above, a copper-containing polymer (P—Cu-14) was synthesized according to the following same synthesis scheme as that of (P—Cu-1). The weight-average molecular weight of the material polymer was 23830. 10 mass % or higher of the copper-containing polymer (P—Cu-14) was dissolved in cyclohexanone at 25° C.

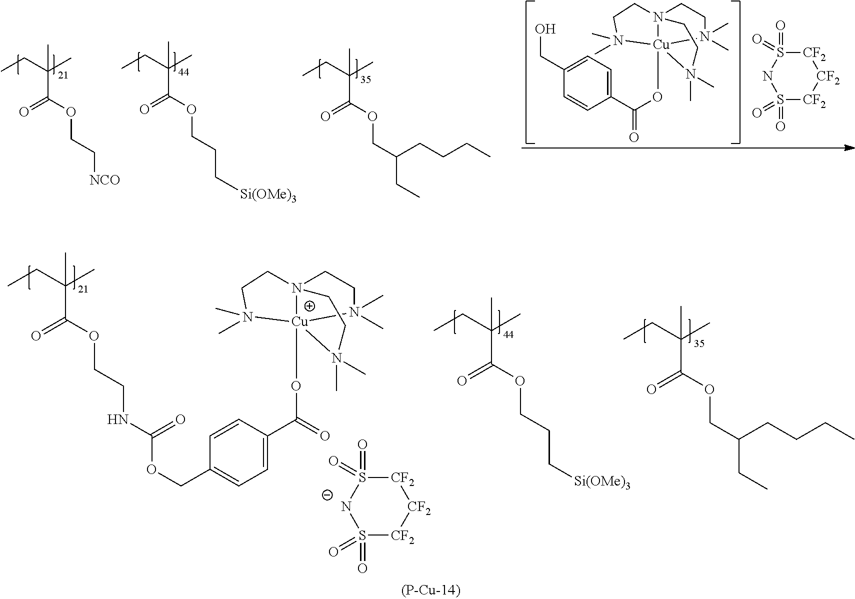

### Synthesis Example 15

A low-molecular-weight copper complex was synthesized using the same method as in Synthesis Example 1, except that dimethylacrylamide was used instead of 2-ethylhexyl methacrylate. Using the low-molecular-weight copper complex synthesized as described above, a copper-containing polymer (P—Cu-15) was synthesized according to the following same synthesis scheme as that of (P—Cu-1). The weight-average molecular weight of the material polymer was 18260. 10 mass % or higher of the copper-containing polymer (P—Cu-15) was dissolved in cyclohexanone at 25° C.

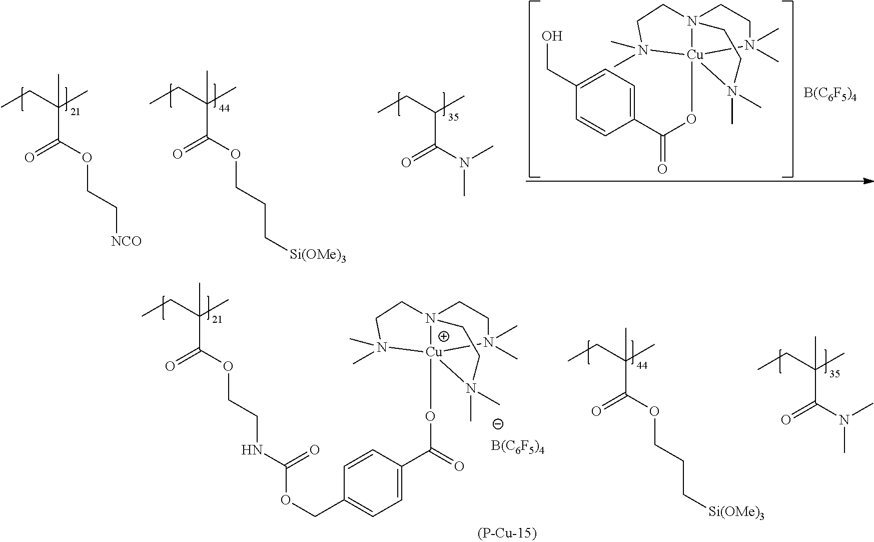

### Synthesis Example 16

A low-molecular-weight copper complex was synthesized using the same method as in Synthesis Example 1, except a portion of dimethylacrylamide was changed to phenylmaleimide. Using the low-molecular-weight copper complex synthesized as described above, a copper-containing polymer (P—Cu-16) was synthesized according to the following same synthesis scheme as that of (P—Cu-15). The weight-average molecular weight of the material polymer was 23110. 10 mass % or higher of the copper-containing polymer (P—Cu-16) was dissolved in cyclohexanone at 25° C.

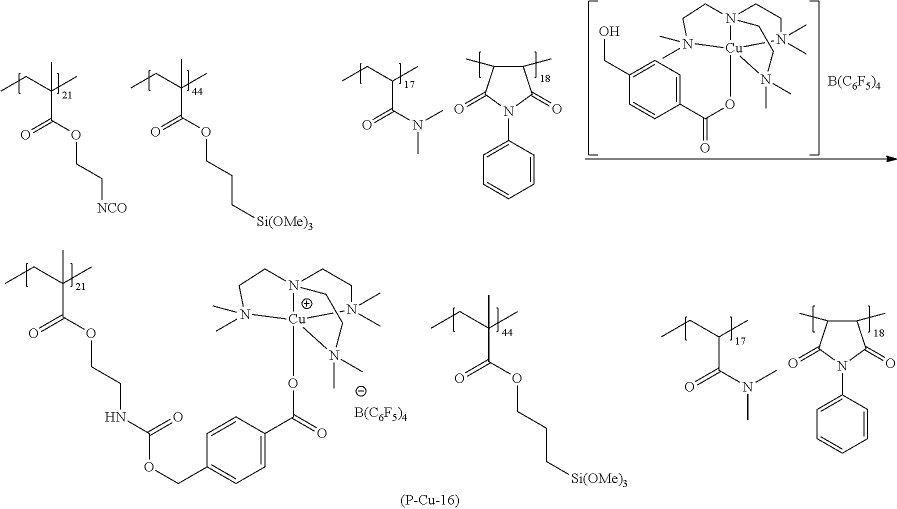

### Synthesis Example 17

A low-molecular-weight copper complex was synthesized using the same method as in Synthesis Example 1, except cyclohexylmaleimide was instead of phenylmaleimide. Using the low-molecular-weight copper complex synthesized as described above, a copper-containing polymer (P—Cu-17) was synthesized according to the following same synthesis scheme as that of (P—Cu-16). The weight-average molecular weight of the material polymer was 19820. 10 mass % or higher of the copper-containing polymer (P—Cu-17) was dissolved in cyclohexanone at 25° C.

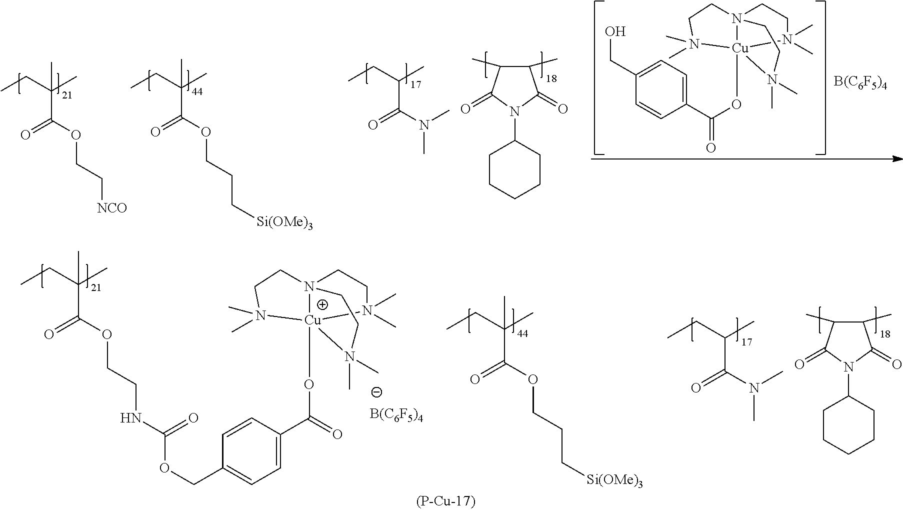

### Synthesis Example 18

A low-molecular-weight copper complex was synthesized using the same method as in Synthesis Example 1, except that phenylmaleimide was used instead of 2-ethylhexyl methacrylate. Using the low-molecular-weight copper complex synthesized as described above, a copper-containing polymer (P—Cu-18) was synthesized according to the following same synthesis scheme as that of (P—Cu-1). The weight-average molecular weight of the material polymer was 25200. 10 mass % or higher of the copper-containing polymer (P—Cu-18) was dissolved in cyclohexanone at 25° C.

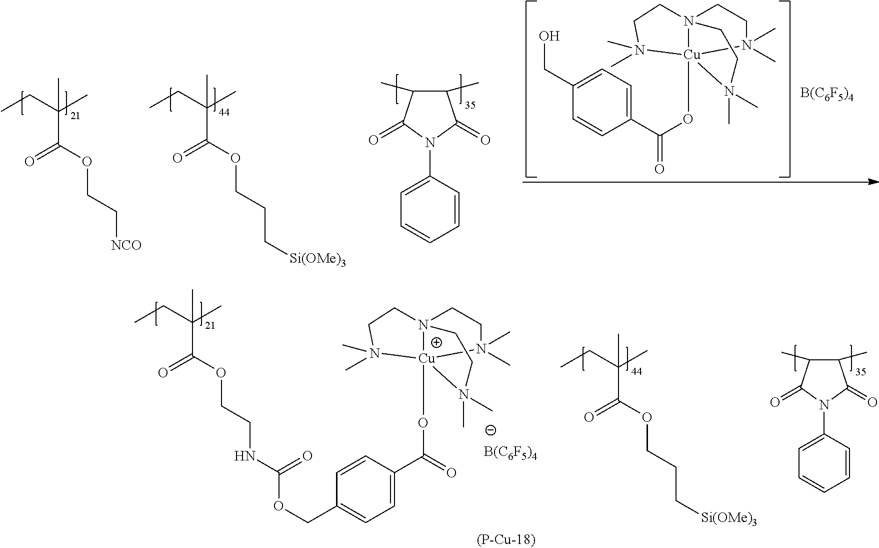

### Synthesis Example 19

A low-molecular-weight copper complex was synthesized using the same method as in Synthesis Example 1, except that 2-hydroxyethyl methacrylate was used instead of 2-isocyanatoethyl methacrylate. Using the low-molecular-weight copper complex synthesized as described above, a copper-containing polymer (P—Cu-19) was synthesized according to the following same synthesis scheme as that of (P—Cu-18). The weight-average molecular weight of the material polymer was 19960. 10 mass % or higher of the copper-containing polymer (P—Cu-19) was dissolved in cyclohexanone at 25° C.

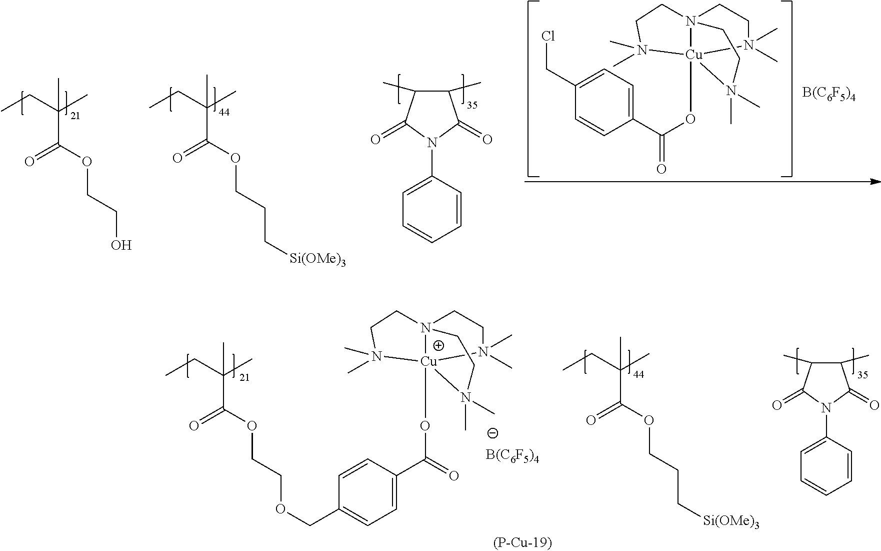

### Synthesis Example 20

A low-molecular-weight copper complex was synthesized using the same method as in Synthesis Example 1, except that 3-(dimethoxymethylsilyl)propyl methacrylate was used instead of 3-(trimethoxysilyl)propyl methacrylate. Using the low-molecular-weight copper complex synthesized as described above, a copper-containing polymer (P—Cu-20) was synthesized according to the following same synthesis scheme as that of (P—Cu-1). The weight-average molecular weight of the material polymer was 17000. 10 mass % or higher of the copper-containing polymer (P—Cu-20) was dissolved in cyclohexanone at 25° C.

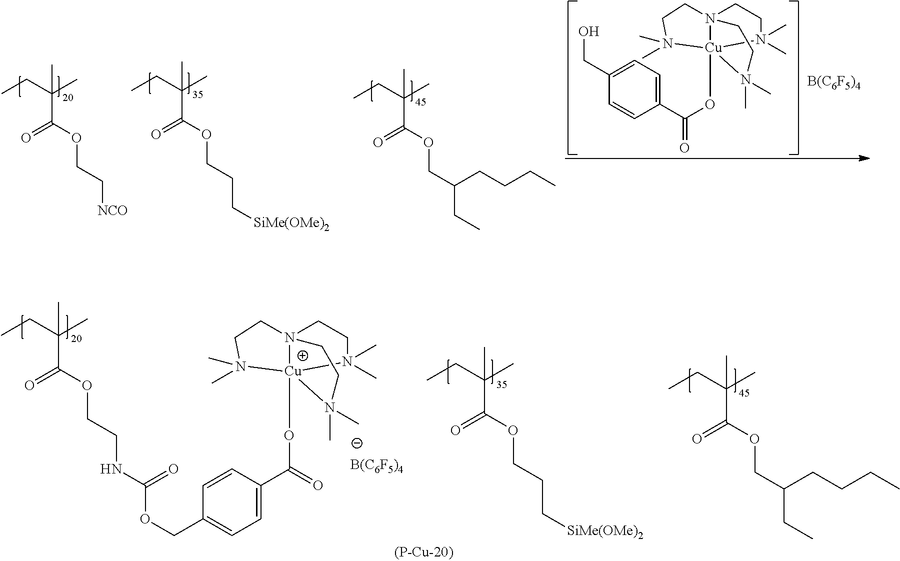

### Synthesis Example 21

A low-molecular-weight copper complex was synthesized using the same method as in Synthesis Example 1, except that diethylacrylamide was used instead of 2-ethylhexyl methacrylate. Using the low-molecular-weight copper complex synthesized as described above, a copper-containing polymer (P—Cu-21) was synthesized according to the following same synthesis scheme as that of (P—Cu-20). The weight-average molecular weight of the material polymer was 19000. 10 mass % or higher of the copper-containing polymer (P—Cu-21) was dissolved in cyclohexanone at 25° C.

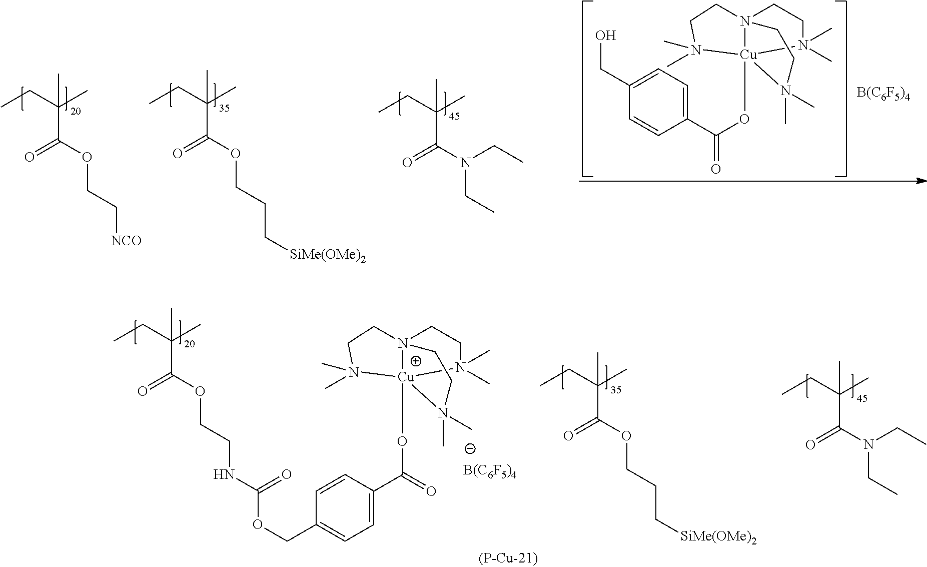

### Synthesis Example 22

A low-molecular-weight copper complex was synthesized using the same method as in Synthesis Example 1, except that dimethylacrylamide was used instead of 2-ethylhexyl methacrylate. Using the low-molecular-weight copper complex synthesized as described above, a copper-containing polymer (P—Cu-22) was synthesized according to the following same synthesis scheme as that of (P—Cu-20). The weight-average molecular weight of the material polymer was 18000. 10 mass % or higher of the copper-containing polymer (P—Cu-22) was dissolved in cyclohexanone at 25° C.

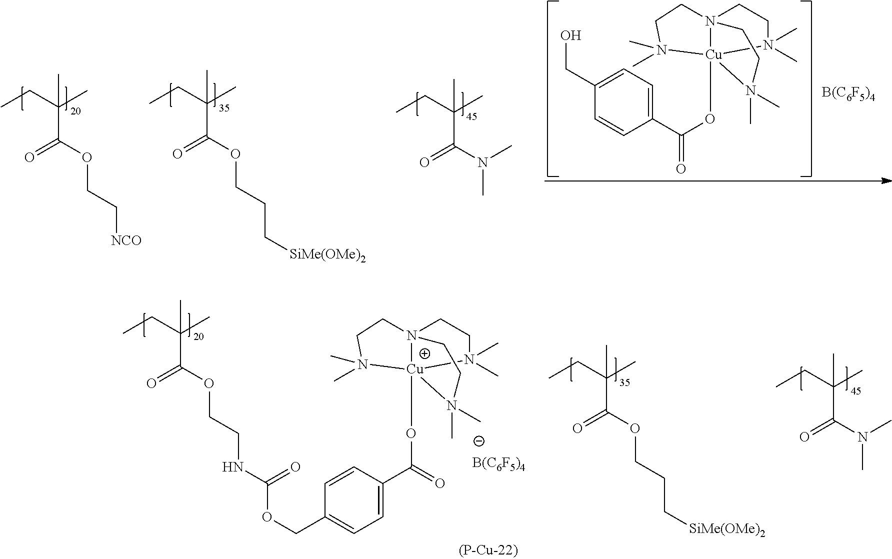

### Synthesis Example 23

A low-molecular-weight copper complex was synthesized using the same method as in Synthesis Example 1, except that phenylmaleimide was used instead of 2-ethylhexyl methacrylate. Using the low-molecular-weight copper complex synthesized as described above, a copper-containing polymer (P—Cu-23) was synthesized according to the following same synthesis scheme as that of (P—Cu-20). The weight-average molecular weight of the material polymer was 21000. 10 mass % or higher of the copper-containing polymer (P—Cu-23) was dissolved in cyclohexanone at 25° C.

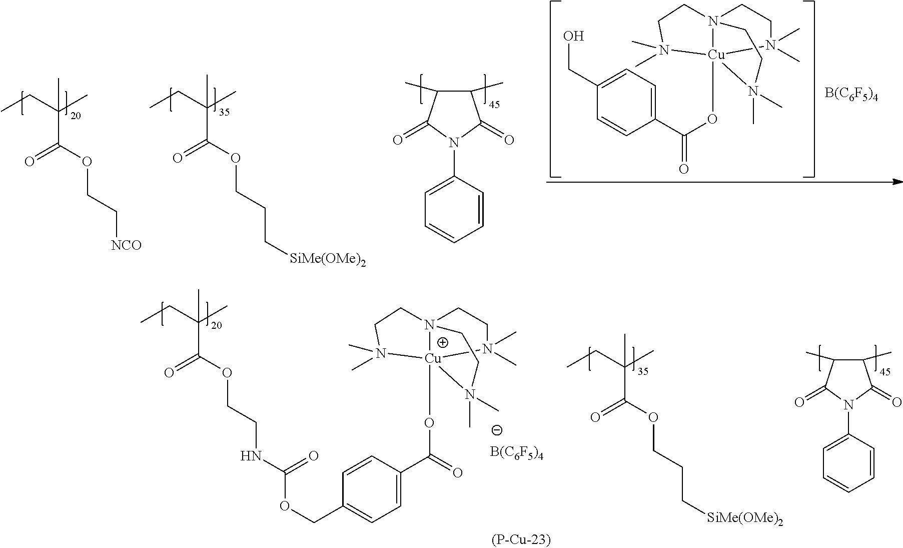

### Synthesis Example 24

A low-molecular-weight copper complex was synthesized using the same method as in Synthesis Example 1, except a portion of phenylmaleimide was changed to dimethylacrylamide. Using the low-molecular-weight copper complex synthesized as described above, a copper-containing polymer (P—Cu-24) was synthesized according to the following same synthesis scheme as that of (P—Cu-23). The weight-average molecular weight of the material polymer was 21000. 10 mass % or higher of the copper-containing polymer (P—Cu-24) was dissolved in cyclohexanone at 25° C.

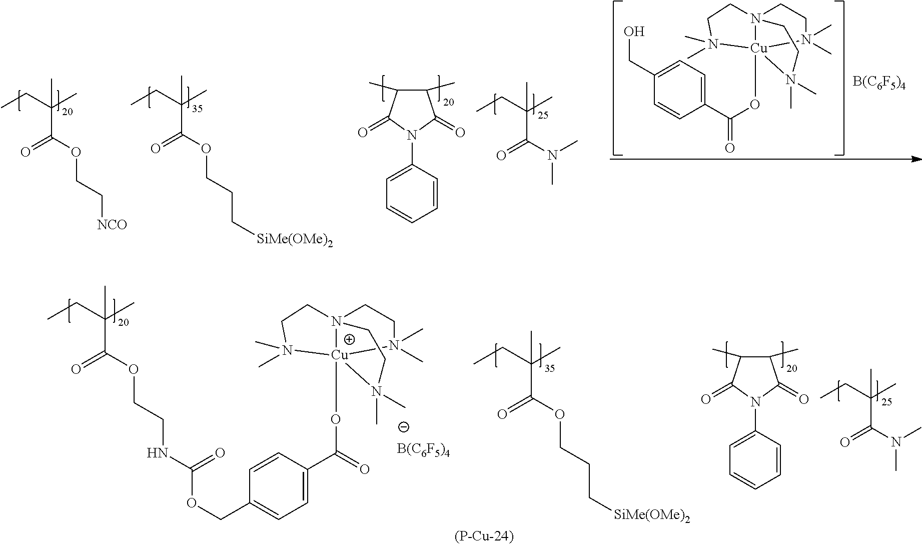

<Manufacturing of Near Infrared Cut Filter>

### Example 1

94.9 parts by mass (with respect to the solid content of the polymer) of the copper-containing polymer synthesized in Synthesis Example 1, 5 parts by mass of IRGACURE-OXE01 (manufactured by BASF SE), 0.1 parts by mass of aluminum tris(2,4-pentanedionate) (manufactured by Tokyo Chemical Industry Co., Ltd.), 66.7 parts by mass of cyclohexanone, and 0.5 parts by mass of water were mixed with each other to prepare a near infrared absorbing composition. The obtained near infrared absorbing composition was applied to a glass wafer using a spin coater such that the thickness of the dried coating film was 100 μm, and then was heated using a hot plate at 150° C. for 3 hours. As a result, a near infrared cut filter was manufactured.

### Examples 2 to 19

Near infrared absorbing compositions were prepared using the same method as in Example 1, except that copper-containing polymers synthesized in Synthesis Examples 2 to 19, respectively. Near infrared cut filters were manufactured using the same method as in Example 1, except that the obtained near infrared absorbing compositions were used, respectively.

### Example 20

A near infrared cut filter was manufactured using the same method as in Example 1, except that IRGACURE-OXEO2 (manufactured by BASF SE) was used instead of IRGACURE-OXE01 (manufactured by BASF SE).

### Example 21

A near infrared cut filter was manufactured using the same method as in Example 1, except that ADEKA ARKLS NCI-930 (manufactured by Adeka Corporation) was used instead of IRGACURE-OXE01 (manufactured by BASF SE).

### Examples 22 to 26

Near infrared absorbing compositions were prepared using the same method as in Example 1, except that copper-containing polymers synthesized in Synthesis Examples 20 to 24, respectively. Near infrared cut filters were manufactured using the same method as in Example 1, except that the obtained near infrared absorbing compositions were used, respectively.

### Example 27

90 parts by mass (with respect to the solid content of the polymer) of the copper-containing polymer synthesized in Synthesis Example 1, 4.9 parts by mass of a copper complex 1 (the following structure), 5 parts by mass of IRGACURE-OXE01 (manufactured by BASF SE), 0.1 parts by mass of aluminum tris(2,4-pentanedionate) (manufactured by Tokyo Chemical Industry Co., Ltd.), 66.7 parts by mass of cyclohexanone, and 0.5 parts by mass of water were mixed with each other to prepare a near infrared absorbing composition. The obtained near infrared absorbing composition was applied to a glass wafer using a spin coater such that the thickness of the dried coating film was 100 μm, and then was heated using a hot plate at 150° C. for 3 hours. As a result, a near infrared cut filter was manufactured.

Copper Complex 1: The Following Structure

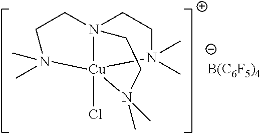

### Example 28

A near infrared absorbing composition was prepared using the same method as in Example 27, except that 4.9 parts by mass of a copper complex 2 (the following structure) was used instead of 4.9 parts by mass of the copper complex 1. Near infrared cut filters were manufactured using the same method as in Example 27, except that the obtained near infrared absorbing compositions were used, respectively.

Copper Complex 2: The Following Structure

### Example 29

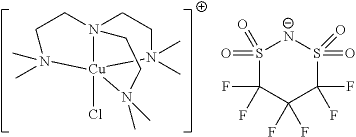

A near infrared absorbing composition was prepared using the same method as in Example 27, except that 2.4 parts by mass of the copper complex 1 and 2.5 parts by mass of the copper complex 2 were used instead of 4.9 parts by mass of the copper complex 1. Near infrared cut filters were manufactured using the same method as in Example 27, except that the obtained near infrared absorbing compositions were used, respectively.

### Example 30

80 parts by mass (with respect to the solid content of the polymer) of the copper-containing polymer synthesized in Synthesis Example 1, 2.9 parts by mass of the copper complex 1, 3.0 parts by mass of the copper complex 2, 9.0 parts by mass of KBM-3066 (manufactured by Shin-Etsu Chemical Co., Ltd.), 5 parts by mass of IRGACURE-OXE01 (manufactured by BASF SE), 0.1 parts by mass of aluminum tris(2,4-pentanedionate) (manufactured by Tokyo Chemical Industry Co., Ltd.), 66.7 parts by mass of cyclohexanone, and 0.5 parts by mass of water were mixed with each other to prepare a near infrared absorbing composition. The obtained near infrared absorbing composition was applied to a glass wafer using a spin coater such that the thickness of the dried coating film was 100 μm, and then was heated using a hot plate at 150° C. for 3 hours. As a result, a near infrared cut filter was manufactured.

### Example 31

A near infrared absorbing composition was prepared using the same method as in Example 30, except that 9.0 parts by mass of a resin 1 (the following structure) was used instead of 9.0 parts by mass of KBM-3066 (manufactured by Shin-Etsu Chemical Co., Ltd.). A near infrared cut filter was manufactured using the same method as in Example 30, except that the obtained near infrared absorbing composition was used.

Resin 1: the following structure (Mw=15000, numerical values added to a main chain represent a molar ratio between the respective constitutional units)

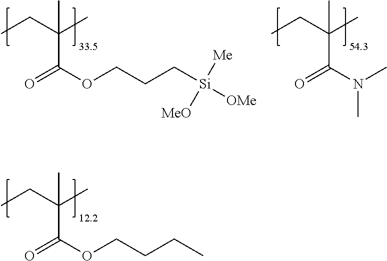

### Example 32

70 parts by mass (with respect to the solid content of the polymer) of the copper-containing polymer synthesized in Synthesis Example 1, 4.9 parts by mass of the copper complex 1, 5.0 parts by mass of the copper complex 2, 6.0 parts by mass of KBM-3066 (manufactured by Shin-Etsu Chemical Co., Ltd.), 9 parts by mass of the resin 1, 5 parts by mass of IRGACURE-OXE01 (manufactured by BASF SE), 0.1 parts by mass of aluminum tris(2,4-pentanedionate) (manufactured by Tokyo Chemical Industry Co., Ltd.), 66.7 parts by mass of cyclohexanone, and 0.5 parts by mass of water were mixed with each other to prepare a near infrared absorbing composition. The obtained near infrared absorbing composition was applied to a glass wafer using a spin coater such that the thickness of the dried coating film was 100 μm, and then was heated using a hot plate at 150° C. for 3 hours. As a result, a near infrared cut filter was manufactured.

### Comparative Example 1

A near infrared cut filter was manufactured using a method described in Example 1 of JP2010-134457A.

<<Evaluation of Heat Resistance>>

Each of the near infrared cut filters obtained as described above was left to stand at 180° C. for 1 minute. Before and after the heat resistance test, the absorbance of the near infrared cut filter at a wavelength of 400 nm and the absorbance of the near infrared cut filter at a wavelength of 800 nm were measured, and a change rate of the absorbance at each of the wavelengths was obtained from the following expression. In order to measure the absorbance, a spectrophotometer U-4100 (manufactured by Hitachi High-Technologies Corporation) was used.

Change Rate (%) of Absorbance at Wavelength of 400 nm=|(Absorbance at Wavelength of 400 nm before Test-Absorbance at Wavelength of 400 nm after Test)/Absorbance at Wavelength of 400 nm before Test×100(%)

Change Rate (%) of Absorbance at Wavelength of 800 nm=|(Absorbance at Wavelength of 800 nm before Test-Absorbance at Wavelength of 800 nm after Test)/Absorbance at Wavelength of 800 nm before Test|×100(%)

The heat resistance at each of the wavelengths was evaluated based on the following standards.

A: Change Rate of Absorbance≤3%

B: 3%<Change Rate of Absorbance≤6%

C: 6%<Change Rate of Absorbance

<<Evaluation of Solvent Resistance>>

Each of the near infrared cut filters obtained as described above was dipped in methyl propylene glycol (MFG) at 25° C. for 2 minutes. Before and after the solvent resistance test, the absorbance of the near infrared cut filter at a wavelength of 800 nm was measured, and a change rate of the absorbance at a wavelength of 800 nm was obtained from the following expression. In order to measure the absorbance, a spectrophotometer U-4100 (manufactured by Hitachi High-Technologies Corporation) was used.

Change Rate (%) of Absorbance at Wavelength of 800 nm=|(Absorbance at Wavelength of 800 nm before Test-Absorbance at Wavelength of 800 nm after Test)/Absorbance at Wavelength of 800 nm before Test|×100(%)

The solvent resistance was evaluated based on the following standards.

A: Change Rate of Absorbance≤3%

B: 3%<Change Rate of Absorbance≤6%

C: 6%<Change Rate of Absorbance

TABLE 1

| | Heat Resistance | | |
|---|---|---|---|
| | 400 nm | 800 nm | Solvent Resistance |
| Example 1 | B | A | A |
| Example 2 | B | A | A |
| Example 3 | B | A | A |
| Example 4 | B | A | A |
| Example 5 | B | A | A |
| Example 6 | B | A | A |
| Example 7 | B | A | A |
| Example 8 | B | A | A |
| Example 9 | B | A | A |
| Example 10 | B | A | A |
| Example 11 | B | A | A |
| Example 12 | B | A | A |
| Example 13 | B | A | A |
| Example 14 | B | A | A |
| Example 15 | B | A | A |
| Example 16 | B | A | A |
| Example 17 | B | A | A |
| Example 18 | B | A | A |
| Example 19 | B | B | A |
| Example 20 | B | A | A |
| Example 21 | B | A | A |
| Example 22 | B | A | A |
| Example 23 | B | A | A |
| Example 24 | B | A | A |
| Example 25 | B | A | A |
| Example 26 | B | A | A |
| Example 27 | B | A | A |
| Example 28 | B | A | A |
| Example 29 | B | A | A |
| Example 30 | B | A | A |
| Example 31 | B | A | A |
| Example 32 | B | A | A |
| Comparative Example 1 | C | C | A |

It was found based on the above results that, in Examples, heat resistance was excellent. Further, solvent resistance was excellent.

On the other hand, in Comparative Example, heat resistance was poor.

Even in a case where each of the compositions according to Examples 1 to 32 was used as a single film peeled from a support, the same effects can be obtained.

### EXPLANATION OF REFERENCES

10: camera module
11: solid image pickup element
12: planarizing layer
13: near infrared cut filter
14: imaging lens
15: lens holder
16: substrate
17: color filter
18: microlens
19: ultraviolet-infrared reflection film
20: transparent substrate
21: near infrared light absorbing layer
22: antireflection layer

What is claimed is:

1. A near infrared absorbing composition comprising:
a copper-containing polymer having a copper complex site at a polymer side chain; and
a solvent,
wherein the copper complex site includes a site multidentate-coordinated to a copper atom and at least one selected from the group consisting of a site monodentate-coordinated to a copper atom and a counter ion to a copper complex skeleton, and
a polymer main chain and a copper atom at the copper complex site are bonded to each other through the site monodentate-coordinated to a copper atom or the counter ion.

2. A near infrared absorbing composition comprising:
a copper-containing polymer having a copper complex site at a polymer side chain; and
a solvent,
wherein the copper-containing polymer includes a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond between a polymer main chain and the copper complex site,
in a case where the linking group has a —C(═O)O— bond, the linking group has at least one —C(═O)O— bond which is not directly bonded to the polymer main chain, and
in a case where the linking group has a —NH—CO— bond, the linking group has at least one —NH—CO— bond which is not directly bonded to the polymer main chain.

3. The near infrared absorbing composition according to claim 1,
wherein the copper-containing polymer includes a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, and a —NH—C(═S)NH— bond between the polymer main chain and the copper complex site.

4. A near infrared absorbing composition comprising:
a copper-containing polymer that is obtained by causing a polymer having a reactive site at a polymer side chain to react with a copper complex having a functional group which is reactive with the reactive site of the polymer; and
a solvent.

5. The near infrared absorbing composition according to claim 1,
wherein 10 mass % or higher of the copper-containing polymer is dissolved in cyclohexanone at 25° C.

6. The near infrared absorbing composition according to claim 1,
wherein the number of atoms constituting a chain that links the copper atom and the polymer main chain in the copper-containing polymer is 8 or more.

7. The near infrared absorbing composition according to claim 1, comprising:
a copper-containing polymer having a group represented by the following Formula (1) at a polymer side chain,
*-L¹-Y¹ (1),
wherein in Formula (1), L¹ represents a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond,
Y¹ represents a copper complex site,
represents a direct bond to the polymer,
in a case where L¹ has a —C(═O)O— bond, L¹ has at least one —C(═O)O— bond which is not directly bonded to the polymer main chain, and
in a case where L¹ has a —NH—CO— bond, L¹ has at least one —NH—CO— bond which is not directly bonded to the polymer main chain.

8. The near infrared absorbing composition according to claim 1,
wherein the copper-containing polymer includes a constitutional unit represented by the following Formula (A1-1), 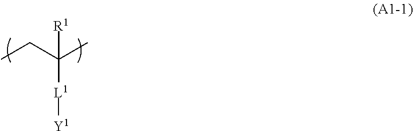
in Formula (A1-1), R¹ represents a hydrogen atom or a hydrocarbon group,
L¹ represents a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond,
Y¹ represents a copper complex site,
in a case where L¹ has a —C(═O)O— bond, L¹ has at least one —C(═O)O— bond which is not directly bonded to the polymer main chain, and
in a case where L¹ has a —NH—CO— bond, L¹ has at least one —NH—CO— bond which is not directly bonded to the polymer main chain.

9. The near infrared absorbing composition according to claim 1,
wherein the copper-containing polymer includes constitutional units represented by the following Formulae (A1-1-1), (A1-1-2), or (A1-1-3), 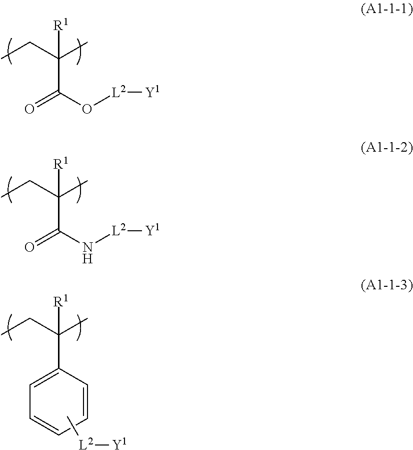
in Formulae (A1-1-1) to (A1-1-3), R¹ represents a hydrogen atom or a hydrocarbon group,
L² represents a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond, and
Y¹ represents a copper complex site.

10. The near infrared absorbing composition according to any one of claim 1,
wherein the copper-containing polymer includes a site tetradentate- or pentadentate-coordinated to a copper atom.

11. The near infrared absorbing composition according to claim 1, which is a composition for forming a near infrared cut filter.

12. A near infrared cut filter which is formed using the near infrared absorbing composition according to claim 1.

13. A method of manufacturing a near infrared cut filter,
wherein the near infrared absorbing composition according to claim 1 is used.

14. A device comprising:
the near infrared cut filter according to claim 12,
wherein the device is at least one selected from the group consisting of a solid image pickup element, a camera module, and an image display device.

15. A method of manufacturing a copper-containing polymer comprising:
causing a polymer having a reactive site at a polymer side chain to react with a copper complex having a functional group which is reactive with the reactive site of the polymer.

16. A copper-containing polymer having a copper complex site at a polymer side chain,
wherein the copper complex site includes a site multidentate-coordinated to a copper atom and at least one selected from the group consisting of a site monodentate-coordinated to a copper atom and a counter ion to a copper complex skeleton, and
a polymer main chain and a copper atom at the copper complex site are bonded to each other through the site monodentate-coordinated to a copper atom or the counter ion.

17. A copper-containing polymer having a copper complex site at a polymer side chain,
wherein the copper-containing polymer includes a linking group having at least one bond selected from the group consisting of a —NH—C(═O)O— bond, a —NH—C(═O)S— bond, a —NH—C(═O)NH— bond, a —NH—C(═S)O— bond, a —NH—C(═S)S— bond, a —NH—C(═S)NH— bond, a —C(═O)O— bond, a —C(═O)S— bond, and a —NH—CO— bond between a polymer main chain and the copper complex site,
in a case where the linking group has a —C(═O)O— bond, the linking group has at least one —C(═O)O— bond which is not directly bonded to the polymer main chain, and
in a case where the linking group has a —NH—CO— bond, the linking group has at least one —NH—CO— bond which is not directly bonded to the polymer main chain.

18. A copper-containing polymer that is obtained by causing a polymer having a reactive site at a polymer side chain to react with a copper complex having a functional group which is reactive with the reactive site of the polymer.
